(19) United States
(12) Patent Application Publication
(10) Pub. No.: US 2025/0185501 A1
(43) Pub. Date: Jun. 5, 2025

(54) LIGHT-EMITTING DEVICE

(71) Applicant: SEMICONDUCTOR ENERGY LABORATORY CO., LTD., Atsugi-shi (JP)

(72) Inventors: Satoshi SEO, Sagamihara (JP); Nobuharu OHSAWA, Zama (JP); Hiromitsu KIDO, Atsugi (JP); Yui YOSHIYASU, Atsugi (JP); Satoko NUMATA, Atsugi (JP); Eriko AOYAMA, Atsugi (JP); Anna TADA, Isehara (JP)

(21) Appl. No.: 18/953,278

(22) Filed: Nov. 20, 2024

(30) Foreign Application Priority Data
Nov. 30, 2023 (JP) 2023-203482

(51) Int. Cl. H10K 85/40; C09K 11/02; H10K 50/12; H10K 85/60; H10K 101/25

(52) U.S. Cl. CPC H10K 85/40; C09K 11/02; H10K 85/626; H10K 85/633; H10K 85/636; H10K 85/657; H10K 85/6572; H10K 85/6576; H10K 50/12; H10K 85/615; H10K 85/6574; H10K 2101/25

(57) ABSTRACT

A highly reliable light-emitting device is provided. The light-emitting device includes a first electrode, a second electrode, and a light-emitting layer. The light-emitting layer is positioned between the first electrode and the second electrode. The light-emitting layer includes a first organic compound, a second organic compound, and a substance that can convert triplet excitation energy into light emission. The first organic compound includes a π-electron deficient heteroaromatic ring. The second organic compound includes a π-electron rich heteroaromatic ring or an aromatic amine skeleton. The first organic compound and the second organic compound each contain deuterium. A difference between the lowest triplet excitation level of the first organic compound and that of the second organic compound is less than or equal to 0.10 eV.

### BACKGROUND OF THE INVENTION

### 1. Field of the Invention

One embodiment of the present invention relates to an organic compound, an organic semiconductor element, a light-emitting device, a photodiode sensor, a display module, a lighting module, a display apparatus, an electronic appliance, a lighting device, and an electronic device. Note that one embodiment of the present invention is not limited to the above technical field. The technical field of one embodiment of the invention disclosed in this specification and the like relates to an object, a method, or a manufacturing method. One embodiment of the present invention relates to a process, a machine, manufacture, or a composition of matter. Specifically, examples of the technical field of one embodiment of the present invention disclosed in this specification include a semiconductor device, a display apparatus, a liquid crystal display apparatus, a lighting device, a power storage device, a memory device, an image capturing device, a driving method thereof, and a manufacturing method thereof.

### 2. Description of the Related Art

Light-emitting devices (also referred to as organic EL elements) including organic compounds and utilizing electroluminescence (EL) have been put into more practical use. In the basic structure of such light-emitting devices, an organic compound layer containing a light-emitting material is interposed between a pair of electrodes. Carriers are injected by application of a voltage to the device, and recombination energy of the carriers is used to obtain light emission from the light-emitting material.

Since such light-emitting devices are of self-luminous type, display apparatuses in which the light-emitting devices are used for pixels have higher visibility than liquid crystal display apparatuses and do not need a backlight. Display apparatuses including such light-emitting devices are also highly advantageous in that they can be thin and lightweight. Another feature of such light-emitting devices is that they have an extremely high response speed.

Since a continuous planar light-emitting layer can be formed for such light-emitting devices, planar light emission can be achieved. This feature is difficult to realize with point light sources typified by incandescent lamps and LEDs or linear light sources typified by fluorescent lamps; thus, the light-emitting devices also have great potential as planar light sources, which can be used for lighting devices and the like.

Display apparatuses or lighting devices that include light-emitting devices are suitable for a variety of electronic appliances as described above, and research and development of light-emitting devices have progressed for better characteristics.

Patent Document 1 discloses a light-emitting device whose reliability is improved by delaying a decomposition mechanism that causes deterioration of a metal complex, with use of a deuterated host in combination with the metal complex.

### REFERENCE

[Patent Document 1] Japanese Published Patent Application No. 2022-132158

### SUMMARY OF THE INVENTION

An object of one embodiment of the present invention is to provide a light-emitting device with favorable characteristics. Another object of one embodiment of the present invention is to provide a highly reliable light-emitting device. Another object of one embodiment of the present invention is to provide a light-emitting device having a low driving voltage. Another object of one embodiment of the present invention is to provide a highly reliable light-emitting device having a low driving voltage.

Another object of one embodiment of the present invention is to provide a light-emitting device that can achieve a display apparatus with favorable characteristics. Another object of one embodiment of the present invention is to provide a light-emitting device that can achieve a highly reliable display apparatus. Another object of one embodiment of the present invention is to provide a display apparatus having a low driving voltage. Another object of one embodiment of the present invention is to provide a light-emitting device that can achieve a highly reliable display apparatus having a low driving voltage. Another object of one embodiment of the present invention is to provide an organic compound suitable for any of the light-emitting devices.

Another object is to provide any of a low-power-consumption organic semiconductor device, a low-power-consumption light-emitting device, a low-power-consumption light-receiving device, a low-power-consumption display apparatus, a low-power-consumption electronic appliance, and a low-power-consumption lighting device. Another object is to provide any of a highly reliable display apparatus, a highly reliable electronic appliance, and a highly reliable lighting device.

It is only necessary that at least one of the above-described objects be achieved in the present invention.

One embodiment of the present invention is a light-emitting device including a first electrode, a second electrode, and a light-emitting layer. The light-emitting layer is positioned between the first electrode and the second electrode. The light-emitting layer includes a first organic compound, a second organic compound, and a substance that can convert triplet excitation energy into light emission. The first organic compound includes a π-electron deficient heteroaromatic ring. The second organic compound includes a π-electron rich heteroaromatic ring or an aromatic amine skeleton. The first organic compound and the second organic compound each contain deuterium. A difference between the lowest triplet excitation level of the first organic compound and the lowest triplet excitation level of the second organic compound is less than or equal to 0.20 eV.

Another embodiment of the present invention is a light-emitting device including a first electrode, a second electrode, and a light-emitting layer. The light-emitting layer is positioned between the first electrode and the second electrode. The light-emitting layer includes a first organic compound, a second organic compound, and a substance that can convert triplet excitation energy into light emission. The first organic compound includes a π-electron deficient heteroaromatic ring. The second organic compound includes a π-electron rich heteroaromatic ring or an aromatic amine skeleton. The first organic compound and the second organic compound each contain deuterium. A combination of the first organic compound and the second organic compound forms an exciplex. An emission spectrum of the exciplex and an emission spectrum of the substance that can convert triplet excitation energy into light emission overlap with each other.

Another embodiment of the present invention is the light-emitting device having the above structure, in which a difference between the maximum peak wavelength in the emission spectrum of the exciplex and the maximum peak wavelength in the emission spectrum of the substance that can convert triplet excitation energy into light emission is less than or equal to 30 nm.

Another embodiment of the present invention is a light-emitting device including a first electrode, a second electrode, and a light-emitting layer. The light-emitting layer is positioned between the first electrode and the second electrode. The light-emitting layer includes a first organic compound, a second organic compound, and a substance that can convert triplet excitation energy into light emission. The first organic compound includes a π-electron deficient heteroaromatic ring. The second organic compound includes a π-electron rich heteroaromatic ring or an aromatic amine skeleton. The first organic compound and the second organic compound each contain deuterium. A phosphorescence lifetime or a delayed fluorescence lifetime at 77 K of the first organic compound is 1.20 times or more a phosphorescence lifetime or a delayed fluorescence lifetime at 77 K of a third organic compound that is a non-deuterated substance of the first organic compound. A phosphorescence lifetime or a delayed fluorescence lifetime at 77 K of the second organic compound is 1.05 times or more a phosphorescence lifetime or a delayed fluorescence lifetime at 77 K of a fourth organic compound that is a non-deuterated substance of the second organic compound.

Another embodiment of the present invention is the light-emitting device having the above structure, in which an emission spectrum of the substance that can convert triplet excitation energy into light emission has a peak wavelength greater than or equal to 450 nm and less than 500 nm. Another embodiment of the present invention is the light-emitting device having the above structure, in which the emission spectrum of the substance that can convert triplet excitation energy into light emission has a peak wavelength greater than 600 nm and less than or equal to 700 nm.

Another embodiment of the present invention is a light-emitting device including a first electrode, a second electrode, and a light-emitting layer. The light-emitting layer is positioned between the first electrode and the second electrode. The light-emitting layer includes a first organic compound, a second organic compound, and a substance that can convert triplet excitation energy into light emission. The first organic compound includes a π-electron deficient heteroaromatic ring. The second organic compound includes a π-electron rich heteroaromatic ring or an aromatic amine skeleton. The first organic compound and the second organic compound each contain deuterium. A phosphorescence lifetime or a delayed fluorescence lifetime at 77 K of the first organic compound is 1.50 times or more a phosphorescence lifetime or a delayed fluorescence lifetime at 77 K of a third organic compound that is a non-deuterated organic compound of the first organic compound. A phosphorescence lifetime or a delayed fluorescence lifetime at 77 K of the second organic compound is 3.00 times or more a phosphorescence lifetime or a delayed fluorescence lifetime at 77 K of a fourth organic compound that is a non-deuterated organic compound of the second organic compound.

Another embodiment of the present invention is the light-emitting device having the above structure, an emission spectrum of the substance that can convert triplet excitation energy into light emission has a peak wavelength greater than or equal to 500 nm and less than or equal to 600 nm.

Another embodiment of the present invention is a light-emitting device including a first electrode, a second electrode, and a light-emitting layer. The light-emitting layer is positioned between the first electrode and the second electrode. The light-emitting layer includes a first organic compound, a second organic compound, and a substance that can convert triplet excitation energy into light emission. The first organic compound includes a π-electron deficient heteroaromatic ring. The second organic compound includes a π-electron rich heteroaromatic ring or an aromatic amine skeleton. The first organic compound and the second organic compound each contain deuterium. In the case where a phosphorescence lifetime or a delayed fluorescence lifetime at 77 K of the first organic compound is X times a phosphorescence lifetime or a delayed fluorescence lifetime at 77 K of a third organic compound that is a non-deuterated substance of the first organic compound and a phosphorescence lifetime or a delayed fluorescence lifetime at 77 K of the second organic compound is Y times a phosphorescence lifetime or a delayed fluorescence lifetime at 77 K of a fourth organic compound that is a non-deuterated substance of the second organic compound, a product of X and Y is greater than or equal to 1.26.

Another embodiment of the present invention is a light-emitting device including a first electrode, a second electrode, and a light-emitting layer. The light-emitting layer is positioned between the first electrode and the second electrode. The light-emitting layer includes a first organic compound, a second organic compound, and a substance that can convert triplet excitation energy into light emission. A peak wavelength of light emitted by the substance that can convert triplet excitation energy into light emission is greater than or equal to 500 nm and less than or equal to 600 nm. The first organic compound includes a π-electron deficient heteroaromatic ring. The second organic compound includes a π-electron rich heteroaromatic ring or an aromatic amine skeleton. The first organic compound and the second organic compound each contain deuterium. In the case where a phosphorescence lifetime or a delayed fluorescence lifetime at 77 K of the first organic compound is X times a phosphorescence lifetime or a delayed fluorescence lifetime at 77 K of a third organic compound that is a non-deuterated substance of the first organic compound and a phosphorescence lifetime or a delayed fluorescence lifetime at 77 K of the second organic compound is Y times a phosphorescence lifetime or a delayed fluorescence lifetime at 77 K of a fourth organic compound that is a non-deuterated substance of the second organic compound, a product of X and Y is greater than or equal to 4.50.

Another embodiment of the present invention is a light-emitting device including a first electrode, a second electrode, and a light-emitting layer. The light-emitting layer is positioned between the first electrode and the second electrode. The light-emitting layer includes a first organic compound, a second organic compound, and a substance that can convert triplet excitation energy into light emission. The first organic compound includes a π-electron deficient heteroaromatic ring. The second organic compound includes a π-electron rich heteroaromatic ring or an aromatic amine skeleton. The first organic compound and the second organic compound each contain deuterium. A difference between a 5% weight loss temperature of the first organic compound at 10 Pa and a 5% weight loss temperature of the second organic compound at 10 Pa is less than or equal to 60° C.

Another embodiment of the present invention is the light-emitting device having the above structure, in which the substance that can convert triplet excitation energy into light emission is a phosphorescent substance.

Another embodiment of the present invention is the light-emitting device having the above structure, in which a combination of the first organic compound and the second organic compound forms an exciplex.

Another embodiment of the present invention is the light-emitting device having the above structure, in which the first organic compound includes a diazine skeleton or a triazine skeleton and the second organic compound includes a bicarbazole skeleton.

Another embodiment of the present invention is the light-emitting device having the above structure, in which the substance that can convert triplet excitation energy into light emission contains deuterium.

Another embodiment of the present invention is the light-emitting device having the above structure further including a first layer. The first layer is positioned between the light-emitting layer and the first electrode. The first layer includes a fifth organic compound. The fifth organic compound includes a π-electron rich heteroaromatic ring or an aromatic amine skeleton and deuterium.

Another embodiment of the present invention is the light-emitting device having the above structure further including a first layer. The first layer is positioned between the light-emitting layer and the first electrode. The first layer includes a fifth organic compound. The fifth organic compound includes a π-electron rich heteroaromatic ring or an aromatic amine skeleton and deuterium. A difference between the lowest triplet excitation level of the first organic compound and the lowest triplet excitation level of the fifth organic compound is less than or equal to 0.10 eV.

Another embodiment of the present invention is the light-emitting device having the above structure, in which the fifth organic compound is the same as the second organic compound.

Another embodiment of the present invention is a display apparatus including any of the above light-emitting devices.

Another embodiment of the present invention is an electronic appliance including any of the above light-emitting devices and a sensor, an operation button, a speaker, or a microphone. Another embodiment of the present invention is a lighting device including any of the above light-emitting devices and a housing.

Another embodiment of the present invention is an organic compound represented by a formula below.

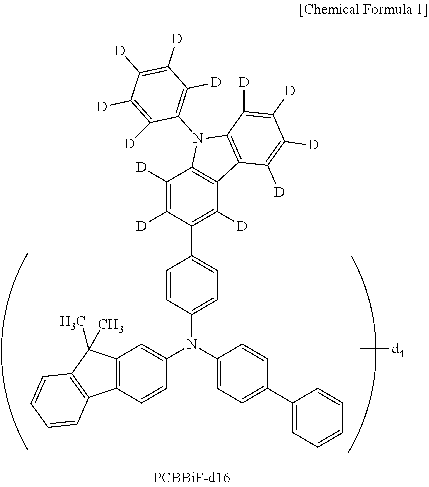

According to one embodiment of the present invention, a light-emitting device having high emission efficiency can be provided. According to another embodiment of the present invention, a highly reliable light-emitting device can be provided. According to another embodiment of the present invention, any of a low-power-consumption display apparatus, a low-power-consumption electronic appliance, and a low-power-consumption lighting device can be provided. According to another embodiment of the present invention, any of a highly reliable display apparatus, a highly reliable electronic appliance, and a highly reliable lighting device can be provided. According to another embodiment of the present invention, a highly reliable organic compound can be provided.

Note that the description of these effects does not preclude the existence of other effects. One embodiment of the present invention does not necessarily have all of these effects. Other effects will be apparent from and can be derived from the description of the specification, the drawings, the claims, and the like.

### BRIEF DESCRIPTION OF THE DRAWINGS

In the accompanying drawings:

FIGS. 1A to 1C are schematic views of light-emitting devices of one embodiment of the present invention;

FIG. 2 shows a method for calculating emission lifetime;

FIGS. 3A and 3B illustrate a display apparatus of one embodiment of the present invention;

FIGS. 4A and 4B illustrate a display apparatus of one embodiment of the present invention;

FIGS. 5A to 5E are cross-sectional views illustrating an example of a method for manufacturing a display apparatus;

FIGS. 6A and 6B are cross-sectional views illustrating the example of a method for manufacturing a display apparatus;

FIGS. 7A to 7D are cross-sectional views illustrating the example of a method for manufacturing a display apparatus;

FIGS. 8A to 8C are cross-sectional views illustrating the example of a method for manufacturing a display apparatus;

FIGS. 9A to 9C are cross-sectional views illustrating the example of a method for manufacturing a display apparatus;

FIGS. 10A to 10C are cross-sectional views illustrating the example of a method for manufacturing a display apparatus;

FIGS. 11A and 11B are perspective views illustrating a structure example of a display module;

FIGS. 12A and 12B are cross-sectional views illustrating structure examples of a display apparatus;

FIG. 13 is a perspective view illustrating a structure example of a display apparatus;

FIG. 14 is a cross-sectional view illustrating a structure example of a display apparatus;

FIG. 15 is a cross-sectional view illustrating a structure example of a display apparatus;

FIGS. 16A to 16C illustrate a structure example of a display apparatus;

FIG. 17 is a cross-sectional view illustrating a structure example of a display apparatus;

FIGS. 18A to 18C illustrate a structure example of a display apparatus;

FIGS. 19A to 19D illustrate examples of wearable devices;

FIGS. 20A to 20F illustrate examples of electronic appliances;

FIGS. 21A to 21G illustrate examples of electronic appliances;

FIG. 22 shows luminance-current density characteristics of a light-emitting device 1 and a comparative light-emitting device 1-1 to a comparative light-emitting device 1-3;

FIG. 23 shows current efficiency-current density characteristics of the light-emitting device 1 and the comparative light-emitting devices 1-1 to 1-3;

FIG. 24 shows luminance-voltage characteristics of the light-emitting device 1 and the comparative light-emitting devices 1-1 to 1-3;

FIG. 25 shows current density-voltage characteristics of the light-emitting device 1 and the comparative light-emitting devices 1-1 to 1-3;

FIG. 26 shows external quantum efficiency-luminance characteristics of the light-emitting device 1 and the comparative light-emitting devices 1-1 to 1-3;

FIG. 27 shows blue index (BI)-current density characteristics of the light-emitting device 1 and the comparative light-emitting devices 1-1 to 1-3;

FIG. 28 shows electroluminescence spectra of the light-emitting device 1 and the comparative light-emitting devices 1-1 to 1-3;

FIG. 29 shows time dependence of normalized luminance of the light-emitting device 1 and the comparative light-emitting devices 1-1 to 1-3;

FIG. 30 shows luminance-current density characteristics of a light-emitting device 2 and a comparative light-emitting device 2-1 to a comparative light-emitting device 2-3;

FIG. 31 shows current efficiency-current density characteristics of the light-emitting device 2 and the comparative light-emitting devices 2-1 to 2-3;

FIG. 32 shows luminance-voltage characteristics of the light-emitting device 2 and the comparative light-emitting devices 2-1 to 2-3;

FIG. 33 shows current density-voltage characteristics of the light-emitting device 2 and the comparative light-emitting devices 2-1 to 2-3;

FIG. 34 shows external quantum efficiency-luminance characteristics of the light-emitting device 2 and the comparative light-emitting devices 2-1 to 2-3;

FIG. 35 shows blue index (BI)-current density characteristics of the light-emitting device 2 and the comparative light-emitting devices 2-1 to 2-3;

FIG. 36 shows electroluminescence spectra of the light-emitting device 2 and the comparative light-emitting devices 2-1 to 2-3;

FIG. 37 shows time dependence of normalized luminance of the light-emitting device 2 and the comparative light-emitting devices 2-1 to 2-3;

FIG. 38 shows luminance-current density characteristics of a light-emitting device 3 and a comparative light-emitting device 3-1 to a comparative light-emitting device 3-3;

FIG. 39 shows current efficiency-current density characteristics of the light-emitting device 3 and the comparative light-emitting devices 3-1 to 3-3;

FIG. 40 shows luminance-voltage characteristics of the light-emitting device 3 and the comparative light-emitting devices 3-1 to 3-3;

FIG. 41 shows current density-voltage characteristics of the light-emitting device 3 and the comparative light-emitting devices 3-1 to 3-3;

FIG. 42 shows external quantum efficiency-luminance characteristics of the light-emitting device 3 and the comparative light-emitting devices 3-1 to 3-3;

FIG. 43 shows blue index (BI)-luminance characteristics of the light-emitting device 3 and the comparative light-emitting devices 3-1 to 3-3;

FIG. 44 shows electroluminescence spectra of the light-emitting device 3 and the comparative light-emitting devices 3-1 to 3-3;

FIG. 45 shows time dependence of normalized luminance of the light-emitting device 3 and the comparative light-emitting devices 3-1 to 3-3;

FIG. 46 shows luminance-current density characteristics of a light-emitting device 4 and a comparative light-emitting device 4-1 to a comparative light-emitting device 4-3;

FIG. 47 shows current efficiency-current density characteristics of the light-emitting device 4 and the comparative light-emitting devices 4-1 to 4-3;

FIG. 48 shows luminance-voltage characteristics of the light-emitting device 4 and the comparative light-emitting devices 4-1 to 4-3;

FIG. 49 shows current density-voltage characteristics of the light-emitting device 4 and the comparative light-emitting devices 4-1 to 4-3;

FIG. 50 shows external quantum efficiency-luminance characteristics of the light-emitting device 4 and the comparative light-emitting devices 4-1 to 4-3;

FIG. 51 shows blue index (BI)-current density characteristics of the light-emitting device 4 and the comparative light-emitting devices 4-1 to 4-3;

FIG. 52 shows electroluminescence spectra of the light-emitting device 4 and the comparative light-emitting devices 4-1 to 4-3;

FIG. 53 shows time dependence of normalized luminance of the light-emitting device 4 and the comparative light-emitting devices 4-1 to 4-3;

FIG. 54 shows luminance-current density characteristics of a light-emitting device 5 and a comparative light-emitting device 5-1 to a comparative light-emitting device 5-3;

FIG. 55 shows luminance-voltage characteristics of the light-emitting device 5 and the comparative light-emitting devices 5-1 to 5-3;

FIG. 56 shows current efficiency-current density characteristics of the light-emitting device 5 and the comparative light-emitting devices 5-1 to 5-3;

FIG. 57 shows current density-voltage characteristics of the light-emitting device 5 and the comparative light-emitting devices 5-1 to 5-3;

FIG. 58 shows external quantum efficiency-current density characteristics of the light-emitting device 5 and the comparative light-emitting devices 5-1 to 5-3;

FIG. 59 shows electroluminescence spectra of the light-emitting device 5 and the comparative light-emitting devices 5-1 to 5-3;

FIG. 60 shows time dependence of normalized luminance of the light-emitting device 5 and the comparative light-emitting devices 5-1 to 5-3;

FIGS. 61A and 61B show a method for calculating the lowest triplet excitation energy.

FIG. 62 shows PL spectra of SiTrzCz2-d16, PSiCzCz-d15, and an exciplex formed by SiTrzCz2-d16 and PSiCzCz-d15;

FIG. 63 shows PL spectra of PtON-TBBI and an exciplex formed by PSiCzCz-d15 and SiTrzCz2-d16;

FIG. 64 shows PL spectra of Pt (mmtBubOcz5m4ppy-d3) and an exciplex formed by PSiCzCz-d15 and SiTrzCz2-d16;

FIG. 65 shows PL spectra of 8mpTP-4mDBtPBfpm-d13, βNCCP-d26, and an exciplex formed by 8mpTP-4mDBtPBfpm-d13 and βNCCP-d26;

FIG. 66 shows PL spectra of Ir(5m4dppy-d3)3 and an exciplex formed by βNCCP-d26 and 8mpTP-4mDBtPBfpm-d13;

FIG. 67 shows PL spectra of 8(βN2)-4mDBtPBfpm-d13, PCBBiF-d16, and an exciplex formed by 8(βN2)-4mDBtPBfpm-d13 and PCBBiF-d16;

FIG. 68 shows PL spectra of OCPG-006 and an exciplex formed by 8(βN2)-4mDBtPBfpm-d13 and PCBBiF-d16;

FIG. 69 shows luminance-current density characteristics of a light-emitting device 6 and a comparative light-emitting device 6;

FIG. 70 shows luminance-voltage characteristics of the light-emitting device 6 and the comparative light-emitting device 6;

FIG. 71 shows current efficiency-current density characteristics of the light-emitting device 6 and the comparative light-emitting device 6;

FIG. 72 shows current density-voltage characteristics of the light-emitting device 6 and the comparative light-emitting device 6;

FIG. 73 shows external quantum efficiency-current density characteristics of the light-emitting device 6 and the comparative light-emitting device 6;

FIG. 74 shows electroluminescence spectra of the light-emitting device 6 and the comparative light-emitting device 6;

FIG. 75 shows time dependence of normalized luminance of the light-emitting device 6 and the comparative light-emitting device 6;

FIGS. 76A and 76B each show a ¹H NMR spectrum of 2,6-dibromonaphthalene;

FIGS. 77A and 77B each show ¹H NMR spectra of 2,6-dibromonaphthalene and 2,6-dibromonaphthalene-d6;

FIGS. 78A and 78B each show ¹H NMR spectra of 2,6-dibromonaphthalene-d6 and 1,1,2-trichloroethane;

FIGS. 79A and 79B each show a ¹H NMR spectrum of 8(βN2)-4mDBtPBfpm-d13;

FIG. 80 shows an absorption spectrum and a PL spectrum of 8(βN2)-4mDBtPBfpm-d13 in a toluene solution;

FIG. 81 shows an absorption spectrum and a PL spectrum of a thin film of 8(βN2)-4mDBtPBfpm-d13;

FIGS. 82A and 82B each show a ¹H NMR spectrum of FBiPhBr;

FIGS. 83A and 83B each show ¹H NMR spectra of FBiPhBr-d4 and FBiPhBr;

FIGS. 84A and 84B each show a ¹H NMR spectrum of PCBBiF;

FIGS. 85A and 85B each show ¹H NMR spectra of PCBBiF-d16 and PCBBiF;

FIG. 86 shows an absorption spectrum and a PL spectrum of PCBBiF-d16 in a toluene solution; and

FIG. 87 shows an absorption spectrum and a PL spectrum of a thin film of PCBBiF-d16.

### DETAILED DESCRIPTION OF THE INVENTION

Embodiments of the present invention will be described in detail below with reference to the drawings. Note that the present invention is not limited to the following description, and it will be readily appreciated by those skilled in the art that modes and details of the present invention can be modified in various ways without departing from the spirit and scope of the present invention. Thus, the present invention should not be construed as being limited to the description in the following embodiments.

In this specification and the like, a device formed using a metal mask or a fine metal mask (FMM) is sometimes referred to as a device having a metal mask (MM) structure. In this specification and the like, a device formed without using a metal mask or an FMM is sometimes referred to as a device having a metal maskless (MML) structure.

### Embodiment 1

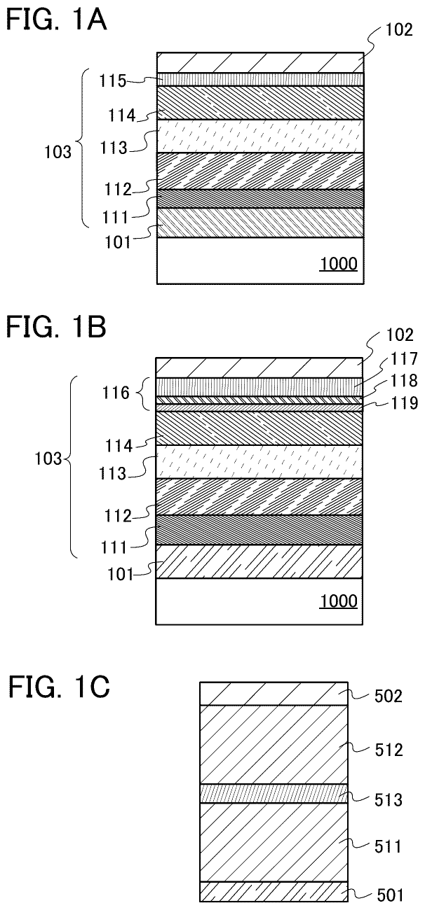

An organic semiconductor device includes at least a pair of electrodes (a first electrode and a second electrode) and an organic compound layer, and the organic compound layer includes an active layer or an active region. As illustrated in FIGS. 1A to 1C, the organic compound layer preferably has a stacked-layer structure formed of functional layers that have different functions and contain organic compounds with properties required for their respective functions.

The functional layers having a variety of functions are required: typical examples of the functional layer are a carrier-injection layer, a carrier-transport layer, an active layer (e.g., a light-emitting layer or a photoelectric conversion layer), a charge-generation layer, a carrier-blocking layer, and an exciton-blocking layer. Note that each of the functional layers may further have another function. For example, the electron-blocking layer and the hole-blocking layer are assumed to transport holes and electrons, respectively, and thus can also be referred to as carrier-blocking layers (a hole-transport layer and an electron-transport layer).

As described above, the functional layers include organic compounds with properties required for their respective functions. Thus, organic compounds with properties suitable for the functional layers have been actively developed, and a variety of organic compounds have been proposed and put into practical use.

In addition, the characteristics of a light-emitting device are greatly affected by a combination of these organic compounds. In view of the above, structures of light-emitting devices have also been actively researched.

For example, in the case of a light-emitting device in which excitation is caused by current, the light-emitting device can have high emission efficiency when using a substance that can convert triplet excitation energy into light emission (a phosphorescent substance or a substance exhibiting thermally activated delayed fluorescence) as a light-emitting substance (guest material).

In another known structure, two kinds of organic compounds (specifically, an organic compound with an electron-transport property and an organic compound with a hole-transport property) are used as host materials in combination with a light-emitting substance (guest material) in a light-emitting layer.

In particular, a technology using a structure where an exciplex formed by two kinds of organic compounds is used as an energy donor and a substance that can convert triplet excitation energy into light emission (a phosphorescent substance or a substance exhibiting thermally activated delayed fluorescence) is used as an energy acceptor in a light-emitting layer, which is called exciplex-triplet energy transfer (ExTET), is a capable technology that can achieve high efficiency, a low driving voltage, and a long lifetime.

That is, a light-emitting device whose light-emitting layer contains an exciplex as an energy donor and a substance that can convert triplet excitation energy into light emission as an energy acceptor, i.e., a light-emitting substance, can have excellent characteristics.

When two kinds of organic compounds (a first organic compound and a second organic compound) functioning as the host materials each contain deuterium, the light-emitting device can have higher reliability. In particular, as described later, in the case where a difference in the lowest triplet excited level (T₁ level) between the first and second organic compounds is small, that is, in the case where the T₁ levels of the first and second organic compounds are close to each other, the triplet excitation energy is less likely to be localized in one of the organic compounds, and energy transfer from the organic compounds in the triplet excited state to the substance that can convert triplet excitation energy into light emission might occur. The efficiency of the energy transfer from the organic compounds is improved by the influence of the deuterium, whereby deterioration of the first and second organic compounds containing deuterium can be inhibited.

This effect is significant particularly when the two kinds of organic compounds form an exciplex. The singlet excitation energy of the exciplex is lower than those of the first and second organic compounds, and thus energy is transferred from the exciplex to the light-emitting substance. Meanwhile, the triplet excitation energy can be transferred not only directly to the light-emitting substance but also indirectly to the light-emitting substance through the first organic compound and/or the second organic compound in the triplet excited state. In particular, as described later, in the case where a difference in the T₁ level between the first and second organic compounds containing deuterium is small, that is, in the case where the T₁ levels of the first and second organic compounds are close to each other, energy can be transferred, through the organic compounds in the triplet excited state, to the substance that can convert triplet excitation energy into light emission. This is because the excitation energy is less likely to be localized in one of the organic compounds. The efficiency of the energy transfer from the organic compounds in the triplet excited state is improved by the influence of the deuterium, whereby deterioration of the first and second organic compounds containing deuterium can be inhibited.

Accordingly, a light-emitting device that uses an exciplex formed by deuterated organic compounds as an energy donor can have less deterioration than a light-emitting device that uses an exciplex formed by non-deuterated organic compounds as an energy donor, and thus can have high reliability.

Note that each of the first and second organic compounds may contain both hydrogen and deuterium, or may contain not hydrogen but deuterium.

In each of the first and second organic compounds, all hydrogen in the molecule may be substituted by deuterium, but a group or a skeleton where the lowest triplet excited level is localized is preferably deuterated. This enables the first or second organic compound to be obtained at low cost as compared with the case where all hydrogen in the molecule is substituted by deuterium.

In this specification and the like, “containing deuterium” means that the proportion of deuterium in an organic compound containing hydrogen and deuterium is much higher than, specifically, 500 times or more the natural abundance of deuterium, and a “deuterated organic compound” refers to an organic compound where the proportion of deuterium in an organic compound containing hydrogen and deuterium is much higher than, specifically, 500 times or more the natural abundance of deuterium. Note that this proportion is not a proportion in one molecule, but is an average proportion in a plurality of target organic compounds in a certain area.

Note that the first organic compound has an electron-transport property, and preferably includes a T-electron deficient heteroaromatic ring. The second organic compound has a hole-transport property, and preferably includes a π-electron rich heteroaromatic ring or an aromatic amine skeleton.

In the light-emitting device of one embodiment of the present invention, an improvement in energy transfer efficiency due to the first and second organic compounds containing deuterium is derived from the phosphorescence lifetime or delayed fluorescence lifetime of a deuterated organic compound which is longer than that of a non-deuterated organic compound. This is because a deuterated organic compound in the lowest triplet excited state (T₁ state) has less intramolecular vibration than a non-deuterated organic compound in the T₁ state and accordingly has less non-radiative transition from the T₁ state to a more stable state.

The energy transfer efficiency ϕ_{ET} from an energy donor (an exciplex in one embodiment of the present invention) to an energy acceptor (a substance that can convert triplet excitation energy into light emission in one embodiment of the present invention) is expressed by Formula (1) below. According to this formula, it is found that the energy transfer efficiency ϕ_{ET} can be increased by increasing the rate constant k_{h*→g} of energy transfer so that another competing rate constant kᵣ+kₙᵣ(=1/τ) becomes relatively small.

In Formula (1), kᵣ represents the rate constant of a light emission process (a fluorescent emission process in the case where energy transfer from a singlet excited state is discussed, and a phosphorescent emission process or a delayed fluorescent emission process in the case where energy transfer from a triplet excited state is discussed) of the energy donor, kₙᵣ represents the rate constant of a non-light-emission process (thermal deactivation and intersystem crossing) of the energy donor, and τ represents a measured lifetime of an excited state of the energy donor. In addition, k_{h*→g} represents the rate constant of energy transfer (Förster mechanism or Dexter mechanism).

$$[ Formula 1 ]$$

$${∅}_{ET} = \frac{{k}_{{h}^{*} \to g}}{{k}_{r} + {k}_{nr} + {k}_{{h}^{*}} \to g} = \frac{{k}_{{h}^{*} \to g}}{( \frac{1}{τ} ) + {k}_{{h}^{*} \to g}} \qquad ( 1 )$$

A deuterated organic compound and a non-deuterated organic compound have substantially the same atomic arrangement in a molecule and substantially the same spectrum shape, for example, and thus have substantially the same rate constant k_{h*→g} of energy transfer (see Formula (2) or (3) below). Thus, in comparison between the deuterated organic compound and the non-deuterated organic compound, the rate constant k_{h*→g} of energy transfer is found to be greatly affected by the emission lifetime (phosphorescence lifetime or delayed fluorescence lifetime) τ. That is, the energy transfer efficiency is improved as the emission lifetime (phosphorescence lifetime or delayed fluorescence lifetime) is longer.

$$[ Formula 2 ]$$

$${k}_{{h}^{*} \to g} = \frac{9000 {K}^{2} ∅ln10}{128 {π}^{5} {n}^{4} N τ {R}^{6}} \int \frac{{f}_{h}^{′} ( v ) {ε}_{g} ( v )}{{v}^{4}} dv \qquad ( 2 )$$

$$[ Formula 3 ]$$

$${k}_{{h}^{*} \to g} = ( \frac{2 π}{h} ) {K}^{2} exp ( - \frac{2 R}{L} ) \int {f}_{h}^{′} ( v ) {ε}_{g}^{′} ( v ) dv \qquad ( 3 )$$

Formula (2) is a formula of the rate constant k_{h*→g} of the Förster mechanism and Formula (3) is a formula of the rate constant k_{h*→g} of the Dexter mechanism.

In Formula (2), v represents a frequency, f′ₕ(v) represents a normalized emission spectrum of the host material (a fluorescent spectrum in the case where energy transfer from a singlet excited state is discussed, and a phosphorescent spectrum in the case where energy transfer from a triplet excited state is discussed), ε_{g}(v) represents a molar absorption coefficient of the guest material, N represents Avogadro's number, n represents a refractive index of a medium, R represents an intermolecular distance between the host material and the guest material, τ represents a measured lifetime of an excited state (fluorescence lifetime or phosphorescence lifetime), ϕ represents an emission quantum yield (a fluorescence quantum yield in the case where energy transfer from a singlet excited state is discussed, and a phosphorescence quantum yield in the case where energy transfer from a triplet excited state is discussed), and K² represents a coefficient (0 to 4) of orientation of a transition dipole moment between the host material and the guest material. Note that K² is ⅔ in random orientation.

In Formula (3), h represents a Planck constant, K represents a constant having an energy dimension, v represents a frequency, f′ₕ(v) represents a normalized emission spectrum of the host material (a fluorescent spectrum in the case where energy transfer from a singlet excited state is discussed, and a phosphorescent spectrum in the case where energy transfer from a triplet excited state is discussed), ε′_{g}(v) represents a normalized absorption spectrum of the guest material, L represents an effective molecular radius, and R represents an intermolecular distance between the host material and the guest material.

As described above, in energy transfer from the first and second organic compounds, the efficiency of energy transfer from the triplet excited state is important and thus the lifetime of the triplet excited state is important. That is, longer phosphorescence lifetimes or delayed fluorescence lifetimes of the deuterated first and second organic compounds can improve the energy transfer efficiency and inhibit deterioration of the deuterated organic compounds. Accordingly, a light-emitting device including an energy donor formed by deuterated organic compounds has less deterioration of the organic compounds than a light-emitting device including an energy donor formed by non-deuterated organic compounds, and thus can have high reliability.

Note that an exciplex formed by the first and second organic compounds serves as an energy donor in the light-emitting device of one embodiment of the present invention, and as described above, the triplet excitation energy can be transferred from the exciplex in the triplet excited state to the light-emitting substance through the first and second organic compounds in the triplet excited state; thus, the phosphorescence lifetimes or delayed fluorescence lifetimes of the first and second organic compounds forming the exciplex are important. In the light-emitting device of one embodiment of the present invention including the exciplex as the energy donor, it is found that the first and second organic compounds each containing deuterium have the phosphorescence lifetimes or the delayed fluorescence lifetimes longer than a certain length and significantly improve the reliability of the light-emitting device. Note that when lifetimes are compared, the same measurement conditions are preferably used. For example, comparison is preferably made between samples in the same form, e.g., between thin films or between solutions. In addition, the phosphorescence lifetimes measured at low temperature (a temperature in a range of 4 K to 80 K) are compared, and the delayed fluorescence lifetimes measured at room temperature (a temperature in a range of 290 K to 300 K) are compared.

That is, the phosphorescence lifetime or delayed fluorescence lifetime of the first organic compound is preferably 1.20 times or more that of a third organic compound that is a non-deuterated substance of the first organic compound, and the phosphorescence lifetime or delayed fluorescence lifetime of the second organic compound is preferably 1.05 times or more that of a fourth organic compound that is a non-deuterated substance of the second organic compound. In this case, it is preferable that light emitted from the substance that can convert triplet excitation energy into light emission (the light-emitting substance contained in the light-emitting layer) be in the blue region, that is, the peak wavelength be typically greater than or equal to 450 nm and less than 500 nm. Alternatively, it is preferable that light emitted from the substance that can convert triplet excitation energy into light emission (the light-emitting substance contained in the light-emitting layer) be in the red region, that is, the peak wavelength be typically greater than 600 nm and less than or equal to 700 nm.

Alternatively, the phosphorescence lifetime or delayed fluorescence lifetime of the first organic compound is preferably 1.50 times or more that of the third organic compound that is a non-deuterated substance of the first organic compound, and the phosphorescence lifetime or delayed fluorescence lifetime of the second organic compound is preferably 3.00 times or more that of the fourth organic compound that is a non-deuterated substance of the second organic compound. In this case, it is preferable that light emitted from the substance that can convert triplet excitation energy into light emission (the light-emitting substance contained in the light-emitting layer) be in the green region, that is, the peak wavelength be typically greater than or equal to 500 nm and less than or equal to 600 nm.

In the light-emitting device of one embodiment of the present invention including the exciplex as the energy donor, where the first and second organic compounds have improved phosphorescence lifetimes or delayed fluorescence lifetimes by containing deuterium, the reliability is significantly improved when the product of increasing rates of lifetimes is greater than or equal to a certain value.

That is, in the light-emitting device of one embodiment of the present invention, in the case where the phosphorescence lifetime of the first organic compound is X times that of the third organic compound that is a non-deuterated substance of the first organic compound and the phosphorescence lifetime of the second organic compound is Y times that of the fourth organic compound that is a non-deuterated substance of the second organic compound, it is preferable to use the first and second organic compounds that make the product of X and Y greater than or equal to 1.26.

In the case where the phosphorescence lifetime or delayed fluorescence lifetime of the first organic compound is X times that of the third organic compound that is a non-deuterated substance of the first organic compound and the phosphorescence lifetime or delayed fluorescence lifetime of the second organic compound is Y times that of the fourth organic compound that is a non-deuterated substance of the second organic compound, it is preferable to use the first and second organic compounds that make the product of X and Y greater than or equal to a certain value, in which case a light-emitting device with better characteristics can be obtained.

Specifically, in the case where the substance that can convert triplet excitation energy into light emission (the light-emitting substance contained in the light-emitting layer) emits light in the green region, that is, in the case where the peak wavelength is typically greater than or equal to 500 nm and less than or equal to 600 nm, it is preferable to use the first and second organic compounds that make the product of X and Y greater than or equal to 4.50, in which case a light-emitting device with better characteristics can be obtained.

In the case where the substance that can convert triplet excitation energy into light emission (the light-emitting substance contained in the light-emitting layer) emits light in the blue region, that is, in the case where the peak wavelength is typically greater than or equal to 450 nm and less than 500 nm, it is preferable to use the first and second organic compounds that make the product of X and Y greater than or equal to 1.26. In the case where the substance that can convert triplet excitation energy into light emission (the light-emitting substance contained in the light-emitting layer) emits light in the red region, that is, in the case where the peak wavelength is typically greater than 600 nm and less than or equal to 700 nm, it is preferable to use the first and second organic compounds that make the product of X and Y greater than or equal to 1.26.

The phosphorescence lifetime and the delayed fluorescence lifetime are calculated by measuring the transient PL by time-resolved measurement, in which the intensity of light attenuating after the excitation light is blocked by a shutter is measured at certain intervals. In this measurement, a graph is sometimes not linear because fluorescence components are mixed at the initial stage of attenuation. In such a case, a starting point is set in a portion where the graph is straight, and the time taken for the intensity at the starting point to attenuate to 1/e is regarded as the phosphorescence lifetime or the delayed fluorescence lifetime.

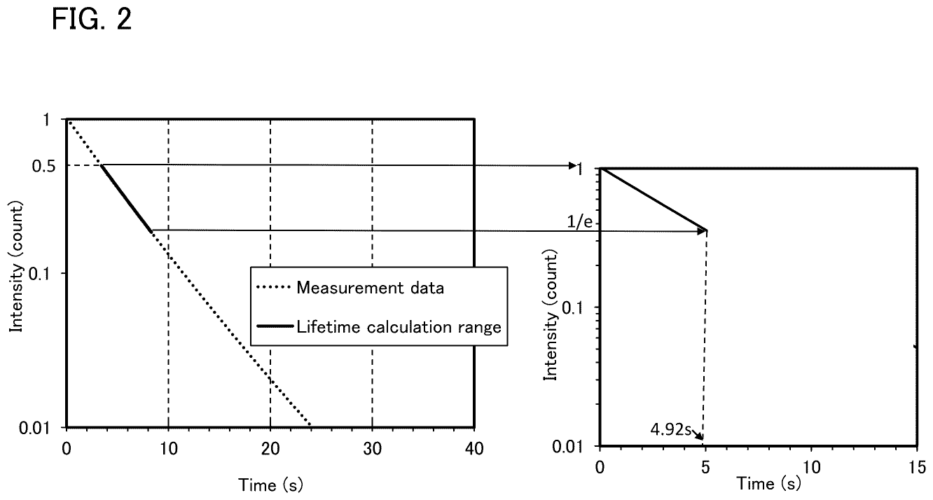

From the measurement data shown in the left graph in FIG. 2, the starting point is set as 1=0 within the range where the graph is straight (here, the time at which the light amount becomes 50% of that at the start of the measurement is set as 1=0) (the right diagram in FIG. 2). The time taken for the light amount to attenuate to 1/e of that at 1=0 is regarded as the phosphorescence lifetime or the delayed fluorescence lifetime. In the graphs in FIG. 2, the time at which the intensity reaches 50% of that at the start of the measurement is set as time 0 s, the light amount at 0 s is regarded as 1, and the time taken for the light amount to become 1/e is the phosphorescence lifetime or the delayed fluorescence lifetime. Although the point where the intensity becomes 50% of that at the start of the measurement is easily used as the starting point, a point with another intensity may be used as the starting point.

The phosphorescence lifetime can be measured at liquid nitrogen temperature (77 K) with a fluorescence spectrophotometer such as FP-8600 produced by JASCO Corporation, in which a liquid nitrogen cooling unit is set. A solution of a material is prepared in a glove box in the following manner: a sample is dissolved in 2-MeTHF that has been deoxidized, and then stirring is performed with a stirrer at room temperature for approximately 30 minutes (heating is also performed in the case where the material has low solubility) so that the concentration of the solution is adjusted to approximately 1.2 E⁻⁴ M.

The time-resolved measurement can be performed in the following manner: a sample cell is irradiated with excitation light for approximately 30 seconds and the intensity of light attenuating after the excitation light is blocked by a shutter is measured at 10 ms intervals. The peak wavelength of the phosphorescence spectrum is preferably used for measuring the phosphorescence lifetime. In the case where the phosphorescence spectrum has a plurality of peaks, a wavelength with the highest peak intensity is preferably selected. Depending on the wavelength, the measurement cannot be performed accurately because of a mixed fluorescence spectrum in some cases. In such a case, an emission spectrum (including phosphorescence components) measured at low temperature (e.g., 77 K) and an emission spectrum (including only fluorescence components and not including phosphorescence components) measured at normal temperature are compared, and a phosphorescence wavelength in the emission spectrum not overlapping with the fluorescence spectrum as much as possible is preferably selected. Alternatively, a wavelength of a peak on the longest wavelength side in the phosphorescence spectrum can be selected. In the case of a frozen solution, light emission from a state other than the lowest triplet excited state is also observed in some cases. In this case, a wavelength of a peak on the longest wavelength side is selected.

Note that the excitation wavelength is appropriately selected within a wavelength range where a solvent has no influence. As long as the material can be excited sufficiently, measurement is preferably performed at a wavelength of 330 nm because there is no influence by a solvent. The band widths of excitation light and measured light are each approximately 10 nm.

Ideally, light emission attenuates single-exponentially; thus, a starting point is set in a portion where a graph is straight, and the time taken for the intensity at the starting point to attenuate to 1/e can be defined as the phosphorescence lifetime or the delayed fluorescence lifetime.

Note that the fluorescence lifetime can be distinguished from the phosphorescence lifetime and the delayed fluorescence lifetime by the length of the lifetime in time-resolved measurement. An emission lifetime on the order of nanoseconds is the fluorescence lifetime, and an emission lifetime on the order of microseconds to milliseconds or more is the phosphorescence lifetime or the delayed fluorescence lifetime.

The reliability of the light-emitting device of one embodiment of the present invention is improved in accordance with an increase in the phosphorescence lifetime, i.e., the lifetime of triplet excitons, of the first and second organic compounds. The increase in the lifetime of triplet excitons is caused by inhibited non-radiative deactivation of the triplet excitation energy, which is due to inhibited vibration owing to deuteration. At this time, the difference in the T₁ level between the first and second organic compounds is preferably small, in which case the excitation energy is less likely to be localized in one of the organic compounds and thus significant deterioration of one of the organic compounds can be prevented, leading to high reliability of the light-emitting device. Specifically, the difference in the T₁ level between the first and second organic compounds is preferably less than or equal to 0.20 eV, further preferably less than or equal to 0.15 eV, still further preferably less than or equal to 0.10 eV.

Note that the T₁ level is calculated by measuring an emission spectrum (phosphorescence spectrum) at a measurement temperature of 10 K using a 50-nm-thick thin film of a sample formed over a quartz substrate, for example. The measurement is preferably performed with a PL microscope (LabRAM HR-PL, HORIBA, Ltd.) and a He—Cd laser (325 nm) as excitation light. Note that the emission edge is determined as the intersection of a tangent and the horizontal axis (representing wavelength) or the baseline. The tangent is drawn to have the maximum slope at a point on a shorter wavelength side of the shortest-wavelength peak (or the shortest-wavelength shoulder peak) of the emission spectrum (phosphorescence spectrum).

In one embodiment of the present invention, the sublimation temperature of the first organic compound is preferably close to that of the second organic compound. For example, a difference in the 5% weight loss temperature measured by thermogravimetry between the first and second organic compounds is preferably less than or equal to 60° C., further preferably less than or equal to 45° C., still further preferably less than or equal to 20° C., yet still further preferably less than or equal to 10° C. This enables evaporation using a mixed material of the first and second organic compounds, thereby reducing the number of evaporation sources and providing a light-emitting device with favorable characteristics at low cost. Note that the 5% weight loss temperature may be a value at atmospheric pressure, and is preferably a value calculated at a pressure close to that in evaporation, e.g., at a pressure of approximately 10 Pa.

The 5% weight loss temperature can be obtained from the relation between weight and temperature (thermogravimetry) by performing thermogravimetry-differential thermal analysis (TG-DTA). In the case where the pressure for the evaporation is determined in advance, it is preferable to use a value measured under the pressure.

By combining a preferable difference in T₁ level, a preferable difference in sublimation temperature, a preferable increasing rate of a phosphorescence lifetime or a delayed fluorescence lifetime owing to deuteration, and a preferable product of the increasing rates of the first and second organic compounds, a light-emitting device with better characteristics can be obtained.

In addition, the photoluminescence (PL) spectrum of the exciplex formed by the first and second organic compounds and that of the light-emitting substance (the substance that can convert triplet excitation energy into light emission) preferably include an overlap. This is because the driving voltage of the light-emitting device can be decreased when the excitation energy of the exciplex serving as thee energy donor is close to that of the light-emitting substance. Thus, a difference in the maximum peak wavelength in the PL spectrum between the exciplex and the light-emitting substance is preferably less than or equal to 30 nm. Alternatively, a difference in the wavelength of the emission edge on the short wavelength side of the PL spectrum between the exciplex and the light-emitting substance is preferably less than or equal to 30 nm, in which case the driving voltage of the light-emitting device can be decreased.

The PL spectrum of the exciplex is preferably measured using a film formed by co-evaporation of the first and second organic compounds. A sample used for measuring the PL spectrum of the light-emitting substance (the substance that can convert triplet excitation energy into light emission) may be in the form of a thin film or a solution, but is preferably in the form of a solution for examining the state of an isolated molecule. There is no particular limitation on a solvent of the solution as long as the same solvent is used for the comparison. A solvent with relatively low polarity, such as toluene or chloroform, is preferred.

In the case where the substance that can convert triplet excitation energy into light emission (the light-emitting substance contained in the light-emitting layer) emits light in the blue region, that is, in the case where the peak wavelength is typically greater than or equal to 450 nm and less than 500 nm, the first organic compound preferably includes a triazine skeleton or a diazine skeleton, and the second organic compound preferably includes a carbazole skeleton. Specific examples of the first organic compound include 9,9′-{6-[3-(triphenylsilyl)phenyl]-1,3,5-triazine-2,4-diyl}bis(9H-carbazole-1,2,3,4,5,6,7,8,1′,2′,3′,4′,5′,6′,7′,8′-d16) (abbreviation: SiTrzCz2-d16), and specific examples of the second organic compound include 9-[3-(triphenylsilyl)phenyl]-3,9′-(bi-9H-carbazole-d15) (abbreviation: PSiCzCz-d15) and 9′-[3-(triphenylsilyl)phenyl]-9′H-9,3′: 6′,9″-tercarbazole-1,1′,1″,2,2′,2″,3,3″,4,4′,4″,5,5′,5″,6,6″,7,7′,7″,8,8′,8″-d22 (abbreviation: PSiCzGI-d22).

In the case where the substance that can convert triplet excitation energy into light emission (the light-emitting substance contained in the light-emitting layer) emits light in the green region, that is, in the case where the peak wavelength is typically greater than or equal to 500 nm and less than or equal to 600 nm, the first organic compound preferably includes a diazine skeleton or a triazine skeleton, and the second organic compound preferably includes a carbazole skeleton. Specific examples of the first organic compound include 8-(1, l′: 4′,1″-terphenyl-3-yl-2,4,5,6,2′,3′,5′,6′,2″,3″,4″,5″,6″-d13)-4-[3-(dibenzothiophen-4-yl-1,2,3,6,7,8,9-d7)phenyl-2,4,6-d3]-[1]benzofuro[3,2-d]pyrimidine (abbreviation: 8mpTP-4mDBtPBfpm-d23), 8-(1,1′: 4′,1″-terphenyl-3-yl-2,4,5,6,2′,3′,5′,6′,2″,3″,4″,5″,6″-d13)-4-[3-(dibenzothiophen-4-yl)phenyl]-[1]benzofuro[3,2-d]pyrimidine (abbreviation: 8mpTP-4mDBtPBfpm-d13), and 11-[4-(biphenyl-4-yl-2,2′,3,3′,4′,5,5′,6,6′-d9)-6-(phenyl-2,3,4,5,6-d5)-1,3,5-triazin-2-yl]-11,12-dihydro-12-(biphenyl-3-yl) indolo [2,3-a]carbazole-1,2,3,4,5,6,7,8,9,10-d10. Specific examples of the second organic compound include 9-(2-naphthyl-1,3,4,5,6,7,8-d7)-9′-(phenyl-2,3,4,5,6-d5)-3,3′-bi-9H-carbazole-1,1′,2,2′,4,4′,5,5′,6,6′,7,7′,8,8′-d14 (abbreviation: βNCCP-d26) and 9-phenyl-9′-(phenyl-2,3,4,5,6-d5)-3,3′-bis(9H-carbazole) (abbreviation: PCCP-d5).

This embodiment can be freely combined with any of the other embodiments.

### Embodiment 2

In this embodiment, a light-emitting device of one embodiment of the present invention which is an organic semiconductor device is described in detail. FIG. 1A illustrates a light-emitting device of one embodiment of the present invention. The light-emitting device of one embodiment of the present invention includes a first electrode 101 formed over an insulating layer 1000, a second electrode 102 facing the first electrode 101, and an organic compound layer 103 between the first electrode 101 and the second electrode 102. The organic compound layer 103 includes at least a light-emitting layer 113, and may further include another functional layer. Although the exemplary structures illustrated in FIGS. 1A and 1B further include a hole-injection layer 111, a hole-transport layer 112, an electron-transport layer 114, and an electron-injection layer 115, an exciton-blocking layer, a charge-generation layer, or the like may be included. Note that a layer of the hole-transport layer 112 which is in contact with the light-emitting layer 113 is particularly referred to as an electron-blocking layer, and a layer of the electron-transport layer 114 which is in contact with the light-emitting layer 113 is particularly referred to as a hole-blocking layer in some cases. In this embodiment, the case where the first electrode 101 and the second electrode 102 respectively function as an anode and a cathode is described as an example; however, the first electrode 101 and the second electrode 102 may respectively function as a cathode and an anode.

Note that the light-emitting layer has the structure described in Embodiment 1. Accordingly, the light-emitting device of one embodiment of the present invention can have high reliability.

The anode is preferably formed using any of metals, alloys, and conductive compounds with a high work function (specifically, higher than or equal to 4.0 eV), mixtures thereof, and the like. Specific examples include indium oxide-tin oxide (ITO: indium tin oxide), indium oxide-tin oxide containing silicon or silicon oxide (ITSO: indium tin silicon oxide), indium oxide-zinc oxide, and indium oxide containing tungsten oxide and zinc oxide (IWZO). Films of such conductive metal oxides are usually formed by a sputtering method, but may be formed by application of a sol-gel method or the like. For example, a film of indium oxide-zinc oxide is formed by a sputtering method using a target in which 1 wt % to 20 wt % zinc oxide is added to indium oxide. Furthermore, a film of indium oxide containing tungsten oxide and zinc oxide (IWZO) can be formed by a sputtering method using a target in which 0.5 wt % to 5 wt % tungsten oxide and 0.1 wt % to 1 wt % zinc oxide are added to indium oxide. Alternatively, gold (Au), platinum (Pt), nickel (Ni), tungsten (W), chromium (Cr), molybdenum (Mo), iron (Fe), cobalt (Co), copper (Cu), palladium (Pd), titanium (Ti), aluminum (Al), nitride of a metal material (e.g., titanium nitride), or the like can be used for the anode. The anode may be a stack of layers formed using any of these materials. For example, a film in which Al, Ti, and ITSO are stacked in this order over Ti is preferable because the film has high efficiency owing to high reflectivity and enables high resolution of several thousand ppi. Graphene can also be used for the anode. When a composite material that can be included in the hole-injection layer 111 described later is used for a layer (typically, the hole-injection layer) in contact with the anode, an electrode material can be selected regardless of its work function.

The hole-injection layer 111 is provided in contact with the anode and has a function of facilitating injection of holes into the organic compound layer 103. The hole-injection layer 111 can be formed using phthalocyanine (abbreviation: H₂Pc), a phthalocyanine-based compound or complex compound such as copper phthalocyanine (abbreviation: CuPc), an aromatic amine compound such as 4,4′-bis [N-(4-diphenylaminophenyl)-N-phenylamino]biphenyl (abbreviation: DPAB) or 4,4′-bis(N-{4-[N-(3-methylphenyl)-N′-phenylamino]phenyl}-N-phenylamino) biphenyl (abbreviation: DNTPD), or a high molecular compound such as poly(3,4-ethylenedioxythiophene)/poly(styrenesulfonic acid) (abbreviation: PEDOT/PSS).

The hole-injection layer 111 may be formed using a substance with an electron-accepting property. Examples of the substance with an acceptor property include organic compounds having an electron-withdrawing group (a halogen group or a cyano group), such as 7,7,8,8-tetracyano-2,3,5,6-tetrafluoroquinodimethane (abbreviation: F4-TCNQ), chloranil, 2,3,6,7,10,11-hexacyano-1,4,5,8,9,12-hexaazatriphenylene (abbreviation: HAT-CN), 1,3,4,5,7,8-hexafluorotetracyano-naphthoquinodimethane (abbreviation: F6-TCNNQ), and 2-(7-dicyanomethylene-1,3,4,5,6,8,9,10-octafluoro-7H-pyren-2-ylidene) malononitrile. A compound in which electron-withdrawing groups are bonded to a condensed aromatic ring having a plurality of heteroatoms, such as HAT-CN, is particularly preferable because it is thermally stable. A [3]radialene derivative having an electron-withdrawing group (in particular, a cyano group, a halogen group such as a fluoro group, or the like) has a significantly high electron-accepting property and thus is preferable. Specific examples include α,α′,α″-1,2,3-cyclopropanetriylidenetris [4-cyano-2,3,5,6-tetrafluorobenzeneacetonitrile], α,α′,α″-1,2,3-cyclopropanetriylidenetris [2,6-dichloro-3,5-difluoro-4-(trifluoromethyl)benzeneacetonitrile], and α,α′,α″-1,2,3-cyclopropanetriylidenetris [2,3,4,5,6-pentafluorobenzeneacetonitrile]. As the substance with an acceptor property, a transition metal oxide such as molybdenum oxide, vanadium oxide, ruthenium oxide, tungsten oxide, or manganese oxide can be used, other than the above-described organic compounds. Alternatively, the hole-injection layer 111 can be formed using a phthalocyanine-based compound such as phthalocyanine (abbreviation: H₂Pc), a phthalocyanine-based complex compound such as copper phthalocyanine (abbreviation: CuPc), an aromatic amine compound such as 4,4′-bis [N-(4-diphenylaminophenyl)-N-phenylamino]biphenyl (abbreviation: DPAB) or 4,4′-bis(N-{4-[N′-(3-methylphenyl)-N′-phenylamino]phenyl}-N-phenylamino) biphenyl (abbreviation: DNTPD), or a high molecular compound such as poly(3,4-ethylenedioxythiophene)/poly(styrenesulfonic acid) (abbreviation: PEDOT/PSS). The substance with an acceptor property can extract electrons from an adjacent hole-transport layer (or hole-transport material) by application of an electric field.

The hole-injection layer 111 is preferably formed using a composite material containing any of the aforementioned materials with an acceptor property and a substance with a hole-transport property.

As the substance with a hole-transport property used for the composite material, any of a variety of organic compounds such as aromatic amine compounds, heteroaromatic compounds, aromatic hydrocarbons, and high molecular compounds (e.g., oligomers, dendrimers, and polymers) can be used. Note that the substance with a hole-transport property used for the composite material preferably has a hole mobility of 1×10⁻⁶ cm²/Vs or higher. The substance with a hole-transport property used for the composite material is preferably a compound including a condensed aromatic hydrocarbon ring or a π-electron rich heteroaromatic ring. As the condensed aromatic hydrocarbon ring, an anthracene ring, a naphthalene ring, or the like is preferable. As the π-electron rich heteroaromatic ring, a condensed aromatic ring having at least one of a pyrrole skeleton, a furan skeleton, and a thiophene skeleton is preferable; specifically, a carbazole ring, a dibenzothiophene ring, or a ring in which an aromatic ring or a heteroaromatic ring is further condensed to the carbazole ring or the dibenzothiophene ring is preferable.

Such a substance with a hole-transport property further preferably has any of a carbazole skeleton, a dibenzofuran skeleton, a dibenzothiophene skeleton, and an anthracene skeleton. In particular, an aromatic amine including a substituent that has a dibenzofuran ring or a dibenzothiophene ring, an aromatic monoamine that has a naphthalene ring, or an aromatic monoamine in which a 9-fluorenyl group is bonded to nitrogen of an amine through an arylene group may be used. Note that the substance with a hole-transport property preferably includes an N,N-bis(4-biphenyl)amino group to enable fabricating a light-emitting device having a long lifetime.

Specific examples of the substance with a hole-transport property include N-(4-biphenyl)-6,N-diphenylbenzo[b]naphtho[1,2-d]furan-8-amine (abbreviation: BnfABP), NN-bis(4-biphenyl)-6-phenylbenzo[b]naphtho[1,2-d]furan-8-amine (abbreviation: BBABnf), 4,4′-bis(6-phenylbenzo[b]naphtho[1,2-d]furan-8-yl)-4″-phenyltriphenylamine (abbreviation: BnfBB1BP), NN-bis(4-biphenyl)benzo[b]naphtho[1,2-d]furan-6-amine (abbreviation: BBABnf(6)), NN-bis(4-biphenyl)benzo[b]naphtho[1,2-d]furan-8-amine (abbreviation: BBABnf(8)), NN-bis(4-biphenyl)benzo[b]naphtho[2,3-d]furan-4-amine (abbreviation: BBABnf(II)(4)), N,N-bis[4-(dibenzofuran-4-yl)phenyl]-4-amino-p-terphenyl (abbreviation: DBfBB1TP), N-[4-(dibenzothiophen-4-yl)phenyl]-N-phenyl-4-biphenylamine (abbreviation: ThBA1BP), 4-(2-naphthyl)-4′,4″-diphenyltriphenylamine (abbreviation: BBAβNB), 4-[4-(2-naphthyl)phenyl]-4′,4″-diphenyltriphenylamine (abbreviation: BBAβNBi), 4,4′-diphenyl-4″-(6;1′-binaphthyl-2-yl)triphenylamine (abbreviation: BBAαNβNB), 4,4′-diphenyl-4″-(7;1′-binaphthyl-2-yl)triphenylamine (abbreviation: BBAαNβNB-03), 4,4′-diphenyl-4″-(7-phenyl)naphthyl-2-yltriphenylamine (abbreviation: BBAPβNB-03), 4,4′-diphenyl-4″-(6;2′-binaphthyl-2-yl)triphenylamine (abbreviation: BBA(βN2)B), 4,4′-diphenyl-4″-(7;2′-binaphthyl-2-yl)triphenylamine (abbreviation: BBA(βN2)B-03), 4,4′-diphenyl-4″-(4;2′-binaphthyl-1-yl)triphenylamine (abbreviation: BBAβNαNB), 4,4′-diphenyl-4″-(5;2′-binaphthyl-1-yl)triphenylamine (abbreviation: BBAβNαNB-02), 4-(4-biphenylyl)-4′-(2-naphthyl)-4″-phenyltriphenylamine (abbreviation: TPBiAβNB), 4-(3-biphenylyl)-4′-[4-(2-naphthyl)phenyl]-4″-phenyltriphenylamine (abbreviation: mTPBiAβNBi), 4-(4-biphenylyl)-4′-[4-(2-naphthyl)phenyl]-4″-phenyltriphenylamine (abbreviation: TPBiAβNBi), 4-phenyl-4′-(1-naphthyl)triphenylamine (abbreviation: αNBA1BP), 4,4′-bis(1-naphthyl)triphenylamine (abbreviation: αNBB1BP), 4,4′-diphenyl-4″-[4′-(carbazol-9-yl)biphenyl-4-yl]triphenylamine (abbreviation: YGTBi1BP), 4′-[4-(3-phenyl-9H-carbazol-9-yl)phenyl]tris(biphenyl-4-yl)amine (abbreviation: YGTBi1BP-02), 4-[4′-(carbazol-9-yl)biphenyl-4-yl]-4′-(2-naphthyl)-4″-phenyltriphenylamine (abbreviation: YGTBiβNB), N-[4-(9-phenyl-9H-carbazol-3-yl)phenyl]-N-[4-(1-naphthyl)phenyl]-9,9′-spirobi[9H-fluoren]-2-amine (abbreviation: PCBNBSF), N,N-bis(biphenyl-4-yl)-9,9′-spirobi[9H-fluoren]-2-amine (abbreviation: BBASF), N,N-bis(biphenyl-4-yl)-9,9′-spirobi[9H-fluoren]-4-amine (abbreviation: BBASF(4)), N-(biphenyl-2-yl)-N-(9,9-dimethyl-9H-fluoren-2-yl)-9,9′-spirobi[9H-fluoren]-4-amine (abbreviation: oFBiSF), N-(biphenyl-4-yl)-N-(9,9-dimethyl-9H-fluoren-2-yl)dibenzofuran-4-amine (abbreviation: FrBiF), N-[4-(1-naphthyl)phenyl]-N-[3-(6-phenyldibenzofuran-4-yl)phenyl]-1-naphthylamine (abbreviation: mPDBfBNBN), 4-phenyl-4′-(9-phenylfluoren-9-yl)triphenylamine (abbreviation: BPAFLP), 4-phenyl-3′-(9-phenylfluoren-9-yl)triphenylamine (abbreviation: mBPAFLP), 4-phenyl-4′-[4-(9-phenylfluoren-9-yl)phenyl]triphenylamine (abbreviation: BPAFLBi), 4-phenyl-4′-(9-phenyl-9H-carbazol-3-yl)triphenylamine (abbreviation: PCBA1BP), 4,4′-diphenyl-4″-(9-phenyl-9H-carbazol-3-yl)triphenylamine (abbreviation: PCBBi1BP), 4-(1-naphthyl)-4′-(9-phenyl-9H-carbazol-3-yl)triphenylamine (abbreviation: PCBANB), 4,4′-di(1-naphthyl)-4″-(9-phenyl-9H-carbazol-3-yl)triphenylamine (abbreviation: PCBNBB), N-phenyl-N-[4-(9-phenyl-9H-carbazol-3-yl)phenyl]-9,9′-spirobi[9H-fluoren]-2-amine (abbreviation: PCBASF), N-(biphenyl-4-yl)-N-[4-(9-phenyl-9H-carbazol-3-yl)phenyl]-9,9-dimethyl-9H-fluoren-2-amine (abbreviation: PCBBiF), N,N-bis(9,9-dimethyl-9H-fluoren-2-yl)-9,9′-spirobi-9H-fluoren-4-amine, N,N-bis(9,9-dimethyl-9H-fluoren-2-yl)-9,9′-spirobi-9H-fluoren-3-amine, N,N-bis(9,9-dimethyl-9H-fluoren-2-yl)-9,9′-spirobi-9H-fluoren-2-amine, N,N-bis(9,9-dimethyl-9H-fluoren-2-yl)-9,9′-spirobi-9H-fluoren-1-amine, 9-[3-(triphenylsilyl)phenyl]-3,9′-bi-9H-carbazole (abbreviation: PSiCzCz), and 9′-phenyl-9′H-9,3′:6′,9″-tercarbazole (abbreviation: PSiCzGI).

Examples of the substance with a hole-transport property include N,N-di(p-tolyl)-N,N′-diphenyl-p-phenylenediamine (abbreviation: DTDPPA), 4,4′-bis[N-(4-diphenylaminophenyl)-N-phenylamino]biphenyl (abbreviation: DPAB), 4,4′-bis(N-{4-[N-(3-methylphenyl)-N-phenylamino]phenyl}-N-phenylamino)biphenyl (abbreviation: DNTPD), and 1,3,5-tris[N-(4-diphenylaminophenyl)-N-phenylamino]benzene (abbreviation: DPA3B).

The formation of the hole-injection layer 111 can improve the hole-injection property, which allows the light-emitting device to be driven at a low voltage.

Among substances with an acceptor property, the organic compound with an acceptor property is easy to use because it is easily deposited by evaporation.

The hole-transport layer 112 is formed using a substance with a hole-transport property. The substance with a hole-transport property preferably has a hole mobility of 1×10⁻⁶ cm²/Vs or higher.

Examples of the substance with a hole-transport property include compounds having an aromatic amine skeleton, such as 4,4′-bis[N-(1-naphthyl)-N-phenylamino]biphenyl (abbreviation: NPB), N,N-diphenyl-NN-bis(3-methylphenyl)-4,4′-diaminobiphenyl (abbreviation: TPD), N,N′-bis(9,9′-spirobi[9H-fluoren]-2-yl)-N,N-diphenyl-4,4′-diaminobiphenyl (abbreviation: BSPB), 4-phenyl-4′-(9-phenylfluoren-9-yl)triphenylamine (abbreviation: BPAFLP), 4-phenyl-3′-(9-phenylfluoren-9-yl)triphenylamine (abbreviation: mBPAFLP), 4-phenyl-4′-(9-phenyl-9H-carbazol-3-yl)triphenylamine (abbreviation: PCBA1BP), 4,4′-diphenyl-4″-(9-phenyl-9H-carbazol-3-yl)triphenylamine (abbreviation: PCBBi1BP), 4-(1-naphthyl)-4′-(9-phenyl-9H-carbazol-3-yl)triphenylamine (abbreviation: PCBANB), 4,4′-di(1-naphthyl)-4″-(9-phenyl-9H-carbazol-3-yl)triphenylamine (abbreviation: PCBNBB), 9,9-dimethyl-N-phenyl-N-[4-(9-phenyl-9H-carbazol-3-yl)phenyl]fluoren-2-amine (abbreviation: PCBAF), and N-phenyl-N-[4-(9-phenyl-9H-carbazol-3-yl)phenyl]-9,9′-spirobi[9H-fluoren]-2-amine (abbreviation: PCBASF); compounds having a carbazole skeleton, such as 1,3-bis(N-carbazolyl)benzene (abbreviation: mCP), 4,4′-di(N-carbazolyl)biphenyl (abbreviation: CBP), 3,6-bis(3,5-diphenylphenyl)-9-phenylcarbazole (abbreviation: CzTP), 3,3′-bis(9-phenyl-9H-carbazole) (abbreviation: PCCP), 9,9′-bis(biphenyl-4-yl)-3,3′-bi-9H-carbazole (abbreviation: BisBPCz), 9,9′-bis(biphenyl-3-yl)-3,3′-bi-9H-carbazole (abbreviation: BismBPCz), 9-(biphenyl-3-yl)-9′-(biphenyl-4-yl)-9H,9′H-3,3′-bicarbazole (abbreviation: mBPCCBP), 9-(2-naphthyl)-9′-phenyl-9H,9′H-3,3′-bicarbazole (abbreviation: βNCCP), 9-(3-biphenyl)-9′-(2-naphthyl)-3,3′-bi-9H-carbazole (abbreviation: βNCCmBP), 9-(4-biphenyl)-9′-(2-naphthyl)-3,3′-bi-9H-carbazole (abbreviation: βNCCBP), 9,9′-di-2-naphthyl-3,3′-9H,9′H-bicarbazole (abbreviation: BisβNCz), 9-(2-naphthyl)-9′-[1,1′: 4′,1″-terphenyl]-3-yl-3,3′-9H,9′H-bicarbazole, 9-(2-naphthyl)-9′-[1,1′: 3′,1″-terphenyl]-3-yl-3,3′-9H,9′H-bicarbazole, 9-(2-naphthyl)-9′-[1,1′: 3′,1″-terphenyl]-5′-yl-3,3′-9H,9′H-bicarbazole, 9-(2-naphthyl)-9′-[1,1′: 4′,1″-terphenyl]-4-yl-3,3′-9H,9′H-bicarbazole, 9-(2-naphthyl)-9′-[1,1′: 3′,1″-terphenyl]-4-yl-3,3′-9H,9′H-bicarbazole, 9-(2-naphthyl)-9′-(triphenylen-2-yl)-3,3′-9H,9′H-bicarbazole, 9-phenyl-9′-(triphenylen-2-yl)-3,3′-9H,9′H-bicarbazole (abbreviation: PCCzTp), 9,9′-bis(triphenylen-2-yl)-3,3′-9H,9′H-bicarbazole, 9-(4-biphenyl)-9′-(triphenylen-2-yl)-3,3′-9H,9′H-bicarbazole, 9-(triphenylen-2-yl)-9′-[1,1′: 3′,1″-terphenyl]-4-yl-3,3′-9H,9′H-bicarbazole, N,N-bis(9,9-dimethyl-9H-fluoren-2-yl)-9,9′-spirobi-9H-fluoren-1-amine, and 9-[3-(triphenylsylyl)phenyl]-3,9′-bi-9H-carbazole (abbreviation: PSiCzCz); compounds having a thiophene skeleton, such as 4,4′,4″-(benzene-1,3,5-triyl)tri(dibenzothiophene) (abbreviation: DBT3P-II), 2,8-diphenyl-4-[4-(9-phenyl-9H-fluoren-9-yl)phenyl]dibenzothiophene (abbreviation: DBTFLP-III), and 4-[4-(9-phenyl-9H-fluoren-9-yl)phenyl]-6-phenyldibenzothiophene (abbreviation: DBTFLP-IV); and compounds having a furan skeleton, such as 4,4′,4″-(benzene-1,3,5-triyl)tri(dibenzofuran) (abbreviation: DBF3P-II) and 4-{3-[3-(9-phenyl-9H-fluoren-9-yl)phenyl]phenyl}dibenzofuran (abbreviation: mmDBFFLBi-II). Among the above materials, the compound having an aromatic amine skeleton or the compound having a carbazole skeleton is preferable because the compound is highly reliable and has a high hole-transport property to contribute to a reduction in driving voltage. Any of the organic compounds given as examples of the substance with a hole-transport property used in the composite material for the hole-injection layer 111 can also be suitably used as the material contained in the hole-transport layer 112.

The hole-transport layer 112 may have a stacked-layer structure. Among the stacked layers, a layer (electron-blocking layer) in contact with the light-emitting layer 113 is preferably formed using a deuterated organic compound. Examples of a material that is preferably used for the electron-blocking layer include materials similar to later-described materials used as the second organic compound. With the use of the deuterated organic compound for the electron-blocking layer in contact with the light-emitting layer, the electron-blocking layer can have less deterioration of its organic compound even when being excited, whereby the light-emitting device can have less deterioration and high reliability.

An emission center substance contained in the light-emitting layer 113 is preferably a phosphorescent substance or a substance exhibiting thermally activated delayed fluorescence (TADF).

Examples of the material that can be used when a phosphorescent substance is used as the light-emitting substance in the light-emitting layer 113 are as follows.

The examples include organometallic iridium complexes having a 4H-triazole skeleton, such as tris{2-[5-(2-methylphenyl)-4-(2,6-dimethylphenyl)-4H-1,2,4-triazol-3-yl-κN²]phenyl-κC}iridium(III) (abbreviation: [Ir(mpptz-dmp)₃]) and tris(5-methyl-3,4-diphenyl-4H-1,2,4-triazolato)iridium(III) (abbreviation: [Ir(Mptz)₃]); organometallic iridium complexes having a 1H-triazole skeleton, such as tris[3-methyl-1-(2-methylphenyl)-5-phenyl-1H-1,2,4-triazolato]iridium(III) (abbreviation: [Ir(Mptz1-mp)₃]) and tris(1-methyl-5-phenyl-3-propyl-1H-1,2,4-triazolato)iridium(III) (abbreviation: [Ir(Prptz1-Me)₃]); organometallic iridium complexes having an imidazole skeleton, such as fac-tris[l-(2,6-diisopropylphenyl)-2-phenyl-1H-imidazole]iridium(III) (abbreviation: [Ir(iPrpim)₃]), tris[3-(2,6-dimethylphenyl)-7-methylimidazo[1,2-f]phenanthridinato]iridium(III) (abbreviation: [Ir(dmpimpt-Me)₃]), and tris(2-{1-[2,6-bis(1-methylethyl)phenyl]-1H-imidazol-2-yl-κN³}-4-cyanophenyl-κC)iridium(III) (abbreviation: CNImIr); organometallic complexes having a benzimidazolidene skeleton, such as tris[(6-tert-butyl-3-phenyl-2H-imidazo[4,5-b]pyrazin-1-yl-κC2)phenyl-κC]iridium(III) (abbreviation: [Ir(cb)₃]); organometallic iridium complexes in which a phenylpyridine derivative having an electron-withdrawing group is a ligand, such as bis[2-(4′,6′-difluorophenyl)pyridinato-N,C²′]iridium(III) tetrakis(1-pyrazolyl)borate (abbreviation: FIr6), bis[2-(4′,6′-difluorophenyl)pyridinato-N,C^{2′}]iridium(III) picolinate (abbreviation: FIrpic), bis{2-[3′,5′-bis(trifluoromethyl)phenyl]pyridinato-N,C^{2′}}iridium(III) picolinate (abbreviation: [Ir(CF₃ppy)₂(pic)]), and bis[2-(4′,6′-difluorophenyl)pyridinato-N,C^{2′}]iridium(III) acetylacetonate (abbreviation: FIracac); and platinum complexes such as (2-{3-[3-(3,5-di-tert-butylphenyl)banzimidazol-1-yl-2-κC²]phenoxy-κC²}-9-(4-tert-butyl-2-pyridinyl-κN)carbazole-2,1-diyl-κC)platinum(II) (abbreviation: PtON-TBBI). These compounds emit blue phosphorescent light and have an emission peak in the wavelength range from 450 nm to 520 nm. Alternatively, a compound obtained by substituting deuterium for part of hydrogen in any of these compounds can also be used.

Other examples include organometallic iridium complexes having a pyrimidine skeleton, such as tris(4-methyl-6-phenylpyrimidinato)iridium(III) (abbreviation: [Ir(mppm)₃]), tris(4-t-butyl-6-phenylpyrimidinato)iridium(III) (abbreviation: [Ir(tBuppm)₃]), (acetylacetonato)bis(6-methyl-4-phenylpyrimidinato)iridium(III) (abbreviation: [Ir(mppm)₂(acac)]), (acetylacetonato)bis(6-tert-butyl-4-phenylpyrimidinato)iridium(III) (abbreviation: [Ir(tBuppm)₂(acac)]), (acetylacetonato)bis[6-(2-norbornyl)-4-phenylpyrimidinato]iridium(III) (abbreviation: [Ir(nbppm)₂(acac)]), (acetylacetonato)bis[5-methyl-6-(2-methylphenyl)-4-phenylpyrimidinato]iridium(III) (abbreviation: [Ir(mpmppm)₂(acac)]), and (acetylacetonato)bis(4,6-diphenylpyrimidinato)iridium(III) (abbreviation: [Ir(dppm)₂(acac)]); organometallic iridium complexes having a pyrazine skeleton, such as (acetylacetonato)bis(3,5-dimethyl-2-phenylpyrazinato)iridium(III) (abbreviation: [Ir(mppr-Me)₂(acac)]) and (acetylacetonato)bis(5-isopropyl-3-methyl-2-phenylpyrazinato)iridium(III) (abbreviation: [Ir(mppr-iPr)₂(acac)]); organometallic iridium complexes having a pyridine skeleton, such as tris(2-phenylpyridinato-N,C^{2′})iridium(III) (abbreviation: [Ir(ppy)₃]), bis(2-phenylpyridinato-N,C²′)iridium(III) acetylacetonate (abbreviation: [Ir(ppy)₂(acac)]), bis(benzo[h]quinolinato)iridium(III) acetylacetonate (abbreviation: [Ir(bzq)₂(acac)]), tris(benzo[h]quinolinato)iridium(III) (abbreviation: [Ir(bzq)₃]), tris(2-phenylquinolinato-N,C²′)iridium(III) (abbreviation: [Ir(pq)₃]), bis(2-phenylquinolinato-N,C²)iridium(III) acetylacetonate (abbreviation: [Ir(pq)₂(acac)]), [2-d3-methyl-8-(2-pyridinyl-κN)benzofuro[2,3-b]pyridine-κC]bis[2-(5-d₃-methyl-2-pyridinyl-κN²)phenyl-κC]iridium(III) (abbreviation: Ir(5mppy-d₃)₂(mbfpypy-d₃)), {2-(methyl-d₃)-8-[4-(1-methylethyl-1-d)-2-pyridinyl-κN]benzofuro[2,3-b]pyridin-7-yl-κC}bis{5-(methyl-d₃)-2-[5-(methyl-d₃)-2-pyridinyl-κN]phenyl-κC}iridium(III) (abbreviation: Ir(5mtpy-d6)₂(mbfpypy-iPr-d₄)), [2-d₃-methyl-(2-pyridinyl-κN)benzofuro[2,3-b]pyridine-κC]bis[2-(2-pyridinyl-κN)phenyl-κC]iridium(III) (abbreviation: Ir(ppy)₂(mbfpypy-d₃)), [2-(4-methyl-5-phenyl-2-pyridinyl-κN)phenyl-κC]bis[2-(2-pyridinyl-κN)phenyl-κC]iridium(III) (abbreviation: [Ir(ppy)₂(mdppy)]), [2-(4-d₃-methyl-5-phenyl-2-pyridinyl-κN²)phenyl-κC]bis[2-(5-d₃-methyl-2-pyridinyl-κN²)phenyl-κC]iridium(III) (abbreviation: [Ir(5mppy-d₃)2(mdppy-d₃)]), [2-methyl-(2-pyridinyl-κN)benzofuro[2,3-b]pyridine-κC]bis[2-(2-pyridinyl-κN)phenyl-κC]iridium(III) (abbreviation: [Ir(ppy)₂(mbfpypy)]), [2-(4-methyl-5-phenyl-2-pyridinyl-κN)phenyl-κC]bis[2-(2-pyridinyl-κN)phenyl-κC]iridium (abbreviation: [Ir(ppy)₂(mdppy)]), and tris{2-[5-(methyl-d3)-4-phenyl-2-pyridinyl-κN]phenyl-κC}iridium(III) (abbreviation: Ir(5m4dppy-d₃)₃; and rare earth metal complexes such as tris(acetylacetonato) (monophenanthroline)terbium(III) (abbreviation: [Tb(acac)₃(Phen)]). These are mainly compounds that emit green phosphorescent light and have an emission peak in the wavelength range from 500 nm to 600 nm. Note that organometallic iridium complexes having a pyrimidine skeleton have distinctively high reliability or emission efficiency and thus are particularly preferable. Alternatively, a compound obtained by substituting deuterium for part of hydrogen in any of these compounds can also be used.

Other examples include organometallic iridium complexes having a pyrimidine skeleton, such as (diisobutyrylmethanato)bis[4,6-bis(3-methylphenyl)pyrimidinato]iridium(III) (abbreviation: [Ir(5mdppm)₂(dibm)]), bis[4,6-bis(3-methylphenyl)pyrimidinato](dipivaloylmethanato)iridium(III) (abbreviation: [Ir(5mdppm)₂(dpm)]), and bis[4,6-di(naphthalen-1-yl)pyrimidinato](dipivaloylmethanato)iridium(III) (abbreviation: [Ir(d1npm)₂(dpm)]); organometallic iridium complexes having a pyrazine skeleton, such as (acetylacetonato)bis(2,3,5-triphenylpyrazinato)iridium(III) (abbreviation: [Ir(tppr)₂(acac)]), bis(2,3,5-triphenylpyrazinato)(dipivaloylmethanato)iridium(III) (abbreviation: [Ir(tppr)₂(dpm)]), and (acetylacetonato)bis[2,3-bis(4-fluorophenyl)quinoxalinato]iridium(III) (abbreviation: [Ir(Fdpq)₂(acac)]); organometallic iridium complexes having a pyridine skeleton, such as tris(1-phenylisoquinolinato-N,C2′)iridium(III) (abbreviation: [Ir(piq)₃]), bis(1-phenylisoquinolinato-N,C²′)iridium(III) acetylacetonate (abbreviation: [Ir(piq)₂(acac)]), (3,7-diethyl-4,6-nonanedionato-κO⁴,κO⁶)bis[2,4-dimethyl-6-[7-(1-methylethyl)-1-isoquinolinyl-N]phenyl-κC]iridium(III), and (3,7-diethyl-4,6-nonanedionato-κO⁴,κO⁶)bis[2,4-dimethyl-6-[5-(1-methylethyl)-2-quinolinyl-κN]phenyl-κC]iridium(III); platinum complexes such as 2,3,7,8,12,13,17,18-octaethyl-21H,23H-porphyrinplatinum(II) (abbreviation: PtOEP); and rare earth metal complexes such as tris(1,3-diphenyl-1,3-propanedionato)(monophenanthroline)europium(III) (abbreviation: [Eu(DBM)₃(Phen)]) and tris[1-(2-thenoyl)-3,3,3-trifluoroacetonato](monophenanthroline)europium(III) (abbreviation: [Eu(TTA)₃(Phen)]). These compounds emit red phosphorescent light and have an emission peak in the wavelength range from 600 nm to 700 nm. Furthermore, the organometallic iridium complexes having a pyrazine skeleton can provide red light emission with favorable chromaticity. Alternatively, a compound obtained by substituting deuterium for part of hydrogen in any of these compounds can also be used.

Note that in one embodiment of the present invention, the use of a deuterated compound as the emission center substance improves the emission efficiency. Thus, the emission center substance is preferably a deuterated material.

Besides the above phosphorescent compounds, known phosphorescent compounds may be selected and used.

Examples of the TADF material include a fullerene, a derivative thereof, an acridine, a derivative thereof, and an eosin derivative. Furthermore, a metal-containing porphyrin, such as a porphyrin containing magnesium (Mg), zinc (Zn), cadmium (Cd), tin (Sn), platinum (Pt), indium (In), or palladium (Pd), can be given. Examples of the metal-containing porphyrin include a protoporphyrin-tin fluoride complex (SnF₂(Proto IX)), a mesoporphyrin-tin fluoride complex (SnF₂(Meso IX)), a hematoporphyrin-tin fluoride complex (SnF₂(Hemato IX)), a coproporphyrin tetramethyl ester-tin fluoride complex (SnF₂(Copro III-4Me)), an octaethylporphyrin-tin fluoride complex (SnF₂(OEP)), an etioporphyrin-tin fluoride complex (SnF₂(Etio I)), and an octaethylporphyrin-platinum chloride complex (PtCl₂OEP), which are represented by the following structural formulae.

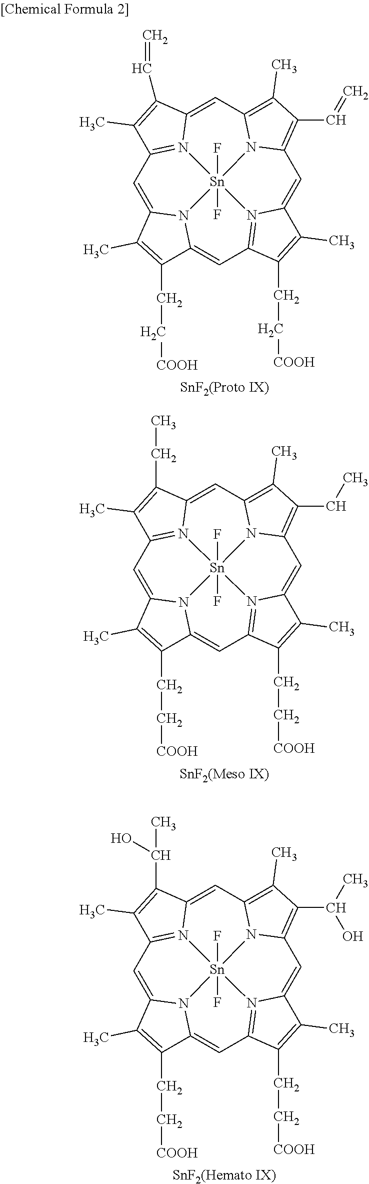

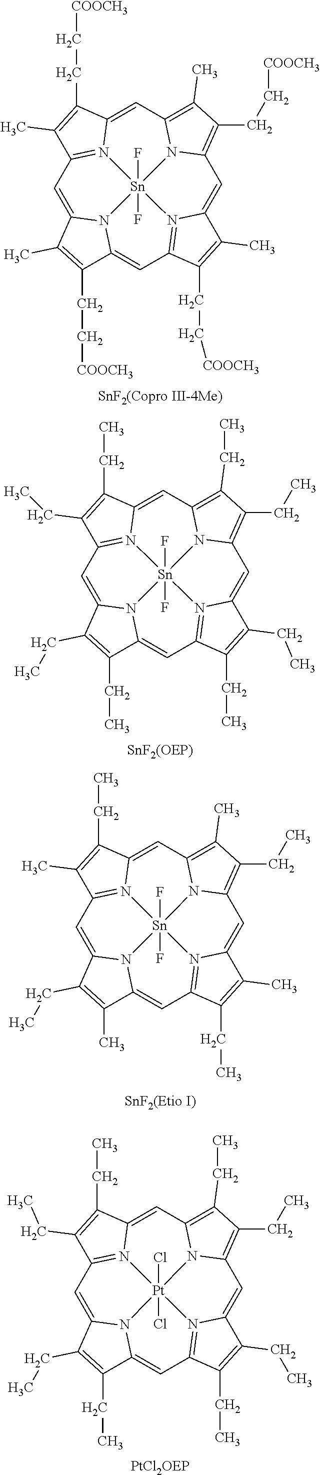

Alternatively, it is possible to use a heterocyclic compound having one or both of a 7r-electron rich heteroaromatic ring and a π-electron deficient heteroaromatic ring which is represented by any of the following structural formulae, such as 2-(biphenyl-4-yl)-4,6-bis(12-phenylindolo[2,3-a]carbazol-11-yl)-1,3,5-triazine (abbreviation: PIC-TRZ), 9-(4,6-diphenyl-1,3,5-triazin-2-yl)-9′-phenyl-9H,9′H-3,3′-bicarbazole (abbreviation: PCCzTzn), 2-{4-[3-(N-phenyl-9H-carbazol-3-yl)-9H-carbazol-9-yl]phenyl}-4,6-diphenyl-1,3,5-triazine (abbreviation: PCCzPTzn), 2-[4-(10H-phenoxazin-10-yl)phenyl]-4,6-diphenyl-1,3,5-triazine (abbreviation: PXZ-TRZ), 3-[4-(5-phenyl-5,10-dihydrophenazin-10-yl)phenyl]-4,5-diphenyl-1,2,4-triazole (abbreviation: PPZ-3TPT), 3-(9,9-dimethyl-9H-acridin-10-yl)-9H-xanthen-9-one (abbreviation: ACRXTN), bis[4-(9,9-dimethyl-9,10-dihydroacridine)phenyl]sulfone (abbreviation: DMAC-DPS), or 10-phenyl-10H,10′H-spiro[acridin-9,9′-anthracen]-10′-one (abbreviation: ACRSA). Such a heterocyclic compound is preferable because of having high electron-transport and hole-transport properties owing to a π-electron rich heteroaromatic ring and a π-electron deficient heteroaromatic ring. Among skeletons having the π-electron deficient heteroaromatic ring, a pyridine skeleton, a diazine skeleton (a pyrimidine skeleton, a pyrazine skeleton, or a pyridazine skeleton), and a triazine skeleton are preferable because of their high stability and reliability. In particular, a benzofuropyrimidine skeleton, a benzothienopyrimidine skeleton, a benzofuropyrazine skeleton, and a benzothienopyrazine skeleton are preferable because of their high acceptor properties and high reliability. Among skeletons having the π-electron rich heteroaromatic ring, an acridine skeleton, a phenoxazine skeleton, a phenothiazine skeleton, a furan skeleton, a thiophene skeleton, and a pyrrole skeleton have high stability and reliability; thus, at least one of these skeletons is preferably included. A dibenzofuran skeleton is preferable as a furan skeleton, and a dibenzothiophene skeleton is preferable as a thiophene skeleton. As a pyrrole skeleton, an indole skeleton, a carbazole skeleton, an indolocarbazole skeleton, a bicarbazole skeleton, and a 3-(9-phenyl-9H-carbazol-3-yl)-9H-carbazole skeleton are particularly preferable. Note that a substance in which the π-electron rich heteroaromatic ring is directly bonded to the π-electron deficient heteroaromatic ring is particularly preferable because the electron-donating property of the π-electron rich heteroaromatic ring and the electron-accepting property of the π-electron deficient heteroaromatic ring are both improved, the energy difference between the lowest singlet excited level (Si level) and the T1 level becomes small, and thus thermally activated delayed fluorescence can be obtained with high efficiency. Note that an aromatic ring to which an electron-withdrawing group such as a cyano group is bonded may be used instead of the π-electron deficient heteroaromatic ring. As a π-electron rich skeleton, an aromatic amine skeleton, a phenazine skeleton, or the like can be used. As a π-electron deficient skeleton, a xanthene skeleton, a thioxanthene dioxide skeleton, an oxadiazole skeleton, a triazole skeleton, an imidazole skeleton, an anthraquinone skeleton, a skeleton containing boron such as phenylborane or boranthrene, an aromatic ring or a heteroaromatic ring having a cyano group or a nitrile group such as benzonitrile or cyanobenzene, a carbonyl skeleton such as benzophenone, a phosphine oxide skeleton, a sulfone skeleton, or the like can be used. As described above, a π-electron deficient skeleton and a π-electron rich skeleton can be used instead of at least one of the π-electron deficient heteroaromatic ring and the π-electron rich heteroaromatic ring. Alternatively, a compound obtained by substituting deuterium for part of hydrogen in any of these compounds can also be used.

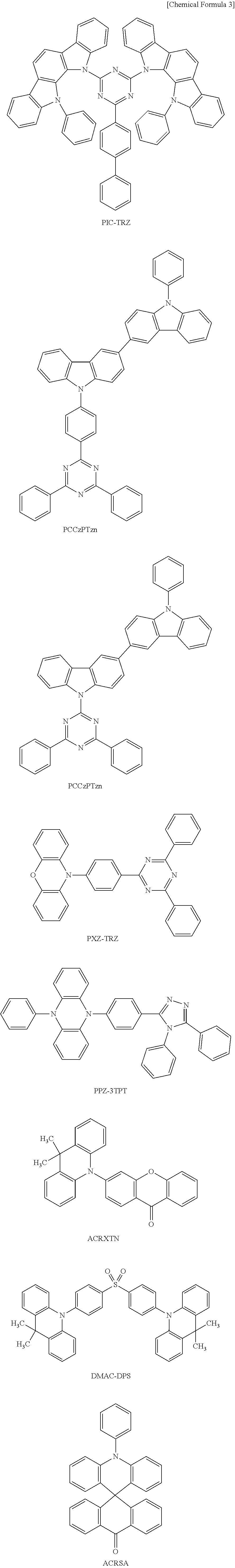

Note that a TADF material is a material having a small difference between the Si level and the T₁ level and a function of converting triplet excitation energy into singlet excitation energy by reverse intersystem crossing. Thus, a TADF material can upconvert triplet excitation energy into singlet excitation energy (i.e., reverse intersystem crossing) using a small amount of thermal energy and efficiently generate a singlet excited state. In addition, the triplet excitation energy can be converted into light emission.

An exciplex whose excited state is formed of two kinds of substances has an extremely small difference between the Si level and the T1 level and functions as a TADF material capable of converting triplet excitation energy into singlet excitation energy.

A phosphorescent spectrum observed at a low temperature (e.g., 77 K to 10 K) is used for an index of the T1 level. When the level of energy with a wavelength of the line obtained by extrapolating a tangent to the fluorescent spectrum at a tail on the short wavelength side is the Si level and the level of energy with a wavelength of the line obtained by extrapolating a tangent to the phosphorescent spectrum at a tail on the short wavelength side is the T1 level, the difference between the Si level and the T1 level of the TADF material is preferably less than or equal to 0.3 eV, further preferably less than or equal to 0.2 eV.

When a TADF material is used as the light-emitting substance, the Si level of the energy donor is preferably higher than that of the TADF material. In addition, the T1 level of the energy donor is preferably higher than that of the TADF material.

An organic compound that can be used as the first organic compound of the light-emitting layer 113 is preferably a substance with an electron-transport property containing deuterium and having an electron mobility higher than or equal to 1×10-7 cm²/Vs, preferably higher than or equal to 1×10⁻⁶ cm²/Vs, when the square root of electric field strength [V/cm] is 600.

An organic compound including a π-electron deficient heteroaromatic ring is preferable as the first organic compound. Examples of the organic compound including a π-electron deficient heteroaromatic ring skeleton include an organic compound including a heteroaromatic ring having a polyazole skeleton, an organic compound including a heteroaromatic ring having a pyridine skeleton, an organic compound including a heteroaromatic ring having a diazine skeleton, and an organic compound including a heteroaromatic ring having a triazine skeleton.

Among the above materials, the organic compound including a heteroaromatic ring having a diazine skeleton (a pyrimidine skeleton, a pyrazine skeleton, or a pyridazine skeleton), the organic compound including a heteroaromatic ring having a pyridine skeleton, and the organic compound including a heteroaromatic ring having a triazine skeleton have high reliability and thus are preferable. In particular, the organic compound including a heteroaromatic ring having a diazine (pyrimidine or pyrazine) skeleton and the organic compound including a heteroaromatic ring having a triazine skeleton have a high electron-transport property to contribute to a reduction in driving voltage. A benzofuropyrimidine skeleton, a benzothienopyrimidine skeleton, a benzofuropyrazine skeleton, and a benzothienopyrazine skeleton are preferable because of their high acceptor properties and high reliability.

An organic compound that includes a π-electron deficient heteroaromatic ring skeleton and can be used as the first organic compound is preferably a deuterated organic compound of any of the following organic compounds, for example. The examples include organic compounds having an azole skeleton, such as 2-(4-biphenylyl)-5-(4-tert-butylphenyl)-1,3,4-oxadiazole (abbreviation: PBD), 3-(4-biphenylyl)-4-phenyl-5-(4-tert-butylphenyl)-1,2,4-triazole (abbreviation: TAZ), 1,3-bis[5-(p-tert-butylphenyl)-1,3,4-oxadiazol-2-yl]benzene (abbreviation: OXD-7), 9-[4-(5-phenyl-1,3,4-oxadiazol-2-yl)phenyl]-9H-carbazole (abbreviation: CO11), 2,2′,2″-(1,3,5-benzenetriyl)tris(1-phenyl-1H-benzimidazole) (abbreviation: TPBI), 2-[3-(dibenzothiophen-4-yl)phenyl]-1-phenyl-1H-benzimidazole (abbreviation: mDBTBIm-II), and 4,4′-bis(5-methylbenzoxazol-2-yl)stilbene (abbreviation: BzOS); organic compounds including a heteroaromatic ring having a pyridine skeleton, such as 3,5-bis[3-(9H-carbazol-9-yl)phenyl]pyridine (abbreviation: 35DCzPPy), 1,3,5-tri[3-(3-pyridyl)phenyl]benzene (abbreviation: TmPyPB), bathophenanthroline (abbreviation: BPhen), bathocuproine (abbreviation: BCP), 2,9-di(naphthalen-2-yl)-4,7-diphenyl-1,10-phenanthroline (abbreviation: NBPhen), 2,2′-(1,3-phenylene)bis(9-phenyl-1,10-phenanthroline) (abbreviation: mPPhen2P), 2-[3-(2-triphenylenyl)phenyl]-1,10-phenanthroline (abbreviation: mTpPPhen), 2-phenyl-9-(2-triphenylenyl)-1,10-phenanthroline (abbreviation: Ph-TpPhen), 2-[4-(9-phenanthrenyl)-1-naphthalenyl]-1,10-phenanthroline (abbreviation: PnNPhen), and 2-[4-(2-triphenylenyl)phenyl]-1,10-phenanthroline (abbreviation: pTpPPhen); organic compounds having a diazine skeleton, such as 2-[3-(dibenzothiophen-4-yl)phenyl]dibenzo[f,h]quinoxaline (abbreviation: 2mDBTPDBq-II), 2-[3′-(dibenzothiophen-4-yl)biphenyl-3-yl]dibenzo[f,h]quinoxaline (abbreviation: 2mDBTBPDBq-II), 2-[3′-(9H-carbazol-9-yl)biphenyl-3-yl]dibenzo[f,h]quinoxaline (abbreviation: 2mCzBPDBq), 2-[4′-(9-phenyl-9H-carbazol-3-yl)-3,1′-biphenyl-1-yl]dibenzo[f,h]quinoxaline (abbreviation: 2mpPCBPDBq), 2-[4-(3,6-diphenyl-9H-carbazol-9-yl)phenyl]dibenzo[f,h]quinoxaline (abbreviation: 2CzPDBq-III), 7-[3-(dibenzothiophen-4-yl)phenyl]dibenzo[f,h]quinoxaline (abbreviation: 7mDBTPDBq-II), 6-[3-(dibenzothiophen-4-yl)phenyl]dibenzo[f,h]quinoxaline (abbreviation: 6mDBTPDBq-II), 9-[3′-(dibenzothiophen-4-yl)biphenyl-3-yl]naphtho[1′,2′:4,5]furo[2,3-b]pyrazine (abbreviation: 9mDBtBPNfpr), 9-[3′-(dibenzothiophen-4-yl)biphenyl-4-yl]naphtho[1′,2′:4,5]furo[2,3-b]pyrazine (abbreviation: 9pmDBtBPNfpr), 4,6-bis[3-(phenanthren-9-yl)phenyl]pyrimidine (abbreviation: 4,6mPnP2Pm), 4,6-bis[3-(dibenzothiophen-4-yl)phenyl]pyrimidine (abbreviation: 4,6mDBTP2Pm-II), 4,6-bis[3-(9H-carbazol-9-yl)phenyl]pyrimidine (abbreviation: 4,6mCzP2Pm), 9,9′-[pyrimidine-4,6-diylbis(biphenyl-3,3′-diyl)]bis(9H-carbazole) (abbreviation: 4,6mCzBP2Pm), 8-(biphenyl-4-yl)-4-[3-(dibenzothiophen-4-yl)phenyl]-[1]benzofuro[3,2-d]pyrimidine (abbreviation: 8BP-4mDBtPBfpm), 3,8-bis[3-(dibenzothiophen-4-yl)phenyl]benzofuro[2,3-b]pyrazine (abbreviation: 3,8mDBtP2Bfpr), 4,8-bis[3-(dibenzothiophen-4-yl)phenyl]-[1]benzofuro[3,2-d]pyrimidine (abbreviation: 4,8mDBtP2Bfpm), 8-[3′-(dibenzothiophen-4-yl)(biphenyl-3-yl)]naphtho[1′,2′: 4,5]furo[3,2-d]pyrimidine (abbreviation: 8mDBtBPNfpm), 8-[(2,2′-binaphthalen)-6-yl]-4-[3-(dibenzothiophen-4-yl)phenyl]-[1]benzofuro[3,2-d]pyrimidine (abbreviation: 8(PN2)-4mDBtPBfpm), 2,2′-(pyridine-2,6-diyl)bis(4-phenylbenzo[h]quinazoline) (abbreviation: 2,6(P-Bqn)2Py), 2,2′-(pyridine-2,6-diyl)bis{4-[4-(2-naphthyl)phenyl]-6-phenylpyrimidine}(abbreviation: 2,6(NP—PPm)2Py), 6-(biphenyl-3-yl)-4-[3,5-bis(9H-carbazol-9-yl)phenyl]-2-phenylpyrimidine (abbreviation: 6mBP-4Cz2PPm), 2,6-bis(4-naphthalen-1-ylphenyl)-4-[4-(3-pyridyl)phenyl]pyrimidine (abbreviation: 2,4NP-6PyPPm), 4-[3,5-bis(9H-carbazol-9-yl)phenyl]-2-phenyl-6-(1,1′-biphenyl-4-yl)pyrimidine (abbreviation: 6BP-4Cz2PPm), 7-[4-(9-phenyl-9H-carbazol-2-yl)quinazolin-2-yl]-7H-dibenzo[c,g]carbazole (abbreviation: PC-cgDBCzQz), and 8-(p-terphenyl-3-yl)-4-[3-(dibenzothiophen-4-yl)phenyl]-[1]benzo[3,2-d]pyrimidine (abbreviation: 8mpTP-4mDBtPBfpm); and organic compounds including a heteroaromatic ring having a triazine skeleton, such as 2-(biphenyl-4-yl)-4-phenyl-6-(9,9′-spirobi[9H-fluoren]-2-yl)-1,3,5-triazine (abbreviation: BP-SFTzn), 2-{3-[3-(benzo[b]naphtho[1,2-d]furan-8-yl)phenyl]phenyl}-4,6-diphenyl-1,3,5-triazine (abbreviation: mBnfBPTzn), 2-{3-[3-(benzo[b]naphtho[1,2-d]furan-6-yl)phenyl]phenyl}-4,6-diphenyl-1,3,5-triazine (abbreviation: mBnfBPTzn-02), 2-{4-[3-(N-phenyl-9H-carbazol-3-yl)-9H-carbazol-9-yl]phenyl}-4,6-diphenyl-1,3,5-triazine (abbreviation: PCCzPTzn), 9-[3-(4,6-diphenyl-1,3,5-triazin-2-yl)phenyl]-9′-phenyl-2,3′-bi-9H-carbazole (abbreviation: mPCCzPTzn-02), 2-[3′-(9,9-dimethyl-9H-fluoren-2-yl)biphenyl-3-yl]-4,6-diphenyl-1,3,5-triazine (abbreviation: mFBPTzn), 5-[3-(4,6-diphenyl-1,3,5-triazin-2-yl)phenyl]-7,7-dimethyl-5H,7H-indeno[2,1-b]carbazole (abbreviation: mINc(II)PTzn), 2-{3-[3-(dibenzothiophen-4-yl)phenyl]phenyl}-4,6-diphenyl-1,3,5-triazine (abbreviation: mDBtBPTzn), 2,4,6-tris(3′-(pyridin-3-yl)biphenyl-3-yl)-1,3,5-triazine (abbreviation: TmPPPyTz), 2-[3-(2,6-dimethyl-3-pyridinyl)-5-(9-phenanthrenyl)phenyl]-4,6-diphenyl-1,3,5-triazine (abbreviation: mPn-mDMePyPTzn), 2-[3′-(triphenylen-2-yl)bipheynyl-3-yl]-4,6-diphenyl-1,3,5-triazine (abbreviation: mTpBPTzn), 3-[9-(4,6-diphenyl-1,3,5-triazin-2-yl)-2-dibenzofuranyl]-9-phenyl-9H-carbazole (abbreviation: PCDBfTzn), 2-[4-(2-naphthalenyl)phenyl]-4-phenyl-6-spiro[9H-fluoren-9,9′-[9H]xanthen]-4-yl-1,3,5-triazine (abbreviation: PNP-SFx(4)Tzn), 9,9′-{6-[3-(triphenylsilyl)phenyl]-1,3,5-triazine-2,4-diyl}bis(9H-carbazole) (abbreviation: SiTrzCz2), 2-phenyl-4,6-bis[3-(triphenylsilyl)phenyl]-1,3,5-triazine (abbreviation: mSiTrz), 11-[4-(biphenyl-4-yl)-6-phenyl-1,3,5-triazin-2-yl]-11,12-dihydro-12-(biphenyl-3-yl)indolo[2,3-a]carbazole (abbreviation: BP-mBPIcz(II)Tzn), 11-[4-(biphenyl-4-yl)-6-phenyl-1,3,5-triazin-2-yl]-11,12-dihydro-12-phenylindolo[2,3-a]carbazole (abbreviation: BP-Icz(II)Tzn), 3-{3-[9-(4,6-diphenyl-1,3,5-triazin-2-yl)-2-dibenzofuranyl]phenyl}-9-phenyl-9H-carbazole (abbreviation: mPCPDBfTzn), 9,9′-[6-(biphenyl-4-yl)-2-phenyl-1,3,5-triazine-4,3″-diyl]bis(9H-carbazole) (abbreviation: Cz-pmCzBPTzn), 2-(biphenyl-3-yl)-4-phenyl-6-{8-[(1,1′: 4′,1″-terphenyl)-4-yl]-1-dibenzofuranyl}-1,3,5-triazine (abbreviation: mBP-TPDBfTzn), 3-phenyl-9-[4-phenyl-6-(9-phenyl-3-dibenzofuranyl)-1,3,5-triazin-2-yl]-9H-carbazole (abbreviation: PDBf-PCzTzn), and 9-[4-(4,6-diphenyl-1,3,5-triazin-2-yl)-2-dibenzothienyl]-2-phenyl-9H-carbazole (abbreviation: PCzDBtTzn). The organic compound including a heteroaromatic ring having a diazine skeleton, the organic compound including a heteroaromatic ring having a pyridine skeleton, and the organic compound including a heteroaromatic ring having a triazine skeleton are preferable because of their high reliability. In particular, the organic compound including a heteroaromatic ring having a diazine (pyrimidine or pyrazine) skeleton and the organic compound including a heteroaromatic ring having a triazine skeleton have a high electron-transport property to contribute to a reduction in driving voltage.

The substance with a hole-transport property that can be used as the second organic compound of the light-emitting layer 113 is preferably an organic compound containing deuterium and having an amine skeleton or a π-electron rich heteroaromatic ring skeleton, for example. As the π-electron rich heteroaromatic ring, a condensed aromatic ring having at least one of an acridine skeleton, a phenoxazine skeleton, a phenothiazine skeleton, a furan skeleton, a thiophene skeleton, and a pyrrole skeleton is preferable; specifically, a carbazole ring, a dibenzothiophene ring, or a ring in which an aromatic ring or a heteroaromatic ring is further condensed to a carbazole ring or a dibenzothiophene ring is preferable.

Such a substance with a hole-transport property further preferably has any of a carbazole skeleton, a dibenzofuran skeleton, a dibenzothiophene skeleton, and an anthracene skeleton. In particular, an aromatic amine including a substituent having a dibenzofuran ring or a dibenzothiophene ring, an aromatic monoamine having a naphthalene ring, or an aromatic monoamine in which a 9-fluorenyl group is bonded to nitrogen of an amine through an arylene group may be used. Note that the substance with a hole-transport property is preferably an organic compound including an N,N-bis(4-biphenyl)amino group to enable fabricating a light-emitting device having a long lifetime.

As such an organic compound, a deuterated organic compound of any of the following organic compounds is preferable, for example. The examples include compounds having an aromatic amine skeleton, such as 4,4′-bis[N-(1-naphthyl)-N-phenylamino]biphenyl (abbreviation: NPB), N,N-diphenyl-N,-bis(3-methylphenyl)-4,4′-diaminobiphenyl (abbreviation: TPD), N,N-bis(9,9′-spirobi[9H-fluoren]-2-yl)-N,N-diphenyl-4,4′-diaminobiphenyl (abbreviation: BSPB), 4-phenyl-4′-(9-phenylfluoren-9-yl)triphenylamine (abbreviation: BPAFLP), 4-phenyl-3′-(9-phenylfluoren-9-yl)triphenylamine (abbreviation: mBPAFLP), 4-phenyl-4′-(9-phenyl-9H-carbazol-3-yl)triphenylamine (abbreviation: PCBA1BP), 4,4′-diphenyl-4″-(9-phenyl-9H-carbazol-3-yl)triphenylamine (abbreviation: PCBBi1BP), 4-(1-naphthyl)-4′-(9-phenyl-9H-carbazol-3-yl)triphenylamine (abbreviation: PCBANB), 4,4′-di(1-naphthyl)-4″-(9-phenyl-9H-carbazol-3-yl)triphenylamine (abbreviation: PCBNBB), 9,9-dimethyl-N-phenyl-N-[4-(9-phenyl-9H-carbazol-3-yl)phenyl]fluoren-2-amine (abbreviation: PCBAF), and N-phenyl-N-[4-(9-phenyl-9H-carbazol-3-yl)phenyl]-9,9′-spirobi[9H-fluoren]-2-amine (abbreviation: PCBASF); compounds having a carbazole skeleton, such as 1,3-bis(N-carbazolyl)benzene (abbreviation: mCP), 4,4′-di(N-carbazolyl)biphenyl (abbreviation: CBP), 3,6-bis(3,5-diphenylphenyl)-9-phenylcarbazole (abbreviation: CzTP), 3,3′-bis(9-phenyl-9H-carbazole) (abbreviation: PCCP), 3,9-bis(9-phenyl-9H-carbazol-3-yl)-9H-carbazole (abbreviation: PCCzPC), 9-(biphenyl-4-yl)-9′-phenyl-3,3′-bi-9H-carbazole (abbreviation: PCCzBP), 9,9′-bis(biphenyl-4-yl)-3,3′-bi-9H-carbazole (abbreviation: BisBPCz), 9,9′-bis(biphenyl-3-yl)-3,3′-bi-9H-carbazole (abbreviation: BismBPCz), 9-(biphenyl-3-yl)-9′-(biphenyl-4-yl)-9H,9′H-3,3′-bicarbazole (abbreviation: mBPCCBP), 9-(2-naphthyl)-9′-phenyl-9H,9′H-3,3′-bicarbazole (abbreviation: βNCCP), 9-(3-biphenyl)-9′-(2-naphthyl)-3,3′-bi-9H-carbazole (abbreviation: βNCCmBP), 9-(4-biphenyl)-9′-(2-naphthyl)-3,3′-bi-9H-carbazole (abbreviation: βNCCBP), 9,9′-di-2-naphthyl-3,3′-9H,9′H-bicarbazole (abbreviation: BisβNCz), 9-(2-naphthyl)-9′-[1,1′: 4′,1″-terphenyl]-3-yl-3,3′-9H,9′H-bicarbazole, 9-(2-naphthyl)-9′-[1,1′: 3′,1″-terphenyl]-3-yl-3,3′-9H,9′H-bicarbazole, 9-(2-naphthyl)-9′-[1,1′: 3′,1″-terphenyl]-5′-yl-3,3′-9H,9′H-bicarbazole, 9-(2-naphthyl)-9′-[1,1′: 4′,1″-terphenyl]-4-yl-3,3′-9H,9′H-bicarbazole, 9-(2-naphthyl)-9′-[1,1′: 3′,1″-terphenyl]-4-yl-3,3′-9H,9′H-bicarbazole, 9-(2-naphthyl)-9′-(triphenylen-2-yl)-3,3′-9H,9′H-bicarbazole, 9-phenyl-9′-(triphenylen-2-yl)-3,3′-9H,9′H-bicarbazole (abbreviation: PCCzTp), 9,9′-bis(triphenylen-2-yl)-3,3′-9H,9′H-bicarbazole, 9-(4-biphenyl)-9′-(triphenylen-2-yl)-3,3′-9H,9′H-bicarbazole, N,N-bis(9,9-dimethyl-9H-fluoren-2-yl)-9,9′-spirobi-9H-fluoren-1-amine, 9-[3-(triphenylsilyl)phenyl]-3,9′-bi-9H-carbazole (abbreviation: PSiCzCz), and 9′-phenyl-9′H-9,3′: 6′,9″-tercarbazole (abbreviation: PSiCzGI); compounds having a thiophene skeleton, such as 4,4′,4″-(benzene-1,3,5-triyl)tri(dibenzothiophene) (abbreviation: DBT3P-II), 2,8-diphenyl-4-[4-(9-phenyl-9H-fluoren-9-yl)phenyl]dibenzothiophene (abbreviation: DBTFLP-III), and 4-[4-(9-phenyl-9H-fluoren-9-yl)phenyl]-6-phenyldibenzothiophene (abbreviation: DBTFLP-IV); and compounds having a furan skeleton, such as 4,4′,4″-(benzene-1,3,5-triyl)tri(dibenzofuran) (abbreviation: DBF3P-II) and 4-{3-[3-(9-phenyl-9H-fluoren-9-yl)phenyl]phenyl}dibenzofuran (abbreviation: mmDBFFLBi-II). Among the above materials, the compound having an aromatic amine skeleton and the compound having a carbazole skeleton are preferable because these compounds are highly reliable and have high hole-transport properties to contribute to a reduction in driving voltage.

In the light-emitting device of one embodiment of the present invention, at least one light-emitting layer has the structure disclosed in Embodiment 1. In the case where the light-emitting device includes a plurality of light-emitting layers, the other light-emitting layers may use fluorescent substances as emission center substances.

Examples of the fluorescent substance that can be used as the emission center substance are given below. Other fluorescent substances can also be used.

The examples include 5,6-bis[4-(10-phenyl-9-anthryl)phenyl]-2,2′-bipyridine (abbreviation: PAP2BPy), 5,6-bis[4′-(10-phenyl-9-anthryl)biphenyl-4-yl]-2,2′-bipyridine (abbreviation: PAPP2BPy), N,N-diphenyl-N,N-bis[4-(9-phenyl-9H-fluoren-9-yl)phenyl]pyrene-1,6-diamine (abbreviation: 1,6FLPAPrn), N,N-bis(3-methylphenyl)-N,N-bis[3-(9-phenyl-9H-fluoren-9-yl)phenyl]pyrene-1,6-diamine (abbreviation: 1,6mMemFLPAPrn), N,N-bis[4-(9H-carbazol-9-yl)phenyl]-N,N-diphenylstilbene-4,4′-diamine (abbreviation: YGA2S), 4-(9H-carbazol-9-yl)-4′-(10-phenyl-9-anthryl)triphenylamine (abbreviation: YGAPA), 4-(9H-carbazol-9-yl)-4′-(9,10-diphenyl-2-anthryl)triphenylamine (abbreviation: 2YGAPPA), N,9-diphenyl-N-[4-(10-phenyl-9-anthryl)phenyl]-9H-carbazol-3-amine (abbreviation: PCAPA), perylene, 2,5,8,11-tetra-tert-butylperylene (abbreviation: TBP), 4-(10-phenyl-9-anthryl)-4′-(9-phenyl-9H-carbazol-3-yl)triphenylamine (abbreviation: PCBAPA), N,N′-(2-tert-butylanthracene-9,10-diyldi-4,1-phenylene)bis(N,N,N-triphenyl-1,4-phenylenediamine) (abbreviation: DPABPA), N,9-diphenyl-N-[4-(9,10-diphenyl-2-anthryl)phenyl]-9H-carbazol-3-amine (abbreviation: 2PCAPPA), N-[4-(9,10-diphenyl-2-anthryl)phenyl]-N,N′,N′-triphenyl-1,4-phenylenediamine (abbreviation: 2DPAPPA), N,N,N′,N′,N″,N″,N′″,N′″-octaphenyldibenzo[g,p]chrysene-2,7,10,15-tetraamine (abbreviation: DBC1), coumarin 30, N-(9,10-diphenyl-2-anthryl)-N,9-diphenyl-9H-carbazol-3-amine (abbreviation: 2PCAPA), N-[9,10-bis(biphenyl-2-yl)-2-anthryl]-N,9-diphenyl-9H-carbazol-3-amine (abbreviation: 2PCABPhA), N-(9,10-diphenyl-2-anthryl)-N,N,N-triphenyl-1,4-phenylenediamine (abbreviation: 2DPAPA), N-[9,10-bis(biphenyl-2-yl)-2-anthryl]-N,N,N-triphenyl-1,4-phenylenediamine (abbreviation: 2DPABPhA), 9,10-bis(biphenyl-2-yl)-N-[4-(9H-carbazol-9-yl)phenyl]-N-phenylanthracen-2-amine (abbreviation: 2YGABPhA), N,N,9-triphenylanthracen-9-amine (abbreviation: DPhAPhA), coumarin 545T, N,N′-diphenylquinacridone (abbreviation: DPQd), rubrene, 5,12-bis(biphenyl-4-yl)-6,11-diphenyltetracene (abbreviation: BPT), 2-(2-{2-[4-(dimethylamino)phenyl]ethenyl}-6-methyl-4H-pyran-4-ylidene)propanedinitrile (abbreviation: DCM1), 2-{2-methyl-6-[2-(2,3,6,7-tetrahydro-1H,5H-benzo[ij]quinolizin-9-yl)ethenyl]-4H-pyran-4-ylidene}propanedinitrile (abbreviation: DCM2), N,N,N′,N′-tetrakis(4-methylphenyl)tetracene-5,11-diamine (abbreviation: p-mPhTD), 7,14-diphenyl-N,N,N′,N′-tetrakis(4-methylphenyl)acenaphtho[1,2-a]fluoranthene-3,10-diamine (abbreviation: p-mPhAFD), 2-{2-isopropyl-6-[2-(1,1,7,7-tetramethyl-2,3,6,7-tetrahydro-1H,5H-benzo[ij]quinolizin-9-yl)ethenyl]-4H-pyran-4-ylidene}propanedinitrile (abbreviation: DCJTI), 2-{2-tert-butyl-6-[2-(1,1,7,7-tetramethyl-2,3,6,7-tetrahydro-1H,5H-benzo[ij]quinolizin-9-yl)ethenyl]-4H-pyran-4-ylidene}propanedinitrile (abbreviation: DCJTB), 2-(2,6-bis{2-[4-(dimethylamino)phenyl]ethenyl}-4H-pyran-4-ylidene)propanedinitrile (abbreviation: BisDCM), 2-{2,6-bis[2-(8-methoxy-1,1,7,7-tetramethyl-2,3,6,7-tetrahydro-1H,5H-benzo[ij]quinolizin-9-yl)ethenyl]-4H-pyran-4-ylidene}propanedinitrile (abbreviation: BisDCJTM), N,N′-diphenyl-N,N′-(1,6-pyrene-diyl)bis[(6-phenylbenzo[b]naphtho[1,2-d]furan)-8-amine](abbreviation: 1,6BnfAPrn-03), N,N-diphenyl-N,N-bis(9-phenyl-9H-carbazol-2-yl)naphtho[2,3-b;6,7-b′]bisbenzofuran-3,10-diamine (abbreviation: 3,10PCA2Nbf(IV)-02), and 3,10-bis[N-(dibenzofuran-3-yl)-N-phenylamino]naphtho[2,3-b;6,7-b′]bisbenzofuran (abbreviation: 3,10FrA2Nbf(IV)-02). Condensed aromatic diamine compounds typified by pyrenediamine compounds such as 1,6FLPAPrn, 1,6mMemFLPAPrn, and 1,6BnfAPrn-03 are particularly preferable because of their high hole-trapping properties, high emission efficiency, or high reliability.

In the case where a fluorescent substance is used as the emission center substance, a material having an acene skeleton, especially an anthracene skeleton is suitably used as the host material. The use of a substance having an anthracene skeleton as the host material for the fluorescent substance makes it possible to obtain a light-emitting layer with high emission efficiency and high durability. Among the substances having an anthracene skeleton, a substance having a diphenylanthracene skeleton, in particular, a substance having a 9,10-diphenylanthracene skeleton, is chemically stable and thus is preferably used as the host material. The host material preferably has a carbazole skeleton because the hole-injection and hole-transport properties are improved; further preferably, the host material has a benzocarbazole skeleton in which a benzene ring is further condensed to a carbazole skeleton because the HOMO level thereof is higher than that of the host material having a carbazole skeleton by approximately 0.1 eV and thus holes enter the host material easily. In particular, the host material preferably has a dibenzocarbazole skeleton because the HOMO level thereof is higher than that of the host material having a carbazole skeleton by approximately 0.1 eV and thus holes enter the host material easily, the hole-transport property is improved, and the heat resistance is increased. Accordingly, a substance that has both a 9,10-diphenylanthracene skeleton and a carbazole skeleton (or a benzocarbazole or dibenzocarbazole skeleton) is further preferable as the host material. Note that in terms of the hole-injection and hole-transport properties described above, instead of a carbazole skeleton, a benzofluorene skeleton or a dibenzofluorene skeleton may be used.

Examples of such a substance include 9-phenyl-3-[4-(10-phenyl-9-anthryl)phenyl]-9H-carbazole (abbreviation: PCzPA), 3-[4-(1-naphthyl)phenyl]-9-phenyl-9H-carbazole (abbreviation: PCPN), 9-[4-(10-phenyl-9-anthracenyl)phenyl]-9H-carbazole (abbreviation: CzPA), 7-[4-(10-phenyl-9-anthryl)phenyl]-7H-dibenzo[c,g]carbazole (abbreviation: cgDBCzPA), 6-[3-(9,10-diphenyl-2-anthryl)phenyl]benzo[b]naphtho[1,2-d]furan (abbreviation: 2mBnfPPA), 9-phenyl-10-[4-(9-phenyl-9H-fluoren-9-yl)biphenyl-4′-yl]anthracene (abbreviation: FLPPA), 9-(1-naphthyl)-10-[4-(2-naphthyl)phenyl]anthracene (abbreviation: αN-βNPAnth), 9-(1-naphthyl)-10-(2-naphthyl)anthracene (abbreviation: α,βADN), 2-(10-phenylanthracen-9-yl)dibenzofuran, 2-(10-phenyl-9-anthracenyl)benzo[b]naphtho[2,3-d]furan (abbreviation: Bnf(II)PhA), 9-(2-naphthyl)-10-[3-(2-naphthyl)phenyl]anthracene (abbreviation: βN-mβNPAnth), and 1-{4-[10-(biphenyl-4-yl)-9-anthracenyl]phenyl}-2-ethyl-1H-benzimidazole (abbreviation: EtBImPBPhA). In particular, CzPA, cgDBCzPA, 2mBnfPPA, and PCzPA exhibit excellent properties and thus are preferably selected.

By mixing the first and second organic compounds, the transport property of the light-emitting layer 113 can be easily adjusted and a recombination region can be easily controlled. The weight ratio of the content of the first organic compound to the content of the second organic compound is 1:19 to 19:1.

The first and second organic compounds form an exciplex. The first and second organic compounds are preferably selected so as to form an exciplex that exhibits light emission whose wavelength overlaps with the wavelength on a lowest-energy-side absorption band of the light-emitting substance, in which case energy can be transferred smoothly and light emission can be obtained efficiently. The use of such a structure is preferable because the driving voltage can also be reduced.

Combination of the first organic compound and the second organic compound whose HOMO level is higher than or equal to that of the first organic compound is preferable for forming an exciplex efficiently. In addition, the LUMO level of the second organic compound is preferably higher than or equal to that of the first organic compound. Note that the LUMO levels and the HOMO levels of the materials can be derived from the electrochemical characteristics (the reduction potentials and the oxidation potentials) of the materials that are measured by cyclic voltammetry (CV).

Note that the formation of an exciplex can be confirmed by, for example, comparing the emission spectra of the first organic compound, the second organic compound, and a mixed film of the first and second organic compounds, and observing a phenomenon in which the emission spectrum of the mixed film is shifted to the longer wavelength side (or has another peak on the longer wavelength side) than the emission spectrum of each of the first and second organic compounds. Alternatively, the formation of an exciplex can be confirmed by comparing transient photoluminescence (PL) of the first organic compound, the second organic compound, and the mixed film of the first and second organic compounds and observing a difference in transient response (e.g., a phenomenon in which the transient PL lifetime of the mixed film has a longer lifetime component or has a higher proportion of delayed components than that of each of the first and second organic compounds). The transient PL can be rephrased as transient electroluminescence (EL). That is, the formation of an exciplex can also be confirmed by comparing the transient EL of the first organic compound, the second organic compound, and the mixed film of the first and second organic compounds and observing a difference in transient response.

The electron-transport layer 114 includes a substance with an electron-transport property. The substance with an electron-transport property is preferably a substance having an electron mobility higher than or equal to 1×10⁻⁷ cm²/Vs, further preferably higher than or equal to 1×10⁻⁶ cm²/Vs, when the square root of electric field strength [V/cm] is 600. Note that any other substance can also be used as long as the substance has an electron-transport property higher than a hole-transport property. An organic compound including a π-electron deficient heteroaromatic ring is preferable as the above organic compound. The organic compound including a π-electron deficient heteroaromatic ring is preferably one or more of an organic compound including a heteroaromatic ring having a polyazole skeleton, an organic compound including a heteroaromatic ring having a pyridine skeleton, an organic compound including a heteroaromatic ring having a diazine skeleton, and an organic compound including a heteroaromatic ring having a triazine skeleton.

As the substance with an electron-transport property that can be used for the electron-transport layer 114, it is possible to use any of the above-listed organic compounds that can be used as the first organic compound of the light-emitting layer 113 when being deuterated. Note that the substance with an electron-transport property that can be used for the electron-transport layer 114 is not necessarily deuterated.

Among the above-listed organic compounds that can be used as the first organic compound when being deuterated, an organic compound including a heteroaromatic ring having a diazine skeleton, an organic compound including a heteroaromatic ring having a pyridine skeleton, or an organic compound including a heteroaromatic ring having a triazine skeleton is preferable because of its high reliability. In particular, the organic compound including a heteroaromatic ring having a diazine (pyrimidine or pyrazine) skeleton and the organic compound including a heteroaromatic ring having a triazine skeleton have a high electron-transport property to contribute to a reduction in driving voltage. In particular, an organic compound having a phenanthroline skeleton such as mTpPPhen, PnNPhen, or mPPhen2P is preferable, and an organic compound having a phenanthroline dimer structure such as mPPhen2P is further preferable because of its high stability.

Note that the electron-transport layer 114 may have a stacked-layer structure. A layer in the stacked-layer structure of the electron-transport layer 114, which is in contact with the light-emitting layer 113, may function as a hole-blocking layer. In the case where the electron-transport layer in contact with the light-emitting layer functions as a hole-blocking layer, the electron-transport layer is preferably formed using a material having a lower HOMO level than a material contained in the light-emitting layer 113 by greater than or equal to 0.5 eV.

A layer containing an alkali metal, an alkaline earth metal, a compound or a complex of an alkali metal or an alkaline earth metal, 1,1′-pyridine-2,6-diyl-bis(1,3,4,6,7,8-hexahydro-2H-pyrimido[1,2-a]pyrimidine) (abbreviation: hpp2Py), or the like may be provided as the electron-injection layer 115. The electron-injection layer 115 may be a layer containing a substance with an electron-transport property and any of the above substances.

Instead of the electron-injection layer 115, a charge-generation layer 116 may be provided (FIG. 1). The charge-generation layer 116 refers to a layer capable of injecting holes into a layer in contact with the cathode side of the charge-generation layer 116 and electrons into a layer in contact with the anode side thereof when a potential is applied. The charge-generation layer 116 includes at least a p-type layer 117. The p-type layer 117 is preferably formed using any of the composite materials given above as examples of materials that can be used for the hole-injection layer 111. The p-type layer 117 may be formed by stacking a film containing the above-described acceptor material as a material included in the composite material and a film containing a hole-transport material. When a potential is applied to the p-type layer 117, electrons are injected into the electron-transport layer 114 and holes are injected into the cathode; thus, the light-emitting device operates. Since the organic compound of one embodiment of the present invention has a low refractive index, using the organic compound for the p-type layer 117 enables the light-emitting device to have high external quantum efficiency.

Note that the charge-generation layer 116 preferably includes one or both of an electron-relay layer 118 and an electron-injection buffer layer 119 in addition to the p-type layer 117.

The electron-relay layer 118 contains at least a substance with an electron-transport property and has a function of preventing an interaction between the electron-injection buffer layer 119 and the p-type layer 117 and smoothly transferring electrons. The LUMO level of the substance with an electron-transport property contained in the electron-relay layer 118 is preferably positioned between the LUMO level of the acceptor substance in the p-type layer 117 and the LUMO level of a substance contained in a layer of the electron-transport layer 114 which is in contact with the charge-generation layer 116. Specifically, the LUMO level of the substance with an electron-transport property used for the electron-relay layer 118 is preferably higher than or equal to −5.0 eV, further preferably higher than or equal to −5.0 eV and lower than or equal to −3.0 eV, still further preferably higher than or equal to −4.30 eV and lower than or equal to −3.00 eV, yet still further preferably higher than or equal to −4.30 eV and lower than or equal to −3.30 eV, in which case an increase in driving voltage can be suppressed. Note that as the substance with an electron-transport property used for the electron-relay layer 118, a phthalocyanine-based material or a metal complex having a metal-oxygen bond and an aromatic ligand is preferably used.

As the substance with an electron-transport property used for the electron-relay layer 118, specifically, it is possible to use diquinoxalino[2,3-a:2′,3′-c]phenazine (abbreviation: HATNA), 2,3,8,9,14,15-hexafluorodiquinoxalino[2,3-a:2′,3′-c]phenazine (abbreviation: HATNA-F6), a perylenetetracarboxylic acid derivative such as 3,4,9,10-perylenetetracarboxylic diimide (abbreviation: PTCDI) or 3,4,9,10-perylenetetracarboxyl-bis-benzimidazole (abbreviation: PTCBI), (C₆₀—Iₕ)[5,6]fullerene (abbreviation: C₆₀), (C₇₀-D₅ₕ)[5,6]fullerene (abbreviation: C₇₀), or the like. It is also possible to use a compound including a heterophane skeleton, which is a cyclophane skeleton having a hetero ring; for example, a phthalocyanine compound such as phthalocyanine (abbreviation: H₂Pc) can be used as the compound. Alternatively, it is possible to use a metal phthalocyanine containing copper, zinc, cobalt, iron, chromium, nickel, or the like or a derivative thereof, such as copper phthalocyanine (abbreviation: CuPc), zinc phthalocyanine (abbreviation: ZnPc), cobalt phthalocyanine (abbreviation: CoPc), iron phthalocyanine (abbreviation: FePc), tin phthalocyanine (abbreviation: SnPc), tin oxide phthalocyanine (abbreviation: SnOPc), titanium oxide phthalocyanine (abbreviation: TiOPc), or vanadium oxide phthalocyanine (abbreviation: VOPc). It is particularly preferable to use 2,3,8,9,14,15-hexafluorodiquinoxalino[2,3-a:2′,3′-c]phenazine or a phthalocyanine-based metal complex such as copper phthalocyanine or zinc phthalocyanine.

The electron-injection buffer layer 119 can be formed using a substance with a high electron-injection property, e.g., an alkali metal, an alkaline earth metal, a rare earth metal, or a compound thereof (an alkali metal compound (including an oxide such as lithium oxide, a halide, and a carbonate such as lithium carbonate or cesium carbonate), an alkaline earth metal compound (including an oxide, a halide, and a carbonate), or a rare earth metal compound (including an oxide, a halide, and a carbonate)).

In the case where the electron-injection buffer layer 119 contains a substance with an electron-transport property and a donor substance, the donor substance can be an organic compound such as tetrathianaphthacene (abbreviation: TTN), nickelocene, or decamethylnickelocene, as well as an alkali metal, an alkaline earth metal, a rare earth metal, or a compound thereof (e.g., an alkali metal compound (including an oxide such as lithium oxide, a halide, and a carbonate such as lithium carbonate or cesium carbonate), an alkaline earth metal compound (including an oxide, a halide, and a carbonate), or a rare earth metal compound (including an oxide, a halide, and a carbonate)). As the substance with an electron-transport property, a material similar to the above-described material for the electron-transport layer 114 can be used.

The second electrode 102 is an electrode including a cathode. The second electrode 102 may have a stacked-layer structure, in which case a layer in contact with the organic compound layer 103 functions as a cathode. For the cathode, a metal, an alloy, an electrically conductive compound, or a mixture thereof each having a low work function (specifically, lower than or equal to 3.8 eV) can be used, for example. Specific examples of such a cathode material include elements belonging to Group 1 or 2 of the periodic table, such as alkali metals (e.g., lithium (Li) and cesium (Cs)), magnesium (Mg), calcium (Ca), and strontium (Sr), alloys containing these elements (e.g., MgAg and AlLi), compounds containing these elements (e.g., lithium fluoride (LiF), cesium fluoride (CsF), and calcium fluoride (CaF₂)), rare earth metals such as europium (Eu) and ytterbium (Yb), and alloys containing these rare earth metals. However, when the electron-injection layer 115 or a thin film formed using any of the above materials having a low work function is provided between the second electrode 102 and the electron-transport layer, a variety of conductive materials such as Al, Ag, ITO, or indium oxide-tin oxide containing silicon or silicon oxide can be used for the cathode regardless of the work function.

When the second electrode 102 is formed using a material that transmits visible light, the light-emitting device can emit light from the second electrode 102 side.

Films of these conductive materials can be formed by a dry process such as a vacuum evaporation method or a sputtering method, an ink-jet method, a spin coating method, or the like. Alternatively, a wet process using a sol-gel method or a wet process using a paste of a metal material may be employed.

The organic compound layer 103 can be formed by any of a variety of methods, including a dry process and a wet process. For example, a vacuum evaporation method, a gravure printing method, an offset printing method, a screen printing method, an ink-jet method, a spin coating method, or the like may be used.

Different film formation methods may be used to form the electrodes or the layers described above.

Next, an embodiment of a light-emitting device with a structure in which a plurality of light-emitting units are stacked (this type of light-emitting device is also referred to as a stacked or tandem device) is described with reference to FIG. 1C. This light-emitting device includes a plurality of light-emitting units between an anode and a cathode. One light-emitting unit has substantially the same structure as the organic compound layer 103 illustrated in FIG. 1A. In other words, the light-emitting device illustrated in FIG. 1C includes a plurality of light-emitting units, and the light-emitting device illustrated in FIG. 1A or 1B includes a single light-emitting unit.

In FIG. 1C, a first light-emitting unit 511 and a second light-emitting unit 512 are stacked between a first electrode 501 and a second electrode 502, and a charge-generation layer 513 is provided between the first light-emitting unit 511 and the second light-emitting unit 512. The first electrode 501 and the second electrode 502 correspond, respectively, to the first electrode 101 and the second electrode 102 illustrated in FIG. 1A, and can be formed using the materials given in the description for FIG. 1A. Furthermore, the first light-emitting unit 511 and the second light-emitting unit 512 may have the same structure or different structures.

The charge-generation layer 513 has a function of injecting electrons into one of the light-emitting units and injecting holes into the other of the light-emitting units when voltage is applied between the first electrode 501 and the second electrode 502. That is, in FIG. 1C, the charge-generation layer 513 injects electrons into the first light-emitting unit 511 and holes into the second light-emitting unit 512 when voltage is applied such that the potential of the anode becomes higher than the potential of the cathode.

The charge-generation layer 513 preferably has a structure similar to that of the charge-generation layer 116 described with reference to FIG. 1B. A composite material of an organic compound and a metal oxide enables low-voltage driving and low-current driving because of its excellent carrier-injection property and excellent carrier-transport property. In the case where the anode-side surface of a light-emitting unit is in contact with the charge-generation layer 513, the charge-generation layer 513 can also function as a hole-injection layer of the light-emitting unit; therefore, a hole-injection layer is not necessarily provided in the light-emitting unit.

In the case where the electron-injection buffer layer 119 is provided in the charge-generation layer 513, the electron-injection buffer layer 119 functions as the electron-injection layer in the light-emitting unit on the anode side; thus, an electron-injection layer is not necessarily formed in the light-emitting unit on the anode side.

The light-emitting device having two light-emitting units is described with reference to FIG. 1C; however, one embodiment of the present invention can also be applied to a light-emitting device in which three or more light-emitting units are stacked. With a plurality of light-emitting units partitioned by the charge-generation layer 513 between a pair of electrodes as in the light-emitting device of this embodiment, it is possible to provide a long-life device that can emit light with high luminance at a low current density. A light-emitting apparatus that can be driven at a low voltage and has low power consumption can also be provided.

When the emission colors of the light-emitting units are different, light emission of a desired color can be obtained from the light-emitting device as a whole. For example, in a light-emitting device having two light-emitting units, the emission colors of the first light-emitting unit may be red and green and the emission color of the second light-emitting unit may be blue, so that the light-emitting device can emit white light as the whole.

The organic compound layer 103, the first light-emitting unit 511, the second light-emitting unit 512, the layers such as the charge-generation layer, and the electrodes that are described above can be formed by a method such as an evaporation method (including a vacuum evaporation method), a droplet discharge method (also referred to as an ink-jet method), a coating method, or a gravure printing method. A low molecular material, a middle molecular material (including an oligomer and a dendrimer), or a high molecular material may be included in the above components.

### Embodiment 3

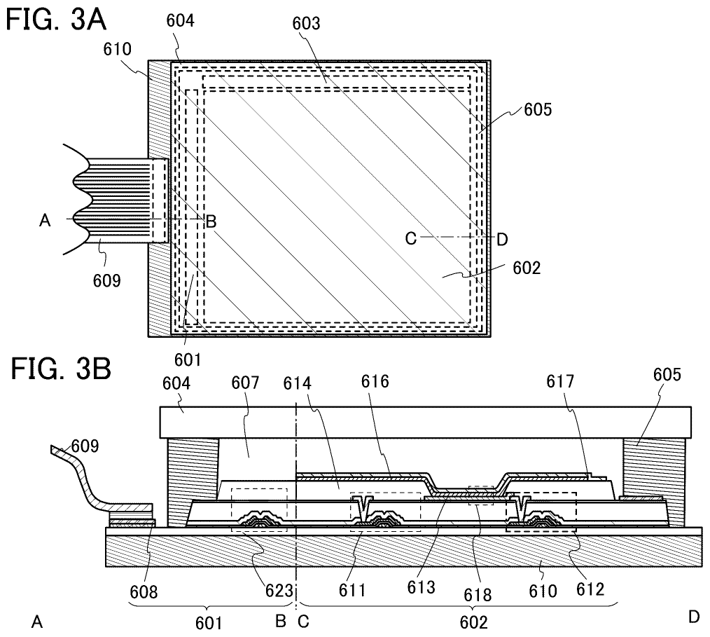

In this embodiment, the display apparatus manufactured using the light-emitting device described in Embodiments 1 and 2 is described with reference to FIGS. 3A and 3B. Note that FIG. 3A is a top view of the display apparatus and FIG. 3B is a cross-sectional view taken along the lines A-B and C-D in FIG. 3A. This display apparatus includes a driver circuit portion (source line driver circuit) 601, a pixel portion 602, and a driver circuit portion (gate line driver circuit) 603, which are to control light emission of a light-emitting device and illustrated with dotted lines. Reference numeral 604 denotes a sealing substrate; 605, a sealing material; and 607, a space surrounded by the sealing material 605.

Reference numeral 608 denotes a wiring for transmitting signals to be input to the source line driver circuit 601 and the gate line driver circuit 603 and receiving signals such as a video signal, a clock signal, a start signal, and a reset signal from a flexible printed circuit (FPC) 609 serving as an external input terminal. Although only the FPC is illustrated here, a printed wiring board (PWB) may be attached to the FPC. The display apparatus in this specification includes, in its category, not only the display apparatus itself but also the display apparatus provided with the FPC or the PWB.

Next, a cross-sectional structure is described with reference to FIG. 3B. The driver circuit portions and the pixel portion are formed over an element substrate 610; FIG. 3B illustrates the source line driver circuit 601, which is a driver circuit portion, and one pixel in the pixel portion 602.

The element substrate 610 may be a substrate formed of glass, quartz, an organic resin, a metal, an alloy, or a semiconductor or a plastic substrate formed of fiber reinforced plastic (FRP), polyvinyl fluoride (PVF), polyester, or an acrylic resin.

The structure of transistors used in the pixels and the driver circuits is not particularly limited. For example, inverted staggered transistors may be used, or staggered transistors may be used. Furthermore, top-gate transistors or bottom-gate transistors may be used. A semiconductor material used for the transistors is not particularly limited, and for example, silicon, germanium, silicon carbide, gallium nitride, or the like can be used. Alternatively, an oxide semiconductor containing at least one of indium, gallium, and zinc, such as an In—Ga—Zn-based metal oxide, may be used.

There is no particular limitation on the crystallinity of a semiconductor material used for the transistors, and either an amorphous semiconductor or a semiconductor having crystallinity (a microcrystalline semiconductor, a polycrystalline semiconductor, a single crystal semiconductor, or a semiconductor partly including crystal regions) can be used. It is preferable to use a semiconductor having crystallinity, in which case degradation of transistor characteristics can be inhibited.

Here, an oxide semiconductor is preferably used for semiconductor devices such as the transistors provided in the pixels and the driver circuits and transistors used for touch sensors described later, and the like. In particular, an oxide semiconductor having a wider band gap than silicon is preferably used. When an oxide semiconductor having a wider band gap than silicon is used, off-state current of the transistors can be reduced.

The oxide semiconductor preferably contains at least indium (In) or zinc (Zn). Further preferably, the oxide semiconductor contains an oxide represented by an In-M-Zn-based oxide (M represents a metal such as Al, Ti, Ga, Ge, Y, Zr, Sn, La, Ce, or Hf).

As a semiconductor layer, it is particularly preferable to use an oxide semiconductor film including a plurality of crystal parts whose c-axes are aligned perpendicular to a surface on which the semiconductor layer is formed or the top surface of the semiconductor layer and in which the adjacent crystal parts have no grain boundary.

The use of such materials for the semiconductor layer makes it possible to provide a highly reliable transistor in which a change in the electrical characteristics is suppressed.

Charge accumulated in a capacitor through a transistor including the above-described semiconductor layer can be held for a long time because of the low off-state current of the transistor. When such a transistor is used in a pixel, operation of a driver circuit can be stopped while a gray scale of a pixel in each display region is maintained. As a result, an electronic appliance with extremely low power consumption can be obtained.

For stable characteristics of the transistor and the like, a base film is preferably provided. The base film can be formed with a single-layer structure or a stacked-layer structure using an inorganic insulating film such as a silicon oxide film, a silicon nitride film, a silicon oxynitride film, or a silicon nitride oxide film. The base film can be formed by a sputtering method, a chemical vapor deposition (CVD) method (e.g., a plasma CVD method, a thermal CVD method, or a metal organic CVD (MOCVD) method), an atomic layer deposition (ALD) method, a coating method, a printing method, or the like. Note that the base film is not necessarily provided.

Note that an FET 623 is illustrated as a transistor formed in the driver circuit portion 601. In addition, the driver circuit may be formed with any of a variety of circuits such as a CMOS circuit, a PMOS circuit, or an NMOS circuit. Although a driver integrated type in which the driver circuit is formed over the substrate is described in this embodiment, the driver circuit is not necessarily formed over the substrate, and can be formed outside.

The pixel portion 602 includes a plurality of pixels including a switching FET 611, a current controlling FET 612, and a first electrode 613 electrically connected to a drain of the current controlling FET 612. One embodiment of the present invention is not limited to the structure, and the pixel portion 602 may include three or more FETs and a capacitor in combination.

Note that an insulator 614 is formed to cover an end portion of the first electrode 613. Here, the insulator 614 can be formed using a positive photosensitive acrylic resin film.

In order to improve coverage with an organic compound layer or the like which is formed later, the insulator 614 is formed to have a curved surface with curvature at its upper or lower end portion. For example, in the case where a positive photosensitive acrylic resin is used as a material of the insulator 614, only the upper end portion of the insulator 614 preferably has a curved surface with a curvature radius (0.2 μm to 3 μm). For the insulator 614, either a negative photosensitive resin or a positive photosensitive resin can be used.

An organic compound layer 616 and a second electrode 617 are formed over the first electrode 613. Here, as a material used for the first electrode 613 functioning as an anode, a material having a high work function is preferably used. For example, a single-layer film of an ITO film, an indium tin oxide film containing silicon, an indium oxide film containing zinc oxide at 2 wt % to 20 wt %, a titanium nitride film, a chromium film, a tungsten film, a Zn film, a Pt film, or the like, a stack of a titanium nitride film and a film containing aluminum as its main component, a stack of three layers of a titanium nitride film, a film containing aluminum as its main component, and a titanium nitride film, or the like can be used. The stacked-layer structure enables low wiring resistance, favorable ohmic contact, and a function as an anode.

The organic compound layer 616 is formed by any of a variety of methods such as an evaporation method using an evaporation mask, an ink-jet method, and a spin coating method. The organic compound layer 616 has the structure described in Embodiments 1 and 2. As another material included in the organic compound layer 616, a low molecular compound or a high molecular compound (including an oligomer or a dendrimer) may be used.

As a material used for the second electrode 617, which is formed over the organic compound layer 616 and functions as a cathode, a material having a low work function (e.g., Al, Mg, Li, and Ca, or an alloy or a compound thereof, such as MgAg, MgIn, and AlLi) is preferably used. In the case where light generated in the organic compound layer 616 is transmitted through the second electrode 617, a stack of a thin metal film and a transparent conductive film (e.g., ITO, indium oxide containing zinc oxide at 2 wt % to 20 wt %, indium tin oxide containing silicon, or zinc oxide (ZnO)) is preferably used for the second electrode 617.

Note that the light-emitting device is formed with the first electrode 613, the organic compound layer 616, and the second electrode 617. The light-emitting device is the light-emitting device described in Embodiments 1 and 2. In the display apparatus of this embodiment, the pixel portion, which includes a plurality of light-emitting devices, may include both the light-emitting device described in Embodiments 1 and 2 and a light-emitting device having a different structure.

The sealing substrate 604 is attached to the element substrate 610 with the sealing material 605, so that a light-emitting device 618 is provided in the space 607 surrounded by the element substrate 610, the sealing substrate 604, and the sealing material 605. The space 607 may be filled with a filler, or may be filled with an inert gas (such as nitrogen or argon), or the sealing material. The structure of the sealing substrate in which a recessed portion is formed and a desiccant is provided is preferable because deterioration due to the influence of moisture can be inhibited.

An epoxy-based resin or glass frit is preferably used for the sealing material 605. It is desirable that such a material not be permeable to moisture or oxygen as much as possible. As the sealing substrate 604, a glass substrate, a quartz substrate, or a plastic substrate formed of fiber reinforced plastic (FRP), polyvinyl fluoride (PVF), polyester, and acrylic resin can be used.

Although not illustrated in FIGS. 3A and 3B, a protective film may be provided over the second electrode. As the protective film, an organic resin film or an inorganic insulating film may be formed. The protective film may be formed so as to cover an exposed portion of the sealing material 605. The protective film may be provided so as to cover surfaces and side surfaces of the pair of substrates and exposed side surfaces of a sealing layer, an insulating layer, and the like.

The protective film can be formed using a material that is less likely to transmit an impurity such as water easily. Thus, diffusion of an impurity such as water from the outside into the inside can be effectively suppressed.

As a material for the protective film, an oxide, a nitride, a fluoride, a sulfide, a ternary compound, a metal, a polymer, or the like can be used. For example, the material may contain aluminum oxide, hafnium oxide, hafnium silicate, lanthanum oxide, silicon oxide, strontium titanate, tantalum oxide, titanium oxide, zinc oxide, niobium oxide, zirconium oxide, tin oxide, yttrium oxide, cerium oxide, scandium oxide, erbium oxide, vanadium oxide, indium oxide, aluminum nitride, hafnium nitride, silicon nitride, tantalum nitride, titanium nitride, niobium nitride, molybdenum nitride, zirconium nitride, gallium nitride, a nitride containing titanium and aluminum, an oxide containing titanium and aluminum, an oxide containing aluminum and zinc, a sulfide containing manganese and zinc, a sulfide containing cerium and strontium, an oxide containing erbium and aluminum, an oxide containing yttrium and zirconium, or the like.

The protective film is preferably formed using a film formation method with favorable step coverage. One such method is an atomic layer deposition (ALD) method. A material that can be deposited by an ALD method is preferably used for the protective film. A dense protective film having reduced defects such as cracks or pinholes or a uniform thickness can be formed by an ALD method. Furthermore, damage caused to a process member in forming the protective film can be reduced.

By an ALD method, a uniform protective film with few defects can be formed even on, for example, a surface with a complex uneven shape or upper, side, and lower surfaces of a touch panel.

As described above, the display apparatus manufactured using the light-emitting device described in Embodiments 1 and 2 can be obtained.

The display apparatus in this embodiment is manufactured using the light-emitting device described in Embodiments 1 and 2 and thus can have favorable characteristics. Specifically, since the light-emitting device described in Embodiments 1 and 2 has high emission efficiency, the display apparatus can achieve low power consumption. Since the light-emitting device described in Embodiments 1 and 2 has high reliability, the display apparatus can be highly reliable. In addition, since the light-emitting device described in Embodiments 1 and 2 can have favorable chromaticity and high color purity, the display apparatus can achieve high display quality.

This embodiment can be freely combined with any of the other embodiments.

### Embodiment 4

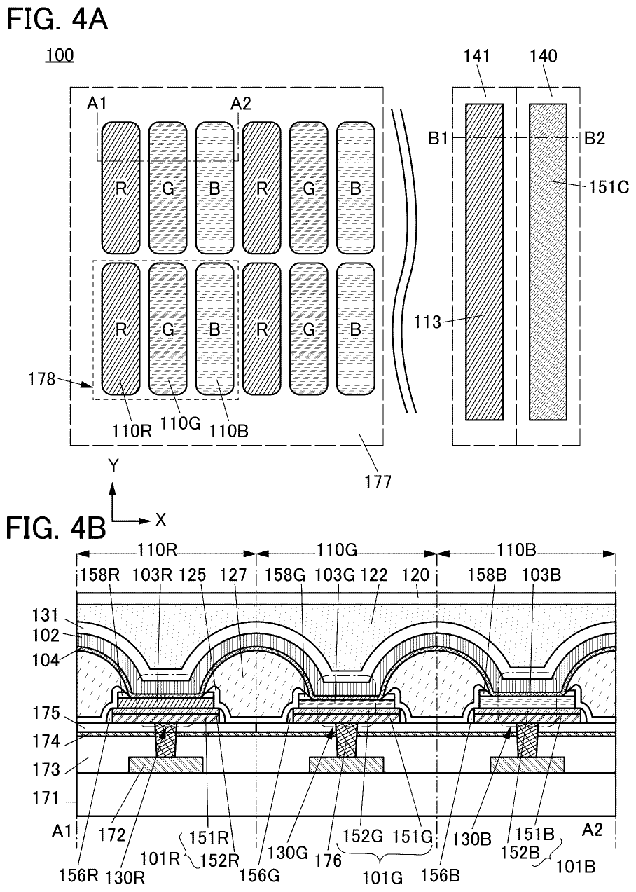

As illustrated in FIGS. 4A and 4B, a plurality of light-emitting devices 130 are formed over an insulating layer 175 to constitute a display apparatus. In this embodiment, the display apparatus of another embodiment of the present invention will be described in detail.

A display apparatus 100 includes a pixel portion 177 in which a plurality of pixels 178 are arranged in a matrix. The pixel 178 includes a subpixel 110R, a subpixel 110G, and a subpixel 110B.

In this specification and the like, for example, description common to the subpixels 110R, 110G, and 110B is sometimes made using the collective term “subpixel 110”. As for other components that are distinguished from each other using letters of the alphabet, matters common to the components are sometimes described using reference numerals excluding the letters of the alphabet.

The subpixel 110R emits red light, the subpixel 110G emits green light, and the subpixel 110B emits blue light. Thus, an image can be displayed on the pixel portion 177. Note that in this embodiment, three colors of red (R), green (G), and blue (B) are given as examples of colors of light emitted by the subpixels; however, subpixels of a different combination of colors may be employed. The number of subpixels is not limited to three, and may be four or more. Examples of four subpixels include subpixels emitting light of four colors of R, G, B, and white (W), subpixels emitting light of four colors of R, G, B, and Y, and four subpixels emitting light of R, G, and B and infrared light (IR).

In this specification and the like, the row direction and the column direction are sometimes referred to as the X direction and the Y direction, respectively. The X direction and the Y direction intersect with each other and are perpendicular to each other, for example.

FIG. 4A illustrates an example where subpixels of different colors are arranged in the X direction and subpixels of the same color are arranged in the Y direction. Note that subpixels of different colors may be arranged in the Y direction, and subpixels of the same color may be arranged in the X direction.

Outside the pixel portion 177, a connection portion 140 is provided and a region 141 may also be provided. In the case where the region 141 is provided, the region 141 is provided between the pixel portion 177 and the connection portion 140. In the case where the region 141 is provided, an organic compound layer is provided in the region 141. A conductive layer 151C is provided in the connection portion 140.

Although FIG. 4A illustrates an example where the region 141 and the connection portion 140 are positioned on the right side of the pixel portion 177, the positions of the region 141 and the connection portion 140 are not particularly limited. The number of the regions 141 and the number of the connection portions 140 can each be one or more.

FIG. 4B is an example of a cross-sectional view along the dashed-dotted line A1-A2 in FIG. 4A. As illustrated in FIG. 4B, the display apparatus 100 includes an insulating layer 171, a conductive layer 172 over the insulating layer 171, an insulating layer 173 over the insulating layer 171 and the conductive layer 172, an insulating layer 174 over the insulating layer 173, and the insulating layer 175 over the insulating layer 174. The insulating layer 171 is provided over a substrate (not illustrated). An opening reaching the conductive layer 172 is provided in the insulating layers 175, 174, and 173, and a plug 176 is provided to fill the opening.

In the pixel portion 177, the light-emitting device 130 is provided over the insulating layer 175 and the plug 176. A protective layer 131 is provided to cover the light-emitting device 130. A substrate 120 is bonded to the protective layer 131 with a resin layer 122. An inorganic insulating layer 125 and an insulating layer 127 over the inorganic insulating layer 125 are preferably provided between the adjacent light-emitting devices 130.

Although FIG. 4B illustrates cross sections of a plurality of the inorganic insulating layers 125 and a plurality of the insulating layers 127, the inorganic insulating layers 125 are preferably connected to each other and the insulating layers 127 are preferably connected to each other when the display apparatus 100 is seen from above.

In FIG. 4B, a light-emitting device 130R, a light-emitting device 130G, and a light-emitting device 130B are each illustrated as the light-emitting device 130. The light-emitting devices 130R, 130G, and 130B emit light of different colors. For example, the light-emitting device 130R can emit red light, the light-emitting device 130G can emit green light, and the light-emitting device 130B can emit blue light. Alternatively, the light-emitting device 130R, the light-emitting device 130G, or the light-emitting device 130B may emit visible light of another color or infrared light.

The display apparatus of one embodiment of the present invention can be, for example, a top-emission display apparatus where light is emitted in the direction opposite to a substrate over which light-emitting devices are formed. Note that the display apparatus of one embodiment of the present invention may be of a bottom emission type.

The light-emitting device 130R includes a first electrode 101R (pixel electrode) including a conductive layer 151R and a conductive layer 152R, an organic compound layer 103R over the first electrode, the common layer 104 over the organic compound layer 103R, and the second electrode 102 (common electrode) over the common layer 104. Although the common layer 104 is not necessarily provided, it is preferable to provide the common layer 104 to reduce damage to the organic compound layer 103R during processing.

The light-emitting device 130G includes a first electrode 101G (pixel electrode) including a conductive layer 151G and a conductive layer 152G, an organic compound layer 103G over the first electrode, the common layer 104 over the organic compound layer 103G, and the second electrode 102 (common electrode) over the common layer 104. Although the common layer 104 is not necessarily provided, it is preferable to provide the common layer 104 to reduce damage to the organic compound layer 103G during processing.

The light-emitting device 130B has a structure described in Embodiment 1 or 2. The light-emitting device 130B includes a first electrode 101B (pixel electrode) including a conductive layer 151B and a conductive layer 152B, an organic compound layer 103B over the first electrode, the common layer 104 over the organic compound layer 103B, and the second electrode 102 (common electrode) over the common layer 104. Although the common layer 104 is not necessarily provided, it is preferable to provide the common layer 104 to reduce damage to the organic compound layer 103B during processing. Furthermore, in the case where the common layer 104 is provided, a stack of the organic compound layer 103B and the common layer 104 corresponds to the organic compound layer 103 described in Embodiments 1 and 2.

Note that the common layer 104 is preferably an electron-injection layer or an electron-transport layer, further preferably an electron-injection layer. In the case where the common layer 104 is an electron-transport layer, it is preferable that the electron-transport layer have a stacked-layer structure, and it is further preferable that, among the stacked layers, a layer on the second electrode side be the common layer 104 and a layer on the light-emitting layer side be the organic compound layer 103.

Since the light-emitting devices 130R and 130G are manufactured through a photolithography process, such a structure can suppress an increase in driving voltage due to the photolithography process and enables the light-emitting devices to have a low driving voltage.

In the light-emitting device 130, one of the pixel electrode and the common electrode functions as an anode and the other functions as a cathode. Hereinafter, description is made on the assumption that the pixel electrode functions as the anode and the common electrode functions as the cathode unless otherwise specified.

The organic compound layers 103R, 103G, and 103B are island-shaped layers that are independent of each other on a light-emitting device basis or on an emission color basis. Providing the island-shaped organic compound layer 103 in each of the light-emitting devices 130 can inhibit leakage current between the adjacent light-emitting devices 130 even in a high-resolution display apparatus. This can prevent crosstalk, so that a display apparatus with extremely high contrast can be obtained. Specifically, a display apparatus having high current efficiency at low luminance can be obtained.

The island-shaped organic compound layer 103 is formed by forming an organic compound film and processing the organic compound film by a photolithography method.

The organic compound layer 103 is preferably provided to cover the top surface and the side surface of the first electrode (pixel electrode) of the light-emitting device 130. In this case, the aperture ratio of the display apparatus 100 can be easily increased as compared to the structure where an end portion of the organic compound layer 103 is positioned inward from an end portion of the pixel electrode. Covering the side surface of the pixel electrode of the light-emitting device 130 with the organic compound layer 103 can inhibit the pixel electrode from being in contact with the second electrode 102; hence, a short circuit of the light-emitting device 130 can be inhibited.

In the display apparatus of one embodiment of the present invention, the first electrode (pixel electrode) of the light-emitting device preferably has a stacked-layer structure. For example, in the example illustrated in FIG. 4B, the first electrode of the light-emitting device 130 is a stack of the conductive layer 151 and the conductive layer 152.

A metal material can be used for the conductive layer 151, for example. Specifically, it is possible to use a metal such as aluminum (Al), titanium (Ti), chromium (Cr), manganese (Mn), iron (Fe), cobalt (Co), nickel (Ni), copper (Cu), gallium (Ga), zinc (Zn), indium (In), tin (Sn), molybdenum (Mo), tantalum (Ta), tungsten (W), palladium (Pd), gold (Au), platinum (Pt), silver (Ag), yttrium (Y), or neodymium (Nd) or an alloy containing an appropriate combination of any of these metals, for example.

For the conductive layer 152, an oxide containing one or more selected from indium, tin, zinc, gallium, titanium, aluminum, and silicon can be used. For example, it is preferable to use a conductive oxide containing one or more of indium oxide, indium tin oxide, indium zinc oxide, zinc oxide, zinc oxide containing gallium, titanium oxide, indium zinc oxide containing gallium, indium zinc oxide containing aluminum, indium tin oxide containing silicon, indium zinc oxide containing silicon, and the like. In particular, an indium tin oxide containing silicon can be suitably used for the conductive layer 152 because of having a work function of higher than or equal to 4.0 eV, for example.

The conductive layer 151 and the conductive layer 152 may each be a stack of a plurality of layers containing different materials. In that case, the conductive layer 151 may include a layer formed using a material that can be used for the conductive layer 152, such as a conductive oxide. Furthermore, the conductive layer 152 may include a layer formed using a material that can be used for the conductive layer 151, such as a metal material. In the case where the conductive layer 151 is a stack of two or more layers, for example, a layer in contact with the conductive layer 152 can be formed using a material that can be used for the conductive layer 152.

The conductive layer 151 preferably has a tapered side surface. Specifically, the side surface of the conductive layer 151 preferably has a tapered shape with a taper angle of less than 90°. In that case, the conductive layer 152 provided along the side surface of the conductive layer 151 also has a tapered shape. When the side surface of the conductive layer 152 has a tapered shape, coverage with the organic compound layer 103 provided along the side surface of the conductive layer 152 can be improved.

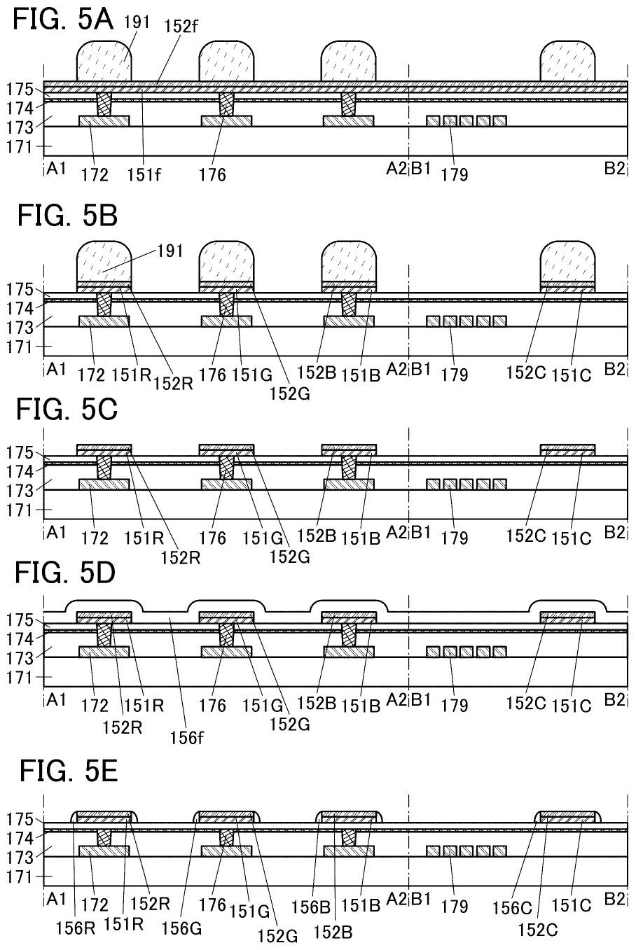

Next, an exemplary method for manufacturing the display apparatus 100 having the structure illustrated in FIG. 4A is described with reference to FIGS. 5A to 5E, FIGS. 6A and 6B, FIGS. 7A to 7D, FIGS. 8A to 8C, FIGS. 9A to 9C, and FIGS. 10A to 10C.

[Manufacturing method example 1]Thin films included in the display apparatus (e.g., insulating films, semiconductor films, and conductive films) can be formed by a sputtering method, a chemical vapor deposition (CVD) method, a vacuum evaporation method, a pulsed laser deposition (PLD) method, an ALD method, or the like.

Thin films included in the display apparatus (e.g., insulating films, semiconductor films, and conductive films) can also be formed by a wet process such as spin coating, dipping, spray coating, ink-jetting, dispensing, screen printing, offset printing, doctor blade coating, slit coating, roll coating, curtain coating, or knife coating.

Thin films included in the display apparatus can be processed by a photolithography method, for example.

As light used for exposure in the photolithography method, for example, light with an i-line (wavelength: 365 nm), light with a g-line (wavelength: 436 nm), light with an h-line (wavelength: 405 nm), or light in which the i-line, the g-line, and the h-line are mixed can be used. Alternatively, ultraviolet rays, KrF laser light, ArF laser light, or the like can be used. Exposure may be performed by liquid immersion exposure technique. As the light for exposure, extreme ultraviolet (EUV) light or X-rays may also be used. Furthermore, instead of the light used for the exposure, an electron beam can also be used.

For etching of thin films, a dry etching method, a wet etching method, a sandblast method, or the like can be used.

First, as illustrated in FIG. 5A, the insulating layer 171 is formed over a substrate (not illustrated). Next, the conductive layer 172 and a conductive layer 179 are formed over the insulating layer 171, and the insulating layer 173 is formed over the insulating layer 171 so as to cover the conductive layer 172 and the conductive layer 179. Then, the insulating layer 174 is formed over the insulating layer 173, and the insulating layer 175 is formed over the insulating layer 174.

As the substrate, a substrate that has heat resistance high enough to withstand at least heat treatment performed later can be used. For example, it is possible to use a glass substrate; a quartz substrate; a sapphire substrate; a ceramic substrate; an organic resin substrate; or a semiconductor substrate such as a single crystal semiconductor substrate or a polycrystalline semiconductor substrate of silicon, silicon carbide, or the like, a compound semiconductor substrate of silicon germanium or the like, or an SOI substrate.

Next, as illustrated in FIG. 5A, an opening reaching the conductive layer 172 is formed in the insulating layer 175, 174, and 173. Then, the plug 176 is formed to fill the opening.

Subsequently, as illustrated in FIG. 5A, a conductive film 151f to be the conductive layers 151R, 151G, 151B, and 151C and a conductive film 152f to be the conductive layers 152R, 152G, 152B, and 152C are formed over the plug 176 and the insulating layer 175. A metal material can be used for the conductive film 151f, for example. For the conductive film 152f, an oxide containing one or more selected from indium, tin, zinc, gallium, titanium, aluminum, and silicon can be used.

Then, as illustrated in FIG. 5A, a resist mask 191 is formed over the conductive film 152f. The resist mask 191 can be formed by application of a photosensitive material (photoresist), light exposure, and development.

Subsequently, as illustrated in FIG. 5B, the conductive films 151f and 152f in a region not overlapping with the resist mask 191 are removed, for example. In this manner, the conductive layers 151 and 152 are formed.

Next, the resist mask 191 is removed as illustrated in FIG. 5C. The resist mask 191 can be removed by ashing using oxygen plasma, for example.

Then, as illustrated in FIG. 5D, an insulating film 156f to be an insulating layer 156R, an insulating layer 156G, an insulating layer 156B, and an insulating layer 156C is formed over the conductive layers 152R, 152G, 152B, and 152C and the insulating layer 175.

As the insulating film 156f, an inorganic insulating film such as an oxide insulating film, a nitride insulating film, an oxynitride insulating film, or a nitride oxide insulating film, e.g., silicon oxynitride, can be used.

Subsequently, as illustrated in FIG. 5E, the insulating film 156f is processed to form the insulating layers 156R, 156G, 156B, and 156C.

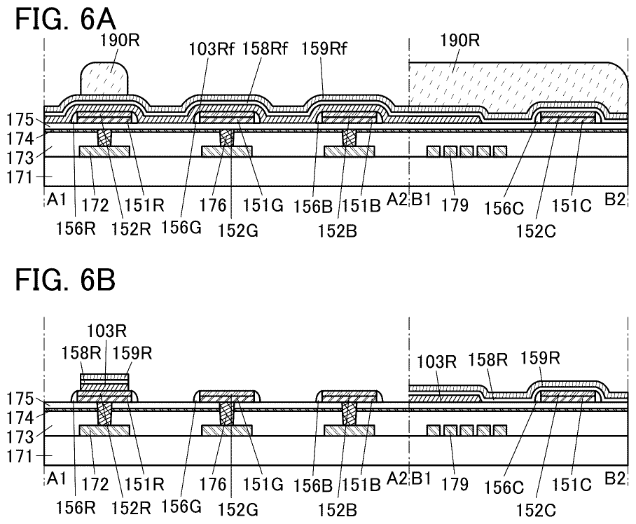

Next, as illustrated in FIG. 6A, an organic compound film 103Rf is formed over the conductive layers 152R, 152G, and 152B and the insulating layer 175. As illustrated in FIG. 6A, the organic compound film 103Rf is not formed over the conductive layer 152C.

Then, as illustrated in FIG. 6A, a sacrificial film 158Rf and a mask film 159Rf are formed.

Providing the sacrificial film 158Rf over the organic compound film 103Rf can reduce damage to the organic compound film 103Rf in the manufacturing process of the display apparatus, resulting in an increase in the reliability of the light-emitting device.

As the sacrificial film 158Rf, a film that is highly resistant to the process conditions for the organic compound film 103Rf, specifically, a film having high etching selectivity with respect to the organic compound film 103Rf is used. For the mask film 159Rf, a film having high etching selectivity with respect to the sacrificial film 158Rf is used.

The sacrificial film 158Rf and the mask film 159Rf are formed at a temperature lower than the upper temperature limit of the organic compound film 103Rf. The typical substrate temperatures in formation of the sacrificial film 158Rf and the mask film 159Rf are each higher than or equal to 100° C. and lower than or equal to 200° C., preferably higher than or equal to 100° C. and lower than or equal to 150° C., further preferably higher than or equal to 100° C. and lower than or equal to 120° C. The light-emitting device of one embodiment of the present invention includes the first organic compound, and thus enables a display apparatus with high display quality even when manufactured through a heating process at higher temperature.

The sacrificial film 158Rf and the mask film 159Rf are preferably films that can be removed by a wet etching method or a dry etching method.

Note that the sacrificial film 158Rf formed over and in contact with the organic compound film 103Rf is preferably formed by a formation method that is less likely to damage the organic compound film 103Rf than a formation method of the mask film 159Rf. For example, the sacrificial film 158Rf is preferably formed by an ALD method or a vacuum evaporation method rather than a sputtering method.

As each of the sacrificial film 158Rf and the mask film 159Rf, one or more of a metal film, an alloy film, a metal oxide film, a semiconductor film, an organic insulating film, an inorganic insulating film, and the like can be used, for example.

For each of the sacrificial film 158Rf and the mask film 159Rf, it is possible to use a metal material such as gold, silver, platinum, magnesium, nickel, tungsten, chromium, molybdenum, iron, cobalt, copper, palladium, titanium, aluminum, yttrium, zirconium, or tantalum or an alloy material containing any of the metal materials, for example. It is particularly preferable to use a low-melting-point material such as aluminum or silver. It is preferable to use a metal material that can block ultraviolet rays for one or both of the sacrificial film 158Rf and the mask film 159Rf, in which case the organic compound film 103Rf can be inhibited from being irradiated with ultraviolet rays in light exposure for patterning and deterioration of the organic compound film 103Rf can be inhibited.

The sacrificial film 158Rf and the mask film 159Rf can each be formed using a metal oxide such as an In—Ga—Zn oxide, an indium oxide, an In—Zn oxide, an In—Sn oxide, an indium titanium oxide (In—Ti oxide), an indium tin zinc oxide (In—Sn—Zn oxide), an indium titanium zinc oxide (In—Ti—Zn oxide), an indium gallium tin zinc oxide (In—Ga—Sn—Zn oxide), or an indium tin oxide containing silicon.

In the above metal oxide, in place of gallium, an element M (M is one or more of aluminum, silicon, boron, yttrium, copper, vanadium, beryllium, titanium, iron, nickel, germanium, zirconium, molybdenum, lanthanum, cerium, neodymium, hafnium, tantalum, tungsten, and magnesium) may be used.

The sacrificial film 158Rf and the mask film 159Rf are preferably formed using a semiconductor material such as silicon or germanium for excellent compatibility with a semiconductor manufacturing process. Alternatively, a compound containing the above semiconductor material can be used.

As each of the sacrificial film 158Rf and the mask film 159Rf, any of a variety of inorganic insulating films can be used. In particular, an oxide insulating film is preferable because its adhesion to the organic compound film 103Rf is higher than that of a nitride insulating film.

Subsequently, a resist mask 190R is formed as illustrated in FIG. 6A. The resist mask 190R can be formed by application of a photosensitive material (photoresist), light exposure, and development.

The resist mask 190R is provided at a position overlapping with the conductive layer 152R. The resist mask 190R is preferably provided also at a position overlapping with the conductive layer 152C. This can inhibit the conductive layer 152C from being damaged during the process of manufacturing the display apparatus.

Next, as illustrated in FIG. 6B, part of the mask film 159Rf is removed using the resist mask 190R, whereby a mask layer 159R is formed. The mask layer 159R remains over the conductive layers 152R and 152C. After that, the resist mask 190R is removed. Then, part of the sacrificial film 158Rf is removed using the mask layer 159R as a mask (also referred to as a hard mask), whereby a sacrificial layer 158R is formed.

The use of a wet etching method can reduce damage to the organic compound film 103Rf in processing of the sacrificial film 158Rf and the mask film 159Rf, as compared to the case of using a dry etching method. In the case of using a wet etching method, it is preferable to use a developer, an alkaline aqueous solution such as a tetramethylammonium hydroxide (TMAH) aqueous solution, or an acid aqueous solution such as/of dilute hydrofluoric acid, oxalic acid, phosphoric acid, acetic acid, nitric acid, or a chemical solution containing a mixed solution of any of these acids, for example.

In the case of using a dry etching method to process the sacrificial film 158Rf, deterioration of the organic compound film 103Rf can be inhibited by not using a gas containing oxygen as the etching gas.

The resist mask 190R can be removed by a method similar to that for the resist mask 191.

Next, as illustrated in FIG. 6B, the organic compound film 103Rf is processed to form the organic compound layer 103R. For example, part of the organic compound film 103Rf is removed using the mask layer 159R and the sacrificial layer 158R as a hard mask, whereby the organic compound layer 103R is formed.

Accordingly, as illustrated in FIG. 6B, the stacked-layer structure of the organic compound layer 103R, the sacrificial layer 158R, and the mask layer 159R remains over the conductive layer 152R. The conductive layers 152G and 152B are exposed.

The organic compound film 103Rf is preferably processed by anisotropic etching. Anisotropic dry etching is particularly preferable. Alternatively, wet etching may be used.

In the case of using a dry etching method, deterioration of the organic compound film 103Rf can be inhibited by not using a gas containing oxygen as the etching gas.

A gas containing oxygen may be used as the etching gas. When the etching gas contains oxygen, the etching rate can be increased. Thus, the etching can be performed under a low-power condition while an adequately high etching rate is maintained. Accordingly, damage to the organic compound film 103Rf can be reduced. Furthermore, a defect such as attachment of a reaction product generated during the etching can be inhibited.

In the case of using a dry etching method, it is preferable to use a gas containing at least one of H₂, CF₄, C₄F₈, SF₆, CHF₃, Cl₂, H₂O, BCl₃, and a Group 18 element such as He or Ar as the etching gas, for example. Alternatively, a gas containing oxygen and at least one of the above is preferably used as the etching gas. Alternatively, an oxygen gas may be used as the etching gas.

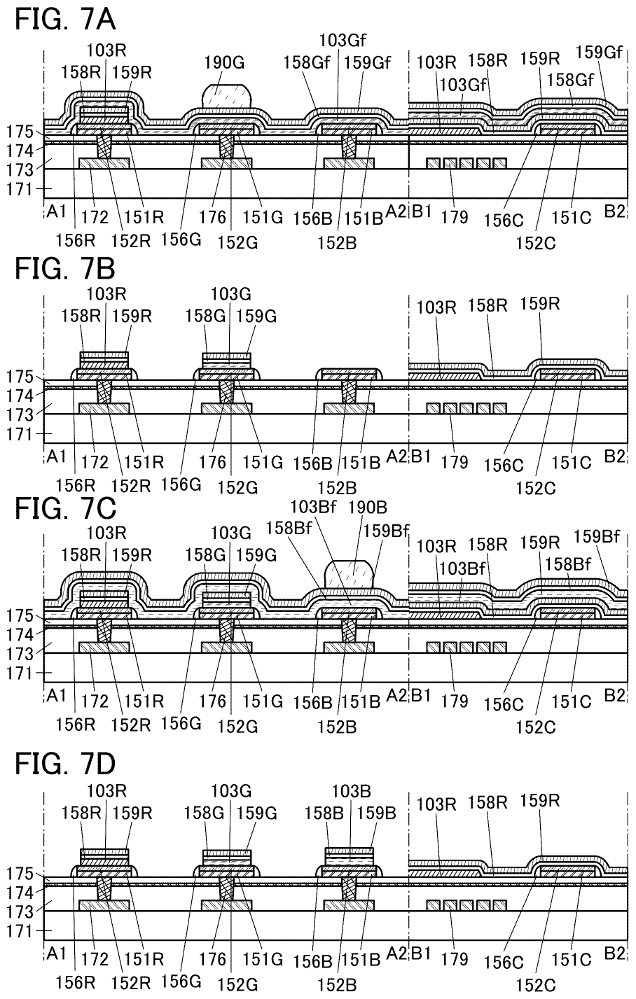

Then, as illustrated in FIG. 7A, an organic compound film 103Gf to be the organic compound layer 103G is formed.

The organic compound film 103Gf can be formed by a method similar to that for forming the organic compound film 103Rf. The organic compound film 103Gf can have a structure similar to that of the organic compound film 103Rf.

Subsequently, a sacrificial film 158Gf and a mask film 159Gf are formed in this order as illustrated in FIG. 7A. After that, the resist mask 190G is removed. The materials and the formation methods of the sacrificial film 158Gf and the mask film 159Gf are similar to those for the sacrificial film 158Rf and the mask film 159Rf. The material and the formation method of the resist mask 190G are similar to those for the resist mask 190R.

The resist mask 190G is provided at a position overlapping with the conductive layer 152G.

Subsequently, as illustrated in FIG. 7B, part of the mask film 159Gf is removed using the resist mask 190G, whereby the mask layer 159G is formed. The mask layer 159G remains over the conductive layer 152G. After that, the resist mask 190G is removed. Then, part of the sacrificial film 158Gf is removed using the mask layer 159G as a mask, whereby the sacrificial layer 158G is formed. Next, the organic compound film 103Gf is processed to form the organic compound layer 103G.

Then, an organic compound film 103Bf is formed as illustrated in FIG. 7C.

The organic compound film 103Bf can be formed by a method similar to that for forming the organic compound film 103Rf. The organic compound film 103Bf can have a structure similar to that of the organic compound film 103Rf.

Subsequently, a sacrificial film 158Bf and a mask film 159Bf are formed in this order as illustrated in FIG. 7C. After that, the resist mask 190B is formed. The materials and the formation methods of the sacrificial film 158Bf and the mask film 159Bf are similar to those for the sacrificial film 158Rf and the mask film 159Rf. The material and the formation method of the resist mask 190B are similar to those for the resist mask 190R.

The resist mask 190B is provided at a position overlapping with the conductive layer 152B.

Subsequently, as illustrated in FIG. 7D, part of the mask film 159Bf is removed using the resist mask 190B, whereby the mask layer 159B is formed. The mask layer 159B remains over the conductive layer 152B. After that, the resist mask 190B is removed. Then, part of the sacrificial film 158Bf is removed using the mask layer 159B as a mask, whereby the sacrificial layer 158B is formed. Next, the organic compound film 103Bf is processed to form the organic compound layer 103B. For example, part of the organic compound film 103Bf is removed using the mask layer 159B and the sacrificial layer 158B as a hard mask, whereby the organic compound layer 103B is formed.

Accordingly, as illustrated in FIG. 7D, the stacked-layer structure of the organic compound layer 103B, the sacrificial layer 158B, and the mask layer 159B remains over the conductive layer 152B. The mask layers 159R and 159G are exposed.

Note that the side surfaces of the organic compound layers 103R, 103G, and 103B are preferably perpendicular or substantially perpendicular to their formation surfaces. For example, the angle between the formation surfaces and these side surfaces is preferably greater than or equal to 60° and less than or equal to 90°.

The distance between two adjacent layers among the organic compound layers 103R, 103G, and 103B, which are formed by a photolithography method as described above, can be reduced to less than or equal to 8 μm, less than or equal to 5 μm, less than or equal to 3 μm, less than or equal to 2 μm, or less than or equal to 1 μm. Here, the distance can be specified, for example, by a distance between facing end portions of two adjacent layers among the organic compound layers 103R, 103G, and 103B. Reducing the distance between the island-shaped organic compound layers makes it possible to provide a display apparatus having high resolution and a high aperture ratio. In addition, the distance between the first electrodes of adjacent light-emitting devices can also be reduced to for example, less than or equal to 10 μm, less than or equal to 8 μm, less than or equal to 5 μm, less than or equal to 3 μm, or less than or equal to 2 μm. Note that the distance between the first electrodes of adjacent light-emitting devices is preferably greater than or equal to 2 μm and less than or equal to 5 μm.

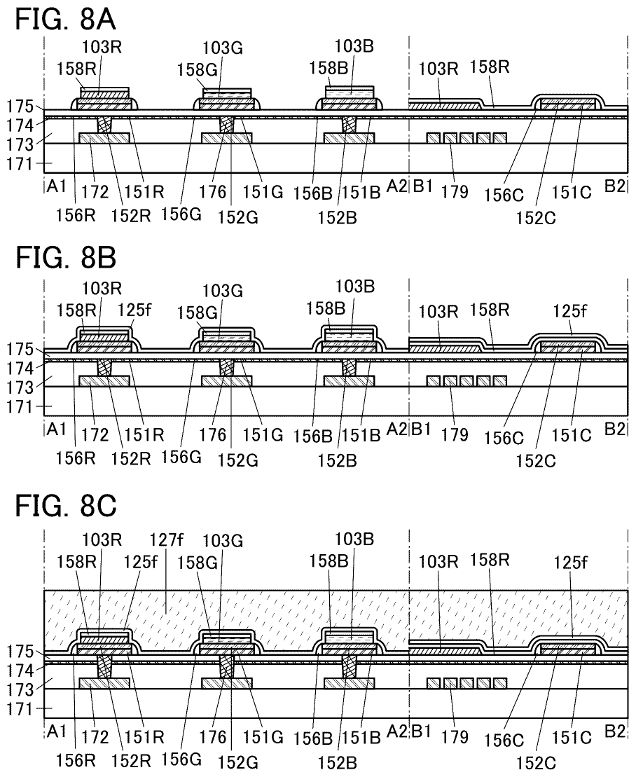

Next, as illustrated in FIG. 8A, the mask layers 159R, 159G, and 159B are preferably removed.

The step of removing the mask layers can be performed by a method similar to that for the step of processing the mask films. Specifically, by using a wet etching method, damage to the organic compound layer 103 at the time of removing the mask layers can be reduced as compared to the case of using a dry etching method.

The mask layers may be removed by being dissolved in a polar solvent such as water or an alcohol. Examples of an alcohol include ethyl alcohol, methyl alcohol, isopropyl alcohol (IPA), and glycerin.

After the mask layers are removed, drying treatment may be performed in order to remove water adsorbed on surfaces. For example, heat treatment in an inert gas atmosphere or a reduced-pressure atmosphere can be performed. The heat treatment can be performed at a substrate temperature higher than or equal to 50° C. and lower than or equal to 200° C., preferably higher than or equal to 60° C. and lower than or equal to 150° C., further preferably higher than or equal to 70° C. and lower than or equal to 120° C. The heat treatment is preferably performed in a reduced-pressure atmosphere, in which case drying at a lower temperature is possible.

Next, an inorganic insulating film 125f is formed as illustrated in FIG. 8B.

Then, as illustrated in FIG. 8C, an insulating film 127f to be the insulating layer 127 is formed over the inorganic insulating film 125f.

The substrate temperature at the time of forming the inorganic insulating film 125f and the insulating film 127f is preferably higher than or equal to 60° C., higher than or equal to 80° C., higher than or equal to 100° C., or higher than or equal to 120° C. and lower than or equal to 200° C., lower than or equal to 180° C., lower than or equal to 160° C., lower than or equal to 150° C., or lower than or equal to 140° C.

As the inorganic insulating film 125f, an insulating film having a thickness greater than or equal to 3 nm, greater than or equal to 5 nm, or greater than or equal to 10 nm and less than or equal to 200 nm, less than or equal to 150 nm, less than or equal to 100 nm, or less than or equal to 50 nm is preferably formed in the above-described range of the substrate temperature.

The inorganic insulating film 125f is preferably formed by an ALD method, for example. An ALD method is preferably used, in which case deposition damage is reduced and a film with good coverage can be formed. As the inorganic insulating film 125f, an aluminum oxide film is preferably formed by an ALD method, for example.

The insulating film 127f is preferably formed by the aforementioned wet process. The insulating film 127f is preferably formed by spin coating using a photosensitive material, for example, and specifically preferably formed using a photosensitive resin composition containing an acrylic resin.

Then, part of the insulating film 127f is exposed to visible light or ultraviolet rays. The insulating layer 127 is formed in regions that are interposed between any two of the conductive layers 152R, 152G, and 152B and around the conductive layer 152C.

The width of the insulating layer 127 formed later can be controlled with the exposed region of the insulating film 127f. In this embodiment, processing is performed such that the insulating layer 127 includes a portion overlapping with the top surface of the conductive layer 151.

Light used for the exposure preferably includes the i-line (wavelength: 365 nm). Furthermore, light used for the exposure may include at least one of the g-line (wavelength: 436 nm) and the h-line (wavelength: 405 nm).

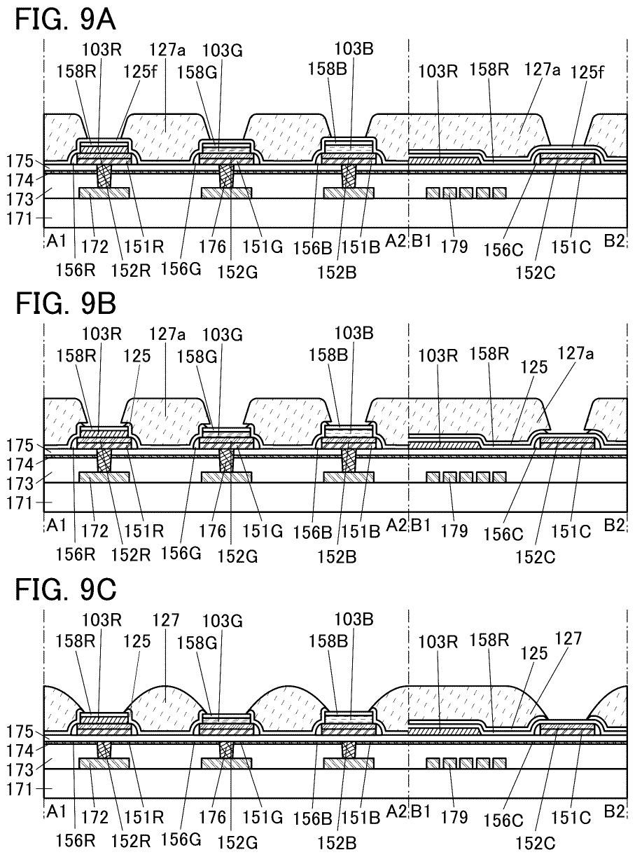

Next, as illustrated in FIG. 9A, development is performed to remove the exposed region of the insulating film 127f, whereby an insulating layer 127a is formed.

Next, as illustrated in FIG. 9B, etching treatment is performed using the insulating layer 127a as a mask to remove part of the inorganic insulating film 125f and reduce the thickness of part of the sacrificial layers 158R, 158G, and 158B. Thus, the inorganic insulating layer 125 is formed under the insulating layer 127a. Moreover, the surfaces of the thin portions in the sacrificial layers 158R, 158G, and 158B are exposed. Note that the etching treatment using the insulating layer 127a as a mask may be hereinafter referred to as first etching treatment.

The first etching treatment can be performed by dry etching or wet etching. Note that the inorganic insulating film 125f is preferably formed using a material similar to that for the sacrificial layers 158R, 158G, and 158B, in which case the first etching treatment can be performed concurrently.

In the case of performing dry etching, a chlorine-based gas is preferably used. As the chlorine-based gas, one of Cl₂, BCl₃, SiCl₄, CCl₄, and the like or a mixture of two or more of them can be used. Moreover, one of an oxygen gas, a hydrogen gas, a helium gas, an argon gas, and the like or a mixture of two or more of them can be added as appropriate to the chlorine-based gas. By the dry etching, the thin regions of the sacrificial layers 158R, 158G, and 158B can be formed with favorable in-plane uniformity.

As a dry etching apparatus, a dry etching apparatus including a high-density plasma source can be used. As the dry etching apparatus including a high-density plasma source, an inductively coupled plasma (ICP) etching apparatus can be used, for example. Alternatively, a capacitively coupled plasma (CCP) etching apparatus including parallel plate electrodes can be used.

The first etching treatment is preferably performed by wet etching. The use of wet etching can reduce damage to the organic compound layers 103R, 103G, and 103B, as compared to the case of using dry etching. Wet etching can be performed using an alkaline solution, for example. For instance, TMAH, which is an alkaline solution, can be used for the wet etching of an aluminum oxide film. Alternatively, an acid solution containing fluoride can also be used. In this case, puddle wet etching can be performed. Note that the inorganic insulating film 125f is preferably formed using a material similar to that for the sacrificial layers 158R, 158G, and 158B, in which case the first etching treatment can be performed concurrently.

The sacrificial layers 158R, 158G, and 158B not be removed completely by the first etching treatment, and the etching treatment be stopped when the thickness of the sacrificial layers 158R, 158G, and 158B is reduced. The sacrificial layers 158R, 158G, and 158B remain over the corresponding organic compound layers 103R, 103G, and 103B in this manner, whereby the organic compound layers 103R, 103G, and 103B can be prevented from being damaged by treatment in a later step.

Next, light exposure is preferably performed on the entire substrate so that the insulating layer 127a is irradiated with visible light or ultraviolet rays. The energy density for the light exposure is preferably greater than 0 mJ/cm² and less than or equal to 800 mJ/cm², further preferably greater than 0 mJ/cm² and less than or equal to 500 mJ/cm². Performing such light exposure after the development can sometimes increase the degree of transparency of the insulating layer 127a. In addition, it is sometimes possible to lower the substrate temperature required for subsequent heat treatment for changing the shape of the insulating layer 127a into a tapered shape.

Here, when a barrier insulating layer against oxygen (e.g., an aluminum oxide film) exists as each of the sacrificial layers 158R, 158G, and 158B, diffusion of oxygen to the organic compound layers 103R, 103G, and 103B can be inhibited.

Then, heat treatment (also referred to as post-baking) is performed. The heat treatment can change the insulating layer 127a into the insulating layer 127 having a tapered side surface (FIG. 9C). The heat treatment is performed at a temperature lower than the upper temperature limit of the organic compound layer. The heat treatment can be performed at a substrate temperature higher than or equal to 50° C. and lower than or equal to 200° C., preferably higher than or equal to 60° C. and lower than or equal to 150° C., further preferably higher than or equal to 70° C. and lower than or equal to 130° C. The heating atmosphere may be an air atmosphere or an inert gas atmosphere. Moreover, the heating atmosphere may be an atmospheric-pressure atmosphere or a reduced-pressure atmosphere. Accordingly, adhesion between the insulating layer 127 and the inorganic insulating layer 125 can be improved, and corrosion resistance of the insulating layer 127 can be increased.

When the sacrificial layers 158R, 158G, and 158B are not completely removed by the first etching treatment and the thinned sacrificial layers 158R, 158G, and 158B are left, the organic compound layers 103R, 103G, and 103B can be prevented from being damaged and deteriorating in the heat treatment. This can increase the reliability of the light-emitting device.

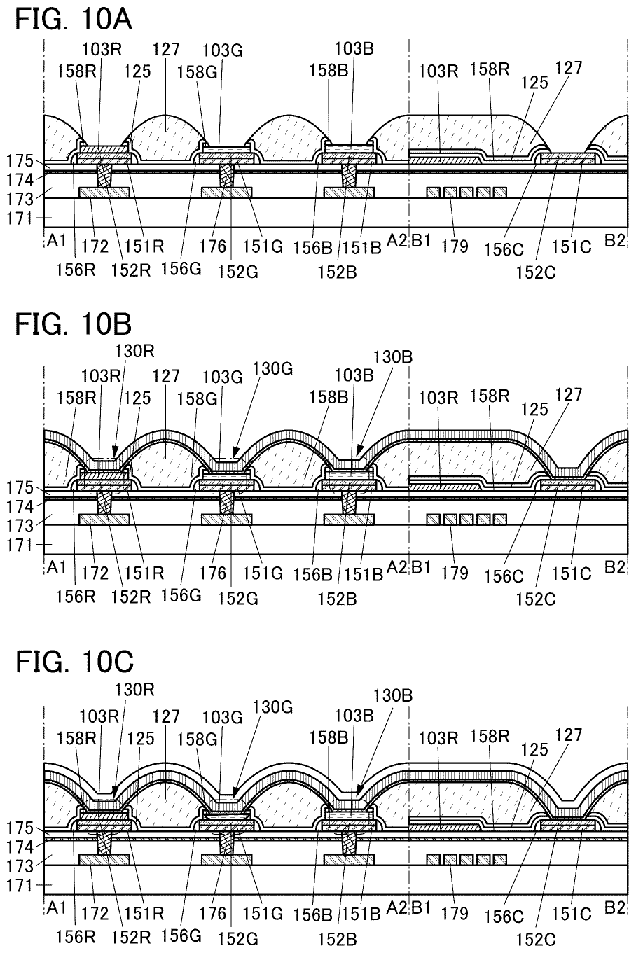

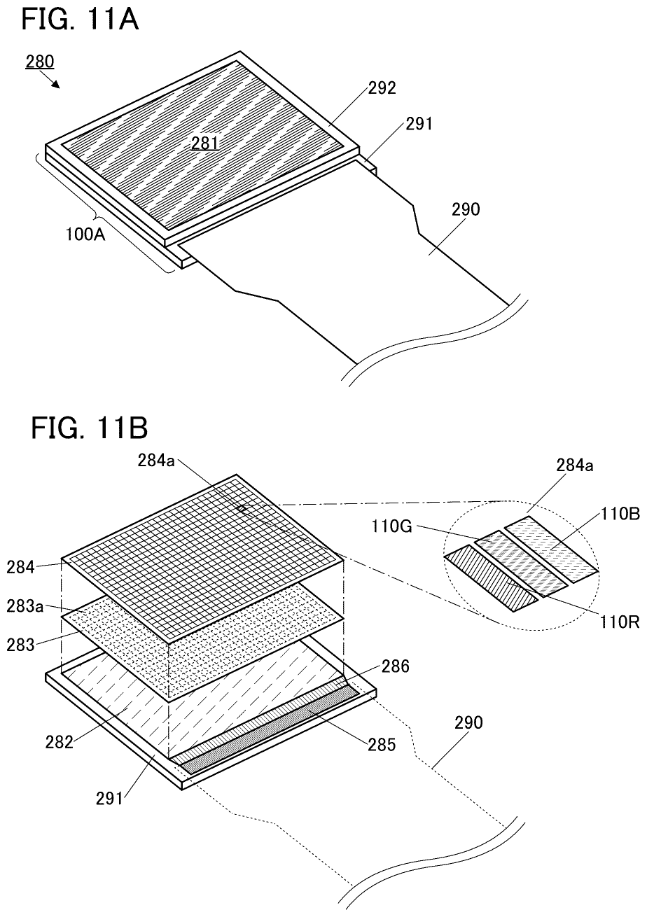

Next, as illustrated in FIG. 10A, etching treatment is performed using the insulating layer 127 as a mask to remove parts of the sacrificial layers 158R, 158G, and 158B. Thus, openings are formed in the sacrificial layers 158R, 158G, and 158B, and the top surfaces of the organic compound layers 103R, 103G, and 103B and the conductive layer 152C are exposed. Note that this etching treatment may be hereinafter referred to as second etching treatment.

An end portion of the inorganic insulating layer 125 is covered with the insulating layer 127. FIG. 10A illustrates an example where part of the end portion of the sacrificial layer 158G (specifically a tapered portion formed by the first etching treatment) is covered with the insulating layer 127 and a tapered portion formed by the second etching treatment is exposed.

The second etching treatment is performed by wet etching. The use of wet etching can reduce damage to the organic compound layers 103R, 103G, and 103B, as compared to the case of using dry etching. Wet etching can be performed using an alkaline solution or an acid solution, for example. An aqueous solution is preferably used in order that the organic compound layer 103 is not dissolved.

Next, as illustrated in FIG. 10B, a common electrode 155 is formed over the organic compound layers 103R, 103G, and 103B, the conductive layer 152C, and the insulating layer 127. The common electrode 155 can be formed by a sputtering method, a vacuum evaporation method, or the like.

Next, as illustrated in FIG. 10C, the protective layer 131 is formed over the common electrode 155. The protective layer 131 can be formed by a vacuum evaporation method, a sputtering method, a CVD method, an ALD method, or the like.

Then, the substrate 120 is bonded to the protective layer 131 using the resin layer 122, so that the display apparatus can be manufactured. In the method for manufacturing the display apparatus of one embodiment of the present invention, the insulating layer 156 is formed to include a region overlapping with the side surface of the conductive layer 151 and the conductive layer 152 is formed to cover the conductive layer 151 and the insulating layer 156 as described above. This can increase the yield of the display apparatus and inhibit generation of defects.

As described above, in the method for manufacturing the display apparatus of one embodiment of the present invention, the island-shaped organic compound layers 103R, 103G, and 103B are formed not by using a fine metal mask but by processing a film formed on the entire surface; thus, the island-shaped layers can be formed to have a uniform thickness. In addition, a high-resolution display apparatus or a display apparatus with a high aperture ratio can be obtained. Furthermore, even when the resolution or the aperture ratio is high and the distance between the subpixels is extremely short, the organic compound layers 103R, 103G, and 103B can be inhibited from being in contact with each other in the adjacent subpixels. As a result, generation of a leakage current between the subpixels can be inhibited. This can prevent crosstalk, so that a display apparatus with extremely high contrast can be obtained. Moreover, even a display apparatus that includes tandem light-emitting devices formed by a photolithography method can have favorable characteristics.

### Embodiment 5

In this embodiment, a display apparatus of one embodiment of the present invention will be described.

The display apparatus in this embodiment can be a high-resolution display apparatus. Thus, the display apparatus in this embodiment can be used for display portions of information terminals (wearable devices) such as watch-type and bracelet-type information terminals and display portions of wearable devices capable of being worn on a head, such as a VR device like a head mounted display (HMID) and a glasses-type AR device.

The display apparatus in this embodiment can be a high-definition display apparatus or a large-sized display apparatus. Accordingly, the display apparatus in this embodiment can be used for display portions of a digital camera, a digital video camera, a digital photo frame, a mobile phone, a portable game console, a portable information terminal, and an audio reproducing device, in addition to display portions of electronic appliances with a relatively large screen, such as a television device, desktop and notebook personal computers, a monitor of a computer and the like, digital signage, and a large game machine such as a pachinko machine.

[Display module]FIG. 11A is a perspective view of a display module 280. The display module 280 includes a display apparatus 100A and an FPC 290. Note that the display apparatus included in the display module 280 is not limited to the display apparatus 100A and may be any of display apparatuses 100B to 100E described later.

The display module 280 includes a substrate 291 and a substrate 292. The display module 280 includes a display portion 281. The display portion 281 is a region of the display module 280 where an image is displayed, and is a region where light emitted from pixels provided in a pixel portion 284 described later can be seen.

FIG. 11B is a perspective view schematically illustrating the structure on the substrate 291 side. Over the substrate 291, a circuit portion 282, a pixel circuit portion 283 over the circuit portion 282, and the pixel portion 284 over the pixel circuit portion 283 are stacked. In addition, a terminal portion 285 for connection to the FPC 290 is included in a portion over the substrate 291 that does not overlap with the pixel portion 284. The terminal portion 285 and the circuit portion 282 are electrically connected to each other through a wiring portion 286 formed of a plurality of wirings.

The pixel portion 284 includes a plurality of pixels 284a arranged periodically. An enlarged view of one pixel 284a is illustrated on the right side in FIG. 11B. The pixels 284a can employ any of the structures described in the above embodiments.

The pixel circuit portion 283 includes a plurality of pixel circuits 283a arranged periodically.

One pixel circuit 283a is a circuit that controls driving of a plurality of elements included in one pixel 284a.

The circuit portion 282 includes a circuit for driving the pixel circuits 283a in the pixel circuit portion 283. For example, the circuit portion 282 preferably includes one or both of a gate line driver circuit and a source line driver circuit. The circuit portion 282 may also include at least one of an arithmetic circuit, a memory circuit, a power supply circuit, and the like.

The FPC 290 functions as a wiring for supplying a video signal, a power supply potential, or the like to the circuit portion 282 from the outside. An IC may be mounted on the FPC 290.

The display module 280 can have a structure in which one or both of the pixel circuit portion 283 and the circuit portion 282 are stacked below the pixel portion 284; hence, the aperture ratio (effective display area ratio) of the display portion 281 can be significantly high.

Such a display module 280 has extremely high resolution, and thus can be suitably used for a VR device such as an HMD or a glasses-type AR device. For example, even in the case of a structure in which the display portion of the display module 280 is seen through a lens, pixels of the extremely-high-resolution display portion 281 included in the display module 280 are prevented from being recognized when the display portion is enlarged by the lens, so that display providing a high sense of immersion can be performed. Without being limited thereto, the display module 280 can be suitably used for electronic appliances including a relatively small display portion.

### [Display Apparatus 100A]

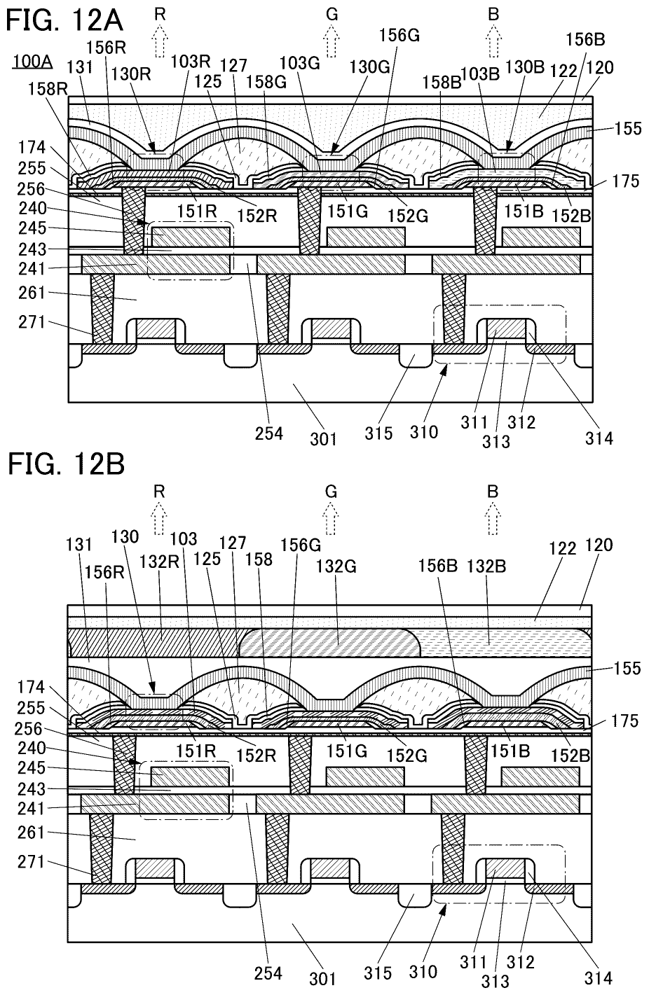

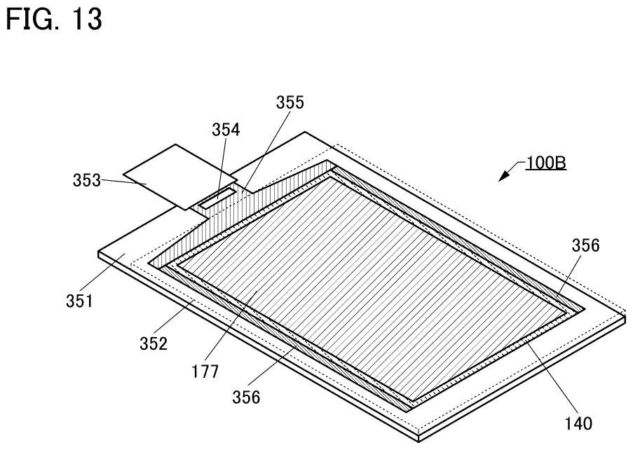

The display apparatus 100A illustrated in FIG. 12A includes a substrate 301, the light-emitting devices 130R, 130G, and 130B, a capacitor 240, and a transistor 310.

The substrate 301 corresponds to the substrate 291 in FIGS. 12A and 12B. The transistor 310 includes a channel formation region in the substrate 301. As the substrate 301, a semiconductor substrate such as a single crystal silicon substrate can be used, for example. The transistor 310 includes part of the substrate 301, a conductive layer 311, a low-resistance region 312, an insulating layer 313, and an insulating layer 314. The conductive layer 311 functions as a gate electrode. The insulating layer 313 is positioned between the substrate 301 and the conductive layer 311 and functions as a gate insulating layer. The low-resistance region 312 is a region where the substrate 301 is doped with an impurity, and functions as a source or a drain. The insulating layer 314 is provided to cover the side surface of the conductive layer 311.

An element isolation layer 315 is provided between two adjacent transistors 310 to be embedded in the substrate 301.

An insulating layer 261 is provided to cover the transistor 310, and the capacitor 240 is provided over the insulating layer 261.

The capacitor 240 includes a conductive layer 241, a conductive layer 245, and an insulating layer 243 between the conductive layers 241 and 245. The conductive layer 241 functions as one electrode of the capacitor 240, the conductive layer 245 functions as the other electrode of the capacitor 240, and the insulating layer 243 functions as a dielectric of the capacitor 240.

The conductive layer 241 is provided over the insulating layer 261 and is embedded in an insulating layer 254. The conductive layer 241 is electrically connected to one of the source and the drain of the transistor 310 through a plug 271 embedded in the insulating layer 261. The insulating layer 243 is provided to cover the conductive layer 241. The conductive layer 245 is provided in a region overlapping with the conductive layer 241 with the insulating layer 243 therebetween.

An insulating layer 255 is provided to cover the capacitor 240. The insulating layer 174 is provided over the insulating layer 255. The insulating layer 175 is provided over the insulating layer 174. The light-emitting devices 130R, 130G, and 130B are provided over the insulating layer 175. An insulator is provided in regions between adjacent light-emitting devices.

The insulating layer 156R is provided to include a region overlapping with the side surface of the conductive layer 151R. The insulating layer 156G is provided to include a region overlapping with the side surface of the conductive layer 151G. The insulating layer 156B is provided to include a region overlapping with the side surface of the conductive layer 151B. The conductive layer 152R is provided to cover the conductive layer 151R and the insulating layer 156R. The conductive layer 152G is provided to cover the conductive layer 151G and the insulating layer 156G. The conductive layer 152B is provided to cover the conductive layer 151B and the insulating layer 156B. The sacrificial layer 158R is positioned over the organic compound layer 103R. The sacrificial layer 158G is positioned over the organic compound layer 103G. The sacrificial layer 158B is positioned over the organic compound layer 103B.

Each of the conductive layers 151R, 151G, and 151B is electrically connected to one of the source and the drain of the corresponding transistor 310 through a plug 256 embedded in the insulating layers 243, 255, 174, and 175, the conductive layer 241 embedded in the insulating layer 254, and the plug 271 embedded in the insulating layer 261. Any of a variety of conductive materials can be used for the plugs.

The protective layer 131 is provided over the light-emitting devices 130R, 130G, and 130B. The substrate 120 is bonded to the protective layer 131 with the resin layer 122. Embodiment 4 can be referred to for the details of the light-emitting device 130 and the components thereover up to the substrate 120. The substrate 120 corresponds to the substrate 292 in FIG. 11A.

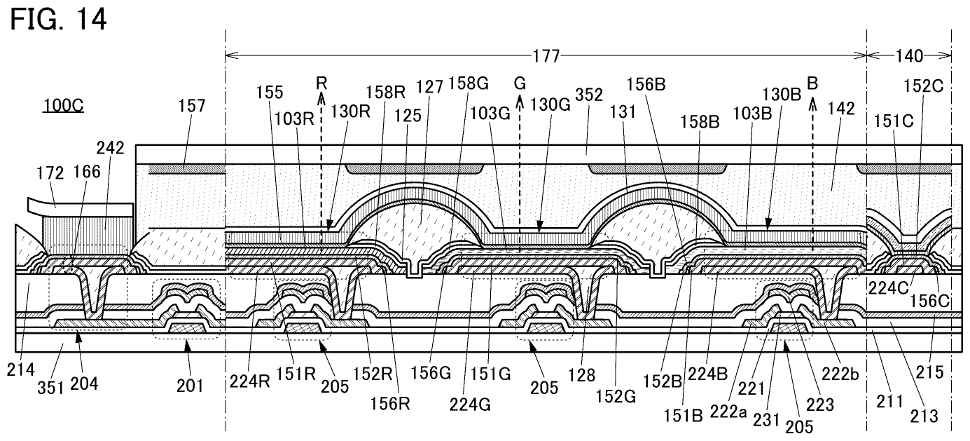

FIG. 12B illustrates a variation example of the display apparatus 100A illustrated in FIG. 12A. The display apparatus illustrated in FIG. 12B includes a coloring layer 132R, a coloring layer 132G, and a coloring layer 132B, and each of the light-emitting devices 130 includes a region overlapping with one of the coloring layers 132R, 132G, and 132B. In the display apparatus illustrated in FIG. 12B, the light-emitting device 130 can emit white light, for example. The coloring layer 132R, the coloring layer 132G, and the coloring layer 132B can transmit red light, green light, and blue light, respectively, for example.

[Display apparatus 100B]FIG. 13 is a perspective view of the display apparatus 100B, and FIG. 14 is a cross-sectional view of the display apparatus 100C.

In the display apparatus 100B, a substrate 352 and a substrate 351 are bonded to each other. In FIG. 13, the substrate 352 is denoted by a dashed line.

The display apparatus 100B includes the pixel portion 177, the connection portion 140, a circuit 356, a wiring 355, and the like. FIG. 13 illustrates an example where an IC 354 and an FPC 353 are mounted on the display apparatus 100B. Thus, the structure illustrated in FIG. 13 can be regarded as a display module including the display apparatus 100B, the integrated circuit (IC), and the FPC. Here, a display apparatus in which a substrate is equipped with a connector such as an FPC or mounted with an IC is referred to as a display module.

The connection portion 140 is provided outside the pixel portion 177. The number of connection portions 140 may be one or more. In the connection portion 140, a common electrode of a light-emitting device is electrically connected to a conductive layer, so that a potential can be supplied to the common electrode.

As the circuit 356, a scan line driver circuit can be used, for example.

The wiring 355 has a function of supplying a signal and power to the pixel portion 177 and the circuit 356. The signal and power are input to the wiring 355 from the outside through the FPC 353 or from the IC 354.

FIG. 13 illustrates an example where the IC 354 is provided over the substrate 351 by a chip on glass (COG) method, a chip on film (COF) method, or the like. An IC including a scan line driver circuit, a signal line driver circuit, or the like can be used as the IC 354, for example. Note that the display apparatus 100B and the display module are not necessarily provided with an IC. Alternatively, the IC may be mounted on the FPC by a COF method, for example.

FIG. 14 illustrates the display apparatus 100C as an example of cross sections of part of a region including the FPC 353, part of the circuit 356, part of the pixel portion 177, part of the connection portion 140, and part of a region including an end portion of the display apparatus 100B in FIG. 13.

### [Display Apparatus 100C]

The display apparatus 100C illustrated in FIG. 14 includes a transistor 201, a transistor 205, the light-emitting device 130R that emits red light, the light-emitting device 130G that emits green light, the light-emitting device 130B that emits blue light, and the like between the substrate 351 and the substrate 352.

Embodiment 4 can be referred to for the details of the light-emitting devices 130R, 130G, and 130B.

The light-emitting device 130R includes a conductive layer 224R, the conductive layer 151R over the conductive layer 224R, and the conductive layer 152R over the conductive layer 151R. The light-emitting device 130G includes a conductive layer 224G, the conductive layer 151G over the conductive layer 224G, and the conductive layer 152G over the conductive layer 151G. The light-emitting device 130B includes a conductive layer 224B, the conductive layer 151B over the conductive layer 224B, and the conductive layer 152B over the conductive layer 151B.

The conductive layer 224R is connected to a conductive layer 222b included in the transistor 205 through an opening provided in an insulating layer 214. An end portion of the conductive layer 151R is positioned outward from an end portion of the conductive layer 224R. The insulating layer 156R is provided to include a region that is in contact with the side surface of the conductive layer 151R, and the conductive layer 152R is provided to cover the conductive layer 151R and the insulating layer 156R.

The conductive layers 224G, 151G, and 152G, and the insulating layer 156G in the light-emitting device 130G are not described in detail because they are respectively similar to the conductive layers 224R, 151R, and 152R, and the insulating layer 156R in the light-emitting device 130R; the same applies to the conductive layers 224B, 151B, and 152B, and the insulating layer 156B in the light-emitting device 130B.

The conductive layers 224R, 224G, and 224B each have a depressed portion covering the opening provided in the insulating layer 214. A layer 128 is embedded in the depressed portion.

The layer 128 has a function of filling the depressed portions of the conductive layers 224R, 224G, and 224B to obtain planarity. Over the conductive layers 224R, 224G, and 224B and the layer 128, the conductive layers 151R, 151G, and 151B that are respectively electrically connected to the conductive layers 224R, 224G, and 224B are provided. Thus, the regions overlapping with the depressed portions of the conductive layers 224R, 224G, and 224B can also be used as light-emitting regions, whereby the aperture ratio of the pixel can be increased.

The layer 128 may be an insulating layer or a conductive layer. Any of a variety of inorganic insulating materials, organic insulating materials, and conductive materials can be used for the layer 128 as appropriate. Specifically, the layer 128 is preferably formed using an insulating material and is particularly preferably formed using an organic insulating material. The layer 128 can be formed using an organic insulating material usable for the insulating layer 127, for example.

The protective layer 131 is provided over the light-emitting devices 130R, 130G, and 130B. The protective layer 131 and the substrate 352 are bonded to each other with an adhesive layer 142. The substrate 352 is provided with a light-blocking layer 157. A solid sealing structure, a hollow sealing structure, or the like can be employed to seal the light-emitting device 130. In FIG. 14, a solid sealing structure is employed, in which a space between the substrate 352 and the substrate 351 is filled with the adhesive layer 142. Alternatively, the space may be filled with an inert gas (e.g., nitrogen or argon), i.e., a hollow sealing structure may be employed. In that case, the adhesive layer 142 may be provided not to overlap with the light-emitting device. Alternatively, the space may be filled with a resin other than the frame-like adhesive layer 142.

FIG. 14 illustrates an example where the connection portion 140 includes a conductive layer 224C obtained by processing the same conductive film as the conductive layers 224R, 224G, and 224B; the conductive layer 151C obtained by processing the same conductive film as the conductive layers 151R, 151G, and 151B; and the conductive layer 152C obtained by processing the same conductive film as the conductive layers 152R, 152G, and 152B. In the example illustrated in FIG. 14, the insulating layer 156C is provided to include a region overlapping with the side surface of the conductive layer 151C.

The display apparatus 100C has a top-emission structure. Light from the light-emitting device is emitted toward the substrate 352. For the substrate 352, a material with a high visible-light-transmitting property is preferably used. The pixel electrode contains a material that reflects visible light, and the counter electrode (the common electrode 155) contains a material that transmits visible light.

An insulating layer 211, an insulating layer 213, an insulating layer 215, and the insulating layer 214 are provided in this order over the substrate 351. Part of the insulating layer 211 functions as a gate insulating layer of each transistor. Part of the insulating layer 213 functions as a gate insulating layer of each transistor. The insulating layer 215 is provided to cover the transistors. The insulating layer 214 is provided to cover the transistors and has a function of a planarization layer. Note that the number of gate insulating layers and the number of insulating layers covering the transistors are not limited and may each be one or more.

An inorganic insulating film is preferably used as each of the insulating layers 211, 213, and 215.

An organic insulating layer is suitable as the insulating layer 214 functioning as a planarization layer.

Each of the transistors 201 and 205 includes a conductive layer 221 functioning as a gate, the insulating layer 211 functioning as the gate insulating layer, a conductive layer 222a and the conductive layer 222b functioning as a source and a drain, a semiconductor layer 231, the insulating layer 213 functioning as the gate insulating layer, and a conductive layer 223 functioning as a gate.

A connection portion 204 is provided in a region of the substrate 351 not overlapping with the substrate 352. In the connection portion 204, one of the source electrode and the drain electrode of the transistor 201 is electrically connected to the FPC 353 through a conductive layer 166 and a connection layer 242. As an example, the conductive layer 166 has a stacked-layer structure of a conductive film obtained by processing the same conductive film as the conductive layers 224R, 224G, and 224B; a conductive film obtained by processing the same conductive film as the conductive layers 151R, 151G, and 151B; and a conductive film obtained by processing the same conductive film as the conductive layers 152R, 152G, and 152B. On the top surface of the connection portion 204, the conductive layer 166 is exposed. Thus, the connection portion 204 and the FPC 353 can be electrically connected to each other through the connection layer 242.

The light-blocking layer 157 is preferably provided on the surface of the substrate 352 on the substrate 351 side. The light-blocking layer 157 can be provided over a region between adjacent light-emitting devices, in the connection portion 140, in the circuit 356, and the like. A variety of optical members can be arranged on the outer surface of the substrate 352.

A material that can be used for the substrate 120 can be used for each of the substrates 351 and 352.

A material that can be used for the resin layer 122 can be used for the adhesive layer 142.

As the connection layer 242, an anisotropic conductive film (ACF), an anisotropic conductive paste (ACP), or the like can be used.

### [Display Apparatus 100D]

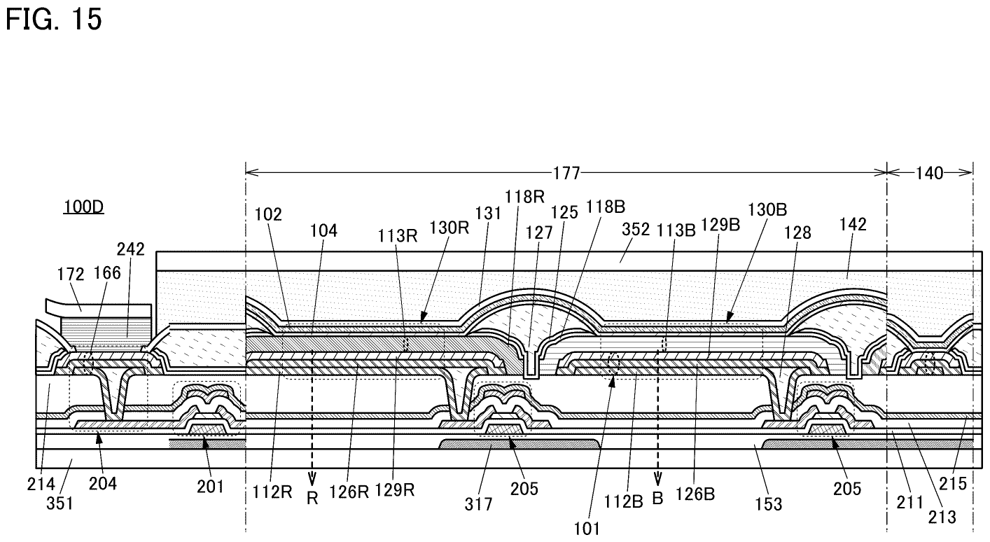

The display apparatus 100D illustrated in FIG. 15 differs from the display apparatus 100C illustrated in FIG. 14 mainly in having a bottom-emission structure.

Light from the light-emitting device is emitted toward the substrate 351. For the substrate 351, a material with a high visible-light-transmitting property is preferably used. By contrast, there is no limitation on the light-transmitting property of a material used for the substrate 352.

A light-blocking layer 317 is preferably formed between the substrate 351 and the transistor 201 and between the substrate 351 and the transistor 205. FIG. 15 illustrates an example where the light-blocking layer 317 is provided over the substrate 351, an insulating layer 153 is provided over the light-blocking layer 317, and the transistors 201 and 205 and the like are provided over the insulating layer 153.

The light-emitting device 130R includes a conductive layer 112R, a conductive layer 126R over the conductive layer 112R, and a conductive layer 129R over the conductive layer 126R.

The light-emitting device 130B includes a conductive layer 112B, a conductive layer 126B over the conductive layer 112B, and a conductive layer 129B over the conductive layer 126B.

A material with a high visible-light-transmitting property is used for each of the conductive layers 112R, 112B, 126R, 126B, 129R, and 129B. A material that reflects visible light is preferably used for the second electrode 102.

Although not illustrated in FIG. 15, the light-emitting device 130G is also provided.

Although FIG. 15 and the like illustrate an example where the top surface of the layer 128 includes a flat portion, the shape of the layer 128 is not particularly limited.

### [Display Apparatus 100D2]

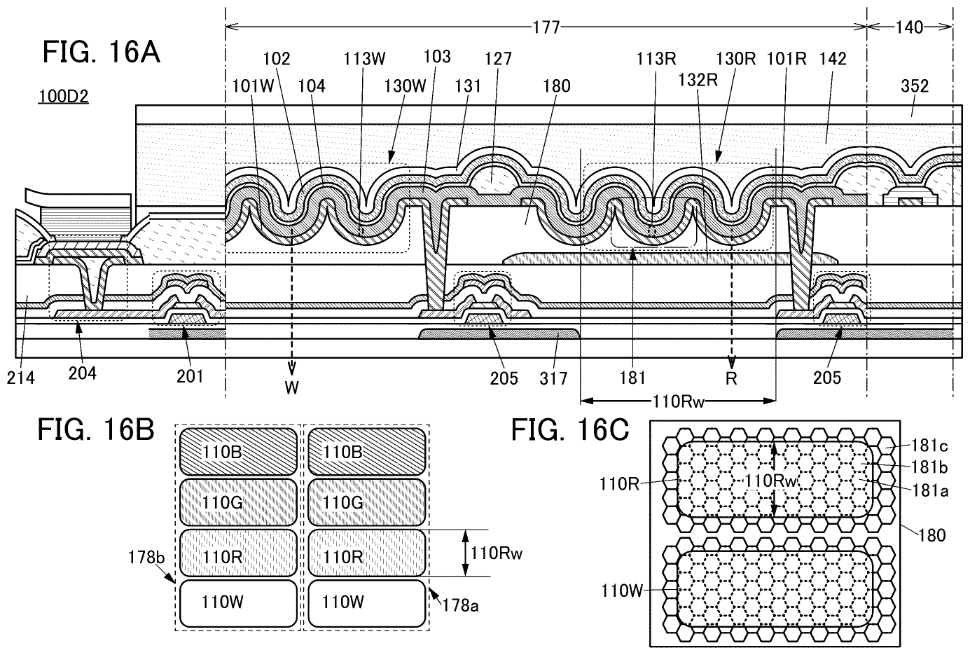

The display apparatus 100D2 illustrated in FIG. 16 is an example of a bottom-emission display apparatus different from the display apparatus 100D illustrated in FIG. 15. The display apparatus 100D2 is different from the display apparatus 100D in including an organic resin layer 180. Note that the reference numerals of the components that are the same as those in FIG. 15 are sometimes omitted and the description for FIG. 15 is preferably referred to for the details of such components.

FIG. 16B is a top-view layout of the pixel 178 (pixels 178a and 178b) including the subpixel 110 (the subpixels 110R, 110G, and 110B and a subpixel 110W), and FIG. 16C is a top view of the organic resin layer 180 in a region where the subpixels 110R and 110G included in the pixel 178 are formed. A region of the subpixel 110R between the light-blocking layers 317 can be represented as a width 110Rw in a light-emitting region.

As illustrated in FIG. 16A, the organic resin layer 180 is provided over the insulating layer 214. As illustrated in FIG. 16C and the region surrounded by the dashed-dotted line in FIG. 16A, the organic resin layer 180 includes a depressed portion 181 (depressed portions 181a and 181b) having a curved surface at least in a region where the subpixel is formed. Note that the depressed portion 181 may be provided outside the light-emitting region, like a depressed portion 181c. With the depressed portion 181c, light emission caused in a region overlapping with the light-blocking layer 317 or light travelled into the region overlapping with the light-blocking layer 317 can be refracted and extracted from the light-emitting region, whereby emission efficiency can be improved.

A plurality of depressed portions 181 may be formed in a matrix. The depressed portions 181a and 181b may be provided in contact with each other or may be provided to have a flat surface therebetween.

In FIG. 16, although the top surface shape and the cross-sectional shape of the depressed portion are hexagonal (FIG. 16C) and semicircular (FIG. 16A), respectively, other shapes may be employed as needed. Examples of the top surface shape of the depressed portion include polygons such as a triangle, a tetragon (including a rectangle and a square), and a pentagon; polygons with rounded corners; an ellipse; and a circle.

An insulating layer containing an organic material can be used as the organic resin layer 180. Examples of materials used for the organic resin layer 180 include an acrylic resin, a polyimide resin, an epoxy resin, an imide resin, a polyamide resin, a polyimide-amide resin, a silicone resin, a siloxane resin, a benzocyclobutene-based resin, a phenol resin, and precursors of these resins. The organic resin layer 180 may be formed using an organic material such as polyvinyl alcohol (PVA), polyvinyl butyral, polyvinylpyrrolidone, polyethylene glycol, polyglycerin, pullulan, water-soluble cellulose, or an alcohol-soluble polyamide resin.

A photosensitive resin can also be used for the organic resin layer 180. A photoresist may be used for the photosensitive resin. As the photosensitive resin, a positive photosensitive material or a negative photosensitive material can be used.

The organic resin layer 180 may contain a material absorbing visible light. For example, the organic resin layer 180 itself may be made of a material absorbing visible light, or the organic resin layer 180 may contain a pigment absorbing visible light. For example, the organic resin layer 180 can be formed using a resin that can be used as a color filter transmitting red, blue, or green light and absorbing light of the other colors; or a resin that contains carbon black as a pigment and functions as a black matrix.

The first electrode 101 (the first electrode 101R and a first electrode 101W) is over the organic resin layer 180 and the organic compound layer 103 is over the first electrode 101. End portions of the first electrode 101 and the organic compound layer 103 may be covered with the insulating layer 127.

The first electrode 101 formed over the organic resin layer 180 also has a depressed portion along the depressed portion of the organic resin layer 180. The organic compound layer 103 formed over the first electrode 101 also has a depressed portion along the depressed portion of the first electrode 101. The common layer 104 formed over the organic compound layer 103 also has a depressed portion along the depressed portion of the organic compound layer 103. The second electrode 102 formed over the common layer 104 also has a depressed portion along the depressed portion of the common layer 104. That is, the depressed portions of the organic resin layer 180, the first electrode 101, the organic compound layer 103, the common layer 104, and the second electrode 102 overlap with each other.

The common layer 104 is provided over the organic compound layer 103 and the insulating layer 127, and the second electrode 102 is provided over the common layer 104. The protective layer 131 is provided over the second electrode 102 and bonded to the substrate 352 with the adhesive layer 142 therebetween.

Although the light-emitting devices 130G and 130B are not illustrated in FIGS. 16A to 16C, the light-emitting devices 130G and 130B are also provided.

The light-emitting apparatus of one embodiment of the present invention including the above-described organic resin layer 180 includes the organic compound represented by General Formula (Gh1) in the organic compound layer 103 as described in Embodiment 1, whereby an organic semiconductor device with high emission efficiency, high reliability, a low driving voltage, and low power consumption can be provided owing to an indivisible effect of the organic resin layer 180 and the organic compound of the present application.

### [Display Apparatus 100E]

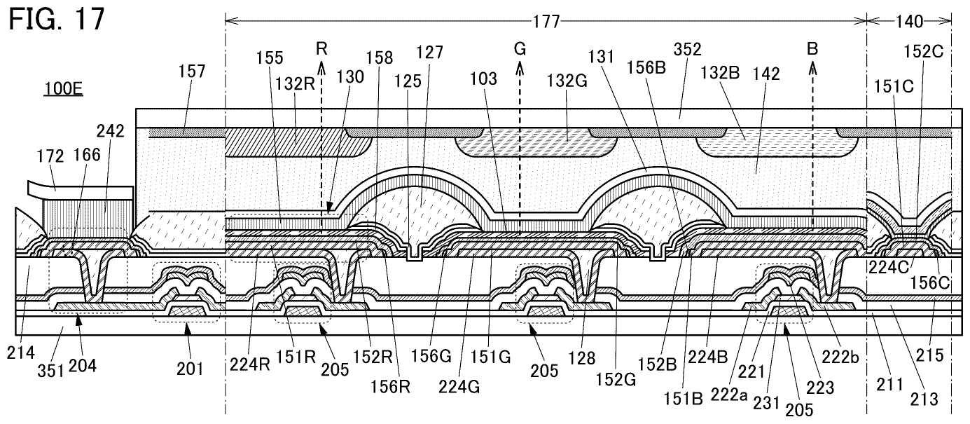

The display apparatus 100E illustrated in FIG. 17 is a variation example of the display apparatus 100C illustrated in FIG. 14 and differs from the display apparatus 100C mainly in including the coloring layers 132R, 132G, and 132B.

In the display apparatus 100E, the light-emitting device 130 includes a region overlapping with one of the coloring layers 132R, 132G, and 132B. The coloring layers 132R, 132G, and 132B can be provided on a surface of the substrate 352 on the substrate 351 side. End portions of the coloring layers 132R, 132G, and 132B can overlap with the light-blocking layer 157.

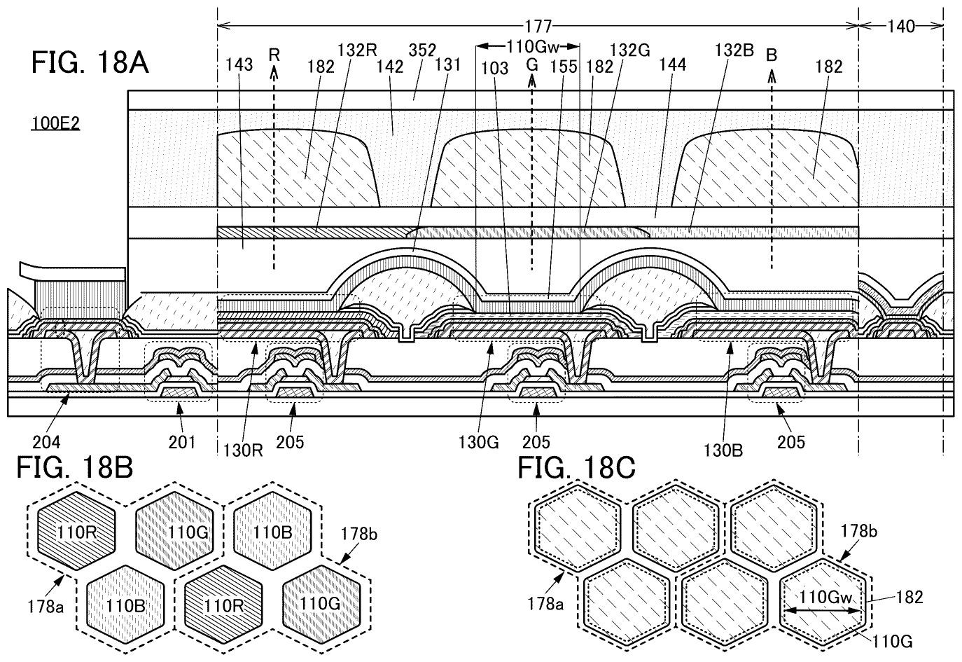

In the display apparatus 100E, the light-emitting device 130 can emit white light, for example. The coloring layer 132R, the coloring layer 132G, and the coloring layer 132B can transmit red light, green light, and blue light, respectively, for example. Note that in the display apparatus 100E, the coloring layers 132R, 132G, and 132B may be provided between the protective layer 131 and the adhesive layer 142.

[Display Apparatus 100E2]A display apparatus 100E2 illustrated in FIG. 18 is a variation example of the display apparatus 100E illustrated in FIG. 17 and includes microlenses 182 over the coloring layers 132R, 132G, and 132B. Note that the reference numerals of the components that are the same as those in FIG. 17 are sometimes omitted and the description for FIG. 17 is preferably referred to for the details of such components.

FIG. 18B is a top-view layout of the pixel 178 (the pixels 178a and 178b) including the subpixel 110 (the subpixels 110R, 110G, and 110B), and FIG. 18C is a top view of the microlens 182 in a region where the subpixels 110R and 110G included in the pixel 178 are formed. A region of the subpixel 110G where the common electrode 155 and the EL layer 103 are in contact with each other can be represented as a width 110Gw in a light-emitting region.

In the display apparatus 100E2 illustrated in FIG. 18A, a planarization film 143 is provided over the protective layer 131, and the coloring layers 132R, 132G, and 132B are provided over a planarization film 144. The planarization film 144 is provided to cover the coloring layers 132R, 132G, and 132B. The microlenses 182 are provided over the planarization film 144.

Note that as illustrated in FIG. 18C, the microlens 182 is preferably provided for each of the subpixels in a region where the subpixel is formed.

Although the top surface shape of the microlens 182 is illustrated as a hexagon in FIG. 18C, other shapes may be employed as needed. Examples of the top surface shape of the depressed portion include polygons such as a triangle, a tetragon (including a rectangle and a square), and a pentagon; polygons with rounded corners; an ellipse; and a circle.

The microlens 182 can be formed using a material similar to that for the organic resin layer 180.

The light-emitting apparatus of one embodiment of the present invention including the above-described microlens 182 includes the organic compound represented by General Formula (Ghl) in the organic compound layer 103 as described in Embodiment 1, whereby an organic semiconductor device with high emission efficiency, high reliability, a low driving voltage, and low power consumption, which is suitable for a mobile display, can be provided owing to an indivisible effect of the microlens 182 and the organic compound of the present application.

This embodiment can be combined as appropriate with the other embodiments or the examples. In this specification, in the case where a plurality of structure examples are shown in one embodiment, the structure examples can be combined as appropriate.

### Embodiment 6

In this embodiment, electronic appliances of embodiments of the present invention will be described.

Electronic appliances in this embodiment each include the display apparatus of one embodiment of the present invention in a display portion. The display apparatus of one embodiment of the present invention has low power consumption and high reliability. Thus, the display apparatus of one embodiment of the present invention can be used for a display portion of a variety of electronic appliances.

Examples of the electronic appliances include a digital camera, a digital video camera, a digital photo frame, a mobile phone, a portable game console, a portable information terminal, and an audio reproducing device, in addition to electronic appliances with a relatively large screen, such as a television device, desktop and notebook personal computers, a monitor of a computer and the like, digital signage, and a large game machine such as a pachinko machine.

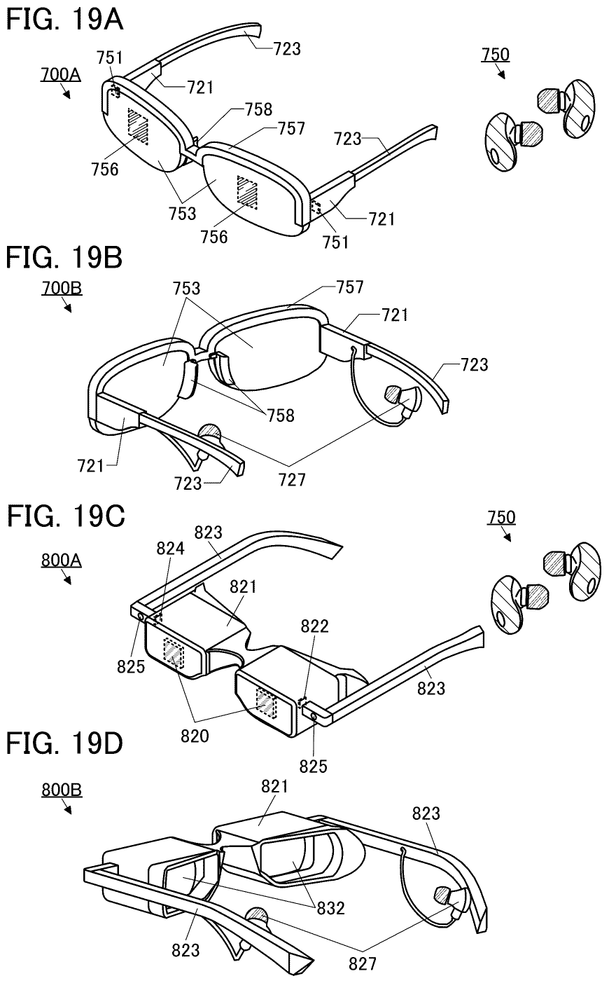

Examples of wearable devices capable of being worn on a head are described with reference to FIGS. 19A to 19D.

An electronic appliance 700A illustrated in FIG. 19A and an electronic appliance 700B illustrated in FIG. 19B each include a pair of display panels 751, a pair of housings 721, a communication portion (not illustrated), a pair of wearing portions 723, a control portion (not illustrated), an image capturing portion (not illustrated), a pair of optical members 753, a frame 757, and a pair of nose pads 758.

The display apparatus of one embodiment of the present invention can be used for the display panels 751. Thus, a highly reliable electronic appliance is obtained.

The electronic appliances 700A and 700B can each project images displayed on the display panels 751 onto display regions 756 of the optical members 753. Since the optical members 753 have a light-transmitting property, the user can see images displayed on the display regions, which are superimposed on transmission images seen through the optical members 753.

In the electronic appliances 700A and 700B, a camera capable of capturing images of the front side may be provided as the image capturing portion. Furthermore, when the electronic appliances 700A and 700B are provided with an acceleration sensor such as a gyroscope sensor, the orientation of the user's head can be sensed and an image corresponding to the orientation can be displayed on the display regions 756.

The communication portion includes a wireless communication device, and a video signal, for example, can be supplied by the wireless communication device. Instead of or in addition to the wireless communication device, a connector that can be connected to a cable for supplying a video signal and a power supply potential may be provided.

The electronic appliances 700A and 700B are provided with a battery, so that they can be charged wirelessly and/or by wire.

A touch sensor module may be provided in the housing 721.

Various touch sensors can be applied to the touch sensor module. For example, any of touch sensors of the following types can be used: a capacitive type, a resistive type, an infrared type, an electromagnetic induction type, a surface acoustic wave type, and an optical type. In particular, a capacitive sensor or an optical sensor is preferably used for the touch sensor module.

An electronic appliance 800A illustrated in FIG. 19C and an electronic appliance 800B illustrated in FIG. 19D each include a pair of display portions 820, a housing 821, a communication portion 822, a pair of wearing portions 823, a control portion 824, a pair of image capturing portions 825, and a pair of lenses 832.

The display apparatus of one embodiment of the present invention can be used in the display portions 820. Thus, a highly reliable electronic appliance is obtained.

The display portions 820 are positioned inside the housing 821 so as to be seen through the lenses 832. When the pair of display portions 820 display different images, three-dimensional display using parallax can be performed.

The electronic appliances 800A and 800B preferably include a mechanism for adjusting the lateral positions of the lenses 832 and the display portions 820 so that the lenses 832 and the display portions 820 are positioned optimally in accordance with the positions of the user's eyes.

The electronic appliance 800A or the electronic appliance 800B can be mounted on the user's head with the wearing portions 823.

The image capturing portion 825 has a function of obtaining information on the external environment. Data obtained by the image capturing portion 825 can be output to the display portion 820. An image sensor can be used for the image capturing portion 825. Moreover, a plurality of cameras may be provided so as to support a plurality of fields of view, such as a telescope field of view and a wide field of view.

The electronic appliance 800A may include a vibration mechanism that functions as bone-conduction earphones.

The electronic appliances 800A and 800B may each include an input terminal. To the input terminal, a cable for supplying a video signal from a video output device or the like, power for charging a battery provided in the electronic appliance, and the like can be connected.

The electronic appliance of one embodiment of the present invention may have a function of performing wireless communication with earphones 750.

The electronic appliance may include an earphone portion. The electronic appliance 700B illustrated in FIG. 19B includes earphone portions 727. Part of a wiring that connects the earphone portion 727 and the control portion may be positioned inside the housing 721 or the wearing portion 723.

Similarly, the electronic appliance 800B illustrated in FIG. 19D includes earphone portions 827. For example, the earphone portion 827 can be connected to the control portion 824 by wire.

As described above, both the glasses-type device (e.g., the electronic appliances 700A and 700B) and the goggles-type device (e.g., the electronic appliances 800A and 800B) are preferable as the electronic appliance of one embodiment of the present invention.

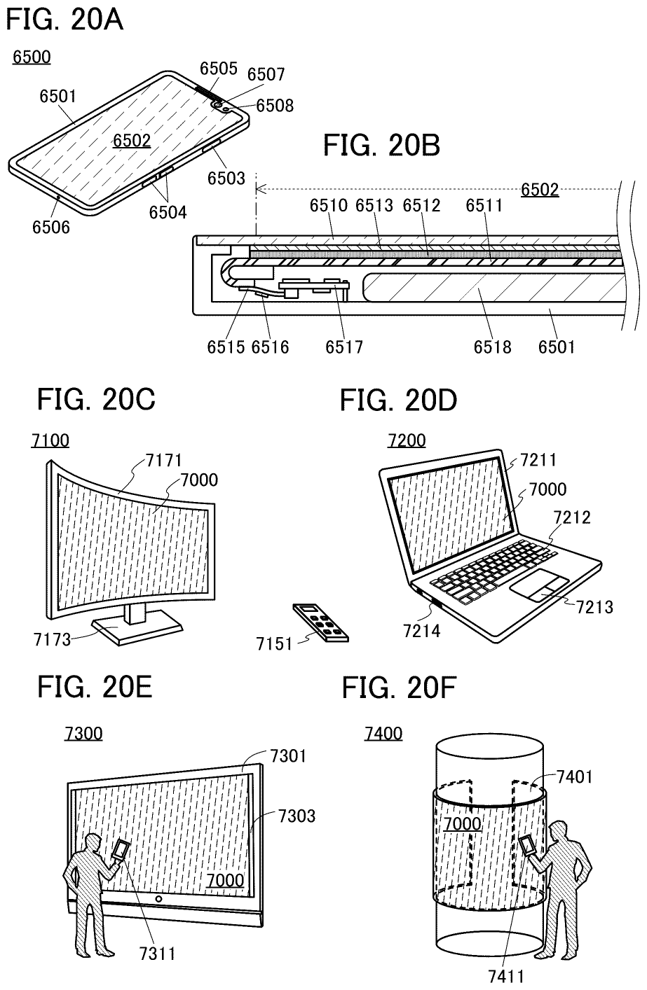

An electronic appliance 6500 illustrated in FIG. 20A is a portable information terminal that can be used as a smartphone.

The electronic appliance 6500 includes a housing 6501, a display portion 6502, a power button 6503, buttons 6504, a speaker 6505, a microphone 6506, a camera 6507, a light source 6508, and the like. The display portion 6502 has a touch panel function.

The display apparatus of one embodiment of the present invention can be used in the display portion 6502. Thus, a highly reliable electronic appliance is obtained.

FIG. 20B is a schematic cross-sectional view including an end portion of the housing 6501 on the microphone 6506 side.

A protection member 6510 having a light-transmitting property is provided on the display surface side of the housing 6501. A display panel 6511, an optical member 6512, a touch sensor panel 6513, a printed circuit board 6517, a battery 6518, and the like are provided in a space surrounded by the housing 6501 and the protection member 6510.

The display panel 6511, the optical member 6512, and the touch sensor panel 6513 are fixed to the protection member 6510 with a bonding layer (not illustrated).

Part of the display panel 6511 is folded back in a region outside the display portion 6502, and an FPC 6515 is connected to the part that is folded back. An IC 6516 is mounted on the FPC 6515. The FPC 6515 is connected to a terminal provided on the printed circuit board 6517.

The display apparatus of one embodiment of the present invention can be used in the display panel 6511. Thus, an extremely lightweight electronic appliance can be achieved. Since the display panel 6511 is extremely thin, the battery 6518 with high capacity can be mounted without an increase in the thickness of the electronic appliance. Moreover, part of the display panel 6511 is folded back so that a connection portion with the FPC 6515 is provided on the back side of the pixel portion, whereby an electronic appliance with a narrow bezel can be achieved.

FIG. 20C illustrates an example of a television device. In a television device 7100, a display portion 7000 is incorporated in a housing 7171. Here, the housing 7171 is supported by a stand 7173.

The display apparatus of one embodiment of the present invention can be used in the display portion 7000. Thus, a highly reliable electronic appliance is obtained.

Operation of the television device 7100 illustrated in FIG. 20C can be performed with an operation switch provided in the housing 7171 and a separate remote controller 7151.

FIG. 20D illustrates an example of a notebook personal computer. A notebook personal computer 7200 includes a housing 7211, a keyboard 7212, a pointing device 7213, an external connection port 7214, and the like. The display portion 7000 is incorporated in the housing 7211.

The display apparatus of one embodiment of the present invention can be used in the display portion 7000. Thus, a highly reliable electronic appliance is obtained.

FIGS. 20E and 20F illustrate examples of digital signage.

Digital signage 7300 illustrated in FIG. 20E includes a housing 7301, the display portion 7000, a speaker 7303, and the like. The digital signage 7300 can also include an LED lamp, an operation key (including a power switch or an operation switch), a connection terminal, a variety of sensors, a microphone, and the like.

FIG. 20F illustrates digital signage 7400 attached to a cylindrical pillar 7401. The digital signage 7400 includes the display portion 7000 provided along a curved surface of the pillar 7401.

In FIGS. 20E and 20F, the display apparatus of one embodiment of the present invention can be used in the display portion 7000. Thus, a highly reliable electronic appliance is obtained.

A larger area of the display portion 7000 can increase the amount of information that can be provided at a time. The larger display portion 7000 attracts more attention, so that the effectiveness of the advertisement can be increased, for example.

As illustrated in FIGS. 20E and 20F, it is preferable that the digital signage 7300 or the digital signage 7400 can work with an information terminal 7311 or an information terminal 7411, such as a smartphone that a user has, through wireless communication.

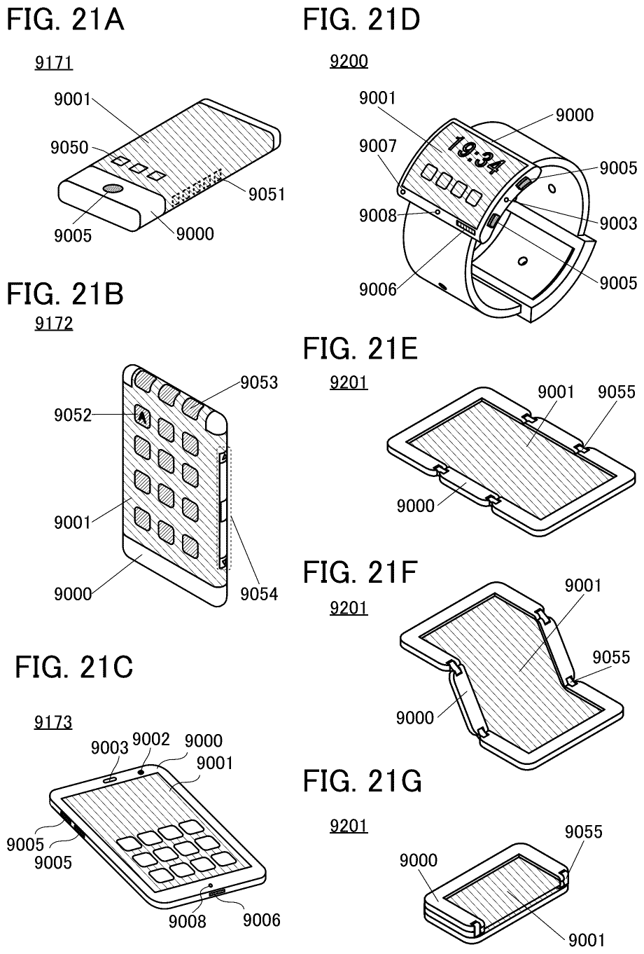

Electronic appliances illustrated in FIGS. 21A to 21G include a housing 9000, a display portion 9001, a speaker 9003, an operation key 9005 (including a power switch or an operation switch), a connection terminal 9006, a sensor 9007 (a sensor having a function of measuring force, displacement, position, speed, acceleration, angular velocity, rotational frequency, distance, light, liquid, magnetism, temperature, chemical substance, sound, time, hardness, electric field, current, voltage, electric power, radiation, flow rate, humidity, gradient, oscillation, odor, or infrared rays), a microphone 9008, and the like.

The electronic appliances illustrated in FIGS. 21A to 21G have a variety of functions. For example, the electronic appliances can have a function of displaying a variety of information (e.g., a still image, a moving image, and a text image) on the display portion, a touch panel function, a function of displaying a calendar, date, time, and the like, a function of controlling processing with use of a variety of software (programs), a wireless communication function, and a function of reading out and processing a program or data stored in a recording medium.

The electronic appliances illustrated in FIGS. 21A to 21G are described in detail below.

FIG. 21A is a perspective view of a portable information terminal 9171. The portable information terminal 9171 can be used as a smartphone, for example. The portable information terminal 9171 may include the speaker 9003, the connection terminal 9006, the sensor 9007, or the like. The portable information terminal 9171 can display text and image information on its plurality of surfaces. FIG. 21A illustrates an example where three icons 9050 are displayed. Furthermore, information 9051 indicated by dashed rectangles can be displayed on another surface of the display portion 9001. Examples of the information 9051 include notification of reception of an e-mail, an SNS message, an incoming call, or the like, the title and sender of an e-mail, an SNS message, or the like, the date, the time, remaining battery, and the radio field intensity. Alternatively, the icon 9050 or the like may be displayed at the position where the information 9051 is displayed.

FIG. 21B is a perspective view of a portable information terminal 9172. The portable information terminal 9172 has a function of displaying information on three or more surfaces of the display portion 9001. In the example illustrated here, information 9052, information 9053, and information 9054 are displayed on different surfaces. For example, the user of the portable information terminal 9172 can check the information 9053 displayed such that it can be seen from above the portable information terminal 9172, with the portable information terminal 9172 put in a breast pocket of his/her clothes.

FIG. 21C is a perspective view of a tablet terminal 9173. The tablet terminal 9173 is capable of executing a variety of applications such as mobile phone calls, e-mailing, viewing and editing texts, music reproduction, Internet communication, and a computer game, for example. The tablet terminal 9173 includes the display portion 9001, the camera 9002, the microphone 9008, and the speaker 9003 on the front surface of the housing 9000; the operation keys 9005 as buttons for operation on the left side surface of the housing 9000; and the connection terminal 9006 on the bottom surface of the housing 9000.

FIG. 21D is a perspective view of a watch-type portable information terminal 9200. The portable information terminal 9200 can be used as a Smartwatch (registered trademark), for example. The display surface of the display portion 9001 is curved, and an image can be displayed on the curved display surface. Furthermore, for example, mutual communication between the portable information terminal 9200 and a headset capable of wireless communication can be performed, and thus hands-free calling is possible. With the connection terminal 9006, the portable information terminal 9200 can perform mutual data transmission with another information terminal and charging. Note that the charging operation may be performed by wireless power feeding.

FIGS. 21E to 21G are perspective views of a foldable portable information terminal 9201. FIG. 21E is a perspective view illustrating the portable information terminal 9201 that is opened. FIG. 21G is a perspective view illustrating the portable information terminal 9201 that is folded. FIG. 21F is a perspective view illustrating the portable information terminal 9201 that is shifted from one of the states in FIGS. 21E and 21G to the other. The portable information terminal 9201 is highly portable when folded. When the portable information terminal 9201 is opened, a seamless large display region is highly browsable. The display portion 9001 of the portable information terminal 9201 is supported by three housings 9000 joined together by hinges 9055. The display portion 9001 can be folded with a radius of curvature greater than or equal to 0.1 mm and less than or equal to 150 mm, for example.

This embodiment can be combined as appropriate with the other embodiments or the examples. In this specification, in the case where a plurality of structure examples are shown in one embodiment, the structure examples can be combined as appropriate.

### Example 1

In this example, fabricating methods and characteristics of a light-emitting device 1 of one embodiment of the present invention and comparative light-emitting devices 1-1 to 1-3 which are comparative examples will be described in detail. Structural formulae of main compounds used for the light-emitting device 1 and the comparative light-emitting devices 1-1 to 1-3 are shown below.

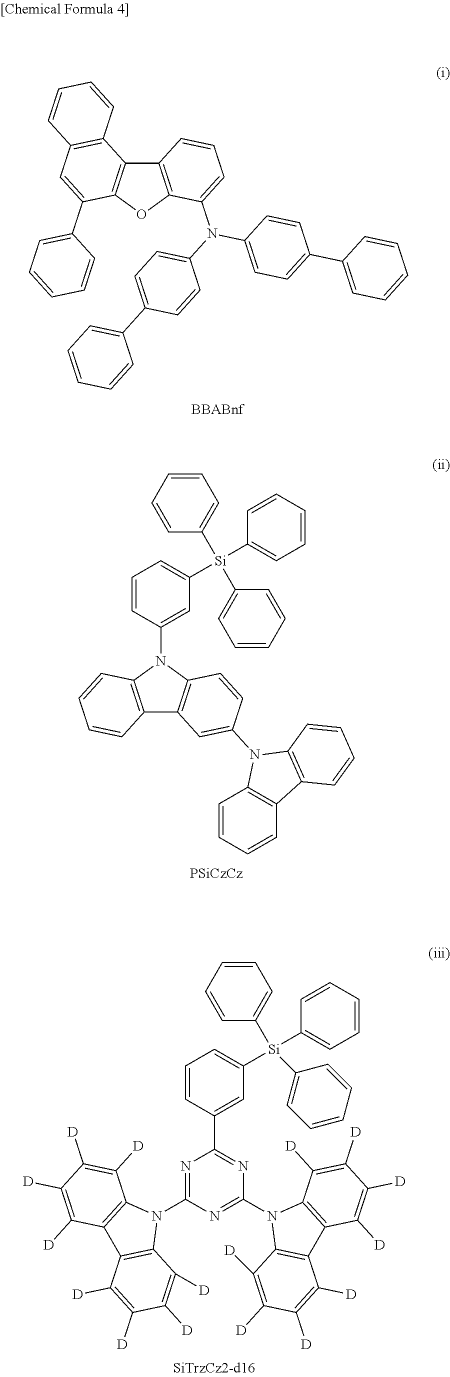 [SMILES: c1ccc(-c2ccc(N(c3ccc(-c4ccccc4)cc3)c3cccc4c3oc3c(-c5ccccc5)cc5ccccc5c34)cc2)cc1 ; c1ccc([Si](c2ccccc2)(c2ccccc2)c2cccc(-n3c4ccccc4c4cc(-n5c6ccccc6c6ccccc65)ccc43)c2)cc1 ; [2H]c1c([2H])c([2H])c2c(c1[2H])c1c([2H])c([2H])c([2H])c([2H])c1n2-c1nc(-c2cccc([Si](c3ccccc3)(c3ccccc3)c3ccccc3)c2)nc(-n2c3c([2H])c([2H])c([2H])c([2H])c3c3c([2H])c([2H])c([2H])c([2H])c32)n1]

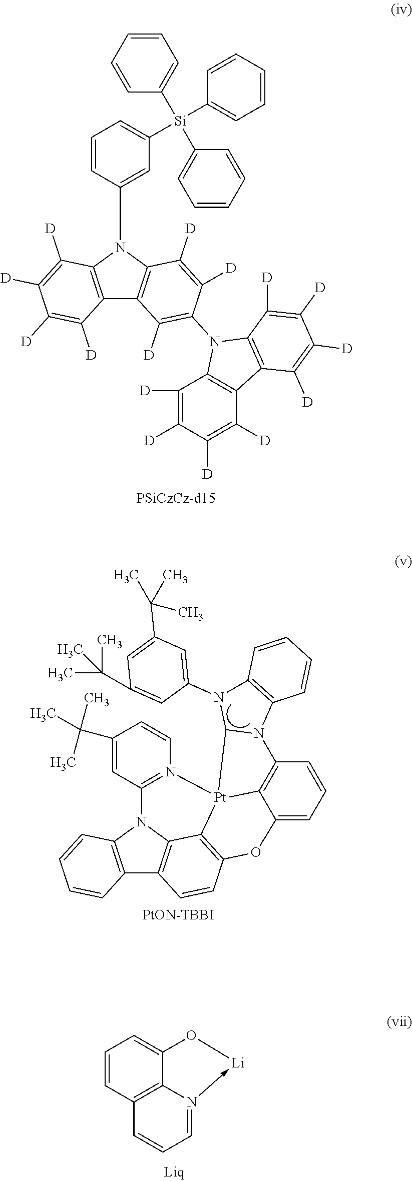

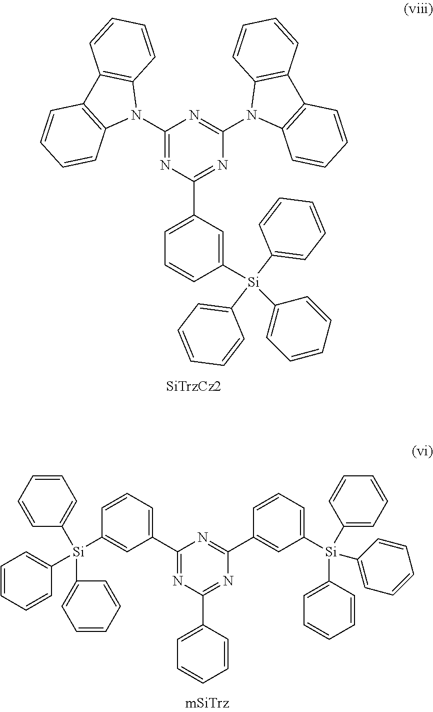 [SMILES: c1ccc([Si](c2ccccc2)(c2ccccc2)c2cccc(-c3nc(-n4c5ccccc5c5ccccc54)nc(-n4c5ccccc5c5ccccc54)n3)c2)cc1 ; c1ccc(-c2nc(-c3cccc([Si](c4ccccc4)(c4ccccc4)c4ccccc4)c3)nc(-c3cccc([Si](c4ccccc4)(c4ccccc4)c4ccccc4)c3)n2)cc1]

### (Fabrication Method of Light-Emitting Device 1)

First, indium tin oxide containing silicon oxide (ITSO) was deposited over a glass substrate to a thickness of 70 nm by a sputtering method, so that the first electrode 101 having a size of 2 mm×2 mm was formed. Note that the first electrode 101 serves as an anode.

Then, pretreatment for formation of the light-emitting device over the substrate was performed by washing the substrate surface with water.

After that, the substrate was transferred into a vacuum evaporation apparatus where the pressure was reduced to approximately 1×10⁻⁴ Pa, and was subjected to vacuum baking at 170° C. for 30 minutes in a heating chamber of the vacuum evaporation apparatus, and then the substrate was cooled down for approximately 30 minutes.

Next, the substrate was fixed to a holder provided in the vacuum evaporation apparatus such that the side on which the first electrode 101 was formed faced downward. Then, over an inorganic insulating film and the first electrode 101, N,N-bis(4-biphenyl)-6-phenylbenzo[b]naphtho[1,2-d]furan-8-amine (abbreviation: BBABnf) represented by Structural Formula (i) above and a fluorine-containing electron acceptor material (OCHD-003) with a molecular weight of 672 were deposited by co-evaporation to a thickness of 10 nm such that the weight ratio of BBABnf to OCHD-003 was 1:0.1; thus, the hole-injection layer 111 was formed.

Over the hole-injection layer 111, BBABnf was deposited by evaporation to a thickness of 30 nm to form a first hole-transport layer and then 9-[3-(triphenylsilyl)phenyl]-3,9′-bi-9H-carbazole (abbreviation: PSiCzCz) represented by Structural Formula (ii) above was deposited by evaporation to a thickness of 5 nm to form a second hole-transport layer, so that the hole-transport layer 112 was formed. Note that the second hole-transport layer also functions as an electron-blocking layer.

Next, over the hole-transport layer 112, 9,9′-{6-[3-(triphenylsilyl)phenyl]-1,3,5-triazine-2,4-diyl}bis(9H-carbazole-1,2,3,4,5,6,7,8,1′,2′,3′,4′,5′,6′,7′,8′-d16) (abbreviation: SiTrzCz2-d16) represented by Structural Formula (iii) above, 9-[3-(triphenylsilyl)phenyl]-3,9′-(bi-9H-carbazole-d₁₅) (abbreviation: PSiCzCz-d15) represented by Structural Formula (iv) above, and (2-{3-[3-(3,5-di-tert-butylphenyl)benzimidazol-1-yl-2-ylidene-κC²]phenoxy-κC²}-9-(4-tert-butyl-2-pyridinyl-κN)carbazole-2,1-diyl-κC)platinum(II) (abbreviation: PtON-TBBI) represented by Structural Formula (v) above were deposited by co-evaporation to a thickness of 35 nm such that the weight ratio of SiTrzCz2-d16, PSiCzCz-d15, and PtON-TBBI was 0.435: 0.435: 0.13, so that the light-emitting layer 113 was formed.

After that, 2-phenyl-4,6-bis[3-(triphenylsilyl)phenyl]-1,3,5-triazine (abbreviation: mSiTrz) represented by Structural Formula (vi) above was deposited by evaporation to a thickness of 5 nm to form a first electron-transport layer, and then mSiTrz and 8-quinolinolato-lithium (abbreviation: Liq) represented by Structural Formula (vii) above were deposited by co-evaporation to a thickness of 20 nm such that the weight ratio of mSiTrz to Liq was 1:1 to form a second electron-transport layer, so that the electron-transport layer 114 was formed.

Then, lithium fluoride (LiF) was deposited by evaporation to a thickness of 1 nm to form the electron-injection layer 115, and then aluminum (Al) was deposited by evaporation to a thickness of 200 nm to form the second electrode 102.

Then, the light-emitting device was sealed using a glass substrate in a glove box containing a nitrogen atmosphere so as not to be exposed to the air. Specifically, a UV curable sealing material was applied to surround the device, only the sealing material was irradiated with UV while the light-emitting device was not irradiated with the UV, and heat treatment was performed at 80° C. under an atmospheric pressure for one hour. In this manner, the light-emitting device 1 was fabricated.

### (Fabrication Method of Comparative Light-Emitting Device 1-1)

The comparative light-emitting device 1-1 was fabricated in a manner similar to that of the light-emitting device 1 except that SiTrzCz2-d16 in the light-emitting device 1 was replaced with 9,9′-{6-[3-(triphenylsilyl)phenyl]-1,3,5-triazine-2,4-diyl}bis(9H-carbazole) (abbreviation: SiTrzCz2) represented by Structural Formula (viii) above and PSiCzCz-d15 was replaced with PSiCzCz.

### (Fabrication Method of Comparative Light-Emitting Device 1-2)

The comparative light-emitting device 1-2 was fabricated in a manner similar to that of the light-emitting device 1 except that PSiCzCz-d15 in the light-emitting device 1 was replaced with PSiCzCz.

### (Fabrication Method of Comparative Light-Emitting Device 1-3)

The comparative light-emitting device 1-3 was fabricated in a manner similar to that of the light-emitting device 1 except that SiTrzCz2-d16 in the light-emitting device 1 was replaced with SiTrzCz2.

Device structures of the light-emitting device 1 and the comparative light-emitting devices 1-1 to 1-3 are shown below.

TABLE 1

| | | | | |
|---|---|---|---|---|
| Film | Light- | Comparative | Comparative | Comparative |
| thickness | emitting | light-emitting | light-emitting | light-emitting |
| (nm) | device 1 | device 1-1 | device 1-2 | device 1-3 |

| | | |
|---|---|---|
| Second electrode | 200 | Al |
| Electron-injection layer | 1 | LiF |
| Electron-transport layer | 20 | mSiTrz:Liq (1:1) |
| | 5 | mSiTrz |
| Light-emitting layer | 35 | *1 |
| Hole-transport layer | 5 | PSiCzCz |
| | 30 | BBABnf |
| Hole-injection layer | 10 | BBABnf:OCHD-003 (1:0.1) |
| First electrode | 70 | ITSO |

TABLE 2

| | *1 |
|---|---|
| Light-emitting | SiTrzCz2-d16:PSiCzCz-d15:PtON-TBBI |
| device 1 | (0.435:0.435:0.13) |
| Comparative | SiTrzCz2:PSiCzCz:PtON-TBBI |
| light-emitting | (0.435:0.435:0.13) |
| device 1-1 | |
| Comparative | SiTrzCz2-d16:PSiCzCz:PtON-TBBI |
| light-emitting | (0.435:0.435:0.13) |
| device 1-2 | |
| Comparative | SiTrzCz2:PSiCzCz-d15:PtON-TBBI |
| light-emitting | (0.435:0.435:0.13) |
| device 1-3 | |

Here, PSiCzCz is a non-deuterated organic compound of PSiCzCz-d15, and SiTrzCz2 is a non-deuterated organic compound of SiTrzCz2-d16.

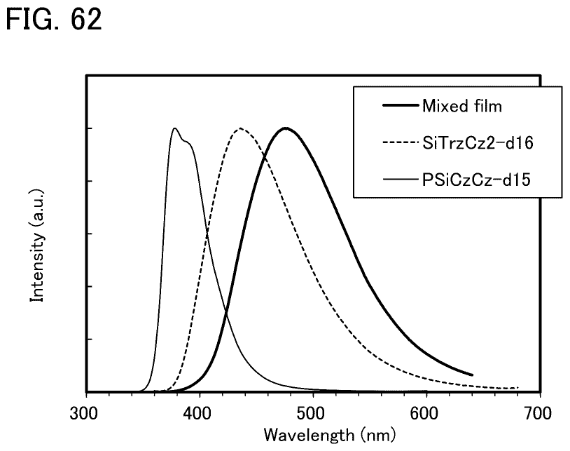

FIG. 62 shows the PL spectra of the following films each formed over a quartz substrate to have a thickness of 50 nm: a thin film of SiTrzCz2-d16, a thin film of PSiCzCz-d15, and a mixed film of SiTrzCz2-d16 and PSiCzCz-d15 obtained by depositing SiTrzCz2-d16 and PSiCzCz-d15 by co-evaporation in a weight ratio of 1:1. The PL spectrum was measured with a fluorescence spectrophotometer (FP-8600DS, JASCO Corporation). As shown in FIG. 62, the PL spectrum of the mixed film is positioned on the longer wavelength side than the PL spectra of the films of the single materials, indicating that SiTrzCz2-d16 and PSiCzCz-d15 form an exciplex.

The phosphorescence lifetimes of PSiCzCz, PSiCzCz-d15, SiTrzCz2, and SiTrzCz2-d16 and the rates of change in phosphorescence lifetime owing to deuteration are shown below. The product of the rates was 1.40. Note that the excitation wavelength of PSiCzCz and PSiCzCz-d15 was 340 nm and the measured wavelength was 440 nm. The excitation wavelength of SiTrzCz2 and SiTrzCz2-d16 was 330 nm and the measured wavelength was 450 nm.

TABLE 3

| | Phosphorescence | Increasing rate |
|---|---|---|
| | lifetime | (Deuterated/ |
| | (seconds) | Non-deuterated) |
| SiTrzCz2 | 6.43 | 1.27 |
| SiTrzCz2-d16 | 8.15 | |
| PSiCzCz | 4.83 | 1.10 |
| PSiCzCz-d15 | 5.31 | |

As shown in FIG. 2, the time at which the light amount becomes 50% of that at the start of the measurement was set as t=0, and the time taken for the light amount to attenuate to 1/e of that at t=0 was regarded as the phosphorescence lifetime. In the graphs in FIG. 2, the time at which the intensity reaches 50% of that at the start of the measurement is set as the time 0 s, the light amount at 0 s is regarded as 1, and the time taken for the light amount to become 1/e of that at 0 s is the phosphorescence lifetime.

The measurement was performed at liquid nitrogen temperature (77 K) with FP-8600 produced by JASCO Corporation, in which a liquid nitrogen cooling unit PMU-830 was set.

A solution of a material was prepared in a glove box of LABstarM13 (1250/780) produced by MBRAUN in the following manner: a sample was dissolved in 2-MeTHF that had been subjected to freeze-pump-thaw, and the concentration of the solution was adjusted to approximately 1.2 E⁻⁴ M. The prepared solution was put in a liquid sample cell (sample tube) LPH-140 for cooling produced by JASCO Corporation, the sample cell was put in a sample cell holder, and the sample cell holder was capped with a fixing nut. After liquid nitrogen was injected into a dewer of the cooling unit of FP-8600, the sample cell was taken out from the globe box and then cooled in the dewer of the unit filled with the liquid nitrogen.

Then, time-resolved measurement was performed in the following manner: the sample cell was irradiated with excitation light for approximately 30 seconds and the intensity of light attenuating after the excitation light was blocked by a shutter was measured at 10 ms intervals. The phosphorescence lifetime measurement was performed using a wavelength at which a fluorescence component is not contained as much as possible, which was selected after comparing a phosphorescence spectrum and a fluorescence spectrum. The excitation wavelength used for the measurement can be appropriately selected, and is preferably 330 nm. The band widths of the excitation light and the measured light are each approximately 10 nm. Since light emission ideally attenuates single-exponentially, the time taken for the emission intensity to attenuate to 1/e with reference to the time at which the light amount becomes 50% of that at the start of the measurement can be defined as the phosphorescence lifetime.

The T₁ level of PSiCzCz-d15 was 2.97 eV, the T₁ level of SiTrzCz2-d16 was 2.93 eV, and the difference therebetween was 0.04 eV.

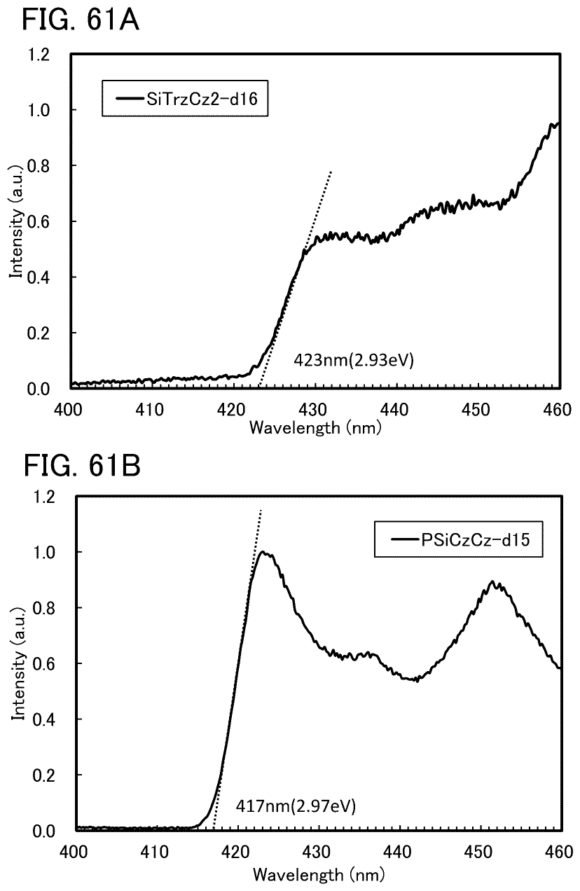

For calculation of the T₁ level, an emission spectrum (a phosphorescence spectrum) was measured at a measurement temperature of 10 K using a 50-nm-thick sample film formed over a quartz substrate. The measurement was performed with a PL microscope (LabRAM HR-PL, HORIBA, Ltd.) and a He—Cd laser (325 nm) as excitation light. Note that the emission edge was determined as the intersection of a tangent and the horizontal axis (representing wavelength) or the baseline as shown in FIGS. 61A and 61B. The tangent is drawn to have the maximum slope at a point on a shorter wavelength side of the shortest-wavelength peak (or the shortest-wavelength shoulder peak) of the emission spectrum (phosphorescence spectrum).

The 5% weight loss temperature of PSiCzCz-d15 at 10 Pa was 254° C., the 5% weight loss temperature of SiTrzCz2-d16 at 10 Pa was 298° C., and the difference therebetween was 45° C.

The 5% weight loss temperature refers to a temperature at which the weight obtained by thermogravimetry was reduced by 5% of the weight at the start of the measurement, in the case where thermogravimetry-differential thermal analysis (TG-DTA) is performed using a compound with a weight greater than or equal to 1 mg and less than or equal to 20 mg at pressures controlled to be greater than or equal to 1.0×10⁻¹ Pa and less than or equal to 10 Pa. The measurement was performed with a high vacuum differential type differential thermal balance (TG-DTA2410SA, Bruker AXS) at a pressure of 10 Pa, at a temperature rising rate of 10° C./min, and under a nitrogen stream (flow rate: 30 mL/min). In this example, the weight of the sample was approximately 3.00 mg (from 2.95 mg to 3.06 mg).

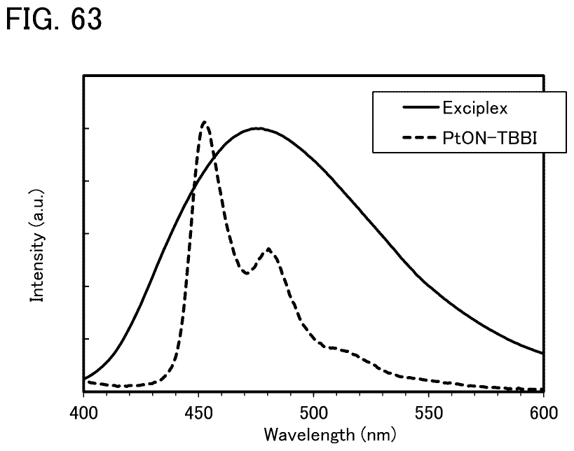

FIG. 63 shows the photoluminescence (PL) spectrum of the exciplex formed by PSiCzCz-d15 and SiTrzCz2-d16 shown in FIG. 62 and the PL spectrum of a polymer film where PtON-TBBI is dispersed, which overlap with each other. As shown in FIG. 63, the PL spectrum of the exciplex formed by PSiCzCz-d15 and SiTrzCz2-d16 and the PL spectrum of a poly(methylmethacrylate) (abbreviation: PMMA) film where PtON-TBBI is dispersed include an overlap, and a difference between their maximum peak wavelengths is less than or equal to 30 nm. The PMMA film where PtON-TBBI is dispersed was formed in the following manner: a film of a solution where deoxidized dichloromethane was used as a solvent and PtON-TBBI was dispersed at a concentration of 1.0 wt % with respect to PMMA was formed over a quartz substrate by a drop casting method, and then drying was performed in a globe box at room temperature under a nitrogen stream for 30 minutes. The emission spectrum of the obtained PMMA film where PtON-TBBI is dispersed was measured with a PL quantum yield measurement apparatus (Quantaurus-QY C11347-01, Hamamatsu Photonics K.K.).

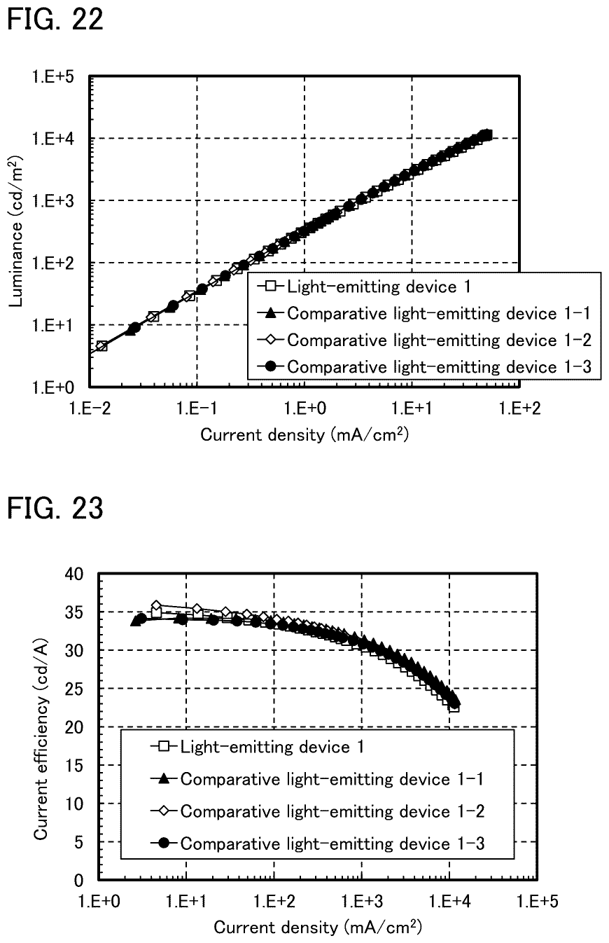

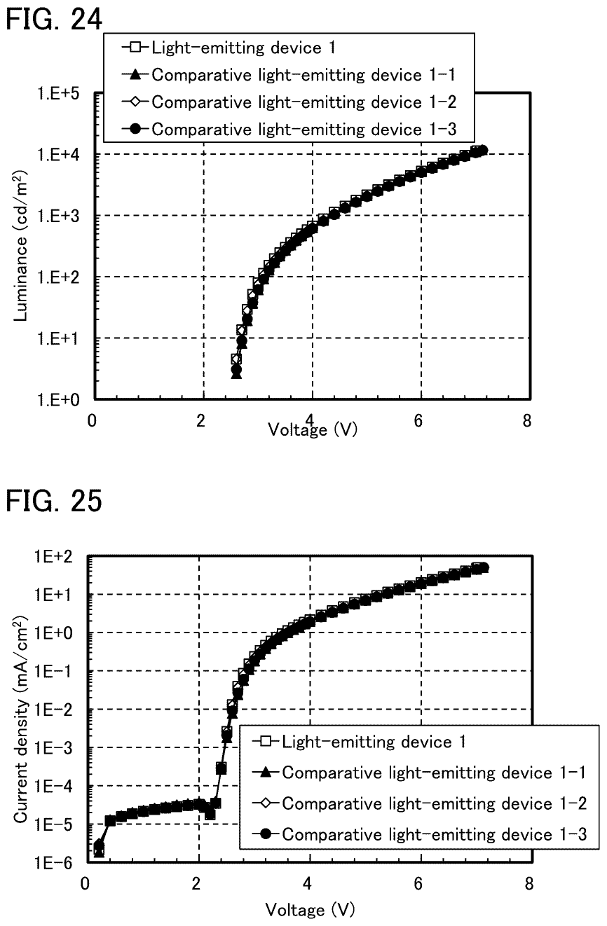

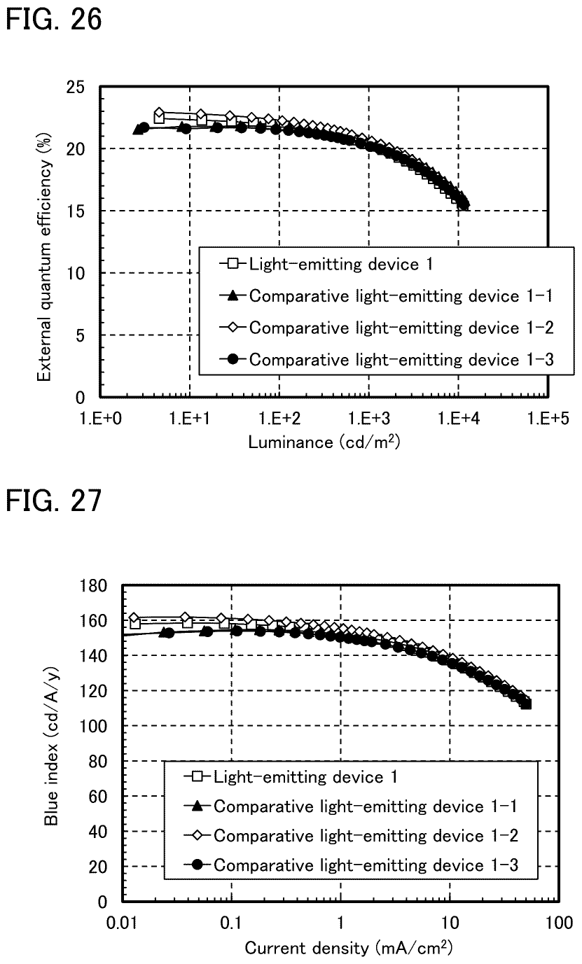

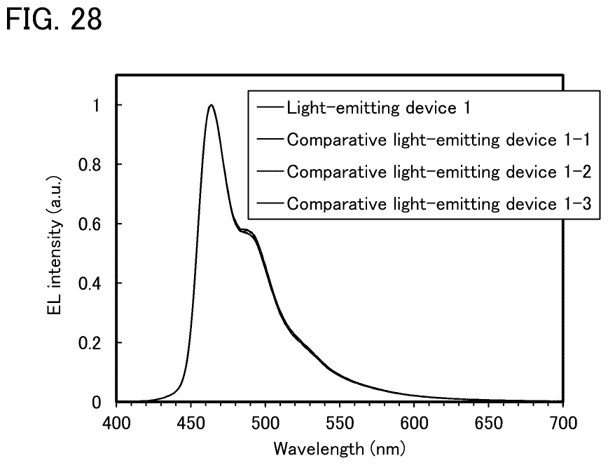

FIG. 22 shows the luminance-current density characteristics of the light-emitting device 1 and the comparative light-emitting devices 1-1 to 1-3. FIG. 23 shows the current efficiency-current density characteristics thereof. FIG. 24 shows the luminance-voltage characteristics thereof. FIG. 25 shows the current density-voltage characteristics thereof. FIG. 26 shows the external quantum efficiency-luminance characteristics thereof. FIG. 27 shows the blue index (BI)-current density characteristics thereof. FIG. 28 shows the electroluminescence spectra thereof.

The values of the voltage, current, current density, CIE chromaticity, current efficiency, external quantum efficiency, and blue index (BI) at around 1000 cd/cm² are shown below. The luminance, CIE chromaticity, and electroluminescence spectra were measured at normal temperature with a spectroradiometer (SR-UL1R, TOPCON TECHNOHOUSE CORPORATION).

Note that the blue index (BI) is a value obtained by dividing current efficiency (cd/A) by chromaticity y, which is calculated with the CIE1931 color system, and is one of the indicators of characteristics of blue light emission. As the chromaticity y is smaller, the color purity of emitted blue light tends to be higher. Blue light emission having a small y chromaticity value and high color purity enables expression of blue colors with a wide range of chromaticity in a display. Using blue light emission with high color purity reduces the luminance of blue light emission necessary for a display to express white, leading to lower power consumption of the display. Thus, BI that is current efficiency based on chromaticity y, which is one of the indicators of color purity of blue, is used as a means for showing efficiency of blue light emission in some cases. A light-emitting device with higher BI can be regarded as a blue-light-emitting device having higher efficiency for a display.

TABLE 4

| | | | | | | | External | |
|---|---|---|---|---|---|---|---|---|
| | | | Current | | | Current | quantum | |
| | Voltage | Current | density | Chromaticity | Chromaticity | efficiency | efficiency | BI |
| | (V) | (mA) | (mA/cm²) | x | y | (cd/A) | (%) | (cd/A/y) |
| Light-emitting | 4.2 | 0.114 | 2.85 | 0.15 | 0.21 | 31 | 20 | 147 |
| device 1 | | | | | | | | |
| Comparative | 4.4 | 0.137 | 3.42 | 0.15 | 0.21 | 31 | 20 | 147 |
| light-emitting | | | | | | | | |
| device 1-1 | | | | | | | | |
| Comparative | 4.4 | 0.139 | 3.47 | 0.15 | 0.21 | 31 | 21 | 149 |
| light-emitting | | | | | | | | |
| device 1-2 | | | | | | | | |
| Comparative | 4.4 | 0.134 | 3.36 | 0.15 | 0.21 | 31 | 20 | 145 |
| light-emitting | | | | | | | | |
| device 1-3 | | | | | | | | |

FIGS. 22 to 28 and Table 4 show that the light-emitting device 1 and the comparative light-emitting devices 1-1 to 1-3 have favorable initial characteristics with equivalent emission efficiencies and driving voltages. It is also shown that the light-emitting device 1 and the comparative light-emitting devices 1-1 to 1-3 each have an electroluminescence spectrum peak at a wavelength of 464 nm, and exhibit blue light emission derived from PtON-TBBI.

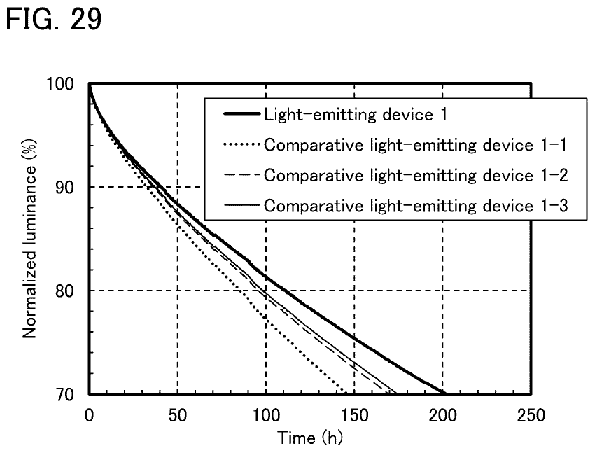

FIG. 29 shows the time dependence of normalized luminance of the light-emitting device 1 and the comparative light-emitting devices 1-1 to 1-3 at a current density of 10 mA/cm².

FIG. 29 shows that the light-emitting device 1 of one embodiment of the present invention has lower time dependence of normalized luminance than the comparative light-emitting devices 1-1 to 1-3 and has high reliability.

### Example 2

In this example, fabricating methods and characteristics of a light-emitting device 2 of one embodiment of the present invention and comparative light-emitting devices 2-1 to 2-3 which are comparative examples will be described in detail. Structural formulae of main compounds used for the light-emitting device 2 and the comparative light-emitting devices 2-1 to 2-3 are shown below.

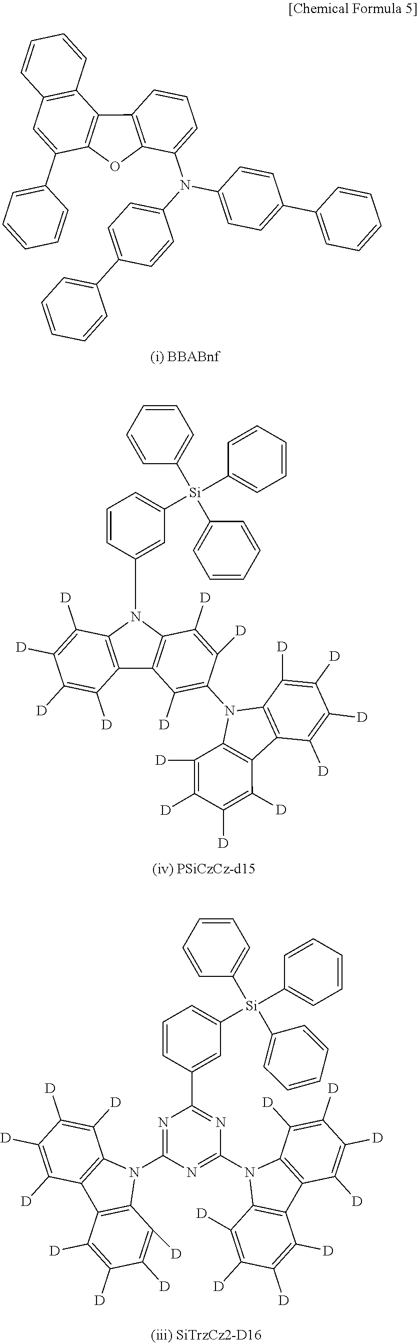 [SMILES: c1ccc(-c2ccc(N(c3ccc(-c4ccccc4)cc3)c3cccc4c3oc3c(-c5ccccc5)cc5ccccc5c34)cc2)cc1 ; [2H]c1c([2H])c([2H])c2c(c1[2H])c1c([2H])c(-n3c4c([2H])c([2H])c([2H])c([2H])c4c4c([2H])c([2H])c([2H])c([2H])c43)c([2H])c([2H])c1n2-c1cccc([Si](c2ccccc2)(c2ccccc2)c2ccccc2)c1 ; [2H]c1c([2H])c([2H])c2c(c1[2H])c1c([2H])c([2H])c([2H])c([2H])c1n2-c1nc(-c2cccc([Si](c3ccccc3)(c3ccccc3)c3ccccc3)c2)nc(-n2c3c([2H])c([2H])c([2H])c([2H])c3c3c([2H])c([2H])c([2H])c([2H])c32)n1]

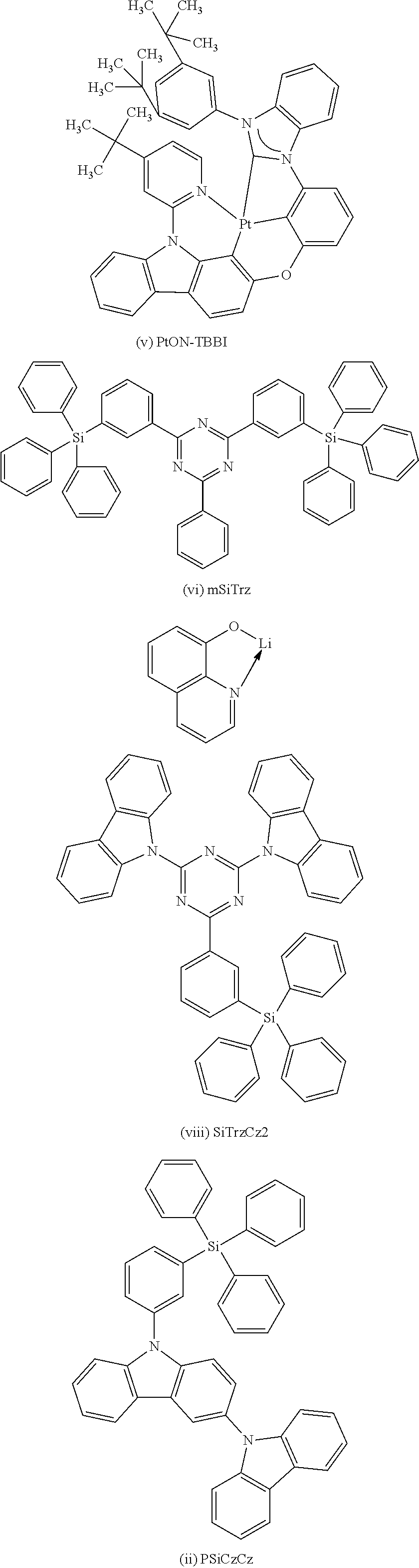

### (Fabrication Method of Light-Emitting Device 2)

First, indium tin oxide containing silicon oxide (ITSO) was deposited over a glass substrate to a thickness of 70 nm by a sputtering method, so that the first electrode 101 having a size of 2 mm×2 mm was formed. Note that the first electrode 101 serves as an anode.

Then, pretreatment for formation of the light-emitting device over the substrate was performed by washing the substrate surface with water.

After that, the substrate was transferred into a vacuum evaporation apparatus where the pressure was reduced to approximately 1×10⁻⁴ Pa, and was subjected to vacuum baking at 170° C. for 30 minutes in a heating chamber of the vacuum evaporation apparatus, and then the substrate was cooled down for approximately 30 minutes.

Next, the substrate was fixed to a holder provided in the vacuum evaporation apparatus such that the side on which the first electrode 101 was formed faced downward. Then, over an inorganic insulating film and the first electrode 101, N,N-bis(4-biphenyl)-6-phenylbenzo[b]naphtho[1,2-d]furan-8-amine (abbreviation: BBABnf) represented by Structural Formula (i) above and a fluorine-containing electron acceptor material (OCHD-003) with a molecular weight of 672 were deposited by co-evaporation to a thickness of 10 nm such that the weight ratio of BBABnf to OCHD-003 was 1:0.1; thus, the hole-injection layer 111 was formed.

Over the hole-injection layer 111, BBABnf was deposited by evaporation to a thickness of 30 nm to form the first hole-transport layer and then 9-[3-(triphenylsilyl)phenyl]-3,9′-(bi-9H-carbazole-d₁₅) (abbreviation: PSiCzCz-d15) represented by Structural Formula (iv) above was deposited by evaporation to a thickness of 5 nm to form the second hole-transport layer, so that the hole-transport layer 112 was formed. Note that the second hole-transport layer also functions as an electron-blocking layer.

Next, over the hole-transport layer 112, 9,9′-{6-[3-(triphenylsilyl)phenyl]-1,3,5-triazine-2,4-diyl}bis(9H-carbazole-1,2,3,4,5,6,7,8,1′,2′,3′,4′,5′,6′,7′,8′-d16) (abbreviation: SiTrzCz2-d16) represented by Structural Formula (iii) above, PSiCzCz-d15, and (2-{3-[3-(3,5-di-tert-butylphenyl)benzimidazol-1-yl-2-ylidene-κC²]phenoxy-κC2}-9-(4-tert-butyl-2-pyridinyl-KN)carbazole-2,1-diyl-κC)platinum(II) (abbreviation: PtON-TBBI) represented by Structural Formula (v) above were deposited by co-evaporation to a thickness of 35 nm such that the weight ratio of SiTrzCz2-d16, PSiCzCz-d15, and PtON-TBBI was 0.435: 0.435: 0.13, so that the light-emitting layer 113 was formed.

After that, 2-phenyl-4,6-bis[3-(triphenylsilyl)phenyl]-1,3,5-triazine (abbreviation: mSiTrz) represented by Structural Formula (vi) above was deposited by evaporation to a thickness of 5 nm to form the first electron-transport layer, and then mSiTrz and 8-quinolinolato-lithium (abbreviation: Liq) represented by Structural Formula (vii) above were deposited by co-evaporation to a thickness of 20 nm such that the weight ratio of mSiTrz to Liq was 1:1 to form the second electron-transport layer, so that the electron-transport layer 114 was formed.

Then, lithium fluoride (LiF) was deposited by evaporation to a thickness of 1 nm to form the electron-injection layer 115, and then aluminum (Al) was deposited by evaporation to a thickness of 200 nm to form the second electrode 102.

Then, the light-emitting device was sealed using a glass substrate in a glove box containing a nitrogen atmosphere so as not to be exposed to the air. Specifically, a UV curable sealing material was applied to surround the device, only the sealing material was irradiated with UV while the light-emitting device was not irradiated with the UV, and heat treatment was performed at 80° C. under an atmospheric pressure for one hour. In this manner, the light-emitting device 2 was fabricated.

### (Fabrication Method of Comparative Light-Emitting Device 2-1)

The comparative light-emitting device 2-1 was fabricated in a manner similar to that of the light-emitting device 2 except that SiTrzCz2-d16 in the light-emitting device 2 was replaced with 9,9′-{6-[3-(triphenylsilyl)phenyl]-1,3,5-triazine-2,4-diyl}bis(9H-carbazole) (abbreviation: SiTrzCz2) represented by Structural Formula (viii) above and PSiCzCz-d15 was replaced with 9-[3-(triphenylsilyl)phenyl]-3,9′-bi-9H-carbazole (abbreviation: PSiCzCz) represented by Structural Formula (ii) above.

### (Fabrication Method of Comparative Light-Emitting Device 2-2)

The comparative light-emitting device 2-2 was fabricated in a manner similar to that of the light-emitting device 2 except that PSiCzCz-d15 in the light-emitting device 2 was replaced with PSiCzCz.

### (Fabrication Method of Comparative Light-Emitting Device 2-3)

The comparative light-emitting device 2-3 was fabricated in a manner similar to that of the light-emitting device 2 except that SiTrzCz2-d16 in the light-emitting device 2 was replaced with SiTrzCz2.

Device structures of the light-emitting device 2 and the comparative light-emitting devices 2-1 to 2-3 are shown below.

TABLE 5

| | | | | |
|---|---|---|---|---|
| Film | | Comparative | Comparative | Comparative |
| thickness | Light-emitting | light-emitting | light-emitting | light-emitting |
| (nm) | device 2 | device 2-1 | device 2-2 | device 2-3 |

| | | |
|---|---|---|
| Second electrode | 200 | Al |
| Electron-injection layer | 1 | LiF |
| Electron-transport layer | 20 | mSiTrz:Liq (1:1) |
| | 5 | mSiTrz |
| Light-emitting layer | 35 | *2 |
| Hole-transport layer | 5 | PSiCzCz-d15 |
| | 30 | BBABnf |
| Hole-injection layer | 10 | BBABnf:OCHD-003 (1:0.1) |
| First electrode | 70 | ITSO |

TABLE 6

| | *2 |
|---|---|
| Light-emitting | SiTrzCz2-d16:PSiCzCz-d15:PtON-TBBI |
| device 2 | (0.435:0.435:0.13) |
| Comparative | SiTrzCz2:PSiCzCz:PtON-TBBI |
| light-emitting | (0.435:0.435:0.13) |
| device 2-1 | |
| Comparative | SiTrzCz2-d16:PSiCzCz:PtON-TBBI |
| light-emitting | (0.435:0.435:0.13) |
| device 2-2 | |
| Comparative | SiTrzCz2:PSiCzCz-d15:PtON-TBBI |
| light-emitting | (0.435:0.435:0.13) |
| device 2-3 | |

Here, PSiCzCz is a non-deuterated organic compound of PSiCzCz-d15, and SiTrzCz2 is a non-deuterated organic compound of SiTrzCz2-d16.

FIG. 62 shows the PL spectra of the following films each formed over a quartz substrate to have a thickness of 50 nm: a thin film of SiTrzCz2-d16, a thin film of PSiCzCz-d15, and a mixed film of SiTrzCz2-d16 and PSiCzCz-d15 obtained by depositing SiTrzCz2-d16 and PSiCzCz-d15 by co-evaporation in a weight ratio of 1:1. The PL spectrum was measured with a fluorescence spectrophotometer (FP-8600DS, JASCO Corporation). As shown in FIG. 62, the PL spectrum of the mixed film is positioned on the longer wavelength side than the PL spectra of the films of the single materials, indicating that SiTrzCz2-d16 and PSiCzCz-d15 form an exciplex.

The phosphorescence lifetimes of PSiCzCz, PSiCzCz-d15, SiTrzCz2, and SiTrzCz2-d16 and the rate of change in phosphorescence lifetime owing to deuteration are shown below. The product of the rates was 1.40. Note that the excitation wavelength of PSiCzCz and PSiCzCz-d15 was 340 nm and the measured wavelength was 440 nm. The excitation wavelength of SiTrzCz2 and SiTrzCz2-d16 was 330 nm and the measured wavelength was 450 nm.

TABLE 7

| | Phosphorescence | Increasing rate |
|---|---|---|
| | lifetime | (Deuterated/ |
| | (seconds) | Non-deuterated) |
| SiTrzCz2 | 6.43 | 1.27 |
| SiTrzCz2-d16 | 8.15 | |
| PSiCzCz | 4.83 | 1.10 |
| PSiCzCz-d15 | 5.31 | |

The T₁ level of PSiCzCz-d15 was 2.97 eV, the T₁ level of SiTrzCz2-d16 was 2.93 eV, and the difference therebetween was 0.04 eV.

The 5% weight loss temperature of PSiCzCz-d15 at 10 Pa was 254° C., the 5% weight loss temperature of SiTrzCz2-d16 at 10 Pa was 298° C., and the difference therebetween was 45° C.

Note that the phosphorescence lifetime, the T₁ level, and the 5% weight loss temperature were calculated in a manner similar to that in Example 1.

FIG. 63 shows the photoluminescence (PL) spectrum of the exciplex formed by PSiCzCz-d15 and SiTrzCz2-d16 shown in FIG. 62 and the PL spectrum of a polymer film where PtON-TBBI is dispersed, which overlap with each other. As shown in FIG. 63, the PL spectrum of the exciplex formed by PSiCzCz-d15 and SiTrzCz2-d16 and the PL spectrum of a poly(methylmethacrylate) (abbreviation: PMMA) film where PtON-TBBI is dispersed include an overlap, and a difference between their maximum peak wavelengths is less than or equal to 30 nm. The PMMA film where PtON-TBBI is dispersed was fabricated in a manner similar to that in Example 1.

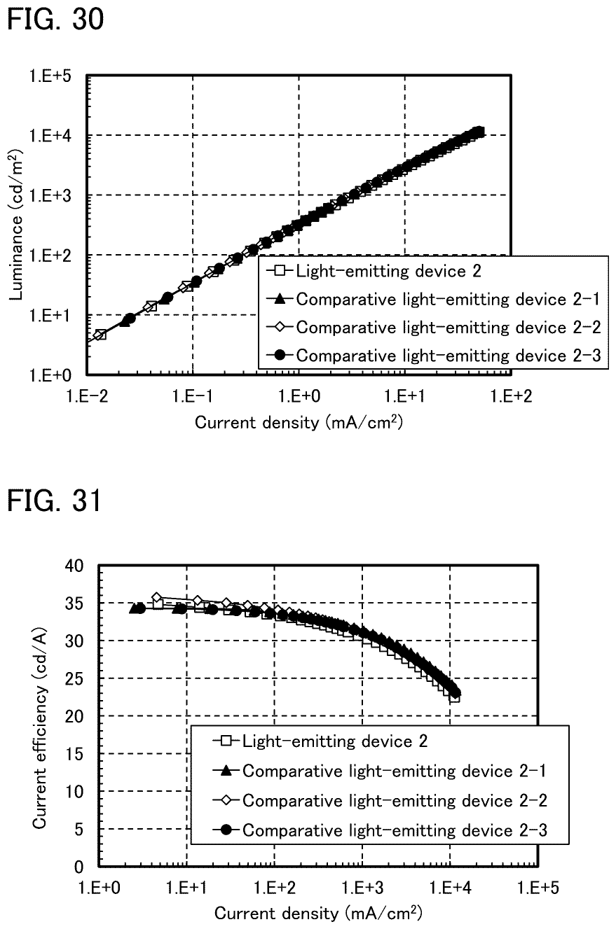

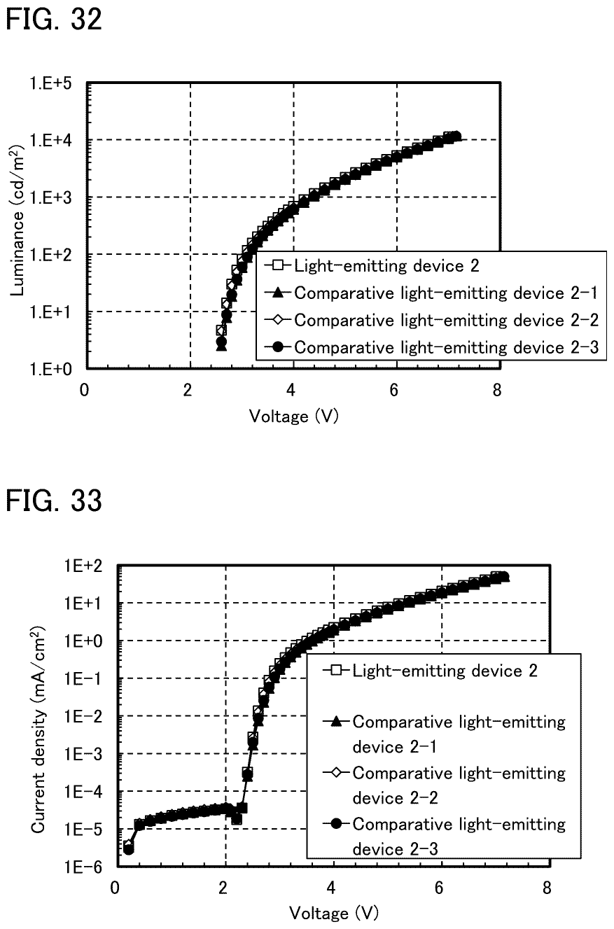

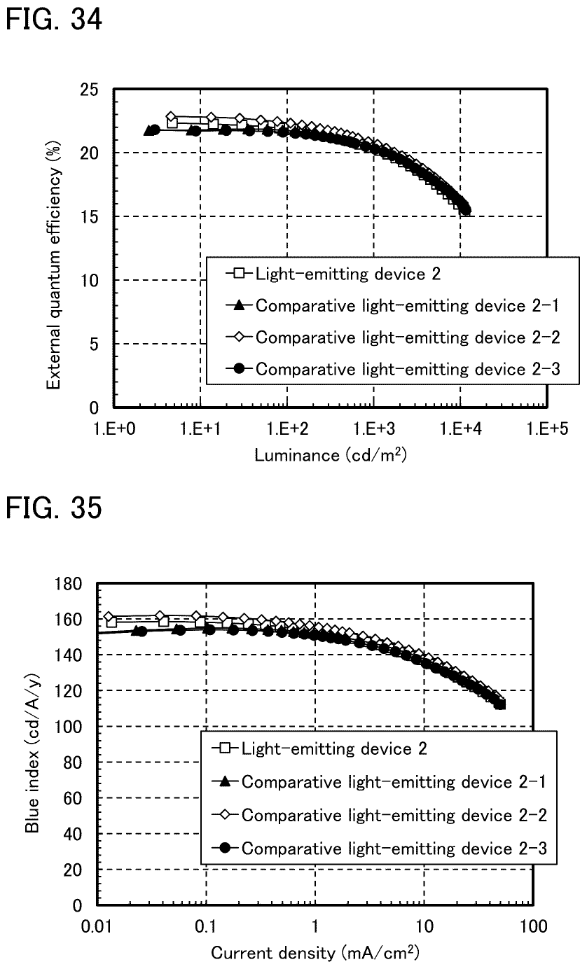

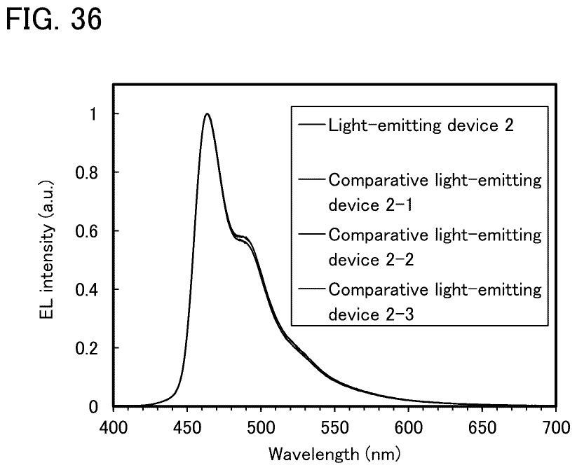

FIG. 30 shows the luminance-current density characteristics of the light-emitting device 2 and the comparative light-emitting devices 2-1 to 2-3. FIG. 31 shows the current efficiency-current density characteristics thereof. FIG. 32 shows the luminance-voltage characteristics thereof. FIG. 33 shows the current density-voltage characteristics thereof. FIG. 34 shows the external quantum efficiency-luminance characteristics thereof. FIG. 35 shows the blue index (BI)-current density characteristics thereof. FIG. 36 shows the electroluminescence spectra thereof.

The values of the voltage, current, current density, CIE chromaticity, current efficiency, external quantum efficiency, and blue index (BI) at around 1000 cd/cm² are shown below. The luminance, CIE chromaticity, and electroluminescence spectra were measured at normal temperature with a spectroradiometer (SR-UL1R, TOPCON TECHNOHOUSE CORPORATION).

TABLE 8

| | | | | | | | External | |
|---|---|---|---|---|---|---|---|---|
| | | | Current | | | Current | quantum | |
| | Voltage | Current | density | Chromaticity | Chromaticity | efficiency | efficiency | BI |
| | (V) | (mA) | (mA/cm²) | x | y | (cd/A) | (%) | (cd/A/y) |
| Light-emitting | 4.2 | 0.117 | 2.93 | 0.15 | 0.21 | 31 | 20 | 147 |
| device 2 | | | | | | | | |
| Comparative | 4.4 | 0.133 | 3.33 | 0.15 | 0.21 | 31 | 20 | 146 |
| light-emitting | | | | | | | | |
| device 2-1 | | | | | | | | |
| Comparative | 4.4 | 0.143 | 3.57 | 0.15 | 0.21 | 31 | 21 | 149 |
| light-emitting | | | | | | | | |
| device 2-2 | | | | | | | | |
| Comparative | 4.4 | 0.133 | 3.34 | 0.15 | 0.21 | 31 | 20 | 145 |
| light-emitting | | | | | | | | |
| device 2-3 | | | | | | | | |

FIGS. 30 to 36 and Table 8 show that the light-emitting device 2 and the comparative light-emitting devices 2-1 to 2-3 have favorable initial characteristics with equivalent emission efficiencies and driving voltages. It is also shown that the light-emitting device 2 and the comparative light-emitting devices 2-1 to 2-3 each have an electroluminescence spectrum peak at a wavelength of 464 nm, and exhibit blue light emission derived from PtON-TBBI.

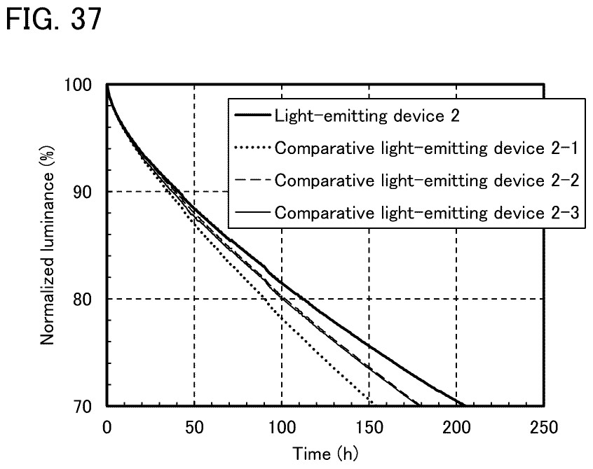

FIG. 37 shows the time dependence of normalized luminance of the light-emitting device 2 and the comparative light-emitting devices 2-1 to 2-3 at a current density of 10 mA/cm².

FIG. 37 shows that the light-emitting device 2 of one embodiment of the present invention has lower time dependence of normalized luminance than the comparative light-emitting devices 2-1 to 2-3 and has high reliability.

### Example 3

In this example, fabricating methods and characteristics of a light-emitting device 3 of one embodiment of the present invention and comparative light-emitting devices 3-1 to 3-3 which are comparative examples will be described in detail. Structural formulae of main compounds used for the light-emitting device 3 and the comparative light-emitting devices 3-1 to 3-3 are shown below.

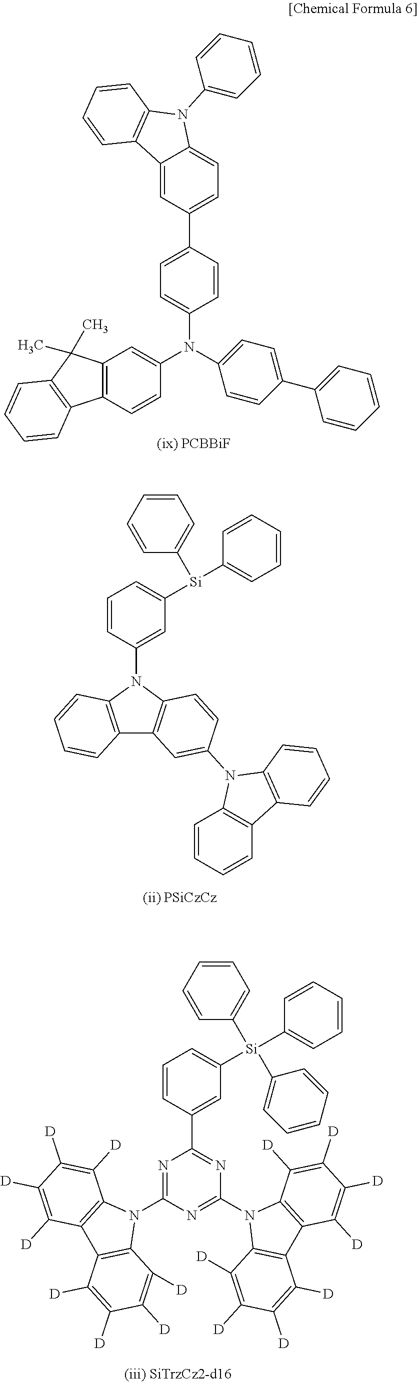

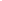

### (Fabrication Method of Light-Emitting Device 3)

First, indium tin oxide containing silicon oxide (ITSO) was deposited over a glass substrate to a thickness of 70 nm by a sputtering method, so that the first electrode 101 having a size of 2 mm×2 mm was formed. Note that the first electrode 101 serves as an anode.

Then, pretreatment for formation of the light-emitting device over the substrate was performed by washing the substrate surface with water.

After that, the substrate was transferred into a vacuum evaporation apparatus where the pressure was reduced to approximately 1×10⁻⁴ Pa, and was subjected to vacuum baking at 170° C. for 30 minutes in a heating chamber of the vacuum evaporation apparatus, and then the substrate was cooled down for approximately 30 minutes.

Next, the substrate was fixed to a holder provided in the vacuum evaporation apparatus such that the side on which the first electrode 101 was formed faced downward. Then, over an inorganic insulating film and the first electrode 101, N-(biphenyl-4-yl)-N-[4-(9-phenyl-9H-carbazol-3-yl)phenyl]-9,9-dimethyl-9H-fluoren-2-amine (abbreviation: PCBBiF) represented by Structural Formula (ix) above and a fluorine-containing electron acceptor material (OCHD-003) with a molecular weight of 672 were deposited by co-evaporation to a thickness of 10 nm such that the weight ratio of PCBBiF to OCHD-003 was 1:0.03; thus, the hole-injection layer 111 was formed.

Over the hole-injection layer 111, PCBBiF was deposited by evaporation to a thickness of 30 nm to form the first hole-transport layer, and then 9-[3-(triphenylsilyl)phenyl]-3,9′-bi-9H-carbazole (abbreviation: PSiCzCz) represented by Structural Formula (ii) above was deposited by evaporation to a thickness of 5 nm to form the second hole-transport layer, so that the hole-transport layer 112 was formed. Note that the second hole-transport layer also functions as an electron-blocking layer.

Next, over the hole-transport layer 112, 9,9′-{6-[3-(triphenylsilyl)phenyl]-1,3,5-triazine-2,4-diyl}bis(9H-carbazole-1,2,3,4,5,6,7,8,1′,2′,3′,4′,5′,6′,7′,8′-d16) (abbreviation: SiTrzCz2-d16) represented by Structural Formula (iii) above, 9-[3-(triphenylsilyl)phenyl]-3,9′-(bi-9H-carbazole-d₁₅) (abbreviation: PSiCzCz-d15) represented by Structural Formula (iv) above, and (2-{3-[3-(3,5-di-tert-butylphenyl)benzimidazol-1-yl-2-ylidene-κC²]phenoxy-κC²}-9-[5-(methyl-d3)-4-phenyl-2-pyridinyl-N]carbazole-2,1-diyl-κC)platinum(II) (abbreviation: Pt(mmtBubOcz5m4ppy-d₃)) represented by Structural Formula (x) above were deposited by co-evaporation to a thickness of 35 nm such that the weight ratio of SiTrzCz2-d16, PSiCzCz-d15, and Pt(mmtBubOcz5m4ppy-d₃) was 0.45: 0.45: 0.10, so that the light-emitting layer 113 was formed.

After that, 2-phenyl-4,6-bis[3-(triphenylsilyl)phenyl]-1,3,5-triazine (abbreviation: mSiTrz) represented by Structural Formula (vi) above was deposited by evaporation to a thickness of 5 nm to form the first electron-transport layer, and then 2,2′-(1,3-phenylene)bis(9-phenyl-1,10-phenanthroline) (abbreviation: mPPhen2P) represented by Structural Formula (xi) above was deposited by evaporation to a thickness of 20 nm to form the second electron-transport layer, so that the electron-transport layer 114 was formed.

Then, lithium fluoride (LiF) was deposited by evaporation to a thickness of 1 nm to form the electron-injection layer 115, and then aluminum (Al) was deposited by evaporation to a thickness of 200 nm to form the second electrode 102.

Then, the light-emitting device was sealed using a glass substrate in a glove box containing a nitrogen atmosphere so as not to be exposed to the air. Specifically, a UV curable sealing material was applied to surround the device, only the sealing material was irradiated with UV while the light-emitting device was not irradiated with the UV, and heat treatment was performed at 80° C. under an atmospheric pressure for one hour. In this manner, the light-emitting device 3 was fabricated.

### (Fabrication Method of Comparative Light-Emitting Device 3-1)

The comparative light-emitting device 3-1 was fabricated in a manner similar to that of the light-emitting device 3 except that SiTrzCz2-d16 in the light-emitting device 3 was replaced with 9,9′-{6-[3-(triphenylsilyl)phenyl]-1,3,5-triazine-2,4-diyl}bis(9H-carbazole) (abbreviation: SiTrzCz2) represented by Structural Formula (viii) above and PSiCzCz-d15 was replaced with PSiCzCz.

### (Fabrication Method of Comparative Light-Emitting Device 3-2)

The comparative light-emitting device 3-2 was fabricated in a manner similar to that of the light-emitting device 3 except that PSiCzCz-d15 in the light-emitting device 3 was replaced with PSiCzCz.

### (Fabrication Method of Comparative Light-Emitting Device 3-3)

The comparative light-emitting device 3-3 was fabricated in a manner similar to that of the light-emitting device 3 except that SiTrzCz2-d16 in the light-emitting device 3 was replaced with SiTrzCz2.

Device structures of the light-emitting device 3 and the comparative light-emitting devices 3-1 to 3-3 are shown below.

TABLE 9

| | | | | |
|---|---|---|---|---|
| Film | | Comparative | Comparative | Comparative |
| thickness | Light-emitting | light-emitting | light-emitting | light-emitting |
| (nm) | device 3 | device 3-1 | device 3-2 | device 3-3 |

| | | |
|---|---|---|
| Second electrode | 200 | Al |
| Electron-injection layer | 1 | LiF |
| Electron-transport layer | 20 | mPPhen2P |
| | 5 | mSiTrz |
| Light-emitting layer | 35 | *3 |
| Hole-transport layer | 5 | PSiCzCz |
| | 30 | PCBBiF |
| Hole-injection layer | 10 | PCBBiF:OCHD-003 (1:0.03) |
| First electrode | 70 | ITSO |

TABLE 10

| | *3 |
|---|---|
| Light-emitting | SiTrzCz2-d16:PSiCzCz-d15:Pt(mmtBubOcz5m4ppy-d3) |
| device 3 | (0.45:0.45:0.10) |
| Comparative | SiTrzCz2:PSiCzCz:Pt(mmtBubOcz5m4ppy-d3) |
| light-emitting | (0.45:0.45:0.10) |
| device 3-1 | |
| Comparative | SiTrzCz2-d16:PSiCzCz:Pt(mmtBubOcz5m4ppy-d3) |
| light-emitting | (0.45:0.45:0.10) |
| device 3-2 | |
| Comparative | SiTrzCz2:PSiCzCz-d15:Pt(mmtBubOcz5m4ppy-d3) |
| light-emitting | (0.45:0.45:0.10) |
| device 3-3 | |

Here, PSiCzCz is a non-deuterated organic compound of PSiCzCz-d15, and SiTrzCz2 is a non-deuterated organic compound of SiTrzCz2-d16.

FIG. 62 shows the PL spectra of the following films each formed over a quartz substrate to have a thickness of 50 nm: a thin film of SiTrzCz2-d16, a thin film of PSiCzCz-d15, and a mixed film of SiTrzCz2-d16 and PSiCzCz-d15 obtained by depositing SiTrzCz2-d16 and PSiCzCz-d15 by co-evaporation in a weight ratio of 1:1. The PL spectrum was measured with a fluorescence spectrophotometer (FP-8600DS, JASCO Corporation). As shown in FIG. 62, the PL spectrum of the mixed film is positioned on the longer wavelength side than the PL spectra of the films of the single materials, indicating that SiTrzCz2-d16 and PSiCzCz-d15 form an exciplex.

The phosphorescence lifetimes of PSiCzCz, PSiCzCz-d15, SiTrzCz2, and SiTrzCz2-d16 and the rate of change in phosphorescence lifetime owing to deuteration are shown below. The product of the rates was 1.40. Note that the excitation wavelength of PSiCzCz and PSiCzCz-d15 was 340 nm and the measured wavelength was 440 nm. The excitation wavelength of SiTrzCz2 and SiTrzCz2-d16 was 330 nm and the measured wavelength was 450 nm.

TABLE 11

| | Phosphorescence | Increasing rate |
|---|---|---|
| | lifetime | (Deuterated/ |
| | (seconds) | Non-deuterated) |
| SiTrzCz2 | 6.43 | 1.27 |
| SiTrzCz2-d16 | 8.15 | |
| PSiCzCz | 4.83 | 1.10 |
| PSiCzCz-d15 | 5.31 | |

The T₁ level of PSiCzCz-d15 was 2.97 eV, the T₁ level of SiTrzCz2-d16 was 2.93 eV, and the difference therebetween was 0.04 eV.

The 5% weight loss temperature of PSiCzCz-d15 at 10 Pa was 254° C., the 5% weight loss temperature of SiTrzCz2-d16 at 10 Pa was 298° C., and the difference therebetween was 45° C.

Note that the phosphorescent lifetime, the T₁ level, and the 5% weight loss temperature were calculated in a manner similar to that in Example 1.

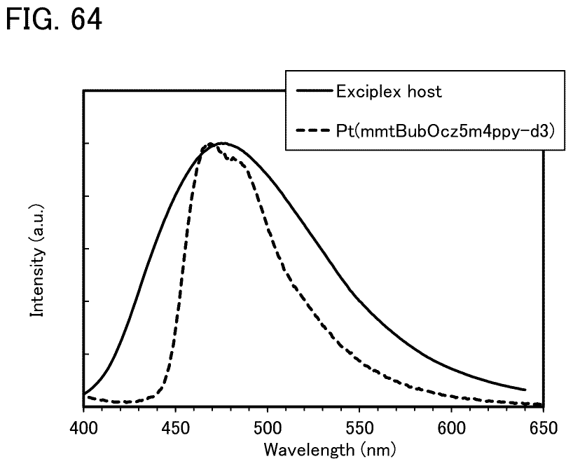

FIG. 64 shows the photoluminescence (PL) spectrum of the exciplex formed by PSiCzCz-d15 and SiTrzCz2-d16 shown in FIG. 62 and the PL spectrum of a poly(methylmethacrylate) (abbreviation: PMMA) film where Pt(mmtBubOcz5m4ppy-d₃) is dispersed, which overlap with each other. As shown in FIG. 64, the PL spectrum of the exciplex formed by PSiCzCz-d15 and SiTrzCz2-d16 and the PL spectrum of the PMMA film where Pt(mmtBubOcz5m4ppy-d₃) is dispersed include an overlap, and a difference between their maximum peak wavelengths is less than or equal to 30 nm. The PMMA film where Pt(mmtBubOcz5m4ppy-d₃) is dispersed was formed in the following manner: a film of a solution where deoxidized dichloromethane was used as a solvent and Pt(mmtBubOcz5m4ppy-d₃) was dispersed at a concentration of 4.7 wt % with respect to PMMA was formed over a quartz substrate by a drop casting method, and then drying was performed in a globe box at room temperature under a nitrogen stream for 30 minutes. The emission spectrum of the obtained PMMA film where Pt(mmtBubOcz5m4ppy-d₃) is dispersed was measured with a PL quantum yield measurement apparatus (Quantaurus-QY C11347-01, Hamamatsu Photonics K.K.).

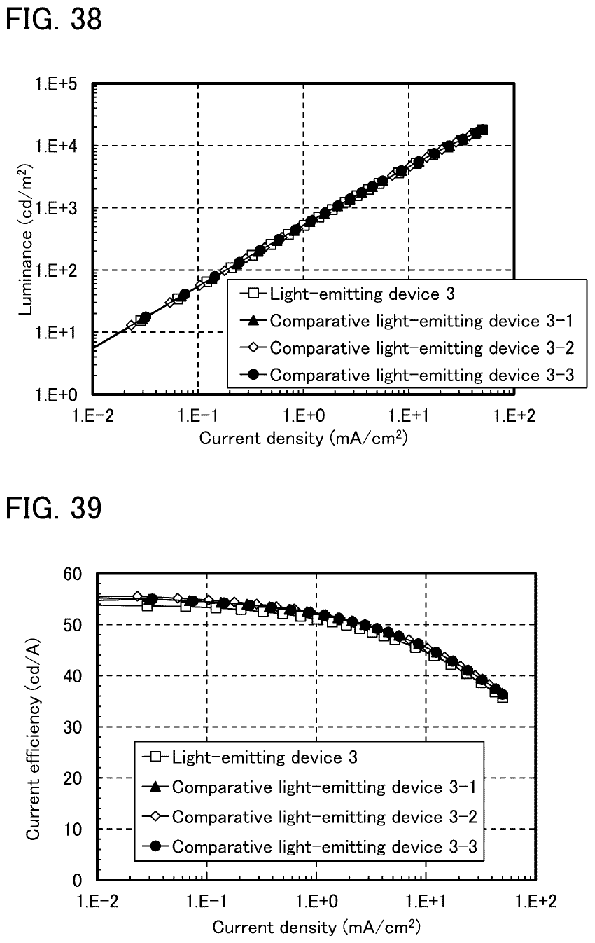

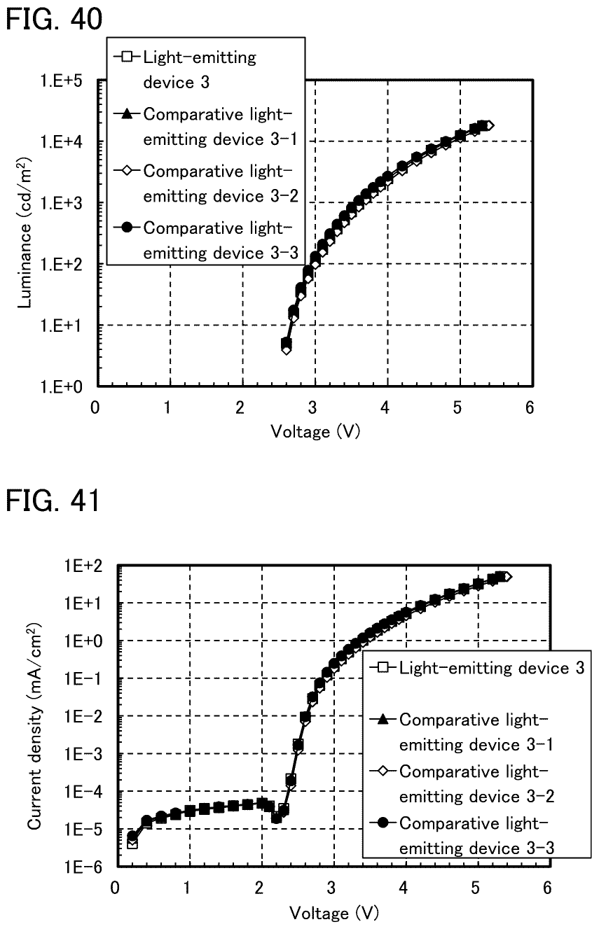

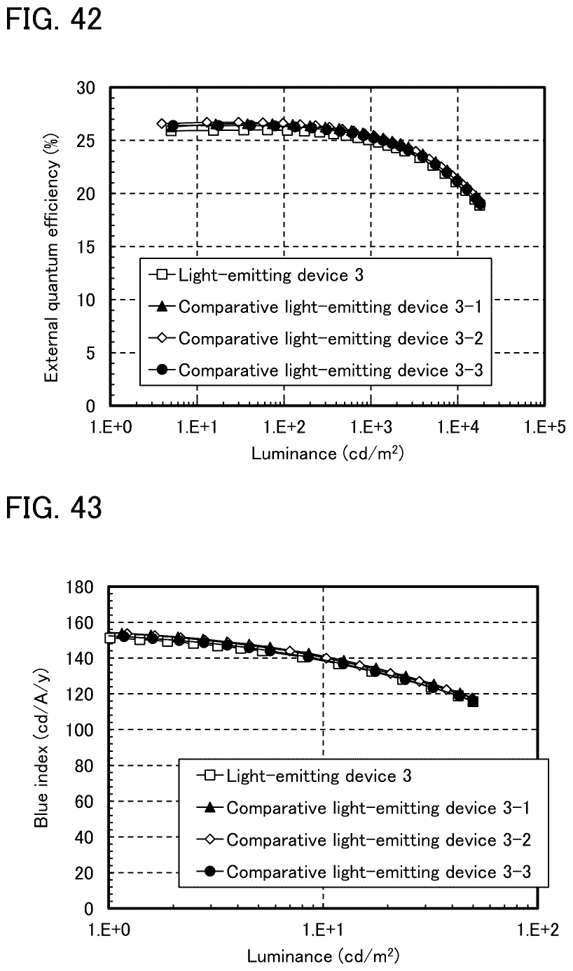

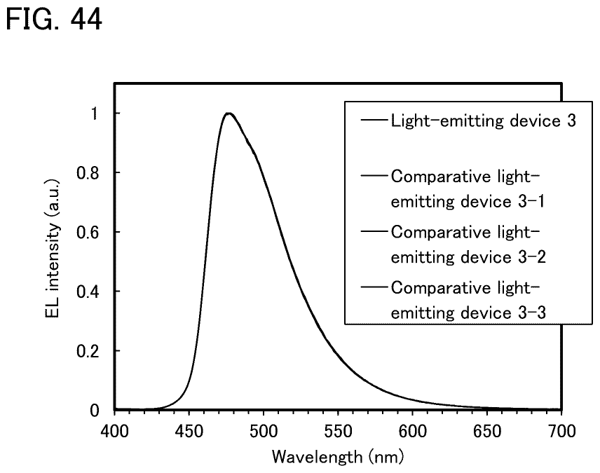

FIG. 38 shows the luminance-current density characteristics of the light-emitting device 3 and the comparative light-emitting devices 3-1 to 3-3. FIG. 39 shows the current efficiency-current density characteristics thereof. FIG. 40 shows the luminance-voltage characteristics thereof. FIG. 41 shows the current density-voltage characteristics thereof. FIG. 42 shows the external quantum efficiency-luminance characteristics thereof. FIG. 43 shows the blue index (BI)-current density characteristics thereof. FIG. 44 shows the electroluminescence spectra thereof.

The values of the voltage, current, current density, CIE chromaticity, current efficiency, external quantum efficiency, and blue index (BI) at around 1000 cd/cm² are shown below. The luminance, CIE chromaticity, and electroluminescence spectra were measured at normal temperature with a spectroradiometer (SR-UL1R, TOPCON TECHNOHOUSE CORPORATION).

TABLE 12

| | | | | | | | External | |
|---|---|---|---|---|---|---|---|---|
| | | | Current | | | Current | quantum | |
| | Voltage | Current | density | Chromaticity | Chromaticity | efficiency | efficiency | BI |
| | (V) | (mA) | (mA/cm²) | x | y | (cd/A) | (%) | (cd/A/y) |
| Light-emitting | 3.6 | 0.075 | 1.88 | 0.15 | 0.33 | 50 | 25 | 149 |
| device 3 | | | | | | | | |
| Comparative | 3.6 | 0.084 | 2.11 | 0.15 | 0.33 | 51 | 25 | 152 |
| light-emitting | | | | | | | | |
| device 3-1 | | | | | | | | |
| Comparative | 3.7 | 0.087 | 2.17 | 0.15 | 0.33 | 51 | 25 | 151 |
| light-emitting | | | | | | | | |
| device 3-2 | | | | | | | | |
| Comparative | 3.6 | 0.085 | 2.13 | 0.15 | 0.34 | 51 | 25 | 150 |
| light-emitting | | | | | | | | |
| device 3-3 | | | | | | | | |

FIGS. 38 to 44 and Table 12 show that the light-emitting device 3 and the comparative light-emitting devices 3-1 to 3-3 have favorable initial characteristics with equivalent emission efficiencies and driving voltages. It is also shown that the light-emitting device 3 and the comparative light-emitting devices 3-1 to 3-3 each have an electroluminescence spectrum peak at a wavelength of 477 nm, and exhibit blue light emission derived from Pt(mmtBubOcz5m4ppy-d₃).

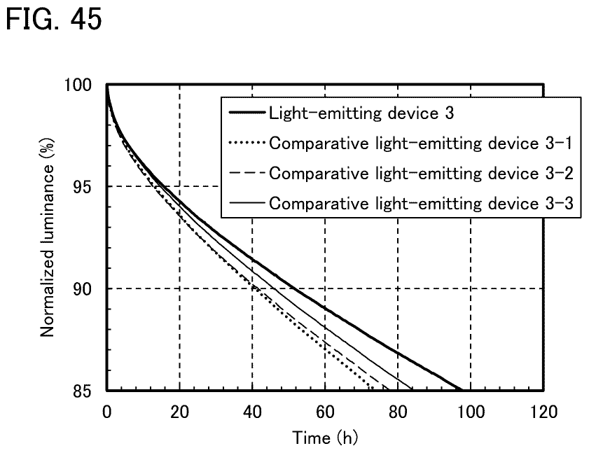

FIG. 45 shows the time dependence of normalized luminance of the light-emitting device 3 and the comparative light-emitting devices 3-1 to 3-3 at a current density of 10 mA/cm².

FIG. 45 shows that the light-emitting device 3 of one embodiment of the present invention has lower time dependence of normalized luminance than the comparative light-emitting devices 3-1 to 3-3 and has high reliability.

### Example 4

In this example, fabricating methods and characteristics of a light-emitting device 4 of one embodiment of the present invention and comparative light-emitting devices 4-1 to 4-3 which are comparative examples will be described in detail. Structural formulae of main compounds used for the light-emitting device 4 and the comparative light-emitting devices 4-1 to 4-3 are shown below.

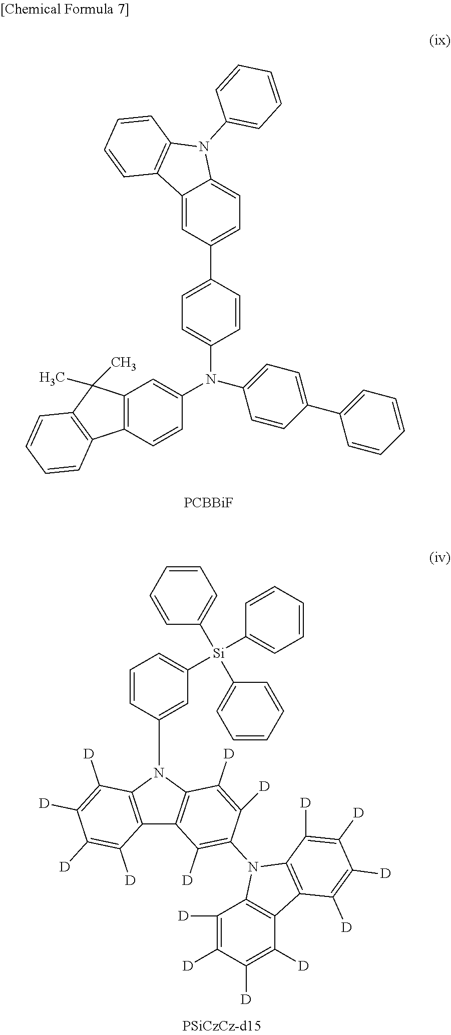

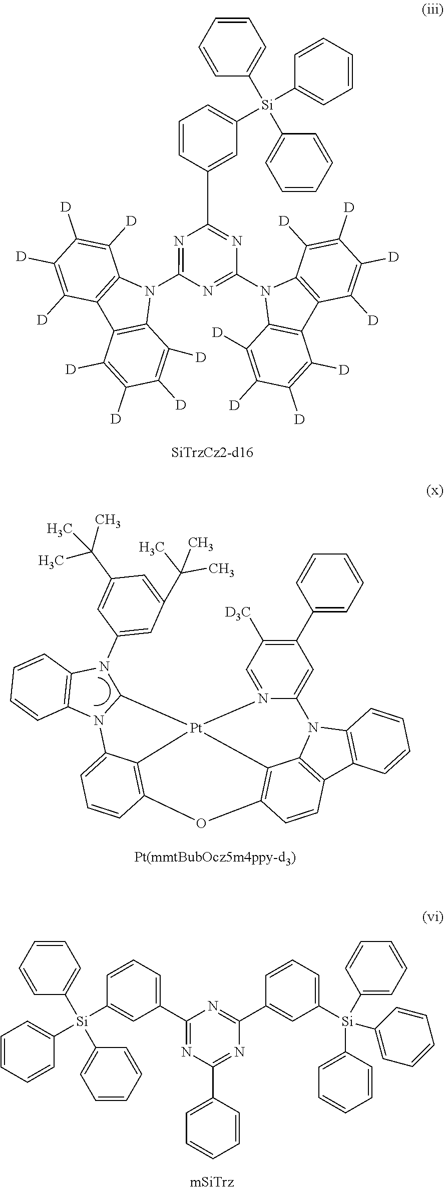

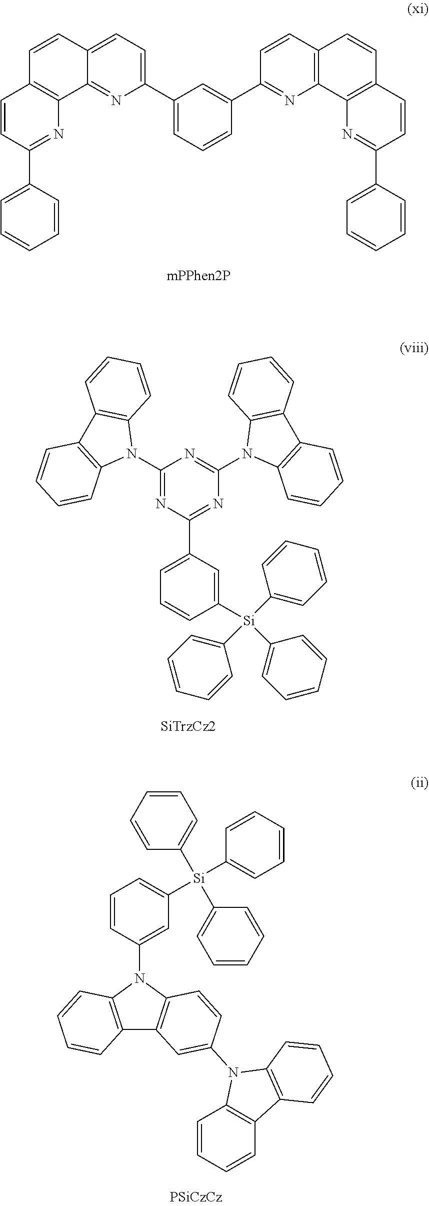 [SMILES: c1ccc(-c2ccc3ccc4ccc(-c5cccc(-c6ccc7ccc8ccc(-c9ccccc9)nc8c7n6)c5)nc4c3n2)cc1 ; c1ccc([Si](c2ccccc2)(c2ccccc2)c2cccc(-c3nc(-n4c5ccccc5c5ccccc54)nc(-n4c5ccccc5c5ccccc54)n3)c2)cc1 ; c1ccc([Si](c2ccccc2)(c2ccccc2)c2cccc(-n3c4ccccc4c4cc(-n5c6ccccc6c6ccccc65)ccc43)c2)cc1]

### (Fabrication Method of Light-Emitting Device 4)

First, indium tin oxide containing silicon oxide (ITSO) was deposited over a glass substrate to a thickness of 70 nm by a sputtering method, so that the first electrode 101 having a size of 2 mm×2 mm was formed. Note that the first electrode 101 serves as an anode.

Then, pretreatment for formation of the light-emitting device over the substrate was performed by washing the substrate surface with water.

After that, the substrate was transferred into a vacuum evaporation apparatus where the pressure was reduced to approximately 1×10-4 Pa, and was subjected to vacuum baking at 170° C. for 30 minutes in a heating chamber of the vacuum evaporation apparatus, and then the substrate was cooled down for approximately 30 minutes.

Next, the substrate was fixed to a holder provided in the vacuum evaporation apparatus such that the side on which the first electrode 101 was formed faced downward. Then, over an inorganic insulating film and the first electrode 101, N-(biphenyl-4-yl)-N-[4-(9-phenyl-9H-carbazol-3-yl)phenyl]-9,9-dimethyl-9H-fluoren-2-amine (abbreviation: PCBBiF) represented by Structural Formula (ix) above and a fluorine-containing electron acceptor material (OCHD-003) with a molecular weight of 672 were deposited by co-evaporation to a thickness of 10 nm such that the weight ratio of PCBBiF to OCHD-003 was 1:0.03; thus, the hole-injection layer 111 was formed.

Over the hole-injection layer 111, PCBBiF was deposited by evaporation to a thickness of 30 nm to form the first hole-transport layer, and then 9-[3-(triphenylsilyl)phenyl]-3,9′-(bi-9H-carbazole-d₁₅) (abbreviation: PSiCzCz-d15) represented by Structural Formula (iv) above was deposited by evaporation to a thickness of 5 nm to form the second hole-transport layer, so that the hole-transport layer 112 was formed. Note that the second hole-transport layer also functions as an electron-blocking layer.

Next, over the hole-transport layer 112, 9,9′-{6-[3-(triphenylsilyl)phenyl]-1,3,5-triazine-2,4-diyl}bis(9H-carbazole-1,2,3,4,5,6,7,8,1′,2′,3′,4′,5′,6′,7′,8′-d16) (abbreviation: SiTrzCz2-d16) represented by Structural Formula (iii) above, PSiCzCz-d15, and (2-{3-[3-(3,5-di-tert-butylphenyl)benzimidazol-1-yl-2-ylidene-κC²]phenoxy-κC²}-9-[5-(methyl-d3)-4-phenyl-2-pyridinyl-κN]carbazole-2,1-diyl-κC)platinum(II) (abbreviation: Pt(mmtBubOcz5m4ppy-d₃)) represented by Structural Formula (x) above were deposited by co-evaporation to a thickness of 35 nm such that the weight ratio of SiTrzCz2-d16, PSiCzCz-d15, and Pt(mmtBubOcz5m4ppy-d₃) was 0.45: 0.45: 0.10, so that the light-emitting layer 113 was formed.

After that, 2-phenyl-4,6-bis[3-(triphenylsilyl)phenyl]-1,3,5-triazine (abbreviation: mSiTrz) represented by Structural Formula (vi) above was deposited by evaporation to a thickness of 5 nm to form the first electron-transport layer, and then 2,2′-(1,3-phenylene)bis(9-phenyl-1,10-phenanthroline) (abbreviation: mPPhen2P) represented by Structural Formula (xi) above was deposited by evaporation to a thickness of 20 nm to form the second electron-transport layer, so that the electron-transport layer 114 was formed.

Then, lithium fluoride (LiF) was deposited by evaporation to a thickness of 1 nm to form the electron-injection layer 115, and then aluminum (Al) was deposited by evaporation to a thickness of 200 nm to form the second electrode 102.

Then, the light-emitting device was sealed using a glass substrate in a glove box containing a nitrogen atmosphere so as not to be exposed to the air. Specifically, a UV curable sealing material was applied to surround the device, only the sealing material was irradiated with UV while the light-emitting device was not irradiated with the UV, and heat treatment was performed at 80° C. under an atmospheric pressure for one hour. In this manner, the light-emitting device 4 was fabricated.

### (Fabrication Method of Comparative Light-Emitting Device 4-1)

The comparative light-emitting device 4-1 was fabricated in a manner similar to that of the light-emitting device 4 except that SiTrzCz2-d16 in the light-emitting device 4 was replaced with 9,9′-{6-[3-(triphenylsilyl)phenyl]-1,3,5-triazine-2,4-diyl}bis(9H-carbazole) (abbreviation: SiTrzCz2) represented by Structural Formula (viii) above and PSiCzCz-d15 was replaced with 9-[3-(triphenylsilyl)phenyl]-3,9′-bi-9H-carbazole (abbreviation: PSiCzCz) represented by Structural Formula (ii) above.

### (Fabrication Method of Comparative Light-Emitting Device 4-2)

The comparative light-emitting device 4-2 was fabricated in a manner similar to that of the light-emitting device 4 except that PSiCzCz-d15 in the light-emitting device 4 was replaced with PSiCzCz.

### (Fabrication Method of Comparative Light-Emitting Device 4-3)

The comparative light-emitting device 4-3 was fabricated in a manner similar to that of the light-emitting device 4 except that SiTrzCz2-d16 in the light-emitting device 4 was replaced with SiTrzCz2.

Device structures of the light-emitting device 4 and the comparative light-emitting devices 4-1 to 4-3 are shown below.

TABLE 13

| | | | | |
|---|---|---|---|---|
| Film | | Comparative | Comparative | Comparative |
| thickness | Light-emitting | light-emitting | light-emitting | light-emitting |
| (nm) | device 4 | device 4-1 | device 4-2 | device 4-3 |

| | | |
|---|---|---|
| Second electrode | 200 | Al |
| Electron-injection layer | 1 | LiF |
| Electron-transport layer | 20 | mPPhen2P |
| | 5 | mSiTrz |
| Light-emitting layer | 35 | *4 |
| Hole-transport layer | 5 | PSiCzCz-d15 |
| | 30 | PCBBiF |
| Hole-injection layer | 10 | PCBBiF:OCHD-003 (1:0.03) |
| First electrode | 70 | ITSO |

TABLE 14

| | *4 |
|---|---|
| Light-emitting | SiTrzCz2-d16:PSiCzCz-d15:Pt(mmtBubOcz5m4ppy-d₃) |
| device 4 | (0.45:0.45:0.10) |
| Comparative | SiTrzCz2:PSiCzCz:Pt(mmtBubOcz5m4ppy-d₃) |
| light-emitting | (0.45:0.45:0.10) |
| device 4-1 | |
| Comparative | SiTrzCz2-d16:PSiCzCz:Pt(mmtBubOcz5m4ppy-d₃) |
| light-emitting | (0.45:0.45:0.10) |
| device 4-2 | |
| Comparative | SiTrzCz2:PSiCzCz-d15:Pt(mmtBubOcz5m4ppy-d₃) |
| light-emitting | (0.45:0.45:0.10) |
| device 4-3 | |

Here, PSiCzCz is a non-deuterated organic compound of PSiCzCz-d15, and SiTrzCz2 is a non-deuterated organic compound of SiTrzCz2-d16.

FIG. 62 shows the PL spectra of the following films each formed over a quartz substrate to have a thickness of 50 nm: a thin film of SiTrzCz2-d16, a thin film of PSiCzCz-d15, and a mixed film of SiTrzCz2-d16 and PSiCzCz-d15 obtained by depositing SiTrzCz2-d16 and PSiCzCz-d15 by co-evaporation in a weight ratio of 1:1. The PL spectrum was measured with a fluorescence spectrophotometer (FP-8600DS, JASCO Corporation). As shown in FIG. 62, the PL spectrum of the mixed film is positioned on the longer wavelength side than the PL spectra of the films of the single materials, indicating that SiTrzCz2-d16 and PSiCzCz-d15 form an exciplex.

The phosphorescence lifetimes of PSiCzCz, PSiCzCz-d15, SiTrzCz2, and SiTrzCz2-d16 and the rate of change in phosphorescence lifetime owing to deuteration are shown below. The product of the rates was 1.40. Note that the excitation wavelength of PSiCzCz and PSiCzCz-d15 was 340 nm and the measured wavelength was 440 nm. The excitation wavelength of SiTrzCz2 and SiTrzCz2-d16 was 330 nm and the measured wavelength was 450 nm.

TABLE 15

| | Phosphorescence | Increasing rate |
|---|---|---|
| | lifetime | (Deuterated/ |
| | (seconds) | Non-deuterated) |
| SiTrzCz2 | 6.43 | 1.27 |
| SiTrzCz2-d16 | 8.15 | |
| PSiCzCz | 4.83 | 1.10 |
| PSiCzCz-d15 | 5.31 | |

The T₁ level of PSiCzCz-d15 was 2.97 eV, the T₁ level of SiTrzCz2-d16 was 2.93 eV, and the difference therebetween was 0.04 eV.

The 5% weight loss temperature of PSiCzCz-d15 at 10 Pa was 254° C., the 5% weight loss temperature of SiTrzCz2-d16 at 10 Pa was 298° C., and the difference therebetween was 45° C.

Note that the phosphorescent lifetime, the T₁ level, and the 5% weight loss temperature were calculated in a manner similar to that in Example 1.

FIG. 64 shows the photoluminescence (PL) spectrum of the exciplex formed by PSiCzCz-d15 and SiTrzCz2-d16 shown in FIG. 62 and the PL spectrum of a poly(methylmethacrylate) (abbreviation: PMMA) film where Pt(mmtBubOcz5m4ppy-d₃) is dispersed, which overlap with each other. As shown in FIG. 64, the PL spectrum of the exciplex formed by PSiCzCz-d15 and SiTrzCz2-d16 and the PL spectrum of the PMMA film where Pt(mmtBubOcz5m4ppy-d₃) is dispersed include an overlap, and a difference between their maximum peak wavelengths is less than or equal to 30 nm. The PMMA film where Pt(mmtBubOcz5m4ppy-d₃) is dispersed was formed in the following manner: a film of a solution where deoxidized dichloromethane was used as a solvent and Pt(mmtBubOcz5m4ppy-d₃) was dispersed at a concentration of 4.7 wt % with respect to PMMA was formed over a quartz substrate by a drop casting method, and then drying was performed in a globe box at room temperature under a nitrogen stream for 30 minutes. The emission spectrum of the obtained PMMA film where Pt(mmtBubOcz5m4ppy-d₃) is dispersed was measured with a PL quantum yield measurement apparatus (Quantaurus-QY C11347-01, Hamamatsu Photonics K.K.).

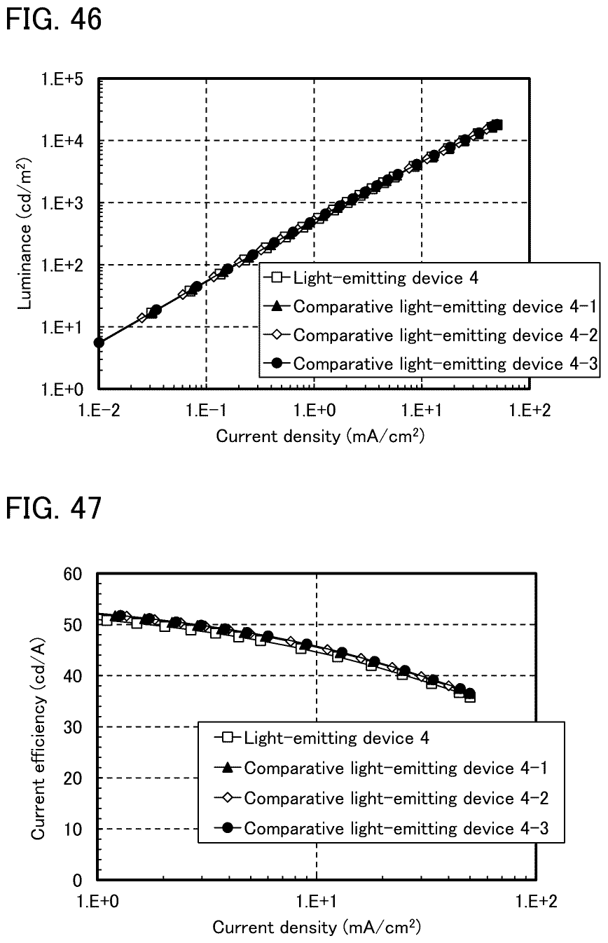

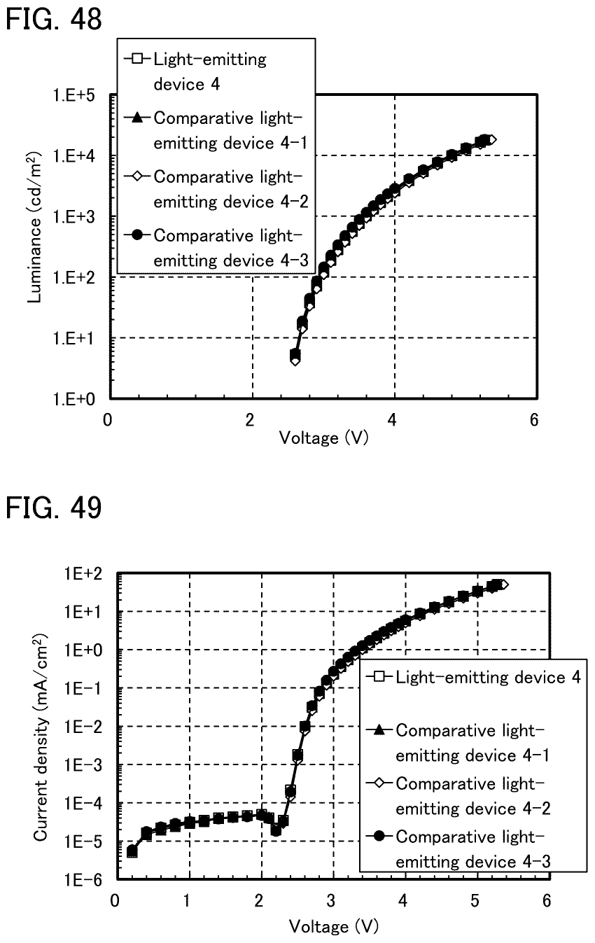

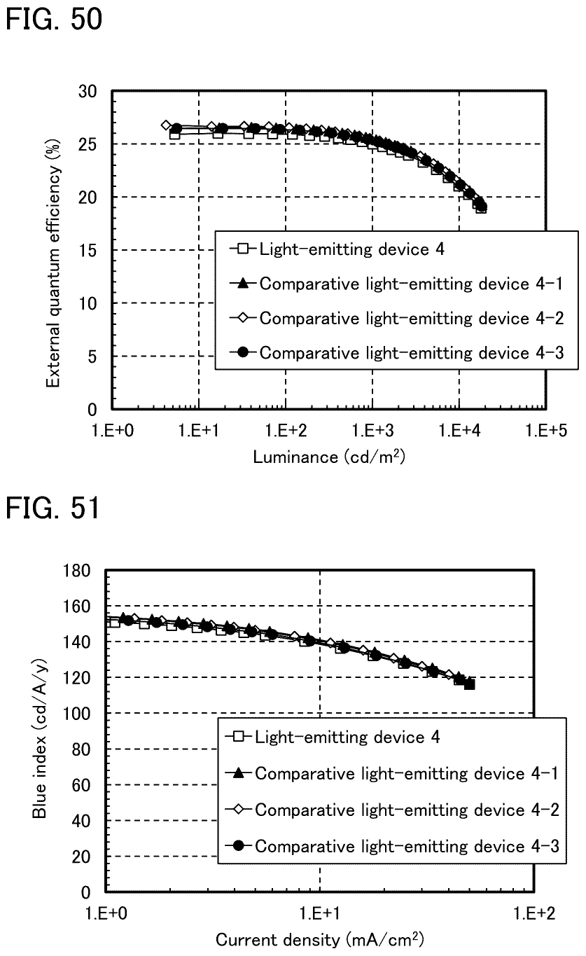

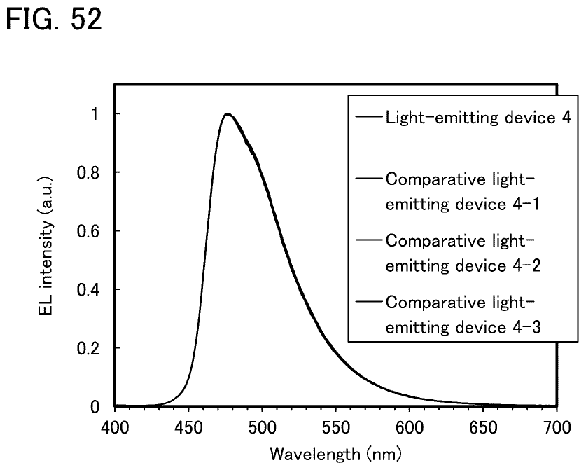

FIG. 46 shows the luminance-current density characteristics of the light-emitting device 4 and the comparative light-emitting devices 4-1 to 4-3. FIG. 47 shows the current efficiency-current density characteristics thereof. FIG. 48 shows the luminance-voltage characteristics thereof. FIG. 49 shows the current density-voltage characteristics thereof. FIG. 50 shows the external quantum efficiency-luminance characteristics thereof. FIG. 51 shows the blue index (BI)-current density characteristics thereof. FIG. 52 shows the electroluminescence spectra thereof.

The values of the voltage, current, current density, CIE chromaticity, current efficiency, external quantum efficiency, and blue index (BI) at around 1000 cd/cm² are shown below. The luminance, CIE chromaticity, and electroluminescence spectra were measured at normal temperature with a spectroradiometer (SR-UL1R, TOPCON TECHNOHOUSE CORPORATION).

TABLE 16

| | | | | | | | External | |
|---|---|---|---|---|---|---|---|---|
| | | | Current | | | Current | quantum | |
| | Voltage | Current | density | Chromaticity | Chromaticity | efficiency | efficiency | BI |
| | (V) | (mA) | (mA/cm²) | x | y | (cd/A) | (%) | (cd/A/y) |
| Light-emitting | 3.6 | 0.081 | 2.03 | 0.15 | 0.33 | 50 | 25 | 149 |
| device 4 | | | | | | | | |
| Comparative | 3.6 | 0.088 | 2.19 | 0.15 | 0.33 | 50 | 25 | 151 |
| light-emitting | | | | | | | | |
| device 4-1 | | | | | | | | |
| Comparative | 3.6 | 0.073 | 1.83 | 0.15 | 0.34 | 51 | 26 | 152 |
| light-emitting | | | | | | | | |
| device 4-2 | | | | | | | | |
| Comparative | 3.5 | 0.069 | 1.73 | 0.15 | 0.34 | 51 | 25 | 151 |
| light-emitting | | | | | | | | |
| device 4-3 | | | | | | | | |

FIGS. 46 to 52 and Table 16 show that the light-emitting device 4 and the comparative light-emitting devices 4-1 to 4-3 have favorable initial characteristics with equivalent emission efficiencies and driving voltages. It is also shown that the light-emitting device 4 and the comparative light-emitting devices 4-1 to 4-3 each have an electroluminescence spectrum peak at a wavelength of 477 nm, and exhibit blue light emission derived from Pt(mmtBubOcz5m4ppy-d₃).

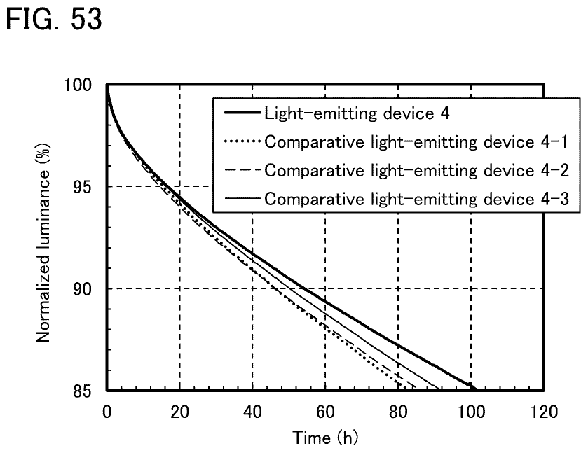

FIG. 53 shows the time dependence of normalized luminance of the light-emitting device 4 and the comparative light-emitting devices 4-1 to 4-3 at a current density of 10 mA/cm².

FIG. 53 shows that the light-emitting device 4 of one embodiment of the present invention has lower time dependence of normalized luminance than the comparative light-emitting devices 4-1 to 4-3 and has high reliability.

### Example 5

In this example, fabricating methods and characteristics of a light-emitting device 5 of one embodiment of the present invention and comparative light-emitting devices 5-1 to 5-3 which are comparative examples will be described in detail. Structural formulae of main compounds used for the light-emitting device 5 and the comparative light-emitting devices 5-1 to 5-3 are shown below.

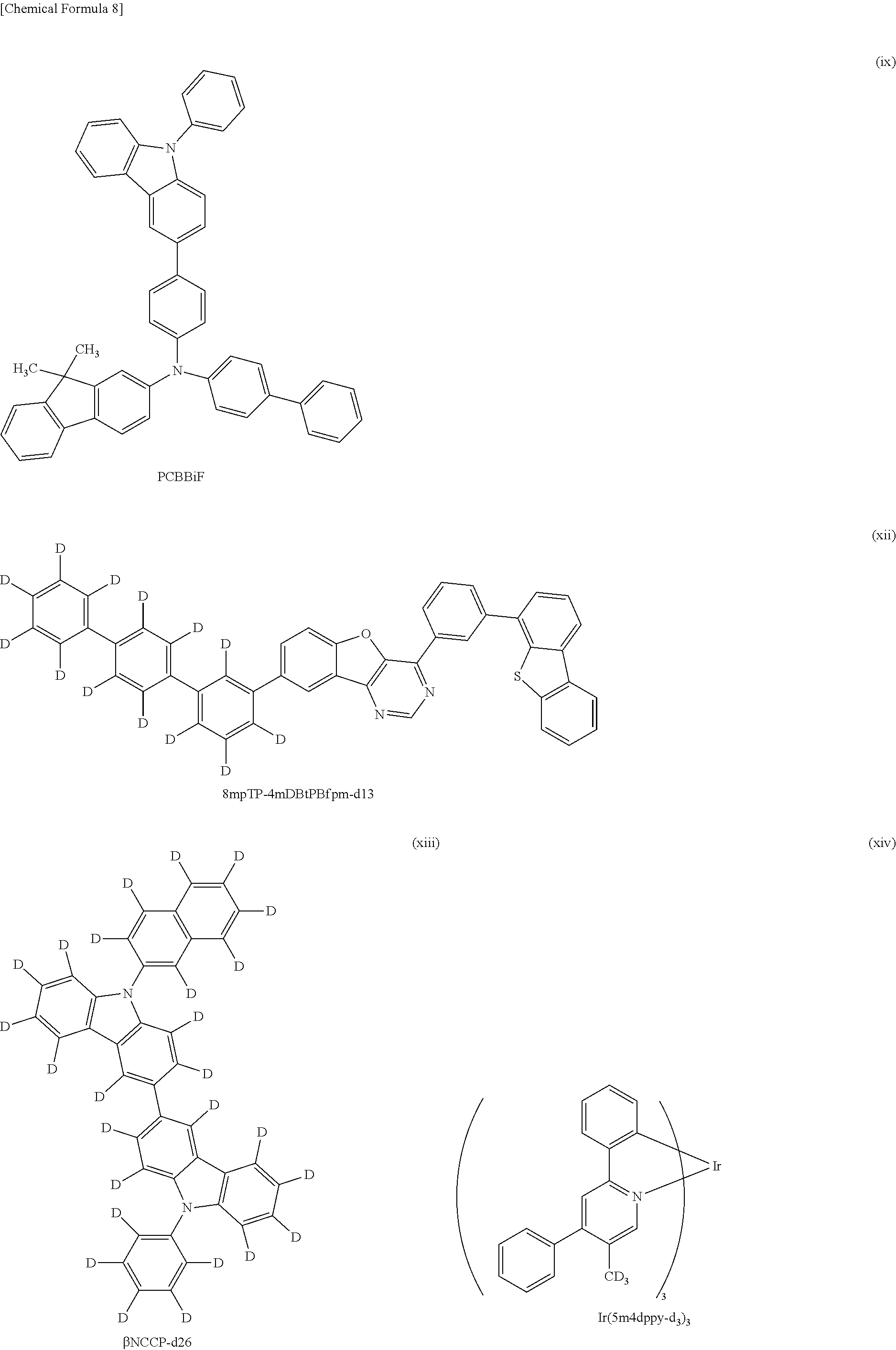

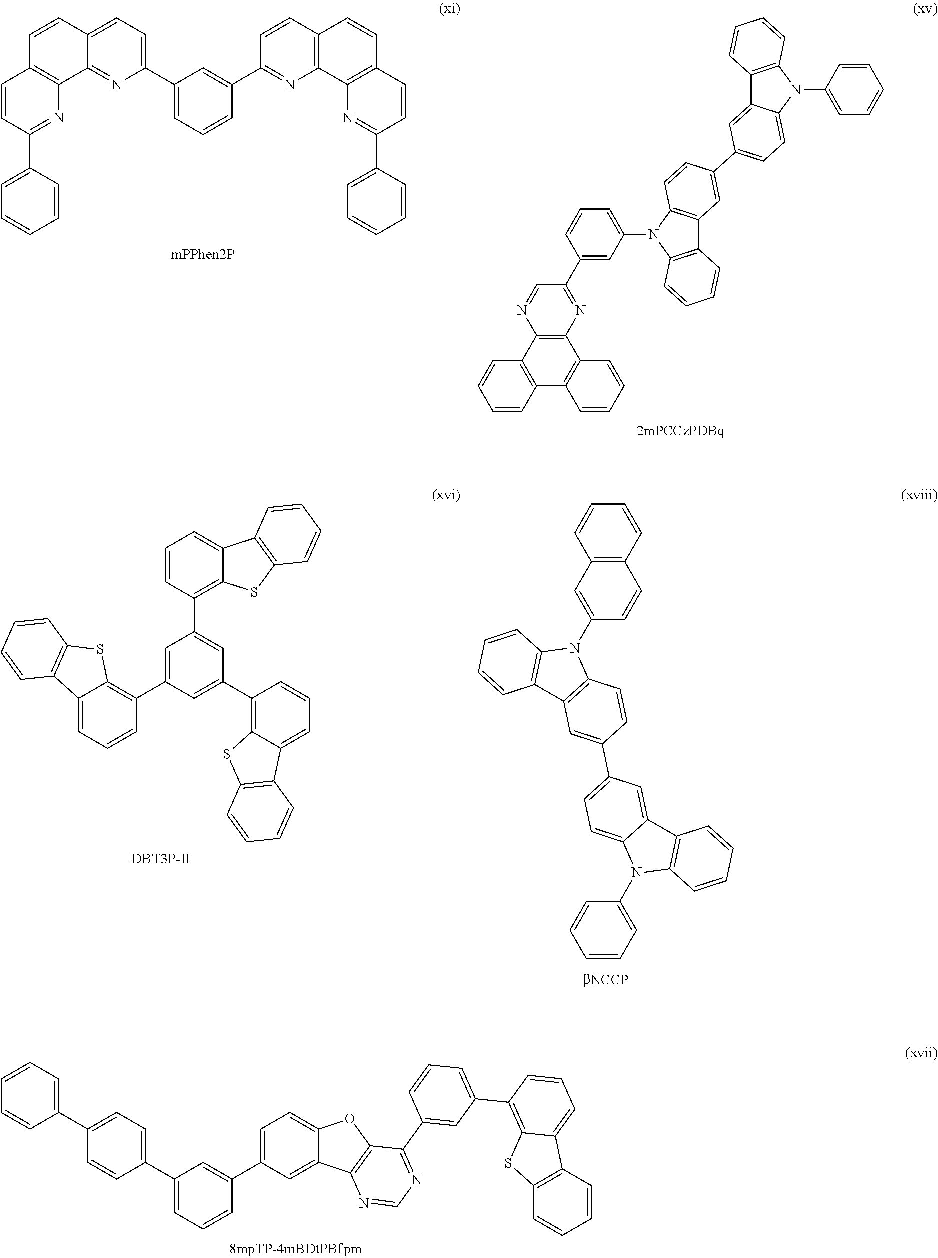 [SMILES: c1ccc(-c2ccc3ccc4ccc(-c5cccc(-c6ccc7ccc8ccc(-c9ccccc9)nc8c7n6)c5)nc4c3n2)cc1 ; c1ccc(-n2c3ccccc3c3cc(-c4ccc5c(c4)c4ccccc4n5-c4cccc(-c5cnc6c7ccccc7c7ccccc7c6n5)c4)ccc32)cc1 ; c1ccc2c(c1)sc1c(-c3cc(-c4cccc5c4sc4ccccc45)cc(-c4cccc5c4sc4ccccc45)c3)cccc12 ; "DBT3P-II" ; c1ccc(-n2c3ccccc3c3cc(-c4ccc5c(c4)c4ccccc4n5-c4ccc5ccccc5c4)ccc32)cc1 ; c1ccc(-c2ccc(-c3cccc(-c4ccc5oc6c(-c7cccc(-c8cccc9c8sc8ccccc89)c7)ncnc6c5c4)c3)cc2)cc1]

### (Fabrication Method of Light-Emitting Device 5)

First, 100-nm-thick silver (Ag) and 10-nm-thick indium tin oxide containing silicon oxide (ITSO) were sequentially stacked over a glass substrate by a sputtering method, so that the first electrode 101 having a size of 2 mm×2 mm was formed. Note that the first electrode 101 serves as an anode.

Then, pretreatment for formation of the light-emitting device over the substrate was performed by washing the substrate surface with water.

After that, the substrate was transferred into a vacuum evaporation apparatus where the pressure was reduced to approximately 1×10⁻⁴ Pa, and was subjected to vacuum baking at 170° C. for 30 minutes in a heating chamber of the vacuum evaporation apparatus, and then the substrate was cooled down for approximately 30 minutes.

Next, the substrate was fixed to a holder provided in the vacuum evaporation apparatus such that the side on which the first electrode 101 was formed faced downward. Then, over an inorganic insulating film and the first electrode 101, N-(biphenyl-4-yl)-N-[4-(9-phenyl-9H-carbazol-3-yl)phenyl]-9,9-dimethyl-9H-fluoren-2-amine (abbreviation: PCBBiF) represented by Structural Formula (ix) above and a fluorine-containing electron acceptor material (OCHD-003) with a molecular weight of 672 were deposited by co-evaporation to a thickness of 10 nm such that the weight ratio of PCBBiF to OCHD-003 was 1:0.03; thus, the hole-injection layer 111 was formed.

Over the hole-injection layer 111, PCBBiF was deposited by evaporation to a thickness of 140 nm, so that the hole-transport layer 112 was formed.

Then, over the hole-transport layer 112, 8-(1,1′: 4′,1″-terphenyl-3-yl-2,4,5,6,2′,3′,5′,6′,2″,3″,4″,5″,6″-d13)-4-[3-(dibenzothiophen-4-yl)phenyl]-[1]benzofuro[3,2-d]pyrimidine (abbreviation: 8mpTP-4mDBtPBfpm-d13) represented by Structural Formula (xii) above, 9-(2-naphthyl-1,3,4,5,6,7,8-d7)-9′-(phenyl-2,3,4,5,6-d5)-9H,9′H-3,3′-bicarbazole-1,1′,2,2′,4,4′,5,5′,6,6′,7,7′,8,8′-d14 (abbreviation: βNCCP-d26) represented by Structural Formula (xiii) above, and tris{2-[5-(methyl-d3)-4-phenyl-2-pyridinyl-N]phenyl-κC}iridium(III) (abbreviation: Ir(5m4dppy-d₃)₃) represented by Structural Formula (xiv) above were deposited by co-evaporation to a thickness of 40 nm such that the weight ratio of 8mpTP-4mDBtPBfpm-d13, βNCCP-d26, and Ir(5m4dppy-d₃)₃ was 0.4: 0.6: 0.1, so that the light-emitting layer 113 was formed.

After that, 2-{3-[3-(N-phenyl-9H-carbazol-3-yl)-9H-carbazol-9-yl]phenyl}dibenzo[f,h]quinoxaline (abbreviation: 2mPCCzPDBq) represented by Structural Formula (xv) above was deposited by evaporation to a thickness of 10 nm to form the first electron-transport layer, and then 2,2′-(1,3-phenylene)bis(9-phenyl-1,10-phenanthroline) (abbreviation: mPPhen2P) represented by Structure Formula (xi) above was deposited by evaporation to a thickness of 20 nm to form the second electron-transport layer, so that the electron-transport layer 114 was formed.

Then, lithium fluoride (LiF) was deposited by evaporation to a thickness of 1 nm to form the electron-injection layer 115, and then silver (Ag) and magnesium (Mg) were deposited by co-evaporation to a thickness of 15 nm such that the volume ratio of Ag to Mg was 1:0.1, so that the second electrode 102 was formed. Finally, over the second electrode 102, 4,4′,4″-(benzene-1,3,5-triyl)tri(dibenzothiophene) (abbreviation: DBT3P-II) represented by Structural Formula (xvi) above was deposited to a thickness of 70 nm as a cap layer.

Then, the light-emitting device was sealed using a glass substrate in a glove box containing a nitrogen atmosphere so as not to be exposed to the air. Specifically, a UV curable sealing material was applied to surround the device, only the sealing material was irradiated with UV while the light-emitting device was not irradiated with the UV, and heat treatment was performed at 80° C. under an atmospheric pressure for one hour. In this manner, the light-emitting device 5 was fabricated.

### (Fabrication Method of Comparative Light-Emitting Device 5-1)

The comparative light-emitting device 5-1 was fabricated in a manner similar to that of the light-emitting device 5 except that 8mpTP-4mDBtPBfpm-d13 in the light-emitting device 5 was replaced with 8-(p-terphenyl-3-yl)-4-[3-(dibenzothiophen-4-yl)phenyl]-[1]benzofuro[3,2-d]pyrimidine (abbreviation: 8mpTP-4mDBtPBfpm) represented by Structural Formula (xvii) above and βNCCP-d26 was replaced with 9-(2-naphthyl)-9′-phenyl-9H,9′H-3,3′-bicarbazole (abbreviation: βNCCP) represented by Structural Formula (xviii) above.

### (Fabrication Method of Comparative Light-Emitting Device 5-2)

The comparative light-emitting device 5-2 was fabricated in a manner similar to that of the light-emitting device 5 except that βNCCP-d26 in the light-emitting device 5 was replaced with βNCCP.

### (Fabrication Method of Comparative Light-Emitting Device 5-3)

The comparative light-emitting device 5-3 was fabricated in a manner similar to that of the light-emitting device 5 except that 8mpTP-4mDBtPBfpm-d13 in the light-emitting device 5 was replaced with 8mpTP-4mDBtPBfpm.

Device structures of the light-emitting device 5 and the comparative light-emitting devices 5-1 to 5-3 are shown below.

TABLE 17

| | | | | |
|---|---|---|---|---|
| Film | | Comparative | Comparative | Comparative |
| thickness | Light-emitting | light-emitting | light-emitting | light-emitting |
| (nm) | device 5 | device 5-1 | device 5-2 | device 5-3 |

| | | |
|---|---|---|
| Cap layer | 70 | DBT3P-II |
| Second electrode | 15 | Ag:Mg (1:0.1) |
| Electron-injection layer | 1 | LiF |
| Electron-transport layer | 20 | mPPhen2P |
| | 10 | 2mPCCzPDBq |
| Light-emitting layer | 40 | *5 |
| Hole-transport layer | 12.5 | PCBBiF |
| Hole-injection layer | 10 | PCBBiF:OCHD-003 (1:0.03) |
| First electrode | 10 | ITSO |
| | 100 | Ag |

TABLE 18

| | *5 |
|---|---|
| Light-emitting | 8mpTP-4mDBtPBfpm-d13:βNCCP-d26:Ir(5m4dppy-d₃)₃ |
| device 5 | (0.4:0.6:0.1) |
| Comparative | 8mpTP-4mDBtPBfpm:βNCCP:Ir(5m4dppy-d₃)₃ |
| light-emitting | (0.4:0.6:0.1) |
| device 5-1 | |
| Comparative | 8mpTP-4mDBtPBfpm-d13:βNCCP:Ir(5m4dppy-d₃)₃ |
| light-emitting | (0.4:0.6:0.1) |
| device 5-2 | |
| Comparative | SmpTP-4mDBtPBfpm:βNCCP-d26:Ir(5m4dppy-d₃)₃ |
| light-emitting | (0.4:0.6:0.1) |
| device 5-3 | |

Here, 8mpTP-4mDBtPBfpm is a non-deuterated organic compound of 8mpTP-4mDBtPBfpm-d13, and βNCCP is a non-deuterated organic compound of βNCCP-d26.

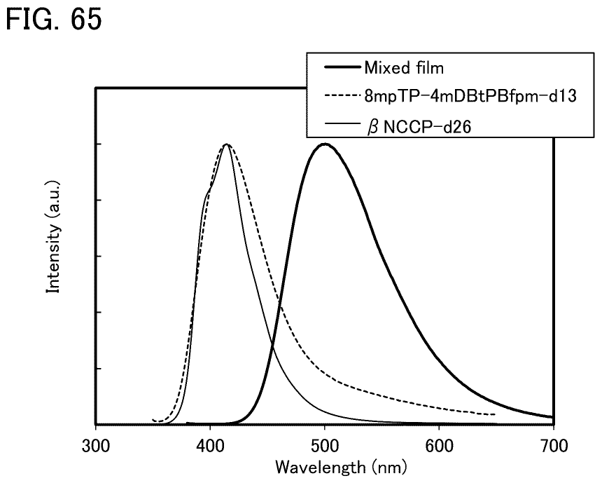

FIG. 65 shows the PL spectra of the following films each formed over a quartz substrate to have a thickness of 50 nm: a thin film of 8mpTP-4mDBtPBfpm-d13, a thin film of βNCCP-d26, and a mixed film of 8mpTP-4mDBtPBfpm-d13 and βNCCP-d26 obtained by depositing 8mpTP-4mDBtPBfpm-d13 and βNCCP-d26 by co-evaporation in a weight ratio of 1:1. The PL spectrum was measured with a fluorescence spectrophotometer (FP-8600DS, JASCO Corporation). As shown in FIG. 65, the PL spectrum of the mixed film is positioned on the longer wavelength side than the PL spectra of the films of the single materials, indicating that 8mpTP-4mDBtPBfpm-d13 and βNCCP-d26 form an exciplex.

The phosphorescence lifetimes of βNCCP, βNCCP-d26, 8mpTP-4mDBtPBfpm, and 8mpTP-4mDBtPBfpm-d13 and the rate of change in phosphorescence lifetime owing to deuteration are shown below. The product of the rates was 5.72. Note that the excitation wavelength of βNCCP and βNCCP-d26 was 330 nm and the measured wavelength was 515 nm. The excitation wavelength of 8mpTP-4mDBtPBfpm and 8mpTP-4mDBtPBfpm-d13 was 320 nm and the measured wavelength was 515 nm.

TABLE 19

| | Phosphorescence | Increasing rate |
|---|---|---|
| | lifetime | (Deuterated/ |
| | (seconds) | Non-deuterated) |
| βNCCP | 1.63 | 3.18 |
| βNCCP-d26 | 5.18 | |
| 8mpTP-4mDBtPBfpm | 2.98 | 1.80 |
| 8mpTP-4mDBtPBfpm-d13 | 5.35 | |

TAPAAT

The T₁ level of βNCCP-d26 was 2.56 eV, the T₁ level of 8mpTP-4mDBtPBfpm-d13 was 2.55 eV, and the difference therebetween was 0.01 eV.

The 5% weight loss temperature of βNCCP-d26 at 10 Pa was 257° C., the 5% weight loss temperature of 8mpTP-4mDBtPBfpm-d13 at 10 Pa was 312° C., and the difference therebetween was 55° C.

Note that the phosphorescent lifetime, the T₁ level, and the 5% weight loss temperature were calculated in a manner similar to that in Example 1.

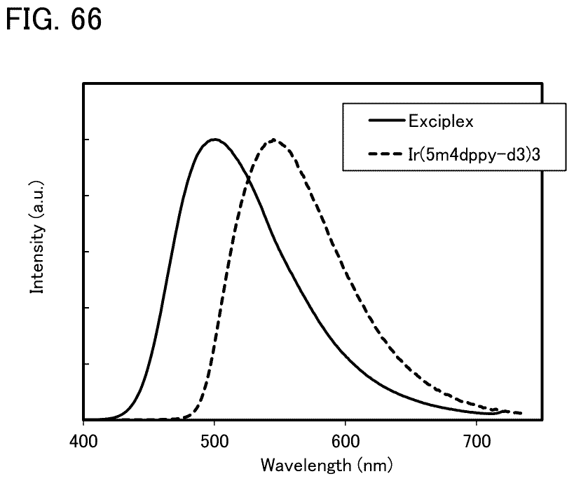

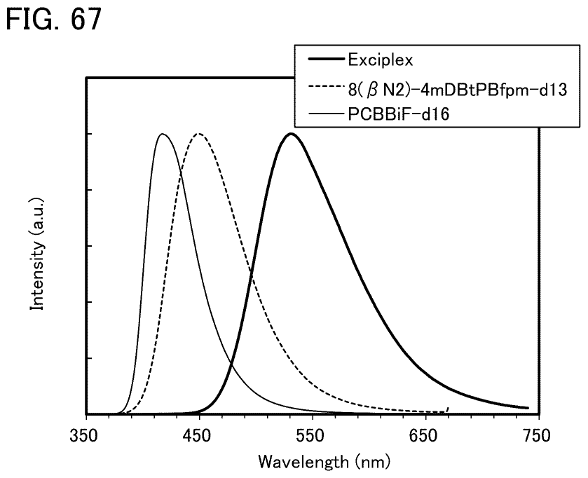

As shown in FIG. 66, the PL spectrum of the exciplex formed by βNCCP-d26 and 8mpTP-4mDBtPBfpm-d13 and the PL spectrum of Ir(5m4dppy-d₃)3 include an overlap. The PL spectrum of Ir(5m4dppy-d₃)3 in a dichloromethane solution was measured with a fluorescence spectrophotometer (FP-8600DS, JASCO Corporation).

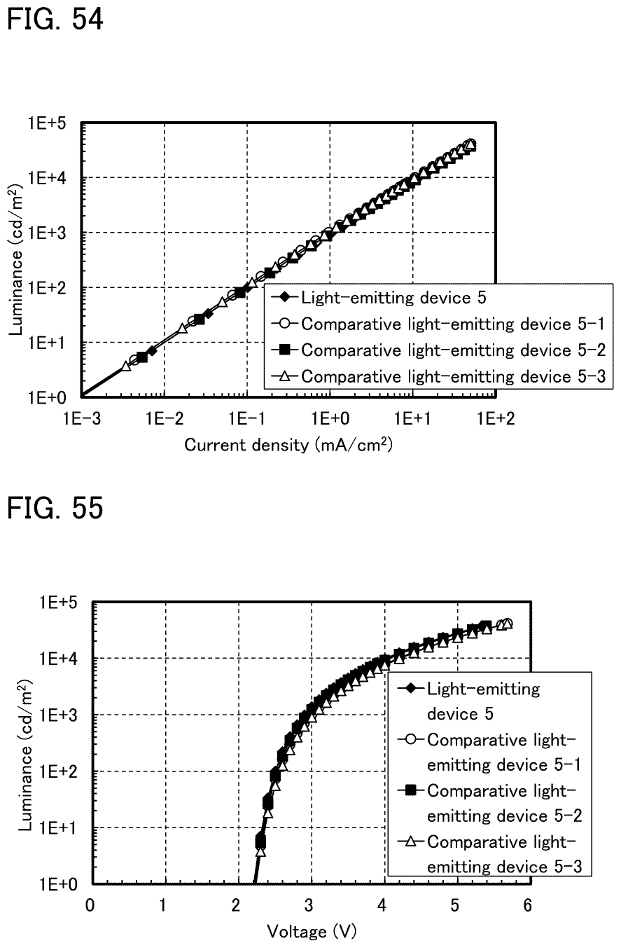

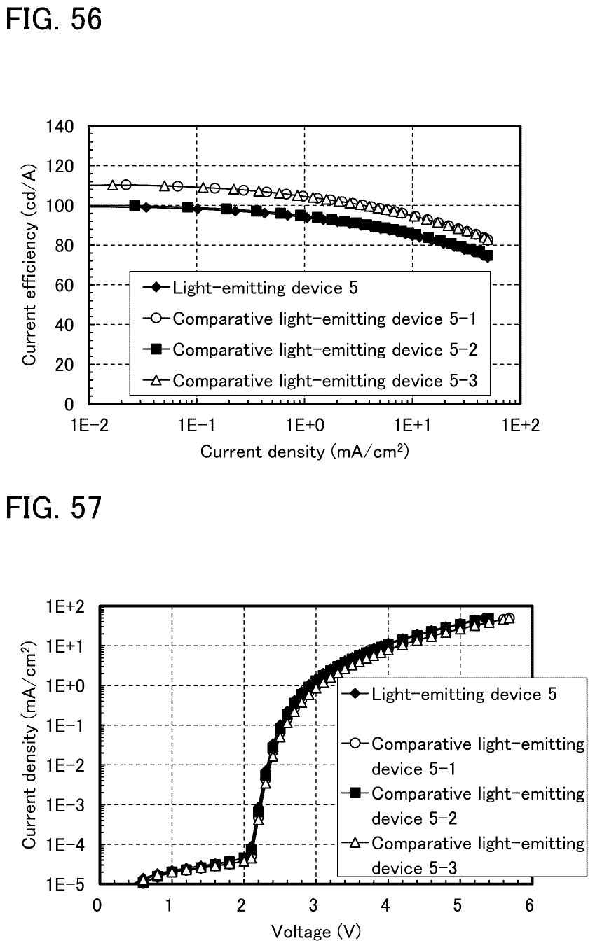

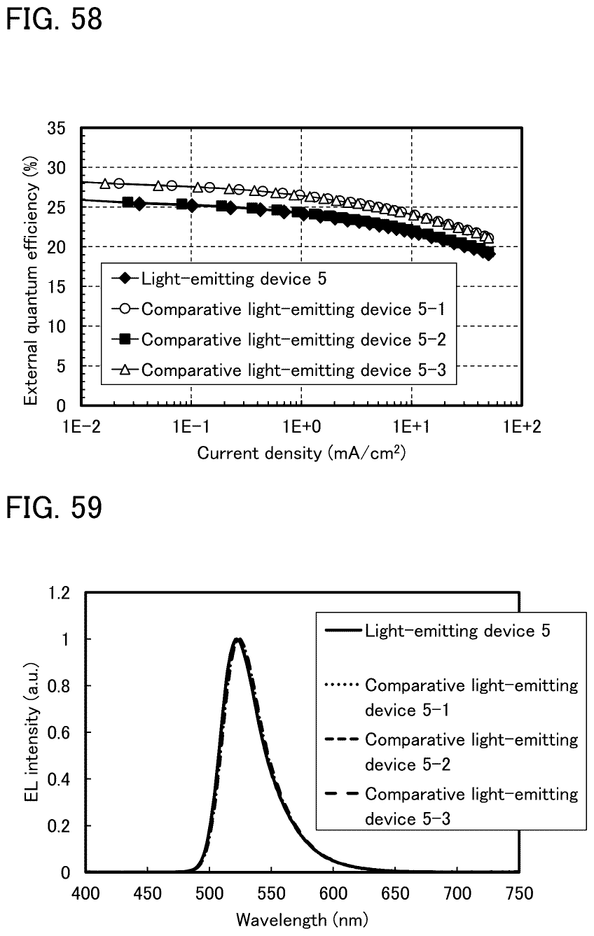

FIG. 54 shows the luminance-current density characteristics of the light-emitting device 5 and the comparative light-emitting devices 5-1 to 5-3. FIG. 55 shows the luminance-voltage characteristics thereof. FIG. 56 shows the current efficiency-current density characteristics thereof. FIG. 57 shows the current density-voltage characteristics thereof. FIG. 58 shows the external quantum efficiency-current density characteristics thereof. FIG. 59 shows the electroluminescence spectra thereof.

The values of the voltage, current, current density, CIE chromaticity, current efficiency, and external quantum efficiency at around 1000 cd/cm² are shown below. The luminance, CIE chromaticity, and electroluminescence spectra were measured at normal temperature with a spectroradiometer (SR-UL1R, TOPCON TECHNOHOUSE CORPORATION).

TABLE 20

| | | | | | | | External |
|---|---|---|---|---|---|---|---|
| | | | Current | | | Current | quantum |
| | Voltage | Current | density | Chromaticity | Chromaticity | efficiency | efficiency |
| | (V) | (mA) | (mA/cm²) | x | y | (cd/A) | (%) |
| Light-emitting | 2.8 | 0.033 | 0.83 | 0.31 | 0.65 | 96 | 25 |
| device 5 | | | | | | | |
| Comparative | 3.0 | 0.046 | 1.14 | 0.32 | 0.64 | 102 | 27 |
| light-emitting | | | | | | | |
| device 5-1 | | | | | | | |
| Comparative | 3.0 | 0.040 | 1.00 | 0.32 | 0.64 | 103 | 27 |
| light-emitting | | | | | | | |
| device 5-2 | | | | | | | |
| Comparative | 2.9 | 0.045 | 1.11 | 0.31 | 0.65 | 95 | 25 |
| light-emitting | | | | | | | |
| device 5-3 | | | | | | | |

FIGS. 54 to 59 and Table 20 show that the light-emitting device 5 and the comparative light-emitting devices 5-1 to 5-3 have favorable initial characteristics with equivalent emission efficiencies and driving voltages.

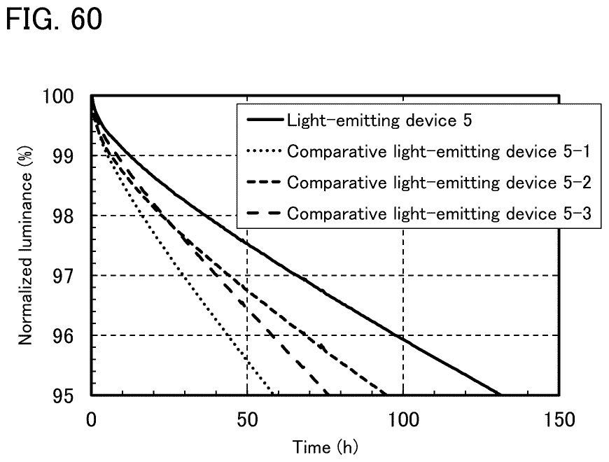

FIG. 60 shows the time dependence of normalized luminance of the light-emitting device 5 and the comparative light-emitting devices 5-1 to 5-3 at a current density of 50 mA/cm².

FIG. 60 shows that the light-emitting device 5 of one embodiment of the present invention has lower time dependence of normalized luminance than the comparative light-emitting devices 5-1 to 5-3 and has high reliability.

### Example 6

In this example, fabricating methods and characteristics of a light-emitting device 6 of one embodiment of the present invention and a comparative light-emitting device 6 which is a comparative example will be described in detail. Structural formulae of main compounds used for the light-emitting device 6 and the comparative light-emitting device 6 are shown below.

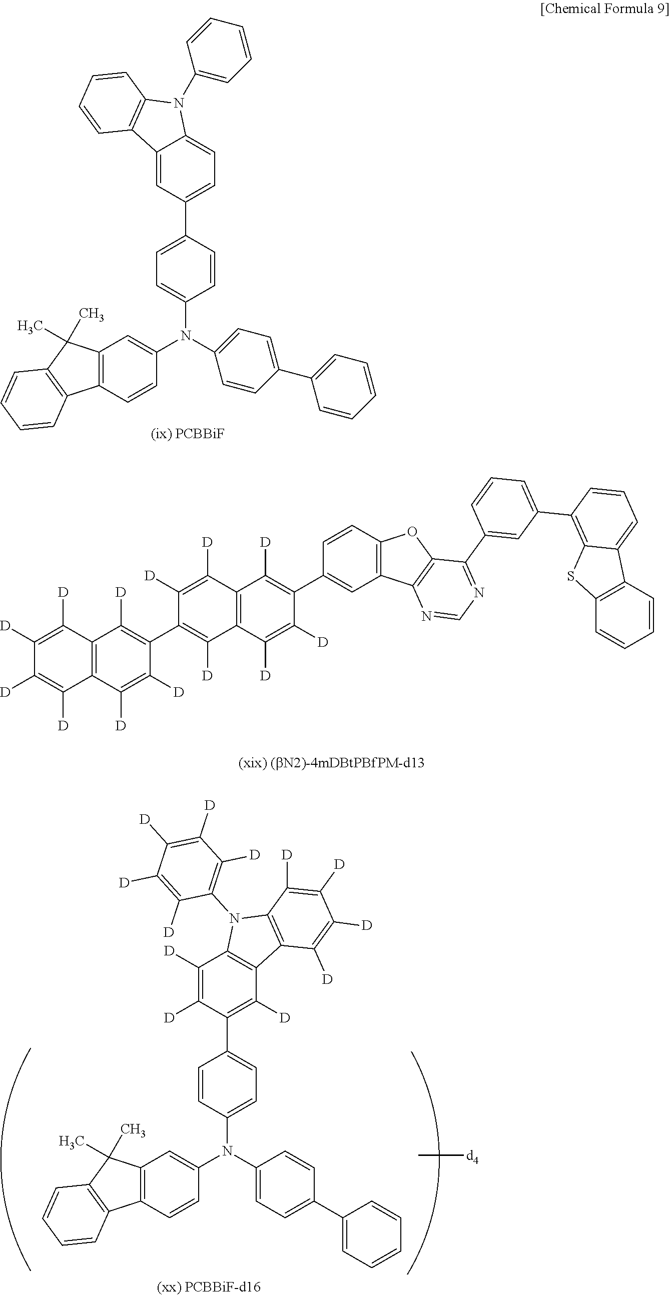

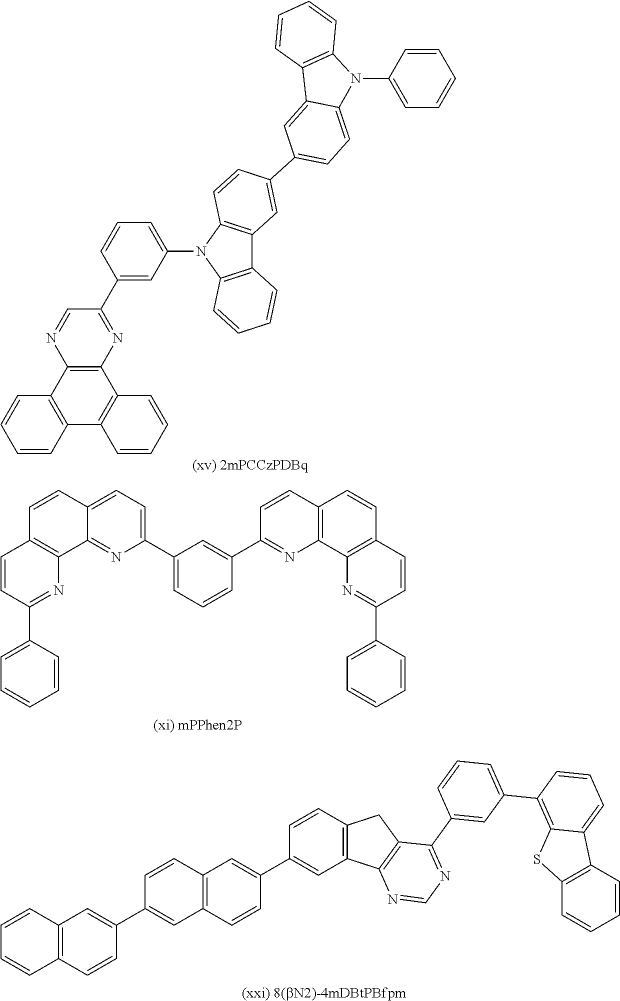

### (Fabrication Method of Light-Emitting Device 6)

First, indium tin oxide containing silicon oxide (ITSO) was deposited over a glass substrate to a thickness of 110 nm by a sputtering method, so that the first electrode 101 having a size of 2 mm×2 mm was formed. Note that the first electrode 101 serves as an anode.

Then, pretreatment for formation of the light-emitting device over the substrate was performed by washing the substrate surface with water.

After that, the substrate was transferred into a vacuum evaporation apparatus where the pressure was reduced to approximately 1×10⁻⁴ Pa, and was subjected to vacuum baking at 170° C. for 30 minutes in a heating chamber of the vacuum evaporation apparatus, and then the substrate was cooled down for approximately 30 minutes.

Next, the substrate was fixed to a holder provided in the vacuum evaporation apparatus such that the side on which the first electrode 101 was formed faced downward. Then, over an inorganic insulating film and the first electrode 101, N-(biphenyl-4-yl)-N-[4-(9-phenyl-9H-carbazol-3-yl)phenyl]-9,9-dimethyl-9H-fluoren-2-amine (abbreviation: PCBBiF) represented by Structural Formula (ix) above and a fluorine-containing electron acceptor material (OCHD-003) with a molecular weight of 672 were deposited by co-evaporation to a thickness of 10 nm such that the weight ratio of PCBBiF to OCHD-003 was 1:0.03; thus, the hole-injection layer 111 was formed.

Over the hole-injection layer 111, PCBBiF was deposited by evaporation to a thickness of 50 nm, so that the hole-transport layer 112 was formed.

Then, over the hole-transport layer 112, 8-[(2,2′-binaphthalen-1,3,4,5,7,8,1′,3′,4′,5′,6′,7′,8′-d13)-6-yl]-4-[3′-(dibenzothiophen-4-yl)biphenyl-3-yl]-[1]benzofuro[3,2-d]pyrimidine (abbreviation: 8(PN2)-4mDBtPBfpm-d13) represented by Structural Formula (xix) above, N-(biphenyl-4-yl)-N-{4-[9-(phenyl-2,3,4,5,6-d5)-9H-carbazol-3-yl-1,2,4,5,6,7,8-d7]phenyl}-9,9-dimethyl-9H-fluoren-2-amine-d4 (abbreviation: PCBBiF-d16) represented by Structural Formula (xx) above, and OCPG-006 that is a red phosphorescent material were deposited by co-evaporation to a thickness of 40 nm such that the weight ratio of 8(PN2)-4mDBtPBfpm-d13, PCBBiF-d16, and OCPG-006 was 0.6: 0.4: 0.05, so that the light-emitting layer 113 was formed.

After that, 2-{3-[3-(N-phenyl-9H-carbazol-3-yl)-9H-carbazol-9-yl]phenyl}dibenzo[f,h]quinoxaline (abbreviation: 2mPCCzPDBq) represented by Structural Formula (xv) above was deposited by evaporation to a thickness of 20 nm to form the first electron-transport layer, and then 2,2′-(1,3-phenylene)bis(9-phenyl-1,10-phenanthroline) (abbreviation: mPPhen2P) represented by Structure Formula (xi) above was deposited by evaporation to a thickness of 20 nm to form the second electron-transport layer, so that the electron-transport layer 114 was formed.

Then, lithium fluoride (LiF) was deposited by evaporation to a thickness of 1 nm to form the electron-injection layer 115, and then aluminum (Al) was deposited by evaporation to a thickness of 200 nm to form the second electrode 102.

Then, the light-emitting device was sealed using a glass substrate in a glove box containing a nitrogen atmosphere so as not to be exposed to the air. Specifically, a UV curable sealing material was applied to surround the device, only the sealing material was irradiated with UV while the light-emitting device was not irradiated with the UV, and heat treatment was performed at 80° C. under an atmospheric pressure for one hour. In this manner, the light-emitting device 6 was fabricated.

### (Fabrication Method of Comparative Light-Emitting Device 6)

The comparative light-emitting device 6 was fabricated in a manner similar to that of the light-emitting device 6 except that 8(PN2)-4mDBtPBfpm-d13 in the light-emitting device 6 was replaced with 8-[(2,2′-binaphthalen)-6-yl]-4-[3-(dibenzothiophen-4-yl)phenyl]-[1]benzofuro[3,2-d]pyrimidine (abbreviation: 8(PN2)-4mDBtPBfpm) represented by Structural Formula (xii) above and PCBBiF-d16 was replaced with PCBBiF.

Device structures of the light-emitting device 6 and the comparative light-emitting device 6 are shown below.

TABLE 21

| | | |
|---|---|---|
| Film | | Comparative |
| thickness | Light-emitting | light-emitting |
| (nm) | device 6 | device 6 |

| | | |
|---|---|---|
| Second electrode | 200 | Al |
| Electron-injection layer | 1 | LiF |
| Electron-transport layer | 20 | mPPhen2P |
| | 20 | 2mPCCzPDBq |
| Light-emitting layer | 40 | *6 |
| Hole-transport layer | 50 | PCBBiF |
| Hole-injection layer | 10 | PCBBiF:OCHD-003 (1:0.03) |
| First electrode | 110 | ITSO |

TABLE 22

| | *6 |
|---|---|
| Light-emitting | 8(βN2)-4mDBtPBfpm-d13:PCBBiF-d16:OCPG-006 |
| device 6 | (0.6:0.4:0.05) |
| Comparative | 8(βN2)-4mDBtPBfpm:PCBBiF:OCPG-006 |
| light-emitting | (0.6:0.4:0.05) |
| device 6 | |

Here, 8(βN2)-4mDBtPBfpm is a non-deuterated organic compound of 8(βN2)-4mDBtPBfpm-d13, and PCBBiF is a non-deuterated organic compound of PCBBiF-d16.

FIG. 67 shows the PL spectra of the following films each formed over a quartz substrate to have a thickness of 50 nm: a thin film of 8(βN2)-4mDBtPBfpm-d13, a thin film of PCBBiF-d16, and a mixed film of 8(βN2)-4mDBtPBfpm-d13 and PCBBiF-d16 obtained by depositing 8(βN2)-4mDBtPBfpm-d13 and PCBBiF-d16 by co-evaporation in a weight ratio of 0.6:0.4. The PL spectrum was measured with a fluorescence spectrophotometer (FP-8600DS, JASCO Corporation). As shown in FIG. 67, the PL spectrum of the mixed film is positioned on the longer wavelength side than the PL spectra of the films of the single materials, indicating that 8(βN2)-4mDBtPBfpm-d13 and PCBBiF-d16 form an exciplex.

The phosphorescence lifetimes of PCBBiF, PCBBiF-d16, 8(βN2)-4mDBtPBfpm, and 8(βN2)-4mDBtPBfpm-d13 and the rate of change in phosphorescence lifetime owing to deuteration are shown below. The product of the rates was 2.85. Note that the excitation wavelengths of PCBBiF and PCBBiF-d16 were each 350 nm and the measured wavelengths were 489 nm and 488 nm. The excitation wavelengths of 8(βN2)-4mDBtPBfpm and 8(βN2)-4mDBtPBfpm-d13 were each 330 nm and the measured wavelengths were 570 nm and 574 nm.

TABLE 23

| | Phosphorescence | Increasing rate |
|---|---|---|
| | lifetime | (Deuterated/ |
| | (seconds) | Non-deuterated) |
| PCBBiF | 0.8 | 1.05 |
| PCBBiF-d16 | 0.84 | |
| 8(βN2)-4mDBtPBfpm | 2.29 | 2.71 |
| 8(βN2)-4mDBtPBfpm-d13 | 6.21 | |

The T₁ level of PCBBiF-d16 was 2.49 eV, the T₁ level of 8(βN2)-4mDBtPBfpm-d13 was 2.25 eV, and the difference therebetween was 0.24 eV.

The 5% weight loss temperature of PCBBiF-d16 at 10 Pa was 265° C., the 5% weight loss temperature of 8(βN2)-4mDBtPBfpm-d13 at 10 Pa was 315° C., and the difference therebetween was 50° C.

Note that the phosphorescent lifetime, the T₁ level, and the 5% weight loss temperature were calculated in a manner similar to that in Example 1.

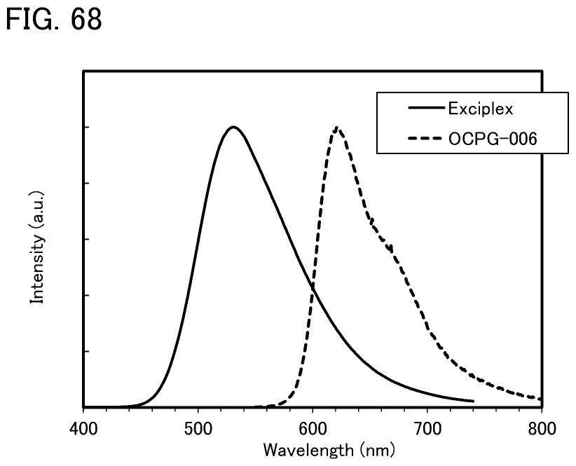

As shown in FIG. 68, the PL spectrum of the exciplex formed by PCBBiF-d16 and 8(βN2)-4mDBtPBfpm-d13 and the PL spectrum of OCPG-006 include an overlap. The PL spectrum of OCPG-006 in a dichloromethane solution was measured with a fluorescence spectrophotometer (FP-8600DS, JASCO Corporation).

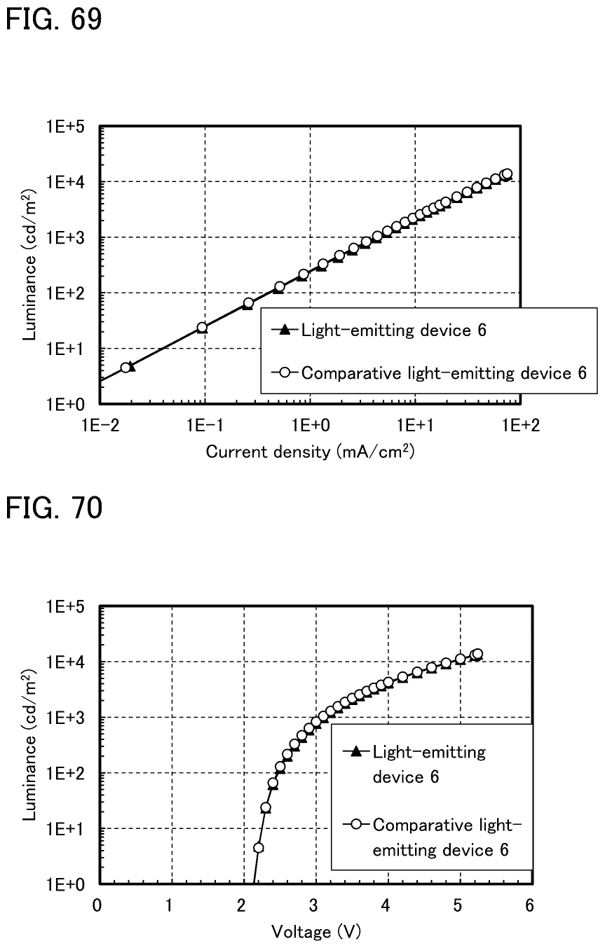

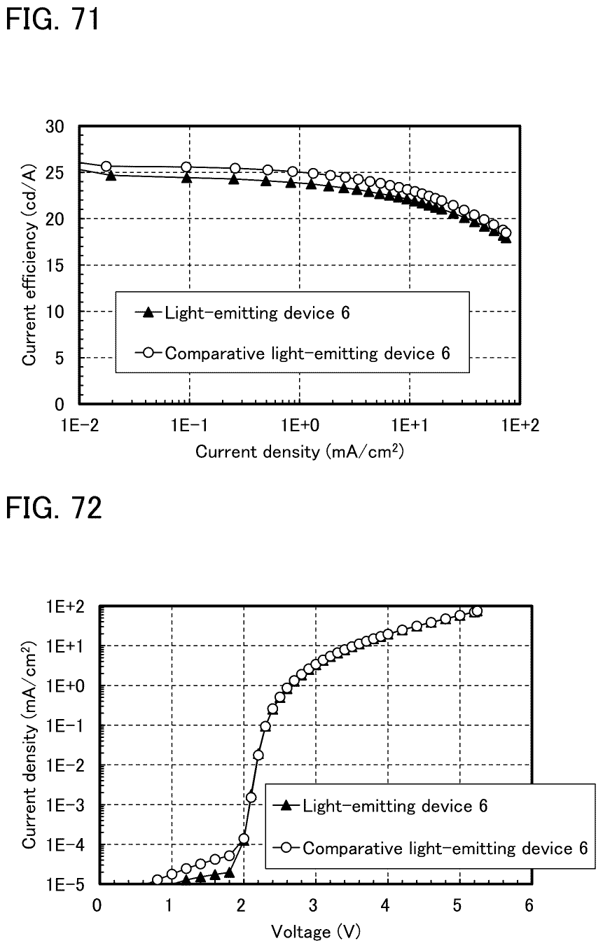

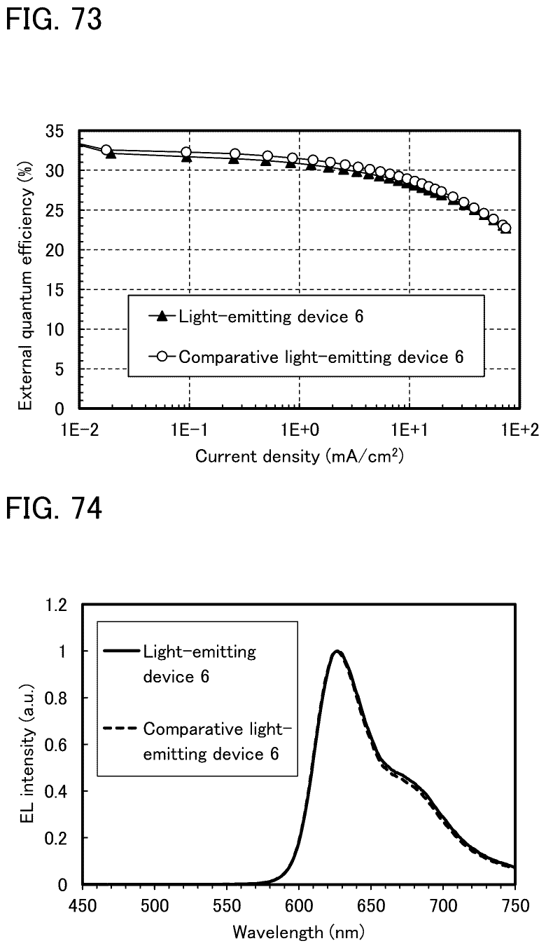

FIG. 69 shows the luminance-current density characteristics of the light-emitting device 6 and the comparative light-emitting device 6. FIG. 70 shows the luminance-voltage density characteristics thereof. FIG. 71 shows the current efficiency-current density characteristics thereof. FIG. 72 shows the current density-voltage characteristics thereof. FIG. 73 shows the external quantum efficiency-current density characteristics thereof. FIG. 74 shows the electroluminescence spectra thereof.

The values of the voltage, current, current density, CIE chromaticity, current efficiency, and external quantum efficiency at around 1000 cd/cm² are shown below. The luminance, CIE chromaticity, and electroluminescence spectra were measured at normal temperature with a spectroradiometer (SR-UL1R, TOPCON TECHNOHOUSE CORPORATION).

TABLE 24

| | | | | | | | External |
|---|---|---|---|---|---|---|---|
| | | | Current | | | Current | quantum |
| | Voltage | Current | density | Chromaticity | Chromaticity | efficiency | efficiency |
| | (V) | (mA) | (mA/cm²) | x | y | (cd/A) | (%) |
| Light-emitting | 3.1 | 0.170 | 4.26 | 0.69 | 0.31 | 23 | 30 |
| device 6 | | | | | | | |
| Comparative | 3.1 | 0.175 | 4.36 | 0.69 | 0.31 | 24 | 30 |
| light-emitting | | | | | | | |
| device 6 | | | | | | | |

FIGS. 69 to 74 and Table 23 show that the light-emitting device 6 and the comparative light-emitting device 6 have favorable initial characteristics with equivalent emission efficiencies and driving voltages. It is also shown that the light-emitting device 6 and the comparative light-emitting device 6 each have an electroluminescence spectrum peak at a wavelength of 627 nm, and exhibit blue light emission derived from OCPG-006.

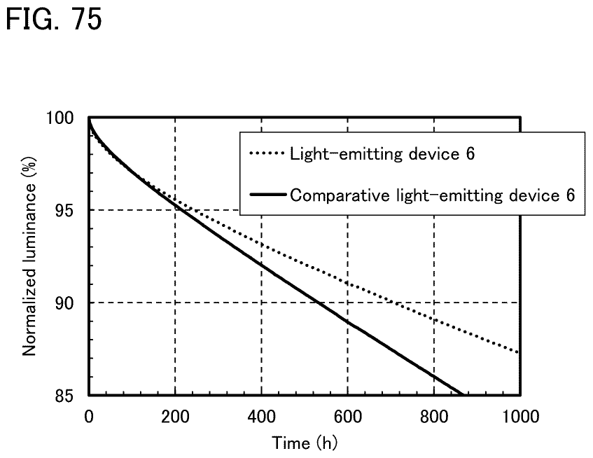

FIG. 75 shows the time-dependence of normalized luminance of the light-emitting device 6 and the comparative light-emitting device 6 at a current density of 50 mA/cm².

FIG. 75 shows that the light-emitting device 6 of one embodiment of the present invention, whose light-emitting layer contains two kinds of host materials each containing deuterium, has lower time dependence of normalized luminance than the comparative light-emitting device 6 and has high reliability.

### Example 7

### Synthesis Example 1

In this synthesis example, a synthesis method of 8-[(2,2′-binaphthalen-1,3,4,5,7,8,1′,3′,4′,5′,6′,7′,8′-d13)-6-yl]-4-[3′-(dibenzothiophen-4-yl)biphenyl-3-yl]-[1]benzofuro[3,2-d]pyrimidine (abbreviation: 8(βN2)-4mDBtPBfpm-d13) represented by a structural formula below is described in detail. The structural formula of 8(βN2)-4mDBtPBfpm-d13 is shown below.

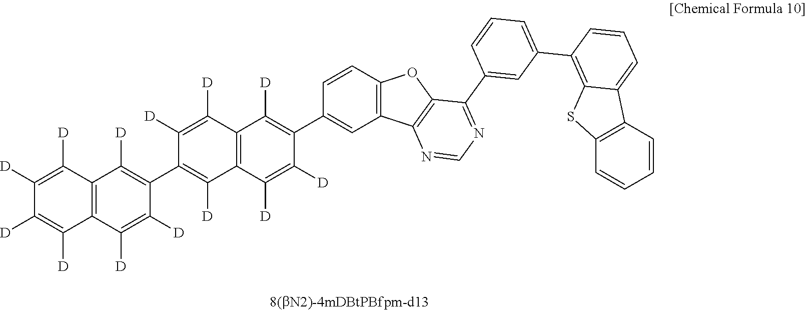 [SMILES: [2H]c1c([2H])c([2H])c2c([2H])c(-c3c([2H])c([2H])c4c([2H])c(-c5ccc6oc7c(-c8cccc(-c9cccc%10c9sc9ccccc9%10)c8)ncnc7c6c5)c([2H])c([2H])c4c3[2H])c([2H])c([2H])c2c1[2H]]

### Step 1: Synthesis of 2,6-dibromonaphtahalane-d6

Into a 100-mL three-neck flask equipped with a reflux pipe were put 8.0 g (28 mmol) of 2,6-dibromonaphthalene and 41 mL of toluene-d8, and the mixture was stirred while being heated at 70° C. to dissolve 2,6-dibromonaphthalene. After 2,6-dibromonaphthalene was completely dissolved, 6.8 g (28 mmol) of molybdenum(V) chloride was added little by little, and the mixture was stirred while being heated at 100° C. for 2 hours and then stirred at room temperature for 16 hours. Chloroform was added to the flask and an insoluble matter was removed by suction filtration. Water was added to the obtained filtrate and an aqueous phase was subjected to extraction with chloroform. Magnesium sulfate was added to the solution of the extract for drying, and magnesium sulfate was removed by gravity filtration. The obtained filtrate was concentrated under reduced pressure and purified by high performance liquid chromatography (mobile phase: chloroform) to give 6.1 g of a target pale brown solid in a yield of 74%. Synthesis Scheme (A-1) of Step 1 is shown below.

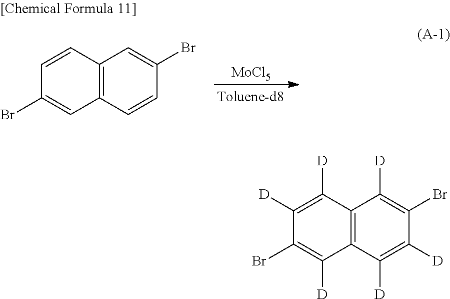

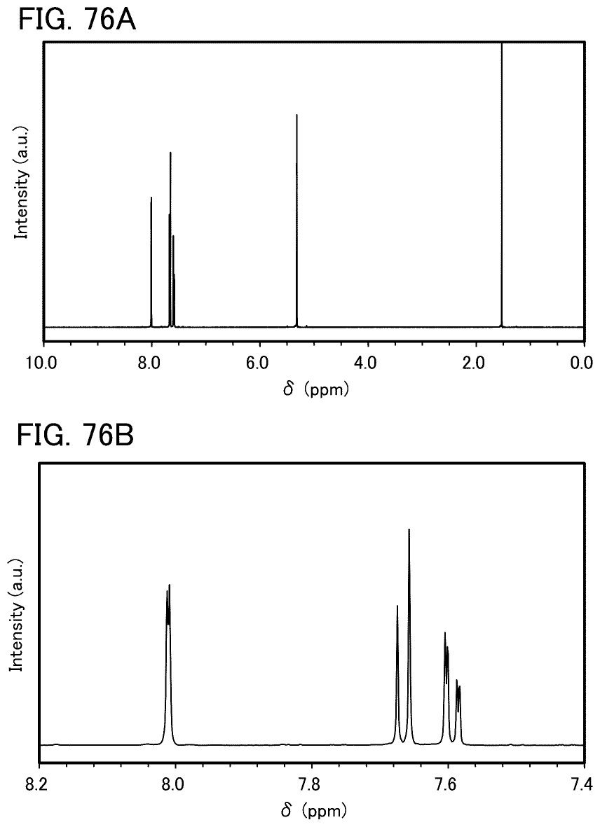

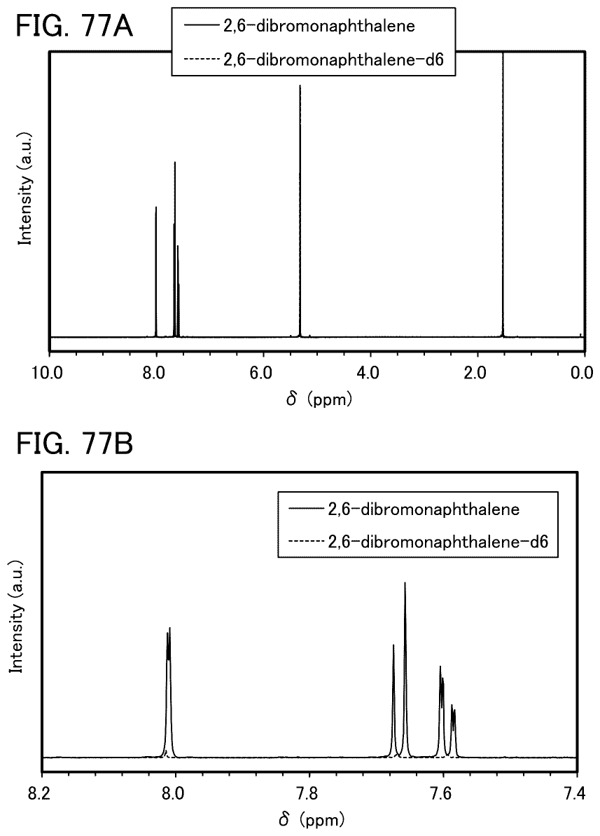

The ¹H NMR spectrum of the pale brown solid obtained in Step 1 was measured and compared with that of 2,6-dibromonaphthalene. FIG. 76A shows the ¹H NMR spectrum of 2,6-dibromonaphthalene that is a non-deuterated substance of 2,6-dibromonaphthalene-d6, and FIG. 77A shows the ¹H NMR spectra of the pale brown solid obtained in Step 1 and 2,6-dibromonaphthalene, which overlap with each other. FIG. 76B is an enlarged chart of FIG. 76A in the range of δ=7.40 ppm to 8.20 ppm, and FIG. 77B is an enlarged chart of FIG. 77A in the range of δ=7.40 ppm to 8.20 ppm.

It is found that the ¹H NMR spectrum of the pale brown solid obtained by the reaction of Synthesis Scheme (A-1) in Step 1, which is a deuteration reaction, has a smaller peak than the ¹H NMR spectrum of 2,6-dibromonaphthalene, which is the source material, or no peak. Thus, it can be determined that 2,6-dibromonaphthalene-d6 was obtained by the reaction of Synthesis Scheme (A-1) in Step 1.

Next, the deuteration rate of 2,6-dibromonaphthalene-d6 obtained in Step 1 was estimated using the ¹H NMR chart.

The sample for the ¹H NMR measurement was fabricated by adding 12.6 mg (43 μmol) of 2,6-dibromonaphthalene-d6, 10 μL (0.11 mmol) of 1,1,2-trichloroethane, and 3 mL of deuterated dichloromethane to a 10-mL brown vial and mixing the materials so as to obtain a homogeneous solution.

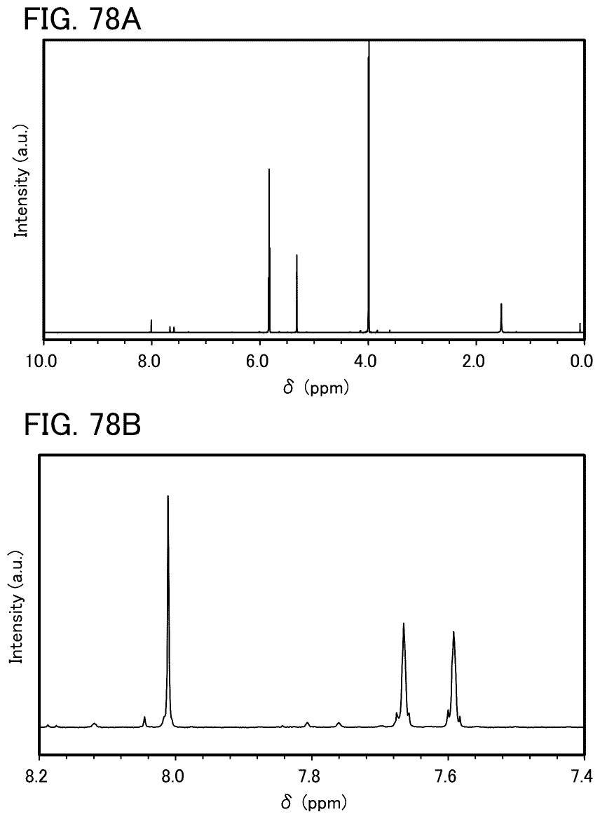

FIG. 78A shows the ¹H NMR spectrum of the above-described sample, and FIG. 78B is an enlarged chart of FIG. 78A in the range of δ=7.40 ppm to 8.20 ppm. In FIGS. 78A and 78B, peaks at around δ=7.59 ppm to 8.01 ppm or other small peaks are considered to be derived from protium that was not deuterated and remained in a product (2,6-dibromonaphthalene-d6) resulting from the reaction of Synthesis Scheme (A-1). The deuteration rate of 2,6-dibromonaphthalene-d6 estimated using these peaks and the peaks of 1,1,2-trichloroethane (peaks at around 3.99 ppm and around 5.83 ppm) was approximately 92%.

### Step 2: Synthesis of 6′-bromo-2,2′-binaphthalene-1,1′,3,3′,4,4′,5,5′,6,7,7′,8,8′-d13

Into a 200-mL three-neck flask were put 6.0 g (21 mmol) of 2,6-dibromonaphthalene-d6, 4.4 g (21 mmol) of 4,4,5,5-tetramethyl-2-(2-naphthalenyl-1,3,4,5,6,7,8-d7)-1,3,2-dioxaborolane, 0.13 g (0.42 mmol) of tri(o-tolyl)phosphine, 5.7 g (41 mmol) of potassium carbonate, 80 mL of toluene, 20 mL of ethanol, and 20 mL of water, the mixture was degassed under reduced pressure, and the air in the flask was replaced with nitrogen. Then, 46 mg (0.21 mmol) of palladium(II) acetate was added to this mixture, and the obtained mixture was stirred at room temperature for 18 hours. After the stirring, water was added to the flask, and the precipitated solid was collected by suction filtration. The obtained solid was washed with toluene, ethanol, and water and dried to give 2.5 g of a target gray solid. A filtrate obtained by the suction filtration was separated into an aqueous phase and an organic phase, and the aqueous phase was subjected to extraction with toluene. The solution of the extract and the organic phase r were mixed and washed with water twice, and further washed with saturated saline. Then, magnesium sulfate was added to the mixture for drying, and magnesium sulfate was removed by gravity filtration. The obtained filtrate was concentrated under reduced pressure and dried in a vacuum to give 4.8 g of a brown solid. The brown solid was purified by high performance liquid chromatography (mobile phase: chloroform) to give 1.8 g of a target pale white solid. As a result, 4.3 g of the target substances were obtained in a yield of 60% in total. Synthesis Scheme (A-2) of Step 2 is shown below.

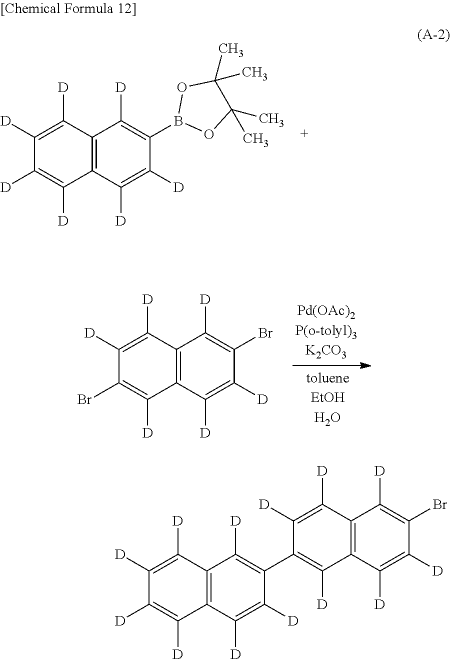 [SMILES: [2H]c1c([2H])c([2H])c2c([2H])c(B3OC(C)(C)C(C)(C)O3)c([2H])c([2H])c2c1[2H] ; [2H]c1c(Br)c([2H])c2c([2H])c([2H])c(Br)c([2H])c2c1[2H] ; [2H]c1c([2H])c([2H])c2c([2H])c(-c3c([2H])c([2H])c4c([2H])c(Br)c([2H])c([2H])c4c3[2H])c([2H])c([2H])c2c1[2H]]

The molecular weight of the pale white solid obtained in Step 2 was measured by LC/MS. As a result, the observed m/z of the target substance was 345, which corresponds to the calculated mass of 345 of 6′-bromo-2,2′-binaphthalene-1,1′,3,3′,4,4′,5,5′,6,7,7′,8,8′-d13. This indicates that 6′-bromo-2,2′-binaphthalene-1,1′,3,3′,4,4′,5,5′,6,7,7′,8,8′-d13 was obtained by the synthesis in Step 2.

Note that in the LC/MS analysis, liquid chromatography (LC) separation was performed with UltiMate 3000 produced by Thermo Fisher Scientific K.K., and mass spectrometry (MS) was performed with Q Exactive produced by Thermo Fisher Scientific K.K.

### Step 3: Synthesis of 2-(2,2′-binaphthalen-1,1′,3,3′,4,4′,5,5′,6′,7,7′,8,8′-d13)-6-yl-4,4,5,5-tetramethyl-1,3,2-dioxaborolane

Into a 200-mL three-neck flask equipped with a reflux pipe were put 4.3 g (12 mmol) of 6′-bromo-2,2′-binaphthalene-1,1′,3,3′,4,4′,5,5′,6,7,7′,8,8′-d13, 3.3 g (13 mmol) of bis(pinacolato)diboron (abbreviation: (Bpin)₂), 2.4 g (25 mmol) of potassium acetate, and 50 mL of 1,4-dioxane, the mixture was degassed under reduced pressure, and the air in the flask was replaced with nitrogen. To this mixture heated at 60° C. was added 0.10 g (0.12 mmol) of [1,1′-bis(diphenylphosphino)ferrocene]palladium(II) dichloride dichloromethane adduct, and the obtained mixture was stirred while being heated and refluxed at 110° C. for 3 hours. After the stirring, the resulting mixture was cooled to room temperature, and 1,4-dioxane in the flask was distilled off under reduced pressure. Then, toluene and water were added to the flask, and an aqueous phase was subjected to extraction with toluene. The obtained solution of the extract was washed with water twice, and further washed with saturated saline. Magnesium sulfate was added to the mixture for drying, and magnesium sulfate was removed by gravity filtration. The obtained filtrate was concentrated under reduced pressure and dried in a vacuum to give 5.8 g of a dark brown solid. The dark brown solid was purified by silica gel chromatography (developing solvent was set to ethyl acetate:hexane=1:10, and changed to ethyl acetate:hexane=1:8 in the middle), so that 4.1 g of a target white solid was obtained in a yield of 83%. Synthesis scheme (A-3) of Step 3 is shown below.

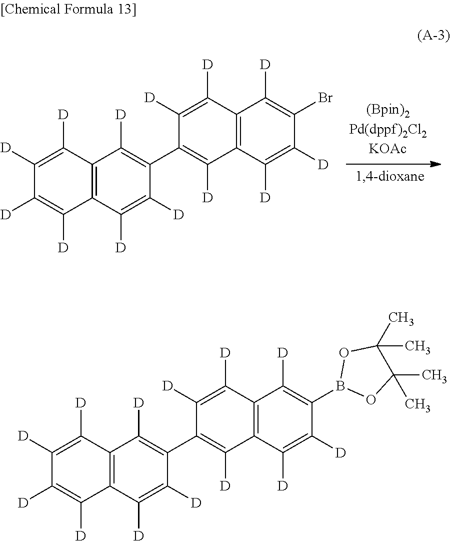 [SMILES: [2H]c1c([2H])c([2H])c2c([2H])c(-c3c([2H])c([2H])c4c([2H])c(Br)c([2H])c([2H])c4c3[2H])c([2H])c([2H])c2c1[2H] ; [2H]c1c([2H])c([2H])c2c([2H])c(-c3c([2H])c([2H])c4c([2H])c(B5OC(C)(C)C(C)(C)O5)c([2H])c([2H])c4c3[2H])c([2H])c([2H])c2c1[2H]]

The molecular weight of the white solid obtained in Step 3 was measured by LC/MS. As a result, the observed m/z was 393, which corresponds to the calculated mass of 393 of the target substance. This indicates that 2-(2,2′-binaphthalen-1,1′,3,3′,4,4′,5,5′,6′,7,7′,8,8′-d13)-6′-yl-4,4,5,5-tetramethyl-1,3,2-dioxaborolane was obtained.

The numerical data of ¹H NMR measurement results of the obtained solid are as follows.

¹H NMR (chloroform-d, 500 MHz): δ=1.41 (s, 12H).

### Step 4: Synthesis of (2,2′-binaphthalen-1,1′,3,3′,4,4′,5,5′,6′,7,7′,8,8′-d13)-6-yl-boronic acid

Into a 200-mL three-neck flask equipped with a reflux pipe were put 4.1 g (10 mmol) of 2-(2,2′-binaphthalen-1,1′,3,3′,4,4′,5,5′,6′,7,7′,8,8′-d13)-6′-yl-4,4,5,5-tetramethyl-1,3,2-dioxaborolane and 63 mL of 6M hydrochloric acid, and the mixture was stirred while being heated and refluxed at 110° C. for 11 hours. After the stirring, the mixture was cooled to room temperature. An insoluble matter was removed by suction filtration. Ethyl acetate was added to the flask and an aqueous phase was subjected to extraction three times. The solutions of the extracts obtained by the three extractions was washed with water twice, and further washed with saturated saline. Magnesium sulfate was added to the mixture for drying, and magnesium sulfate was removed by gravity filtration. The obtained filtrate was concentrated under reduced pressure and dried in a vacuum to give 2.5 g of a target pale yellow solid in a yield of 77%. Synthesis scheme (A-4) of Step 4 is shown below.

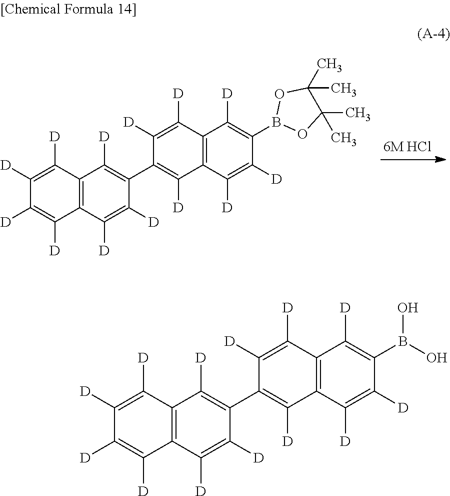 [SMILES: [2H]c1c([2H])c([2H])c2c([2H])c(-c3c([2H])c([2H])c4c([2H])c(B5OC(C)(C)C(C)(C)O5)c([2H])c([2H])c4c3[2H])c([2H])c([2H])c2c1[2H] ; [2H]c1c([2H])c([2H])c2c([2H])c(-c3c([2H])c([2H])c4c([2H])c(B(O)O)c([2H])c([2H])c4c3[2H])c([2H])c([2H])c2c1[2H]]

The molecular weight of the white solid obtained in Step 4 was measured by LC/MS. As a result, the observed m/z was 311, which corresponds to the calculated mass of 311 of the target substance. This indicates that (2,2′-binaphthalene-1,1′,3,3′,4,4′,5,5′,6′,7,7′,8,8′-d13)-6-yl-boronic acid was obtained.

The numerical data of ¹H NMR measurement results of the obtained solid are as follows.

¹H NMR (DMSO-d₆, 500 MHz): δ=8.25 (br, 2H).

### Step 5: Synthesis of 8(βN2)-4mDBtPBfpm-d13

Into a 100-mL three-neck flask equipped with a reflux pipe were put 2.3 g (7.4 mmol) of (2,2′-binaphthalen-1,1′,3,3′,4,4′,5,5′,6′,7,7′,8,8′-d13)-6-yl-boronic acid, 3.08 g (6.6 mmol) of 8-chloro-4-[3-(4-dibenzothienyl)phenyl]benzofuro[3,2-d]pyrimidine, 0.11 g (0.30 mmol) of di(1-adamantyl)-n-butylphosphine (abbreviation: cataCXium (registered trademark) A), 4.2 g (20 mmol) of tripotassium phosphate, 1.5 g (20 mmol) of tert-butyl alcohol, and 50 mL of diethylene glycol dimethyl ether, the mixture was degassed under reduced pressure, and the air in the flask was replaced with nitrogen. To this mixture heated at 60° C. was added 34 mg (0.15 mmol) of palladium(II) acetate, and the obtained mixture was stirred while being heated and refluxed at 130° C. for 3 hours. Then, 34 mg (0.15 mmol) of palladium(II) acetate and 0.11 g (0.30 mmol) of cataCXium (registered trademark) A were added to this mixture, and the obtained mixture was stirred while being heated and refluxed at 130° C. for 7 hours. After the stirring, the mixture was cooled to room temperature and 500 mL of water was added to the flask. The precipitated solid was collected by suction filtration and washed with toluene, ethanol, and water. The obtained solid was dissolved in 3.5 L of heated toluene, and purification was performed by suction filtration through Celite (Catalog No. 537-02305, FUJIFILM Wako Pure Chemical Corporation), Alumina, and Florisil (Catalog No. 066-05265, FUJIFILM Wako Pure Chemical Corporation). The obtained filtrate was concentrated and the obtained solid was recrystallized with heated toluene to give 1.3 g of a target white solid in a yield of 27%. Synthesis Scheme (A-5) of Step 5 is shown below.

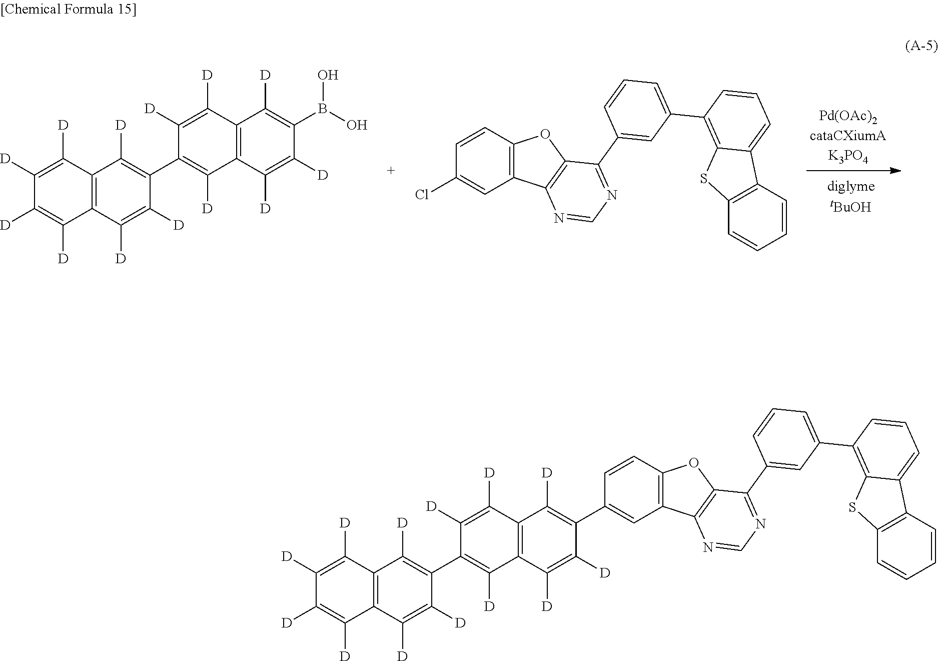 [SMILES: [2H]c1c([2H])c([2H])c2c([2H])c(-c3c([2H])c([2H])c4c([2H])c(B(O)O)c([2H])c([2H])c4c3[2H])c([2H])c([2H])c2c1[2H] ; Clc1ccc2oc3c(-c4cccc(-c5cccc6c5sc5ccccc56)c4)ncnc3c2c1 ; [2H]c1c([2H])c([2H])c2c([2H])c(-c3c([2H])c([2H])c4c([2H])c(-c5ccc6oc7c(-c8cccc(-c9cccc%10c9sc9ccccc9%10)c8)ncnc7c6c5)c([2H])c([2H])c4c3[2H])c([2H])c([2H])c2c1[2H]]

By a train sublimation method, 0.78 g of the obtained solid was purified. In the purification by sublimation, the solid was heated at 335° C. to 345° C. under a pressure of 2.4 Pa with an argon flow rate of 17 mL/min for 53 hours, and a solid precipitated at 260° C. was collected. As a result, 0.62 g of a pale yellow solid was obtained at a collection rate of 79%.

The molecular weight of the pale yellow solid obtained in Step 5 was measured by LC/MS. As a result, the observed m/z was 694, which corresponds to the calculated mass of 694 of the target substance.

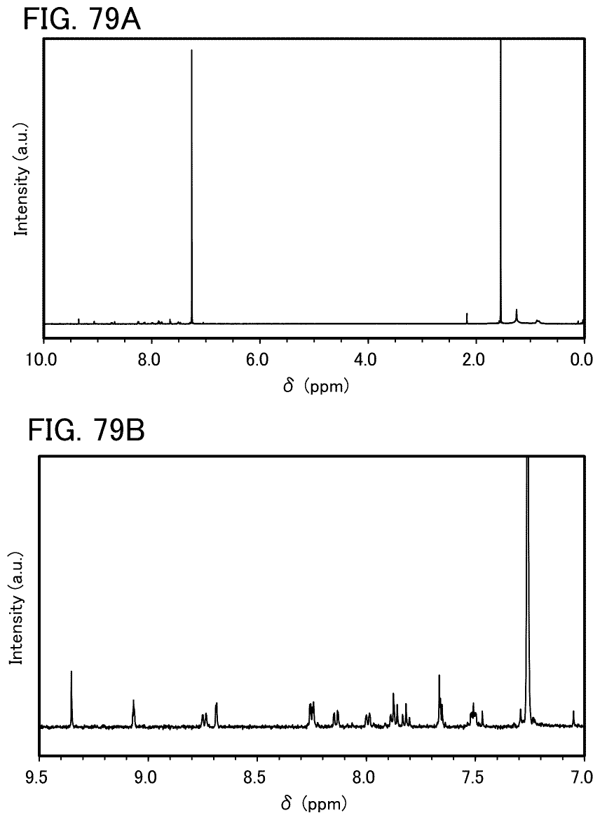

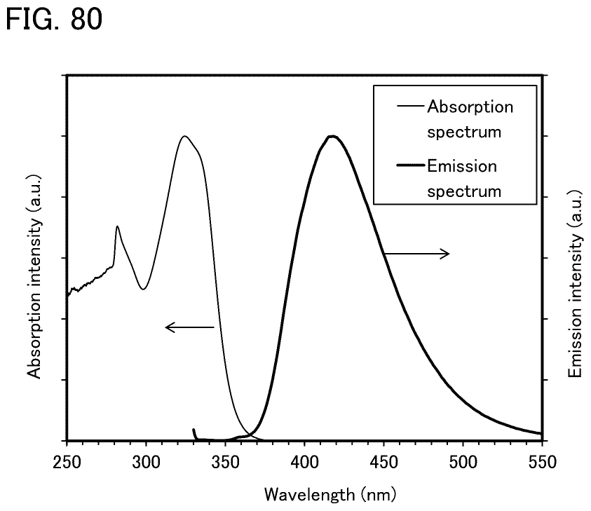

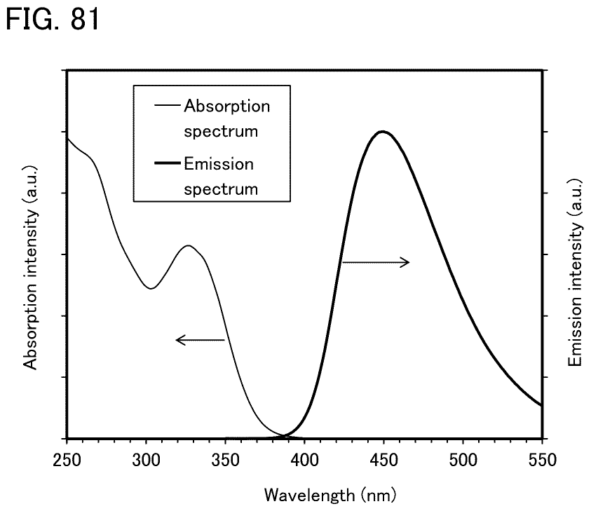

FIGS. 79A and 79B are ¹H NMR charts of the obtained solid. Note that FIG. 79B is an enlarged chart of FIG. 79A in the range of 7.0 ppm to 9.5 ppm. In addition, numerical data is shown below.

¹H NMR (chloroform-d2, 500 MHz): δ=9.35 (s, 1H), 9.07 (d, J=2.0 Hz, 1H), 8.74 (d, J=8.5 Hz, 1H), 8.69 (d, J=2.5 Hz, 1H), 8.25 (d, J=9.0 Hz, 2H), 8.14 (dd, J1=10 Hz, J2=2.5 Hz, 1H), 7.99 (d, J=8.5 Hz, 1H), 7.89-7.86 (m, 2H), 7.81 (t, J=8.0 Hz, 1H), 7.67-7.65 (m, 2H), 7.52-7.47 (m, 2H).

The above results reveal that 8(βN2)-4mDBtPBfpm-d13 was obtained in this synthesis example.

### <Measurement of Physical Properties>

Then, the ultraviolet-visible absorption spectra (hereinafter, simply referred to as “absorption spectra”) and PL spectra of 8(βN2)-4mDBtPBfpm-d13 in a toluene solution and a thin film of 8(βN2)-4mDBtPBfpm-d13 were measured.

The absorption spectrum of the solution was measured with an ultraviolet-visible spectrophotometer (V-770DS, JASCO Corporation), and the absorption spectrum of the thin film was measured with an ultraviolet-visible spectrophotometer (U-4100, Hitachi-High-Tech Corporation). The PL spectrum was measured with a fluorescence spectrophotometer (FP-8600DS, JASCO Corporation).

To calculate the absorption spectrum of 8(βN2)-4mDBtPBfpm-d13 in a toluene solution, the absorption spectrum of toluene put in a quartz cell was measured and then subtracted from the absorption spectrum of the toluene solution of 8(βN2)-4mDBtPBfpm-d13 put in a quartz cell.

To obtain the absorption spectrum and the PL spectrum of the thin film, a measurement sample was measured. The measurement sample was fabricated in the following manner: 8(βN2)-4mDBtPBfpm-d13 was deposited over a quartz substrate by a vacuum evaporation method and sealed using another quartz substrate as a counter substrate. Note that the PL spectrum was obtained by measurement of the measurement sample sealed, and the absorption spectrum was obtained by measurement of the sample from which the sealing was removed and the counter substrate was detached. The absorption spectrum was obtained by subtraction of an absorption spectrum of a quartz substrate from an absorption spectrum of a 8(βN2)-4mDBtPBfpm-d13 film formed over a quartz substrate.

FIGS. 80 and 81 show the measurement results of the toluene solution and the thin film, respectively. The measurement results show that 8(βN2)-4mDBtPBfpm-d13 in the toluene solution has an absorption peak at around 337 nm, the thin film of 8(βN2)-4mDBtPBfpm-d13 has an absorption peak at around 329 nm, and there is no absorption band on a longer wavelength side than 430 nm in both cases of the toluene solution and the thin film. This reveals that in the case where 8(βN2)-4mDBtPBfpm-d13 is used as a light-emitting element, a reduction in emission efficiency caused by absorption does not occur at a wavelength used in a display and thus 8(βN2)-4mDBtPBfpm-d13 can be suitably used. In addition, 8(βN2)-4mDBtPBfpm-d13 in the toluene solution exhibited an emission peak at around 418 nm (excitation wavelength: 324 nm), and the thin film of 8(βN2)-4mDBtPBfpm-d13 exhibited an emission peak at around 449 nm (excitation wavelength: 340 nm).

The HOMO level and the LUMO level of 8(βN2)-4mDBtPBfpm-d13 were obtained through a cyclic voltammetry (CV) measurement. The calculation method is described below.

An electrochemical analyzer (ALS model 600A or 600C, BAS Inc.) was used as a measurement apparatus. To prepare a solution for the CV measurement, dehydrated dimethylformamide (DMF; Sigma-Aldrich Inc., 99.8%, catalog No. 22705-6) was used as a solvent, and tetra-n-butylammonium perchlorate (n-Bu₄NClO₄; Tokyo Chemical Industry Co., Ltd., catalog No. T0836) as a supporting electrolyte was dissolved at a concentration of 100 mmol/L. Furthermore, the measurement target was also dissolved at a concentration of 2 mmol/L.

A platinum electrode (PTE platinum electrode, BAS Inc.) was used as a working electrode, a platinum electrode (Pt counter electrode for VC-3 (5 cm), BAS Inc.) was used as an auxiliary electrode, and an Ag/Ag+ electrode (RE-7 nonaqueous reference electrode, BAS Inc.) was used as a reference electrode. Note that the measurement was performed at room temperature (20° C. to 25° C.). The scan speed in the CV measurement was fixed to 0.1 V/sec, and an oxidation potential Ea [V] and a reduction potential Ec [V] with respect to the reference electrode were measured. The potential Ea is an intermediate potential of an oxidation-reduction wave, and the potential Ec is an intermediate potential of a reduction-oxidation wave. Here, since the potential energy of the reference electrode used in this example with respect to the vacuum level is known to be −4.94 [eV], the HOMO level and the LUMO level can be calculated by the following formulae: HOMO level [eV]−4.94−Ea and LUMO level [eV]−4.94−Ec.

The CV measurement was repeated 100 times, and the oxidation-reduction wave in the 100th cycle was compared with the oxidation-reduction wave in the first cycle to examine the electrical stability of the compound.

As a result, in the measurement of the oxidation potential Ea [V] of 8(βN2)-4mDBtPBfpm-d13, the HOMO level was found to be around −6.0 eV. In contrast, the LUMO level was found to be −3.03 eV in the measurement of the reduction potential Ec [V]. In addition, the results of repetitive measurement of the oxidation-reduction wave showed that when the waveform of the first cycle was compared with that of the 100th cycle, 87% of the peak intensity were maintained in the Ec measurement, which confirmed that 8(βN2)-4mDBtPBfpm-d13 had high resistance to repetitive reduction.

Differential scanning calorimetry (DSC) measurement of 8(βN2)-4mDBtPBfpm-d13 was performed with DSC8500 produced by PerkinElmer, Inc. The DSC measurement was performed in the following manner: the temperature was raised from −10° C. to 320° C. at a temperature rising rate of 40° C./min and held for three minutes, and then the temperature was decreased to −10° C. at a temperature decreasing rate of 100° C./min and held for three minutes. This operation was performed twice in succession. The results of the DSC measurement in the second cycle shows that the glass transition point of 8(βN2)-4mDBtPBfpm-d13 is 119° C. This indicates that 8(βN2)-4mDBtPBfpm-d13 is a substance having extremely high heat resistance and the film of 8(βN2)-4mDBtPBfpm-d13 can maintain a thermally stable quality.

Thermogravimetry-differential thermal analysis (TG-DTA) was performed on 8(βN2)-4mDBtPBfpm-d13. For the measurement, a high-sensitivity differential type differential thermogravimeter (STA-2500 Regulus, NETZSCH Japan K.K.) was used. The measurement was performed under two conditions. The first measurement was performed at atmospheric pressure at a temperature rising rate of 10° C./min under a nitrogen stream (flow rate: 200 mL/min). The second measurement was performed at a pressure of 10 Pa at a temperature rising rate of 10° C./min under a nitrogen stream (flow rate: 1.0 mL/min). Note that 3 mg of 8(βN2)-4mDBtPBfpm-d13 was used for the analysis.

In the thermogravimetry-differential thermal analysis performed under the first measurement condition, the temperature (5% weight loss temperature or decomposition temperature) at which the weight of 8(βN2)-4mDBtPBfpm-d13 obtained by thermogravimetry was reduced by 5% of the weight at the start of the measurement was found to be higher than or equal to 500° C., which shows that 8(βN2)-4mDBtPBfpm-d13 is a substance with high heat resistance.

In the thermogravimetry-differential thermal analysis performed under the second measurement condition, the temperature (5% weight loss temperature or decomposition temperature) at which the weight of 8(βN2)-4mDBtPBfpm-d13 obtained by thermogravimetry was reduced by 5% of the weight at the start of the measurement was found to be 315° C.

### Example 8

### Synthesis Example 2

In this synthesis example, a synthesis method of N-(biphenyl-4-yl)-N-{4-[9-(phenyl-2,3,4,5,6-d5)-9H-carbazol-3-yl-1,2,4,5,6,7,8-d7]phenyl}-9,9-dimethyl-9H-fluoren-2-amine-d4 (abbreviation: PCBBiF-d16) represented by a structural formula below is described in detail. The structural formula of PCBBiF-d16 is shown below.

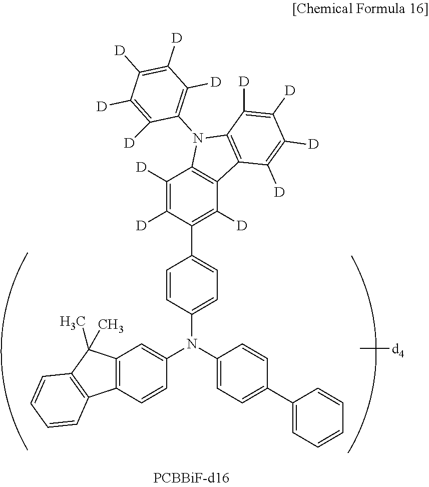

### Step 1: Synthesis of 2-amino-N-(biphenyl-4-yl)-N-(4-bromophenyl)-9,9-dimethylfluorene-d4 (abbreviation: FBiPhBr-d4)

Into a 100-mL three-neck flask equipped with a reflux pipe were put 6.0 g (11.7 mmol) of 2-amino-N-(biphenyl-4-yl)-N-(4-bromophenyl)-9,9-dimethylfluorene and 16 mL of toluene-d8, and the mixture was stirred while being heated at 70° C. to dissolve 2-amino-N-(biphenyl-4-yl)-N-(4-bromophenyl)-9,9-dimethylfluorene. After 2-amino-N-(biphenyl-4-yl)-N-(4-bromophenyl)-9,9-dimethylfluorene was completely dissolved, 3.2 g (11.7 mmol) of molybdenum(V) chloride was added little by little, and the mixture was stirred while being heated at 100° C. for 4 hours and then stirred at room temperature for 16 hours. Chloroform was added to the flask and an insoluble matter was removed by suction filtration. Water was added to the obtained filtrate and an aqueous phase was subjected to extraction with chloroform. Magnesium sulfate was added to the solution of the extract for drying, and magnesium sulfate was removed by gravity filtration. The obtained filtrate was concentrated under reduced pressure and purified by high performance liquid chromatography (mobile phase: chloroform) to give 2.3 g of a target pale yellow solid in a yield of 51%. Synthesis Scheme (B-1) of Step 1 is shown below.

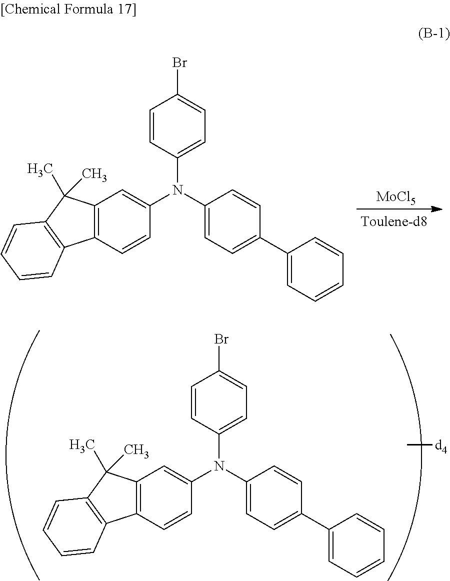

The molecular weight of the pale yellow solid obtained in Step 1 was measured by LC/MS, and a m/z of 520 was observed. The calculated mass of the target substance FBiPhBr-d4 is also 520, showing that FBiPhBr-d4 was obtained by the synthesis of Step 1.

Note that in the LC/MS analysis, liquid chromatography (LC) separation was performed with UltiMate 3000 produced by Thermo Fisher Scientific K.K., and mass spectrometry (MS) was performed with Q Exactive produced by Thermo Fisher Scientific K.K.

Next, the deuteration rate of FBiPhBr-d4 was estimated by ¹H NMR measurement.

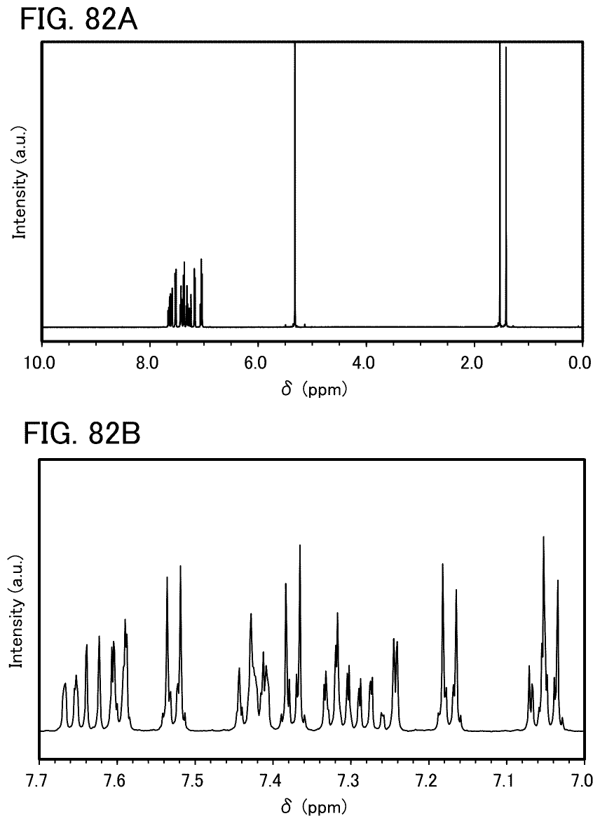

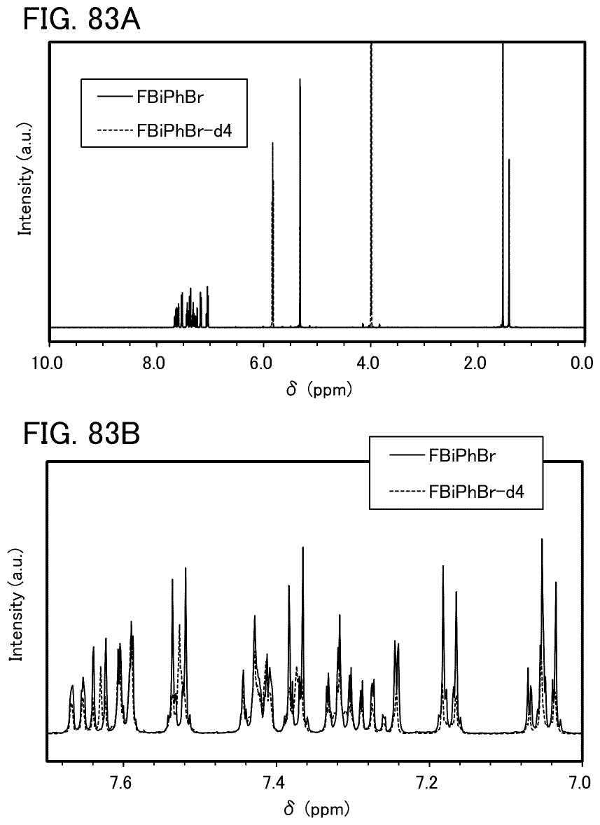

FIG. 82A shows the ¹H NMR spectrum of 2-amino-N-(biphenyl-4-yl)-N-(4-bromophenyl)-9,9-dimethylfluorene (abbreviation: FBiPhBr) that is a non-deuterated substance of FBiPhBr-d4, and FIG. 83A shows the ¹H NMR spectra of FBiPhBr-d4 and FBiPhBr, which overlap with each other. FIG. 82B is an enlarged chart of FIG. 82A in the range of δ=7.00 ppm to 7.70 ppm, and FIG. 83B is an enlarged chart of FIG. 83A in the range of δ=7.00 ppm to 7.70 ppm.

FIG. 83B shows that FBiPhBr-d4 has peaks with lower intensity than FBiPhBr at around δ=7.62 ppm to 7.67 ppm, 7.22 ppm to 7.29 ppm, 7.16 ppm to 7.18 ppm, and 7.04 ppm to 7.07 ppm, for example. These peaks are derived from protium that was not deuterated and remained in the substance synthesized in Synthesis Scheme (B-1).

With use of a peak where FBiPhBr-d4 has a lower intensity than FBiPhBr, a signal of 6=1.42 ppm (s, 6H) in FIG. 83A was normalized as the intensity of six hydrogen atoms, and the deuteration rate of FBiPhBr-d4 with respect to FBiPhBr was calculated. The results show that the deuteration rate is approximately 25% (the number of deuterium atoms corresponds to approximately 0.5 hydrogen atoms) in the range of δ=7.62 ppm to 7.67 ppm, approximately 50% (the number of deuterium atoms corresponds to approximately 1 hydrogen atom) in the range of δ=7.22 ppm to 7.29 ppm, approximately 50% (the number of deuterium atoms corresponds to approximately 1 hydrogen atom) in the range of δ=7.16 ppm to 7.18 ppm, and approximately 50% (the number of deuterium atoms corresponds to approximately 1.5 hydrogen atoms) in the range of δ=7.04 ppm to 7.07 ppm.

Accordingly, approximately four protium atoms are presumably deuterated in the whole molecule of the pale yellow solid obtained in Step 1, and the deuteration rate is estimated to be approximately 15%. This also confirms that the pale yellow solid obtained in Step 1 is FBiPhBr-d4.

The numerical data of ¹H NMR chart of the obtained solid are as follows.

1H NMR (dichloromethane-d₂, 500 MHz): δ=7.67-7.64 (m, 1.51H), 7.60 (dd, J1=7.0 Hz, J2=1.0 Hz, 2H), 7.53-7.51 (m, 2H), 7.44-7.41 (m, 3H), 7.39-7.37 (m, 2H), 7.33-7.30 (m, 2H), 7.29-7.22 (m, 1H), 7.17 (d, J=9.0 Hz, 1H), 7.07-7.04 (m, 1.51H), 1.42 (s, 6H).

### Step 2: Synthesis of PCBBiF-d16

Into a 100-mL three-neck flask equipped with a reflux pipe, 2.3 g (4.4 mmol) of 2-amino-N-(biphenyl-4-yl)-N-(4-bromophenyl)-9,9-dimethyl fluorene-d4, 1.7 g (4.4 mmol) of 9-(phenyl-2,3,4,5,6-d5)-6-(4,4,5,5-tetramethyl-1,3,2-dioxaboran-2-yl)-9H-carbazole-1,2,3,4,5,7,8-d7, 27 mg (88 μmol) of tri(o-tolyl)phosphine, 1.2 g (8.8 mmol) of potassium carbonate, 20 mL of toluene, 5 mL of ethanol, and 4.4 mL of water were put and mixed, the mixture was degassed under reduced pressure, and the air in the flask was replaced with nitrogen. To this mixture heated at 60° C. was added 10 mg (44 μmol) of palladium(II) acetate and the obtained mixture was stirred at room temperature for 3 hours. After the stirring, water was added to the flask to stop reaction. Water was added to the flask for separation into an organic phase and an aqueous phase, and then the aqueous phase was subjected to extraction with toluene. The solution of the extract and the organic phase were mixed and washed with water twice, and further washed with saturated saline. Magnesium sulfate was added to the mixture for drying, and magnesium sulfate was removed by gravity filtration. The obtained filtrate was concentrated under reduced pressure and dried in a vacuum to give 3.4 g of a brown solid. The brown solid was purified by high performance liquid chromatography (mobile phase: chloroform) to give 2.0 g of a target pale white solid in a yield of 68%. Synthesis Scheme (B-2) of Step 2 is shown below.

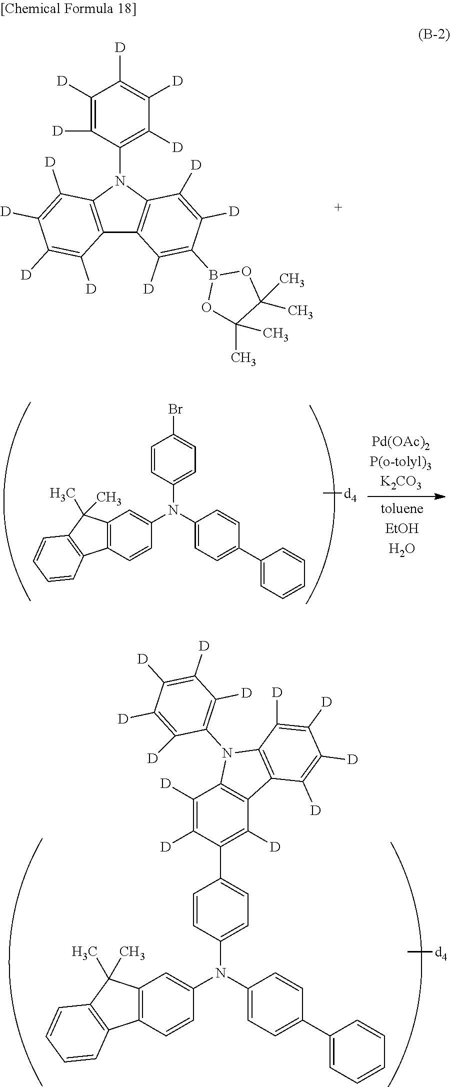

By a train sublimation method, 1.3 g of the obtained solid was purified. In the purification by sublimation, the solid was heated at 290° C. to 300° C. under a pressure of 2.4 Pa with an argon flow rate of 16 mL/min for 19 hours, and a solid precipitated at 230° C. was collected. As a result, 1.1 g of a target pale yellow solid was obtained at a collection rate of 85%.

The molecular weight of the pale yellow solid obtained in Step 2 was measured by LC/MS, and a m/z of 694 was observed. The calculated mass of the target substance PCBBiF-d16 is also 694, showing that PCBBiF-d16 was obtained by the synthesis of Step 2.

The deuteration rate of PCBBiF-d16 was estimated by ¹H NMR measurement.

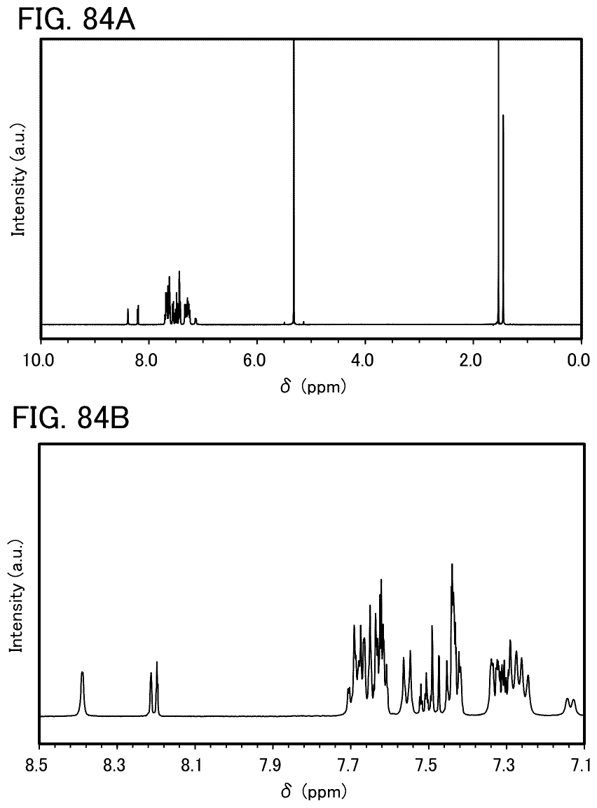

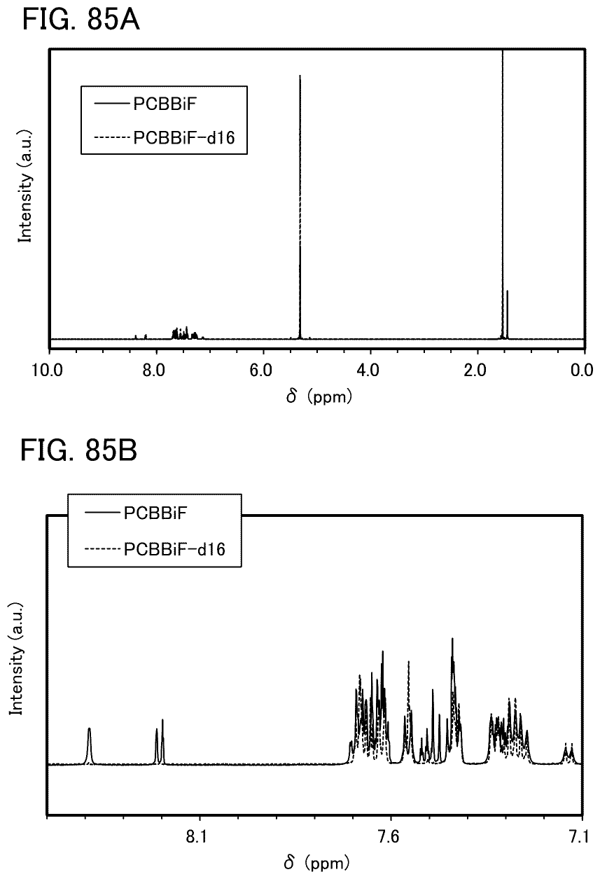

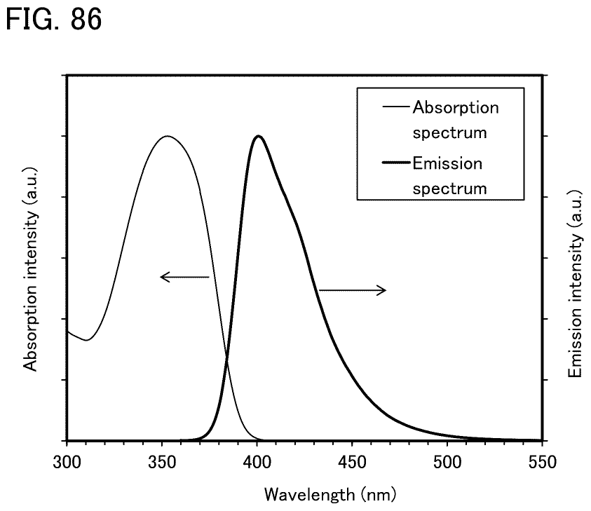

FIG. 84A shows the ¹H NMR spectrum of N-(biphenyl-4-yl)-N-[4-(9-phenyl-9H-carbazol-3-yl-1,2,4,5,6,7,8-d7)phenyl]-9,9-dimethyl-9H-fluorene-2-amine (abbreviation: PCBBiF) that is a non-deuterated substance of PCBBiF-d16, and FIG. 85A shows the ¹H NMR spectra of PCBBiF-d16 and PCBBiF, which overlap with each other. FIG. 84B is an enlarged chart of FIG. 84A in the range of δ=7.10 ppm to 8.50 ppm, and FIG. 85B is an enlarged chart of FIG. 85A in the range of δ=7.10 ppm to 8.50 ppm.

FIG. 85B shows that PCBBiF-d16 has peaks with lower intensity than PCBBiF at around δ=7.62 ppm to 7.70 ppm, 7.42 ppm to 7.45 ppm, 7.24 ppm to 7.34 ppm, and 7.13 ppm to 7.14 ppm, for example. These peaks are derived from protium that was not deuterated and remained in the substance synthesized in Synthesis Scheme (B-2).

With use of a peak where PCBBiF-d16 has a lower intensity than PCBBiF, a signal of δ=1.45 ppm (s, 6H) in the ¹H-NMR chart of PCBBiF was normalized as the intensity of six hydrogen atoms, and the deuteration rate of PCBBiF-d16 with respect to PCBBiF was calculated. The results show that the deuteration rate is approximately 50% (the number of deuterium atoms corresponds to approximately 5.5 hydrogen atoms) in the range of δ=7.62 ppm to 7.70 ppm, approximately 40% (the number of deuterium atoms corresponds to approximately 2 hydrogen atoms) in the range of δ=7.42 ppm to 7.45 ppm, approximately 45% (the number of deuterium atoms corresponds to approximately 4 hydrogen atoms) in the range of δ=7.24 ppm to 7.34 ppm, and approximately 50% (the number of deuterium atoms corresponds to approximately 0.5 hydrogen atoms) in the range of δ=7.13 ppm to 7.14 ppm. In addition, the peaks at around 8.20 ppm to 8.39 ppm and around 7.47 ppm to 7.52 ppm substantially disappear, which indicates that the deuteration rate at 8.20 ppm to 8.39 ppm is approximately 100% (the number of deuterium atoms corresponds to approximately 2 hydrogen atoms), and the deuteration rate at 7.47 ppm to 7.52 ppm is also approximately 100% (the number of deuterium atoms corresponds to approximately 2 hydrogen atoms).

Accordingly, it is presumable that there are approximately 16 deuterium atoms in the whole molecule of the pale yellow solid obtained in Step 2, and the deuteration rate is estimated to be approximately 44%.

The numerical data of ¹H NMR chart of the obtained solid are as follows.

¹H NMR (dichloromethane-d₂, 500 MHz): δ=7.70-7.62 (m, 5.5H), 7.56-7.55 (m, 2H), 7.45-7.42 (m, 3H), 7.34-7.24 (m, 5H), 7.13 (d, J=8.0 Hz, 0.5H), 1.45 (s, 6H).

### <Measurement of Physical Properties>

Next, the absorption spectra and the PL spectra of PCBBiF-d16 in a toluene solution and a thin film of PCBBiF-d16 were measured.

The absorption spectra and the PL spectra were measured in a manner similar to that in Example 7.

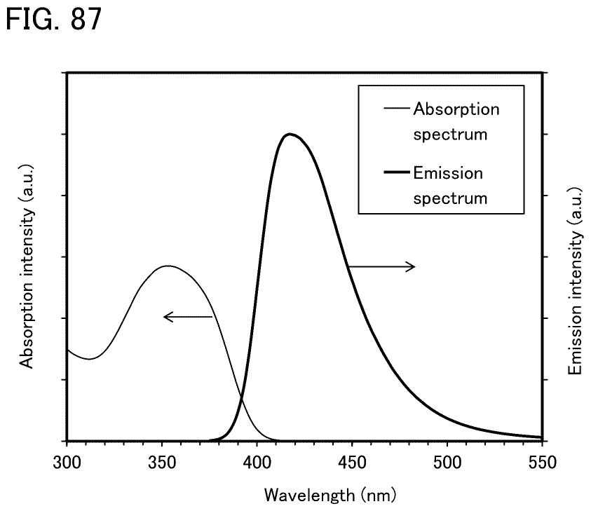

FIGS. 86 and 87 show the measurement results of the toluene solution and the thin film, respectively. The measurement results show that PCBBiF-d16 in the toluene solution has an absorption peak at around 353 nm, the thin film of PCBBiF-d16 has an absorption peak at around 374 nm, and there is no absorption band on a longer wavelength side than 430 nm in both cases of the toluene solution and the thin film. This reveals that in the case where PCBBiF-d16 is used as a light-emitting element, a reduction in emission efficiency caused by absorption does not occur at a wavelength used in a display and thus PCBBiF-d16 can be suitably used. In addition, PCBBiF-d16 in the toluene solution exhibited an emission peak at around 401 nm (excitation wavelength: 353 nm), and the thin film of PCBBiF-d16 exhibited an emission peak at around 417 nm (excitation wavelength: 365 nm).

The HOMO level and the LUMO level of PCBBiF-d16 were obtained through a cyclic voltammetry (CV) measurement. The measurement and calculation methods were similar to those in Example 7.

As a result, in the measurement of the oxidation potential Ea [V] of PCBBiF-d16, the HOMO level was −5.35 eV. In contrast, the LUMO level was found to be −2.0 eV in the measurement of the reduction potential Ec [V]. In addition, the results of repetitive measurement of the oxidation-reduction wave showed that when the waveform of the first cycle was compared with that of the 100th cycle, 90% of the peak intensity were maintained in the Ea measurement, which confirmed that PCBBiF-d16 had high resistance to repetitive reduction.

Furthermore, differential scanning calorimetry (DSC measurement) of PCBBiF-d16 was performed. The measurement method is similar to that in Example 7. The results show that the glass transition point of PCBBiF-d16 is 129° C. This indicates that PCBBiF-d16 is a substance having extremely high heat resistance and the film of PCBBiF-d16 can maintain a thermally stable quality.

Furthermore, thermogravimetry-differential thermal analysis was performed on PCBBiF-d16. The measurement method is similar to that in Example 7.

In the thermogravimetry-differential thermal analysis performed under the first measurement condition (atmospheric pressure), the temperature (decomposition temperature) at which the weight of PCBBiF-d16 obtained by thermogravimetry was reduced by 5% of the weight at the start of the measurement was found to be 455° C., which shows that PCBBiF-d16 is a substance with high heat resistance.

In the thermogravimetry-differential thermal analysis performed under the second measurement condition (10 Pa), the temperature (decomposition temperature) at which the weight of PCBBiF-d16 obtained by thermogravimetry was reduced by 5% of the weight at the start of the measurement was found to be 265° C.

This application is based on Japanese Patent Application Serial No. 2023-203482 filed with Japan Patent Office on Nov. 30, 2023, the entire contents of which are hereby incorporated by reference.

What is claimed is:

1. A light-emitting device comprising:
a first electrode;
a second electrode; and
a light-emitting layer,
wherein the light-emitting layer is between the first electrode and the second electrode,
wherein the light-emitting layer comprises a first organic compound, a second organic compound, and a substance capable of converting triplet excitation energy into light emission,
wherein the first organic compound comprises π-electron deficient heteroaromatic ring,
wherein the second organic compound comprises a π-electron rich heteroaromatic ring or an aromatic amine skeleton,
wherein the first organic compound and the second organic compound each comprise deuterium, and
wherein a difference between a lowest triplet excitation level of the first organic compound and a lowest triplet excitation level of the second organic compound is less than or equal to 0.20 eV.

2. A light-emitting device comprising:
a first electrode;
a second electrode; and
a light-emitting layer,
wherein the light-emitting layer is between the first electrode and the second electrode,
wherein the light-emitting layer comprises a first organic compound, a second organic compound, and a substance capable of converting triplet excitation energy into light emission,
wherein the first organic compound comprises a π-electron deficient heteroaromatic ring,
wherein the second organic compound comprises a π-electron rich heteroaromatic ring or an aromatic amine skeleton,
wherein the first organic compound and the second organic compound each comprise deuterium,
wherein a combination of the first organic compound and the second organic compound forms an exciplex, and
wherein an emission spectrum of the exciplex and an emission spectrum of the substance capable of converting triplet excitation energy into light emission overlap with each other.

3. The light-emitting device according to claim 2, wherein a difference between a maximum peak wavelength in the emission spectrum of the exciplex and a maximum peak wavelength in the emission spectrum of the substance capable of converting triplet excitation energy into light emission is less than or equal to 30 nm.

4. The light-emitting device according to claim 1,
wherein a phosphorescence lifetime or a delayed fluorescence lifetime at 77 K of the first organic compound is 1.20 times or more a phosphorescence lifetime or a delayed fluorescence lifetime at 77 K of a third organic compound being a non-deuterated substance of the first organic compound, and
wherein a phosphorescence lifetime or a delayed fluorescence lifetime at 77 K of the second organic compound is 1.05 times or more a phosphorescence lifetime or a delayed fluorescence lifetime at 77 K of a fourth organic compound being a non-deuterated substance of the second organic compound.

5. The light-emitting device according to claim 4, wherein an emission spectrum of the substance capable of converting triplet excitation energy into light emission has a peak wavelength greater than or equal to 450 nm and less than 500 nm.

6. The light-emitting device according to claim 1,
wherein a phosphorescence lifetime or a delayed fluorescence lifetime at 77 K of the first organic compound is 1.50 times or more a phosphorescence lifetime or a delayed fluorescence lifetime at 77 K of a third organic compound being a non-deuterated organic compound of the first organic compound, and
wherein a phosphorescence lifetime or a delayed fluorescence lifetime at 77 K of the second organic compound is 3.00 times or more a phosphorescence lifetime or a delayed fluorescence lifetime at 77 K of a fourth organic compound being a non-deuterated organic compound of the second organic compound.

7. The light-emitting device according to claim 6, wherein an emission spectrum of the substance capable of converting triplet excitation energy into light emission has a peak wavelength greater than or equal to 500 nm and less than or equal to 600 nm.

8. The light-emitting device according to claim 1,
wherein in the case where a phosphorescence lifetime or a delayed fluorescence lifetime at 77 K of the first organic compound is X times a phosphorescence lifetime or a delayed fluorescence lifetime at 77 K of a third organic compound being a non-deuterated substance of the first organic compound and a phosphorescence lifetime or a delayed fluorescence lifetime at 77 K of the second organic compound is Y times a phosphorescence lifetime or a delayed fluorescence lifetime at 77 K of a fourth organic compound being a non-deuterated substance of the second organic compound, a product of X and Y is greater than or equal to 1.26.

9. The light-emitting device according to claim 1,
wherein an emission spectrum of the substance capable of converting triplet excitation energy into light emission has a peak wavelength greater than or equal to 500 nm and less than or equal to 600 nm, and
wherein in the case where a phosphorescence lifetime or a delayed fluorescence lifetime at 77 K of the first organic compound is X times a phosphorescence lifetime or a delayed fluorescence lifetime at 77 K of a third organic compound being a non-deuterated substance of the first organic compound and a phosphorescence lifetime or a delayed fluorescence lifetime at 77 K of the second organic compound is Y times a phosphorescence lifetime or a delayed fluorescence lifetime at 77 K of a fourth organic compound being a non-deuterated substance of the second organic compound, a product of X and Y is greater than or equal to 4.50.

10. A light-emitting device comprising:
a first electrode;
a second electrode; and
a light-emitting layer,
wherein the light-emitting layer is between the first electrode and the second electrode,
wherein the light-emitting layer comprises a first organic compound, a second organic compound, and a substance capable of converting triplet excitation energy into light emission,
wherein the first organic compound comprises a π-electron deficient heteroaromatic ring,
wherein the second organic compound comprises a π-electron rich heteroaromatic ring or an aromatic amine skeleton,
wherein the first organic compound and the second organic compound each comprise deuterium, and
wherein a difference between a 5% weight loss temperature of the first organic compound at 10 Pa and a 5% weight loss temperature of the second organic compound at 10 Pa is less than or equal to 60° C.

11. The light-emitting device according to claim 1, wherein the substance capable of converting triplet excitation energy into light emission is a phosphorescent substance.

12. The light-emitting device according to claim 1, wherein a combination of the first organic compound and the second organic compound forms an exciplex.

13. The light-emitting device according to claim 1,
wherein the first organic compound comprises a diazine skeleton or a triazine skeleton, and
wherein the second organic compound comprises a bicarbazole skeleton.

14. The light-emitting device according to claim 2, wherein the substance capable of converting triplet excitation energy into light emission is a phosphorescent substance.

15. The light-emitting device according to claim 2,
wherein the first organic compound comprises a diazine skeleton or a triazine skeleton, and
wherein the second organic compound comprises a bicarbazole skeleton.

16. The light-emitting device according to claim 10, wherein the substance capable of converting triplet excitation energy into light emission is a phosphorescent substance.

17. The light-emitting device according to claim 10, wherein a combination of the first organic compound and the second organic compound forms an exciplex.

18. The light-emitting device according to claim 10,
wherein the first organic compound comprises a diazine skeleton or a triazine skeleton, and
wherein the second organic compound comprises a bicarbazole skeleton.
